(19) United States
(12) Patent Application Publication
(10) Pub. No.: US 2023/0348508 A1
(43) Pub. Date: Nov. 2, 2023

(54) METAL COMPLEX, ORGANIC ELECTROLUMINESCENT ELEMENT COMPRISING SAME, AND CONSUMER PRODUCT

(71) Applicant: BEIJING BAYI SPACE LIQUID CRYSTAL TECHNOLOGY CO. LTD., Beijing (CN)

(72) Inventors: Jianhua CAO, Beijing (CN); Bo Zhu, Beijing (CN); Wei Tang, Beijing (CN); Xianfeng Xu, Beijing (CN); Zhijie Wang, Beijing (CN); Chenghui Li, Beijing (CN); Zhenyu Wang, Beijing (CN)

(21) Appl. No.: 18/307,251

(22) Filed: Apr. 26, 2023

(30) Foreign Application Priority Data
Apr. 29, 2022 (CN) 202210465965.2

(51) Int. Cl. C07F 15/00; H10K 85/30

(52) U.S. Cl. CPC C07F 15/0033; H10K 85/342; C07B 2200/05

(57) ABSTRACT

The present invention relates to a metal complex, an organic electroluminescent element containing same, and a consumer product. The metal complex of the present invention is used as a luminescent material to obtain a green phosphorescent material with a high luminescent efficiency. In addition, the prepared luminescent material has a good thermal stability. The organic electroluminescent element of the present invention emits a green phosphorescence and has advantages of a narrow emission spectrum, a high stability, and a high efficiency. An electronic device comprising the organic electroluminescent element of the present invention can enable a consumer product having green electroluminescence and an improved luminous efficiency.

### TECHNICAL FIELD

The present invention belongs to the technical field of luminescent materials and particularly relates to a metal complex, an organic electroluminescent element containing same, and a consumer product.

### BACKGROUND ART

Currently, optoelectronic devices using an organic material become increasingly popular. Besides, many materials used to manufacture the devices are relatively inexpensive. Therefore, the organic optoelectronic device has a potential in terms of cost advantage over an inorganic device. In addition, the inherent properties (e.g., flexibility) of the organic material may make it more suitable for a particular application, such as manufacture on a flexible substrate. Examples of the organic optoelectronic device comprise an organic light emitting diode/device (OLED), an organic phototransistor, an organic photovoltaic cell, and an organic photodetector. With regard to the OLED, the organic material may have a performance advantage over a conventional material.

The OLED utilizes an organic thin film that emits a light when a voltage is applied in the device. The OLED is becoming an increasingly interesting technology for use in a flat-panel display, lighting, and backlighting.

One application of phosphorescent emission molecules is a full-color display. Industry standards for such displays require pixels adapted to emit a particular color. In particular, these standards require saturated red, green, and blue pixels. Alternatively, the OLED may be designed to emit a white light. In a conventional liquid crystal display, an absorption filter is used to filter emission from a white backlight to produce red, green, and blue emission. The same technology may also be used for the OLED. The white OLED may be a single emitting layer (EML) device or a stacked structure. The color may be measured by using a CIE coordinate well known in the art. The luminescent material in the prior art has a poor luminescent stability and a low luminescent efficiency.

In view of the above reasons, the present invention is specifically proposed.

### SUMMARY OF THE INVENTION

In order to solve the above problems existing in the prior art, the present invention provides a metal complex, an organic electroluminescent element containing same, and a consumer product. When used in OLED, particularly a green emission region, the metal complex of the present invention shows an enhanced phosphorescent quantum yield.

A first object of the present invention is to provide a metal complex with an electroluminescent stability and a high luminescent efficiency.

A second object of the present invention is to provide an organic electroluminescent element made from the metal complex.

A third object of the present invention is to provide a consumer product made from the organic electroluminescent element.

In order to achieve the objects, in the present invention the following technical solutions are used:

a metal complex comprises a ligand shown in a formula (LA):

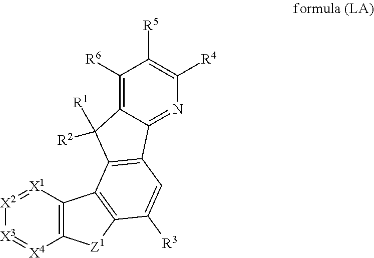

wherein X¹, X², X³, and X⁴ are each independently selected from N or CR⁷;

Z¹ is selected from O, S, CR⁸R⁹, NR⁸, SiR⁸R⁹, C(R⁸R⁹)—C(R⁸R⁹), C(R⁸)═C(R⁹), N═CR⁹, CR⁸═N, NR⁸—CR⁸R⁹, CR⁸R⁹—NR⁹, OCR⁸R⁹, SCR⁸R⁹, CR⁸R⁹O, CR⁸R⁹S, or GeR⁸R⁹;

R¹-R⁹ are identically or differently, at each occurrence, selected from the group consisting of hydrogen, deuterium, a halogen atom, C₁-C₄₀ alkyl, C₃-C₄₀ cycloalkyl, C₁-C₄₀ heteroalkyl, C₃-C₄₀ heterocycloalkyl, C₆-C₆₀ aralkyl, C₁-C₄₀ alkoxy, C₆-C₆₀ aryloxy, amino, C₃-C₄₀ silyl, C₂-C₄₀ alkenyl, C₅-C₄₀ cycloalkenyl, C₃-C₄₀ heteroalkenyl, C₂-C₄₀ alkynyl, C₆-C₆₀ aryl, C₂-C₆₀ heteroaryl, C₁-C₄₀ acyl, a carboxylic acid group, ether, an ester group, a nitrile group, an isonitrile group, thio, sulfinyl, sulfonyl, and phosphino; any two or more adjacent substituents are optionally joined or fused together to form a substituted or unsubstituted five-membered, six-membered or multiple-membered ring;

the metal complex is a five-membered chelate ring formed by the coordination of the ligand shown in the formula (LA) with a metal of M;

the metal complex further comprises other ligands and the ligand shown in the formula (LA) is connected with other ligands to form a tridentate, tetradentate, pentadentate or hexadentate ligand; and

the M is selected from one of Os, Ir, Pd, Pt, Cu, Ag, and Au, and preferably, the M is selected from one of Ir, Pd or Pt.

Further, the formula (LA) comprises one of the following structures LAI-LAXV:

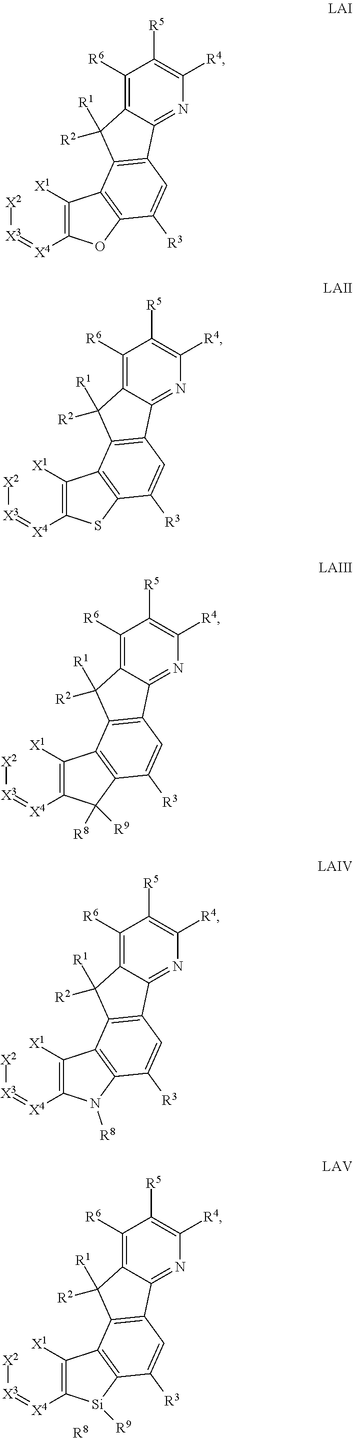

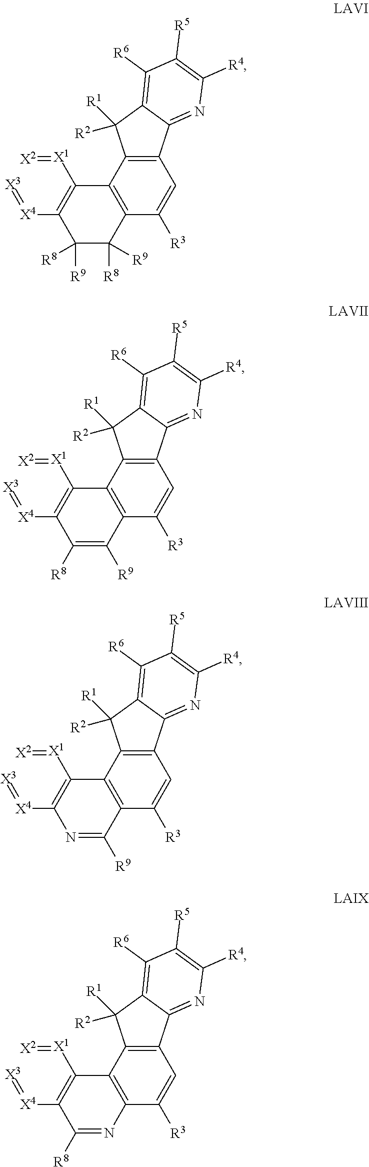

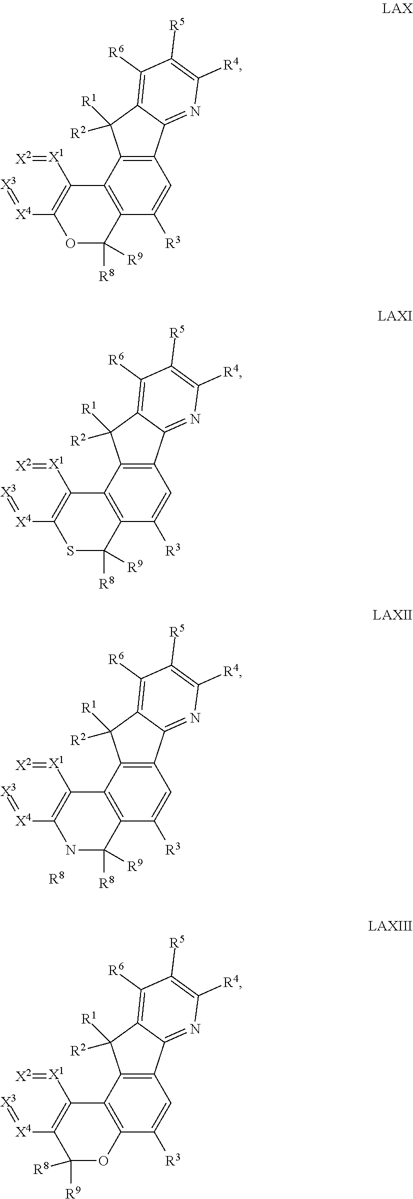

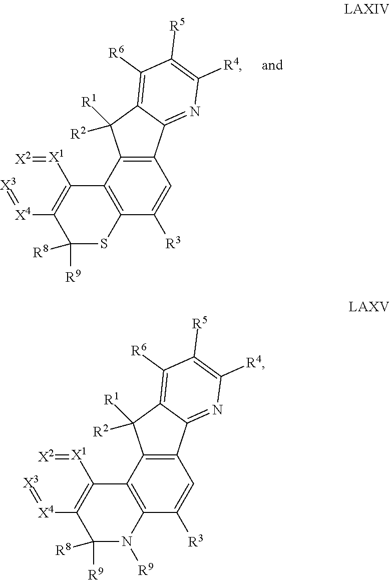

wherein meanings of R¹-R⁶, the R⁸, the R⁹, and X¹-X⁴ are the same as the above definitions, and each R⁸ and R⁹ is the same or different.

Further, the metal complex has a chemical formula of M(LA)ₚ(LB)_{q}, wherein the LB is a bidentate ligand, the p is 1, 2 or 3, the q is 0, 1 or 2, and p+q is equal to an oxidation state of the metal M; preferably, the LB is selected from one of the following structures:

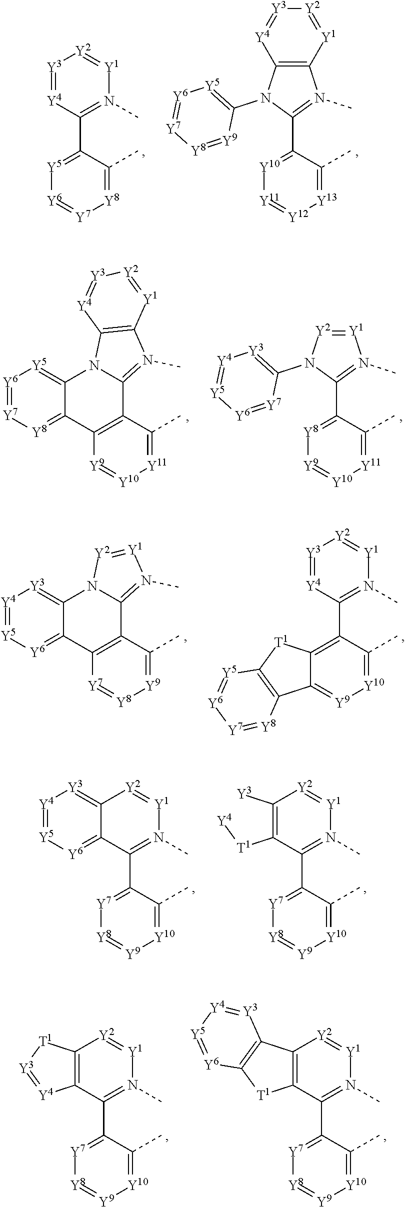

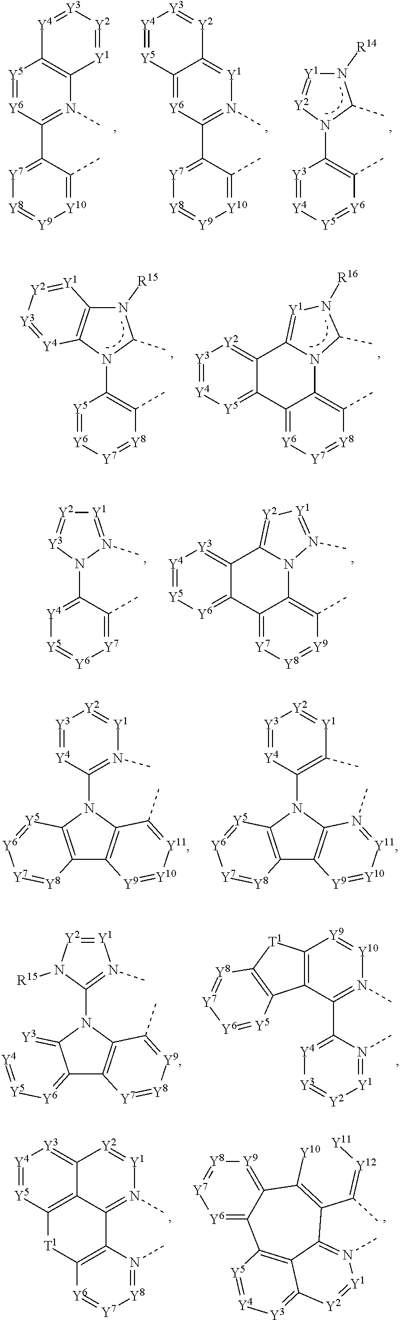

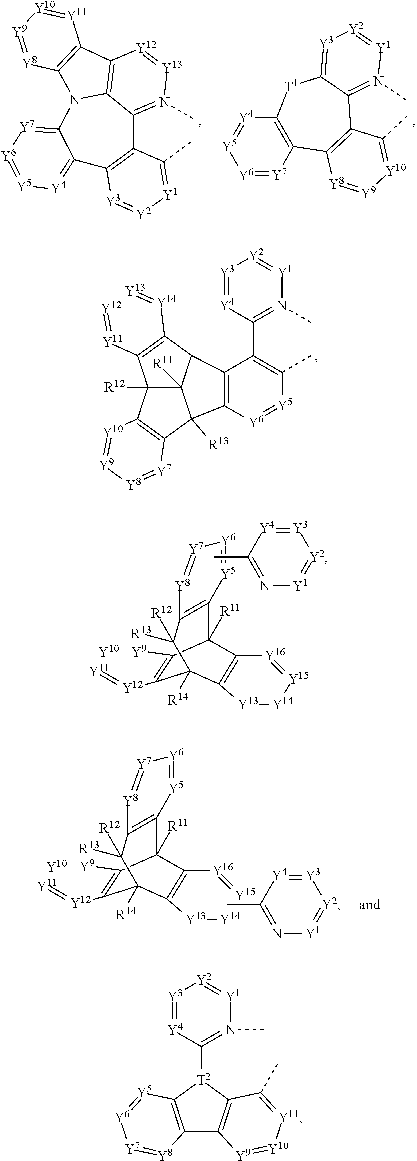

wherein Y¹-Y¹⁶ are each independently selected from N or CR¹⁰, T¹ is selected from one of BR¹², NR¹³, PR¹⁴, O, S, Se, C═O, S═O, SO₂, CR¹²R¹³, SiR¹²R¹³, and GeR¹²R¹³, and the R¹² and the R¹³ is arbitrarily joined or fused to form a ring; T² is selected from N, B, SiR¹², P or P═O;

the R¹⁰, R¹¹, the R¹², the R¹³, the R¹⁴, R¹⁵, and R¹⁶ are each independently selected from the group consisting of hydrogen, deuterium, a halogen atom, C₁-C₄₀ alkyl, C₃-C₄₀ cycloalkyl, C₁-C₄₀ heteroalkyl, C₃-C₄₀ heterocycloalkyl, C₆-C₆₀ aralkyl, C₁-C₄₀ alkoxy, C₆-C₆₀ aryloxy, amino, C₃-C₄₀ silyl, C₂-C₄₀ alkenyl, C₅-C₄₀ cycloalkenyl, C₃-C₄₀ heteroalkenyl, C₂-C₄₀ alkynyl, C₆-C₆₀ aryl, C₂-C₆₀ heteroaryl, C₁-C₄₀ acyl, a carboxylic acid group, ether, an ester group, a nitrile group, an isonitrile group, thio, sulfinyl, sulfonyl, and phosphino; and any two or more adjacent substituents are optionally joined or fused together to form a substituted or unsubstituted five-membered, six-membered or multiple-membered ring.

With regard to the oxidation state of the metal M, when the M is Ir, the oxidation valence of Ir may be 3, and when the M is Pt, the oxidation valence of Pt may be 2.

The “halo”, “halogen”, “halogen atom”, and “halogeno” in the sense of the present invention are used interchangeably and mean fluorine, chlorine, bromine or iodine.

The “acyl” in the sense of the present invention means a substituted carbonyl group (COR).

The “ester” in the sense of the present invention means a substituted oxycarbonyl group (—OCOR or CO₂R).

The “ether” in the sense of the present invention means an —OR group.

The “thio” or the “thioether” described herein are used interchangeably and mean an —SR group.

The “sulfinyl” in the sense of the present invention means an —SOR group.

The “sulfonyl” in the sense of the present invention means an —SO₂R group.

The “phosphino” in the sense of the present invention means a —PR₃ group, wherein each R may be the same or different.

The “silyl” in the sense of the present invention means an —SiR₃ group, wherein each R may be the same or different.

Each of the above R is preferably selected from the group consisting of alkyl, cycloalkyl, aryl, and heteroaryl.

The “alkyl”, the “alkenyl” or the “alkynyl” in the sense of the present invention are preferably to be considered as the following groups: methyl, ethyl, n-propyl, isopropyl, n-butyl, isobutyl, sec-butyl, tert-butyl, 2-methylbutyl, n-pentyl, sec-pentyl, neopentyl, cyclopentyl, n-hexyl, neohexyl, cyclohexyl, n-heptyl, cycloheptyl, n-octyl, cyclooctyl, 2-ethylhexyl, cyclohexenyl, heptenyl, cycloheptenyl, octenyl, cyclooctenyl, ethynyl, propynyl, butynyl, pentynyl, hexynyl, heptynyl or octynyl.

The “alkoxy” in the sense of the present invention is preferably alkoxy having 1-40 carbon atoms and is considered as methoxy, trifluoromethoxy, ethoxy, n-propoxy, isopropoxy, n-butoxy, isobutoxy, sec-butoxy, tert-butoxy, n-pentyloxy, sec-pentyloxy, 2-methylbutoxy, n-hexyloxy, cyclohexyloxy, n-heptyloxy, cycloheptyloxy, n-octyloxy, cyclooctyloxy, 2-ethylhexyloxy, pentafluoroethoxy, and 2,2,2-trifluoroethoxy.

In general, the “cycloalkyl” and the “cycloalkenyl” according to the present invention mean and comprise monocyclic, polycyclic, and spiroalkyl groups. Preferably, the cycloalkyl is cycloalkyl having 3-15 cyclic carbon atoms, and may be cyclopropyl, cyclobutyl, cyclopentyl, cyclohexyl, cyclobutenyl, cyclopentenyl, cyclohexenyl, cycloheptyl, cycloheptenyl, bicyclo[3.1.1]heptyl, spiro[4.5]decyl, spiro[5.5]undecyl, adamantyl, etc., wherein one or more —CH₂— groups may be substituted with the above groups. In addition, one or more hydrogen atoms may also be substituted with a deuterium atom, a halogen atom or a nitrile group.

The “heteroalkyl” or the “heterocycloalkyl” in the sense of the present invention respectively means alkyl or cycloalkyl, preferably alkyl or cycloalkyl having 1-40 carbon atoms, and refers to a group wherein an individual hydrogen atom or a —CH₂— group may be substituted with oxygen, sulfur, a halogen atom, nitrogen, phosphorus, boron, silicon or selenium, preferably a group substituted with oxygen, sulfur or nitrogen. In addition, the heteroalkyl or the heterocycloalkyl may be optionally substituted.

The “heteroalkenyl” or the “heterocycloalkenyl” in the sense of the present invention means alkenyl or cycloalkenyl wherein at least one carbon atom is replaced by a heteroatom. Optionally, the at least one heteroatom is selected from oxygen, sulphur, nitrogen, phosphorus, boron, silicon or selenium, preferably oxygen, sulphur or nitrogen. The preferred, alkenyl and the cycloalkenyl are those containing 3-15 carbon atoms. In addition, the heteroalkenyl and the heterocycloalkenyl may be optionally substituted.

The “aralkyl” or the “arylalkyl” in the sense of the present invention can be used interchangeably and means alkyl substituted with aryl. In addition, the aralkyl may be optionally substituted.

The “aryl” according to the present invention means and comprises a monocyclic aromatic hydrocarbon group and a polycyclic aromatic ring system. The polycyclic ring may have two or more rings in which two carbons are commonly used in two adjoining rings (the rings are “fused”), wherein at least one of the rings is an aromatic hydrocarbon group, e.g., the other rings may be cycloalkyl, cycloalkenyl, aryl, heterocycle, and/or heteroaryl. The preferred aryl is aryl containing 6-30 carbon atoms, preferably 6-20 carbon atoms, and more preferably 6-12 carbon atoms. The especially preferred aryl is aryl with six carbons, ten carbons, or twelve carbons. Suitable aryl comprises phenyl, biphenyl, terphenyl, triphenylene, tetraphenylene, naphthalene, anthracene, phenalene, phenanthrene, fluorene, pyrene, perylene, chrysene, and azulene, preferably phenyl, biphenyl, terphenyl, triphenylene, fluorene, and naphthalene. In addition, the aryl may be optionally substituted.

The “heteroaryl” in the sense of the present invention means and comprises a monocyclic aromatic group and a polycyclic aromatic ring system comprising at least one heteroatom. The heteroatom includes but is not limited to oxygen, sulfur, nitrogen, phosphorus, boron, silicon, or selenium. In many cases, the oxygen, sulfur or nitrogen are preferred heteroatoms. The monocyclic heteroaromatic system is preferably a monocyclic ring with 5 or 6 ring atoms, and the ring may have one to six heteroatoms. The heteropolycyclic system may have two or more rings in which two atoms are commonly used in two adjoining rings (the rings are “fused”), wherein at least one of the rings is heteroaryl, e.g., the other rings may be cycloalkyl, cycloalkenyl, aryl, heterocycle, and/or heteroaryl. The heteropolyaromatic ring system may have one to six heteroatoms in each ring of the polycyclic aromatic ring system. The preferred heteroaryl is heteroaryl containing three to thirty carbon atoms, preferably three to twenty carbon atoms, more preferably three to twelve carbon atoms. The suitable heteroaryl comprises dibenzothiophene, dibenzofuran, dibenzoselenophene, furan, thiophene, benzofuran, benzothiophene, benzoselenophene, carbazole, indolocarbazole, pyridylindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, phenoxazine, benzofuropyridine, furodipyridine, benzothienopyridine, thienodipyridine, benzoselenenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and an aza analog thereof. In addition, the heteroaryl may be optionally substituted.

In many cases, the substituents are generally selected from the group consisting of deuterium, halogen, alkyl, cycloalkyl, heteroalkyl, heterocycloalkyl, aralkyl, alkoxy, aryloxy, amino, silyl, alkenyl, cycloalkenyl, heteroalkenyl, alkynyl, aryl, heteroaryl, acyl, carboxylic acid, ether, ester, nitrile, isonitrile, thio, sulfinyl, sulfonyl, and phosphino.

As used herein, “a combination thereof” or “group” means that one or more members of an applicable list are combined to form a known or chemically stable arrangement that a person of ordinary skill in the art may envisaged from the applicable list. For example, the alkyl and the deuterium may be combined to form a partially or fully deuterated alkyl. The halogen and the alkyl may combine to form a haloalkyl substituent such as trifluoromethyl and the like. The halogen, the alkyl, and the aryl may be combined to form haloaralkyl.

In one example, the term substitution comprises a combination of two to four of the listed groups.

In another example, the term substitution comprises a combination of two to three groups. In yet another example, the term substitution comprises a combination of two groups. A preferred combination of substituents is a combination containing up to fifty atoms other than hydrogen or deuterium, or a combination containing up to forty atoms other than hydrogen or deuterium, or a combination containing up to thirty atoms other than hydrogen or deuterium. In many cases, a preferred combination of the substituents will contain up to twenty atoms other than hydrogen or deuterium.

Further, the R¹, the R², the R³, the R⁴, the R⁵, the R⁶, the R⁷, the R⁸, the R⁹, the R¹⁰, the R¹¹, the R¹², the R¹³, the R¹⁴, the R¹⁵, and the R¹⁶, at each occurrence, are each independently selected from the group consisting of a hydrogen atom, a deuterium atom, a fluorine atom, a nitrile group, R^{A1}-R^{A55}, R^{B1}-R^{B45}, and R^{C1}-R^{C295},

wherein the R^{A1}-R^{A55} have structural formulas as follows:

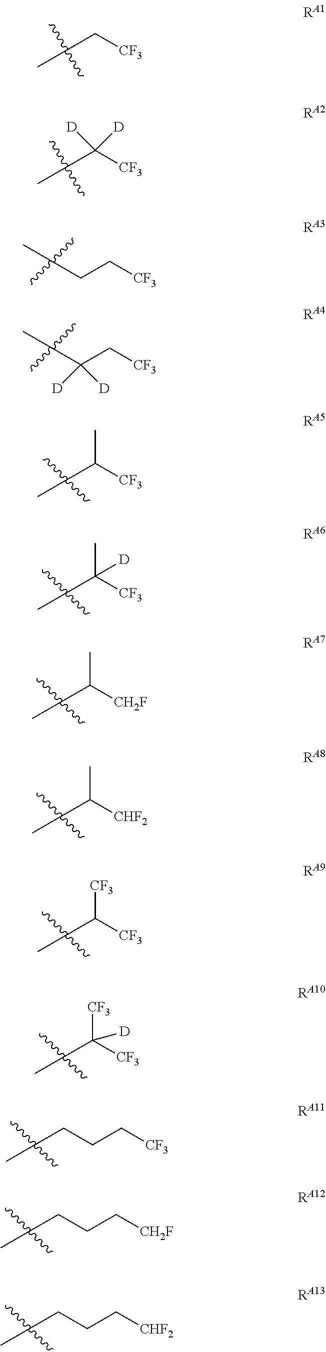

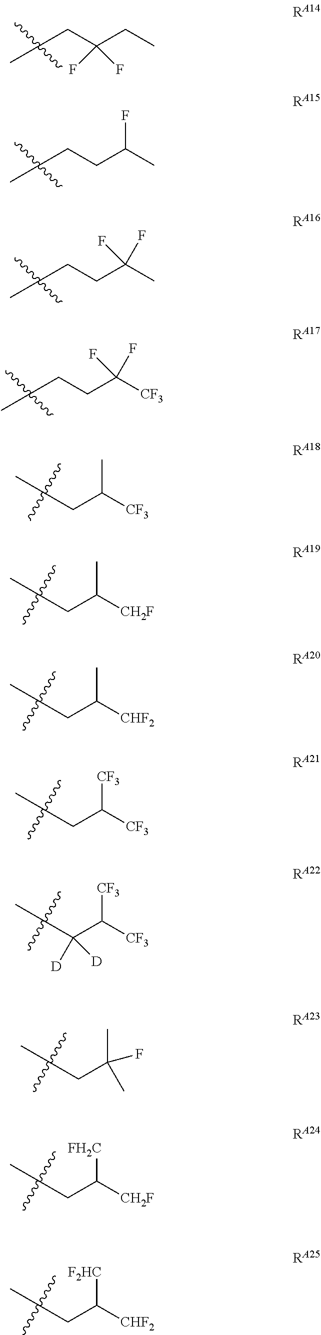

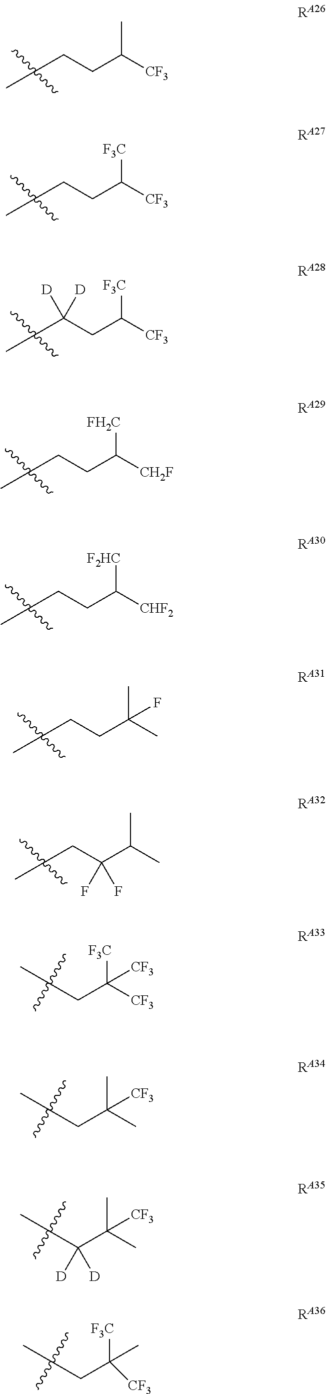

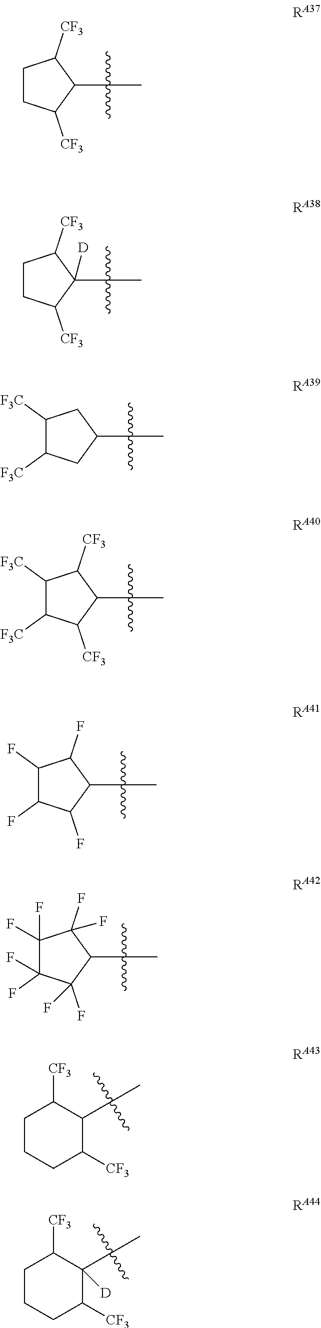

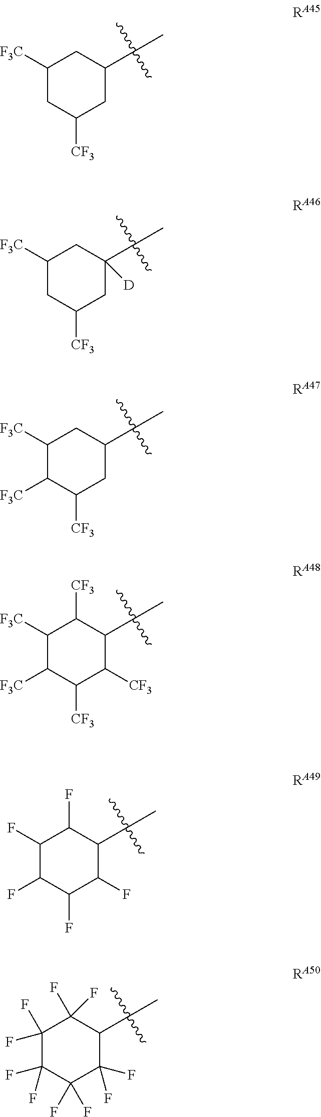 [SMILES: *C1CC(C(F)(F)F)CC(C(F)(F)F)C1 ; *C1([2H])CC(C(F)(F)F)CC(C(F)(F)F)C1 ; *C1CC(C(F)(F)F)C(C(F)(F)F)C(C(F)(F)F)C1 ; *C1C(C(F)(F)F)C(C(F)(F)F)C(C(F)(F)F)C(C(F)(F)F)C1C(F)(F)F ; *C1C(F)C(F)C(F)C(F)C1F ; *C1C(F)(F)C(F)(F)C(F)(F)C(F)(F)C1(F)F]

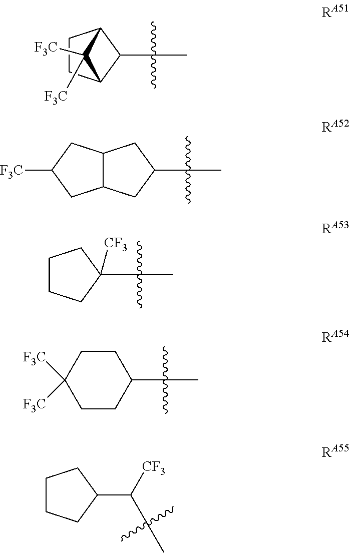 [SMILES: *C1[C@H]2CC[C@@H]1C2(C(F)(F)F)C(F)(F)F ; *C1CC2CC(C(F)(F)F)CC2C1 ; *C1(C(F)(F)F)CCCC1 ; *C1CCC(C(F)(F)F)(C(F)(F)F)CC1 ; *C(C1CCCC1)C(F)(F)F]

the R^{B1}-R^{B45} have structural formulas as follows:

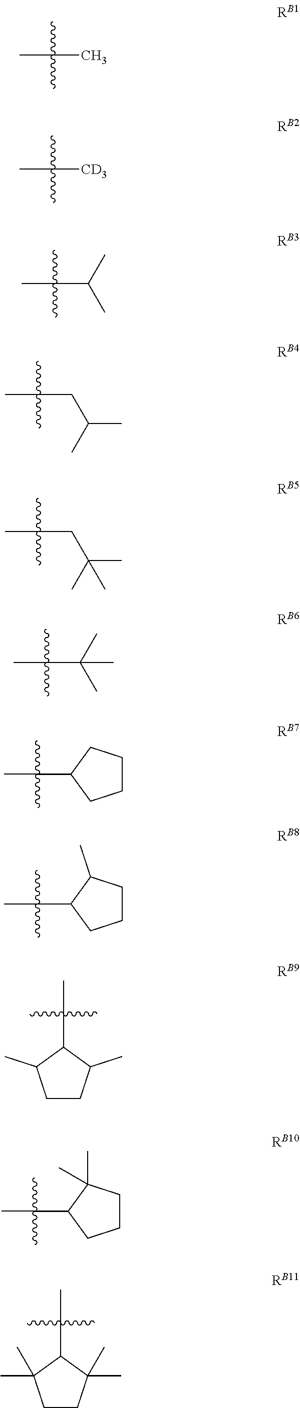

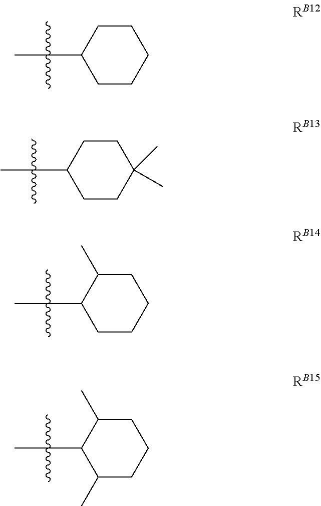

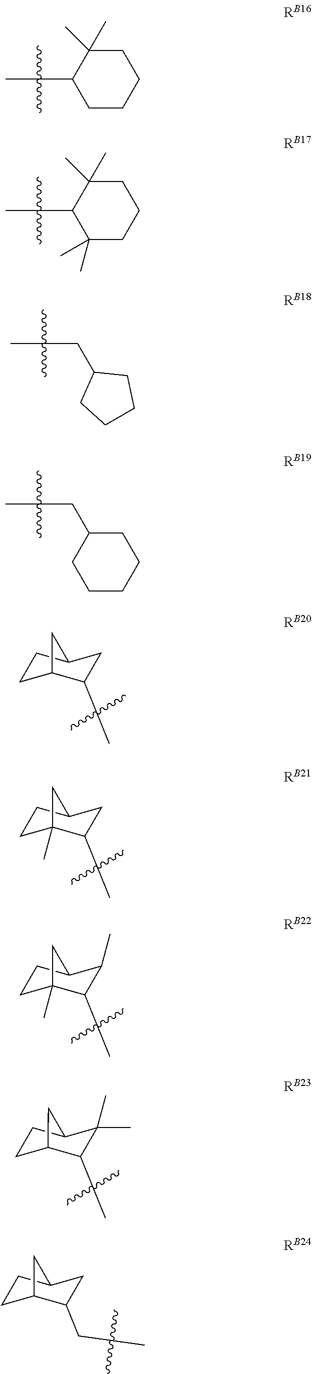

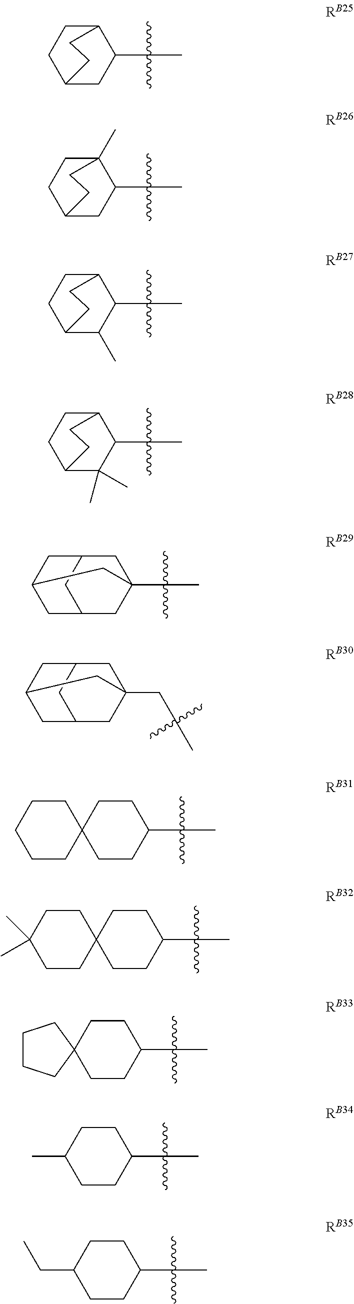

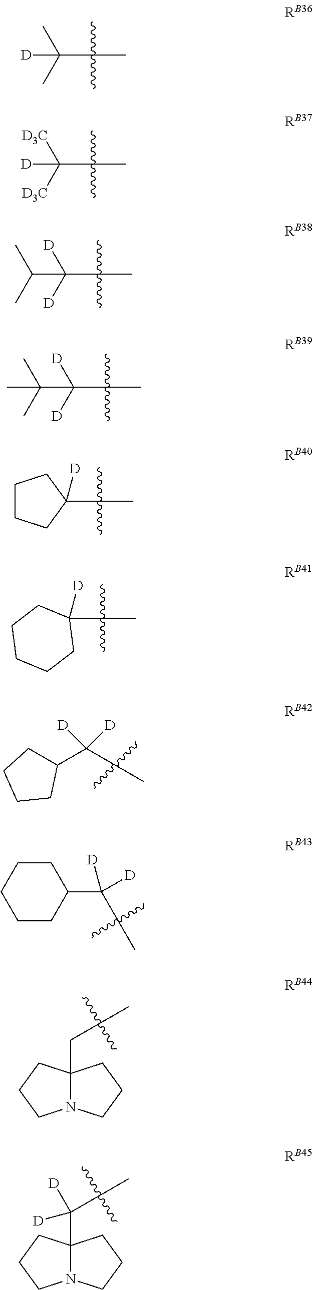

the R^{C1}-R^{C295} have structural formulas as follows:

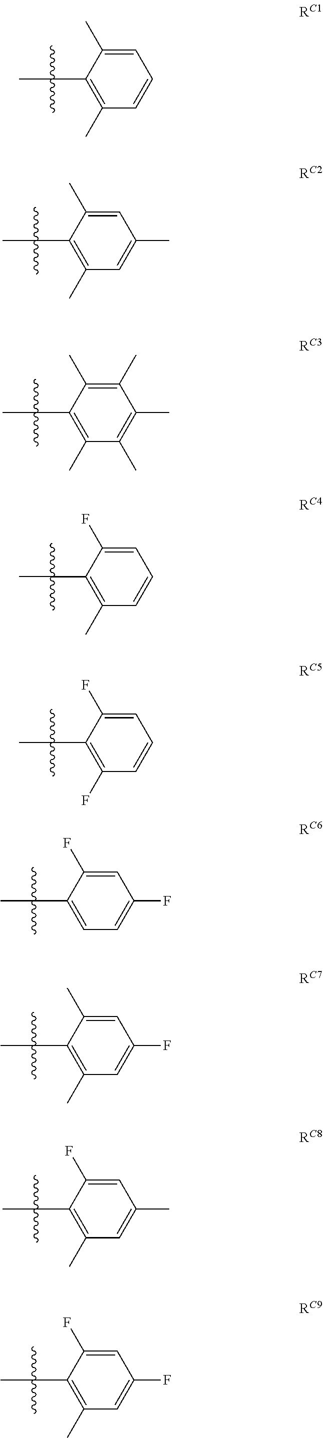

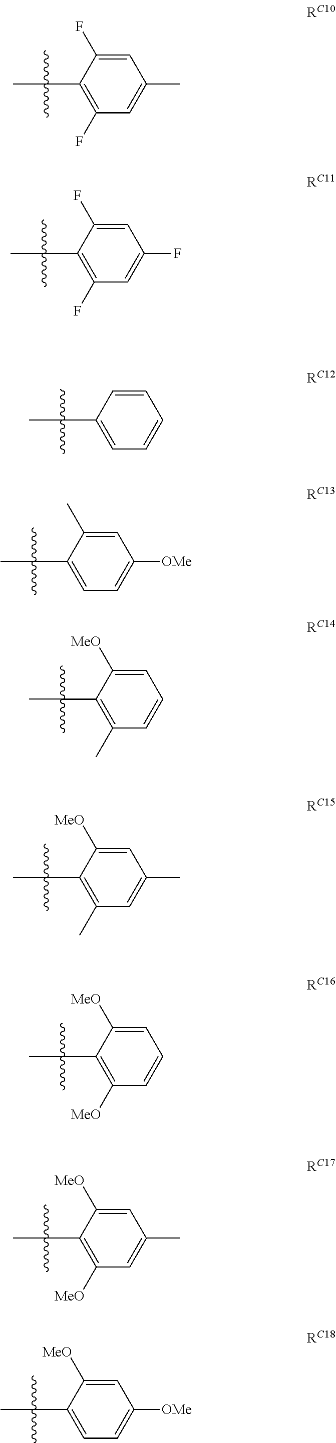

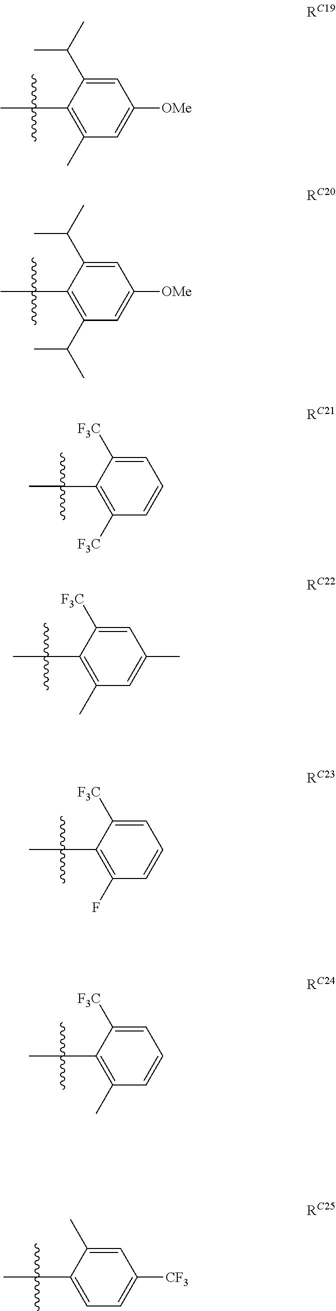

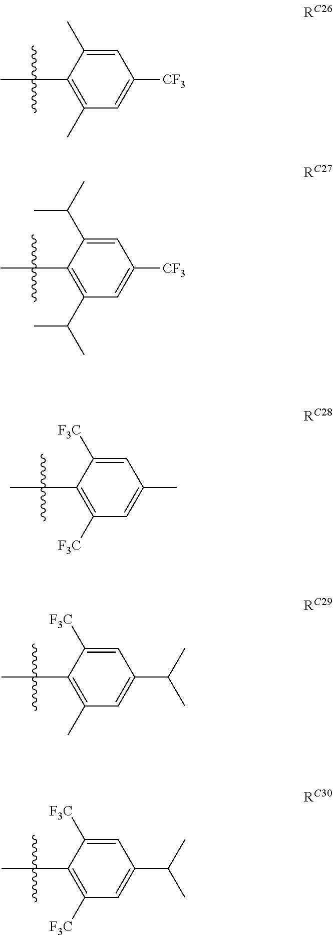 [SMILES: *c1c(C)cc(C(F)(F)F)cc1C ; *c1c(C(C)C)cc(C(F)(F)F)cc1C(C)C ; *c1c(C(F)(F)F)cc(C)cc1C(F)(F)F ; *c1c(C)cc(C(C)C)cc1C(F)(F)F ; *c1c(C(F)(F)F)cc(C(C)C)cc1C(F)(F)F]

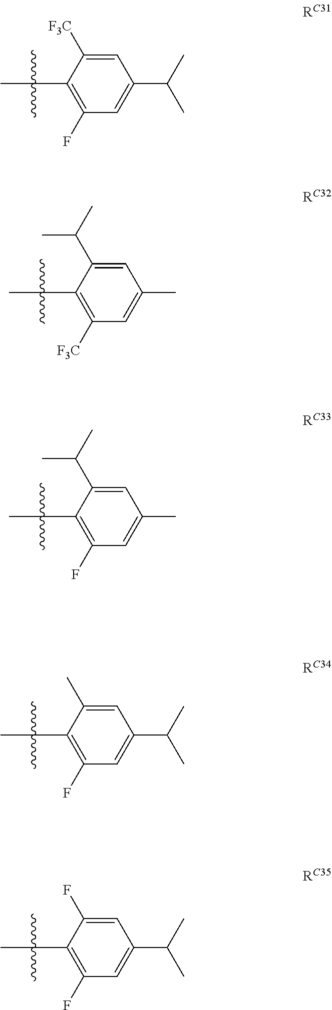 [SMILES: *c1c(F)cc(C(C)C)cc1C(F)(F)F ; *c1c(C(C)C)cc(C)cc1C(F)(F)F ; *c1c(F)cc(C)cc1C(C)C ; *c1c(C)cc(C(C)C)cc1F ; *c1c(F)cc(C(C)C)cc1F]

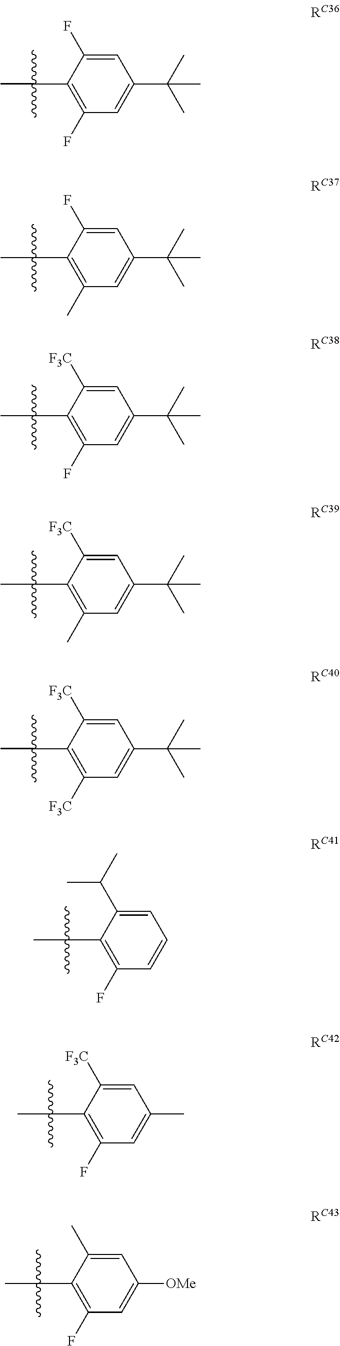

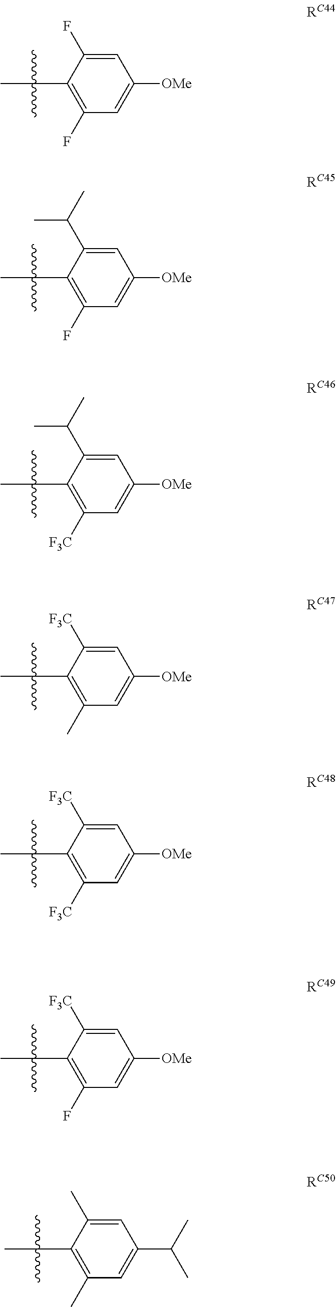

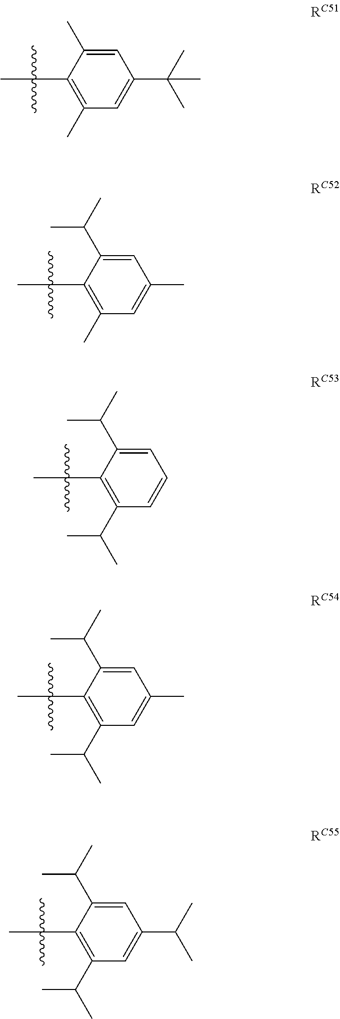 [SMILES: *c1c(C)cc(C(C)(C)C)cc1C ; *c1c(C)cc(C)cc1C(C)C ; *c1c(C(C)C)cccc1C(C)C ; *c1c(C(C)C)cc(C)cc1C(C)C ; *c1c(C(C)C)cc(C(C)C)cc1C(C)C]

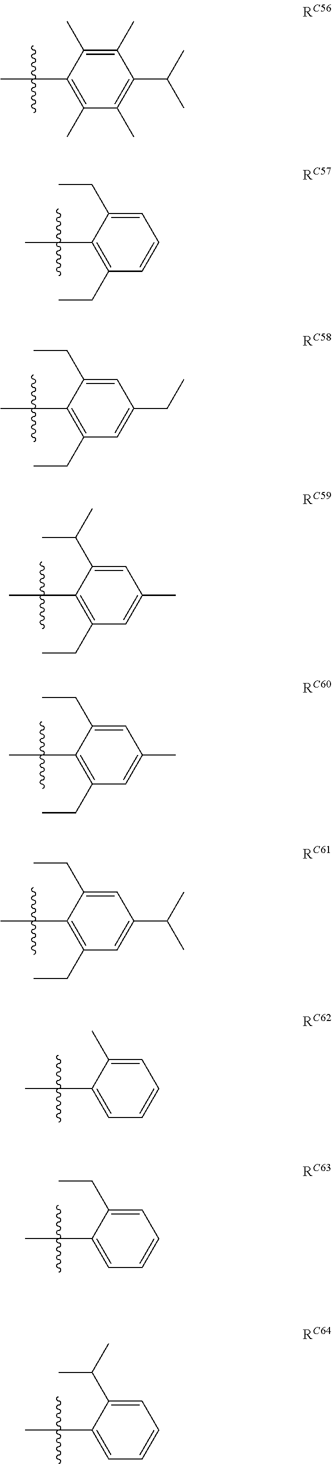

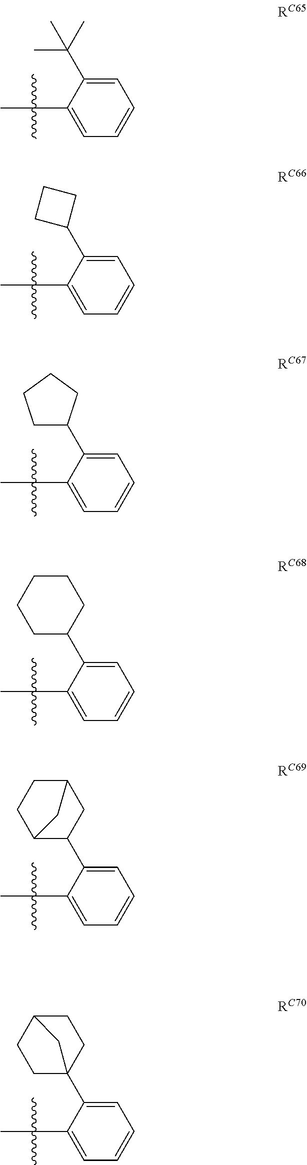 [SMILES: *c1ccccc1C(C)(C)C ; *c1ccccc1C1CCC1 ; *c1ccccc1C1CCCC1 ; *c1ccccc1C1CCCCC1 ; *c1ccccc1C1CC2CCC1C2 ; *c1ccccc1C12CCC(CC1)C2]

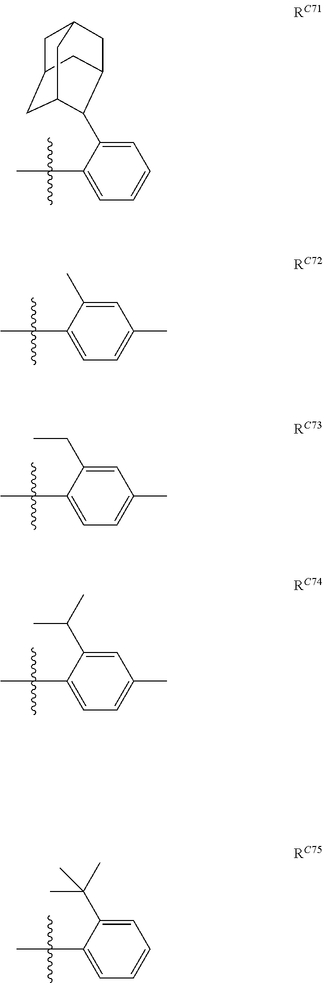

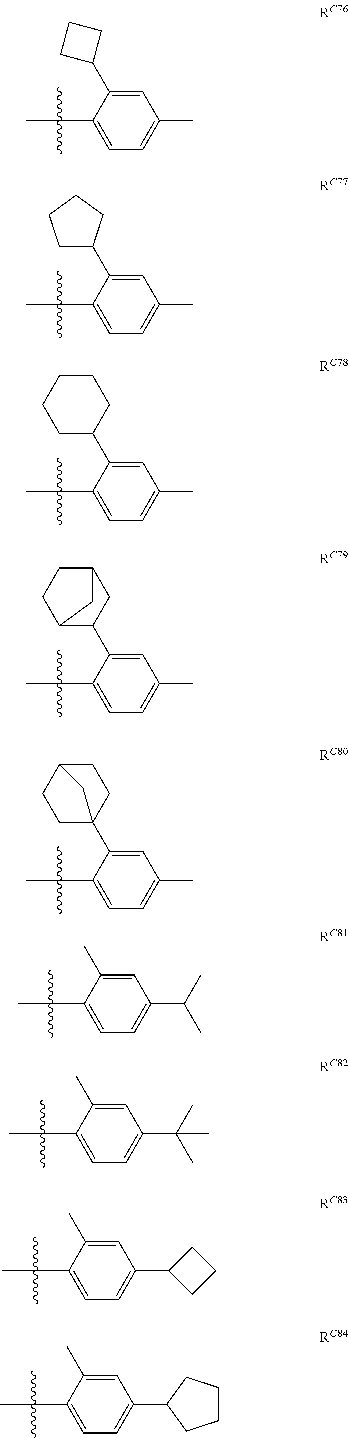

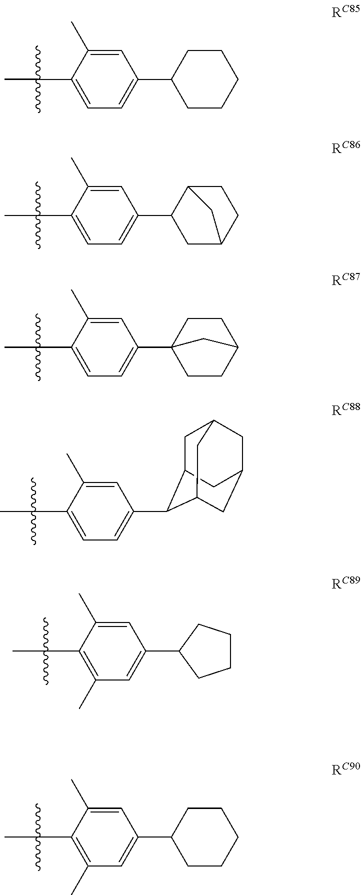

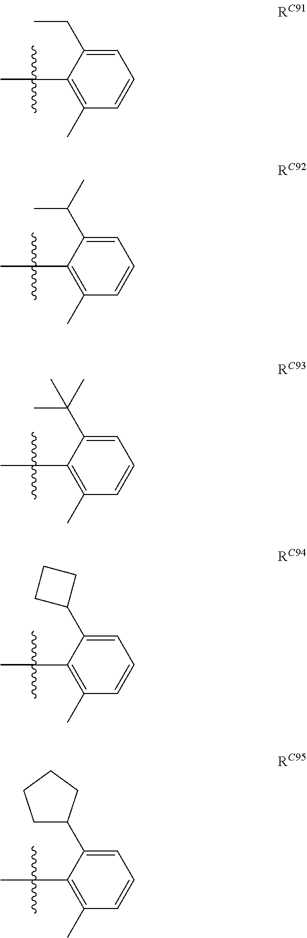

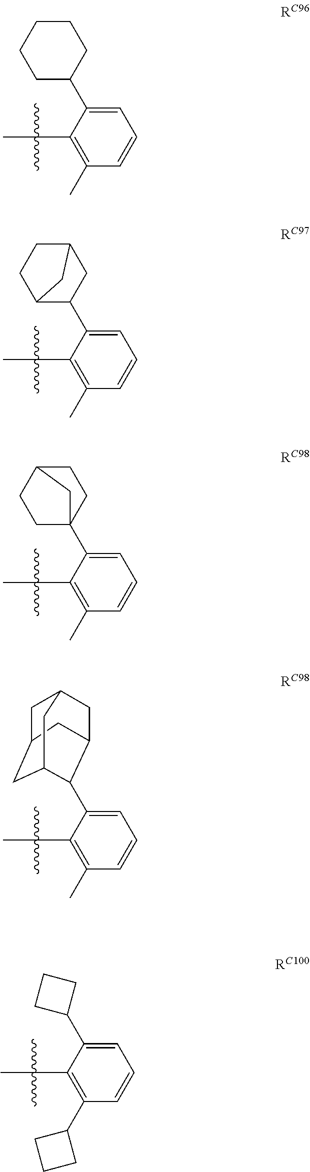 [SMILES: *c1c(C)cccc1C1CCCCC1 ; *c1c(C)cccc1C1CC2CCC1C2 ; *c1c(C)cccc1C12CCC(CC1)C2 ; *c1c(C)cccc1C1C2CC3CC(C2)CC1C3 ; *c1c(C2CCC2)cccc1C1CCC1]

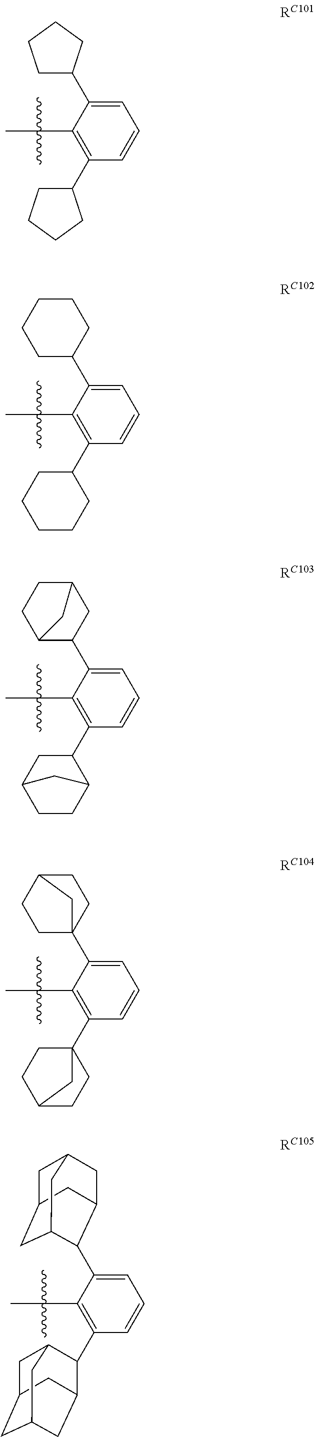 [SMILES: *c1c(C2CCCC2)cccc1C1CCCC1 ; *c1c(C2CCCCC2)cccc1C1CCCCC1 ; *c1c(C2CC3CCC2C3)cccc1C1CC2CCC1C2 ; *c1c(C23CCC(CC2)C3)cccc1C12CCC(CC1)C2 ; *c1c(C2C3CC4CC(C3)CC2C4)cccc1C1C2CC3CC(C2)CC1C3]

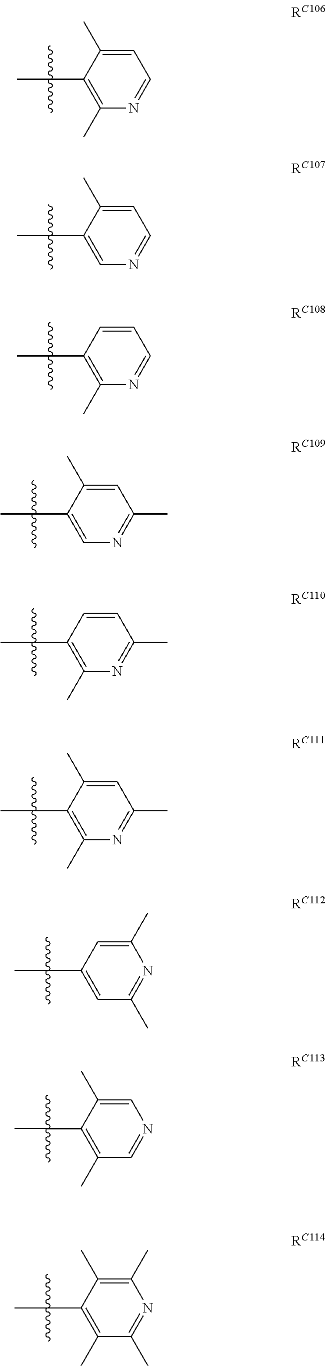

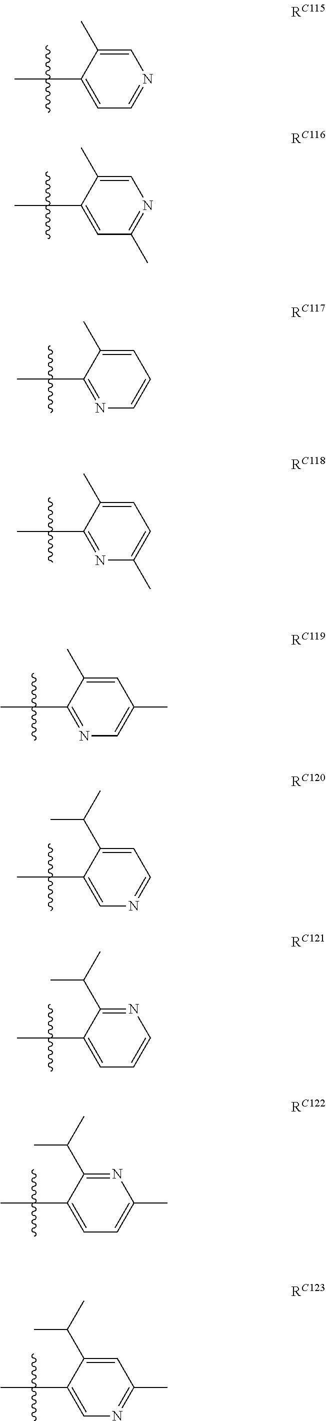

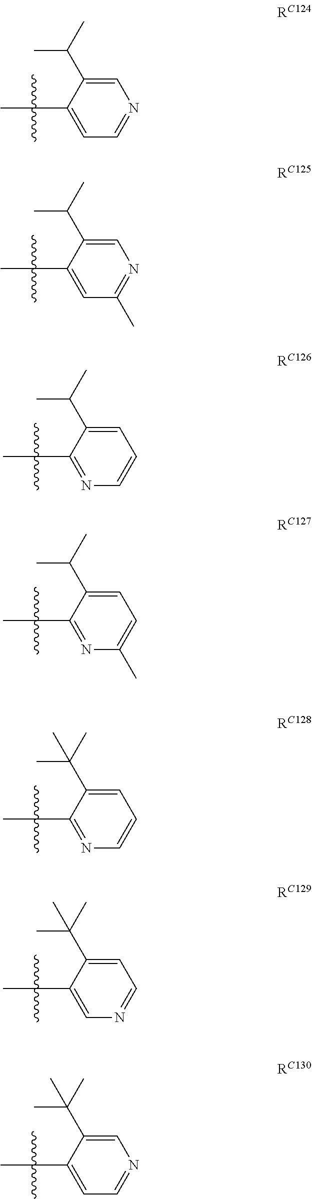

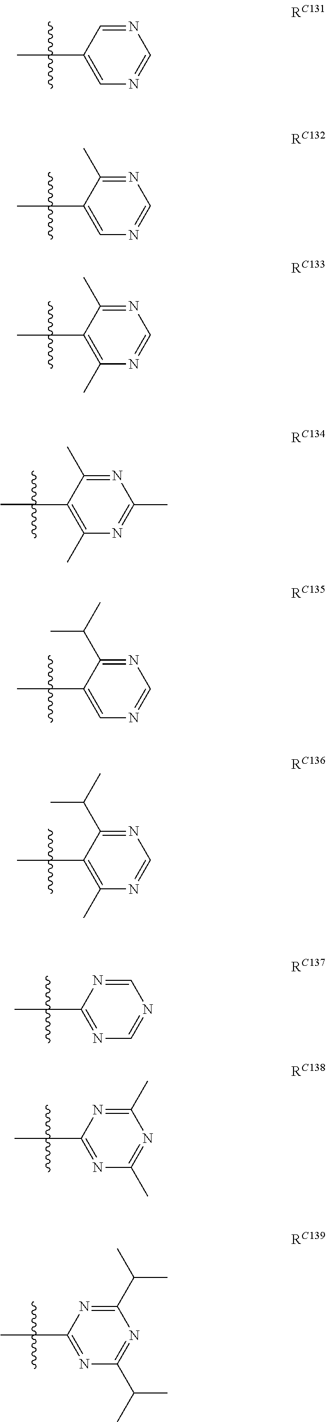

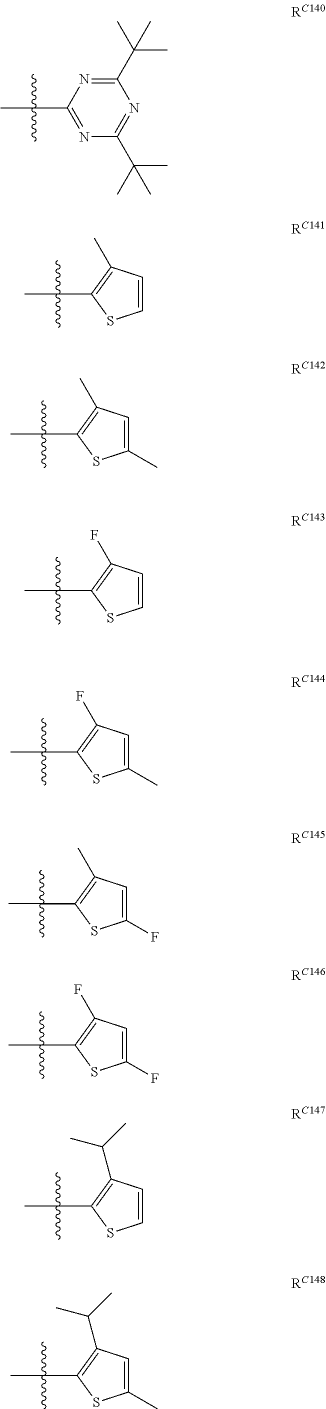

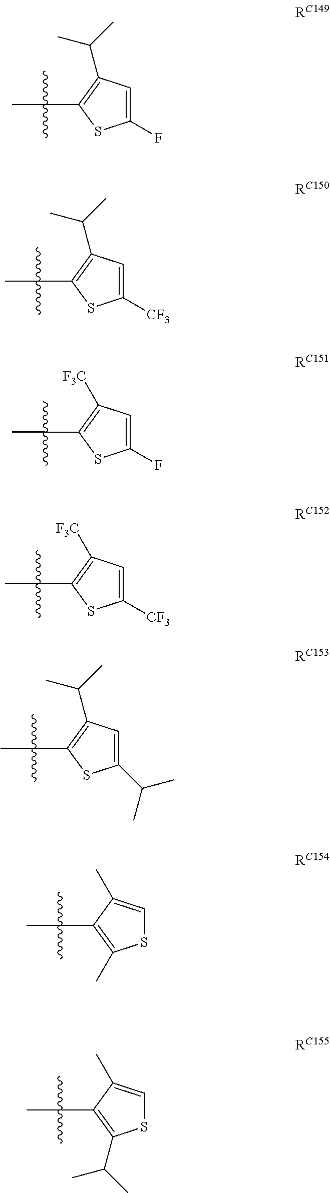

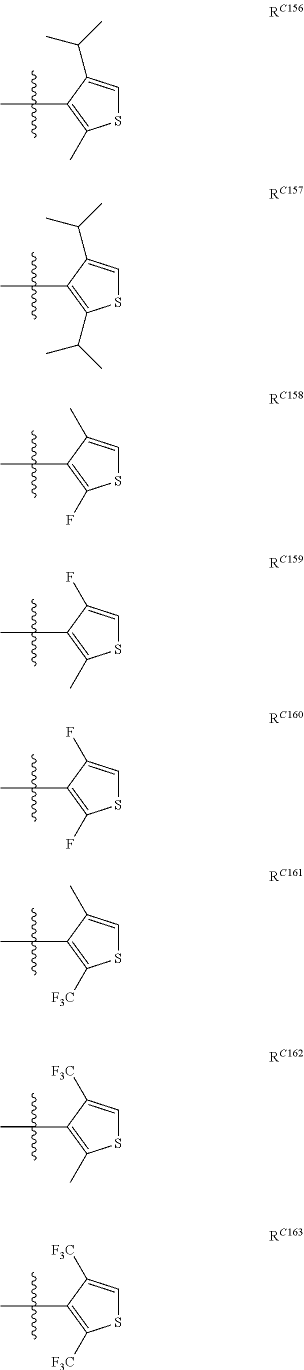

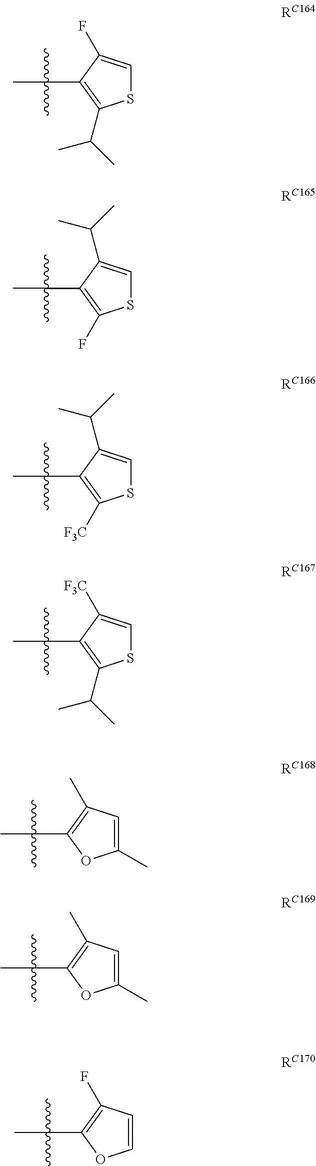

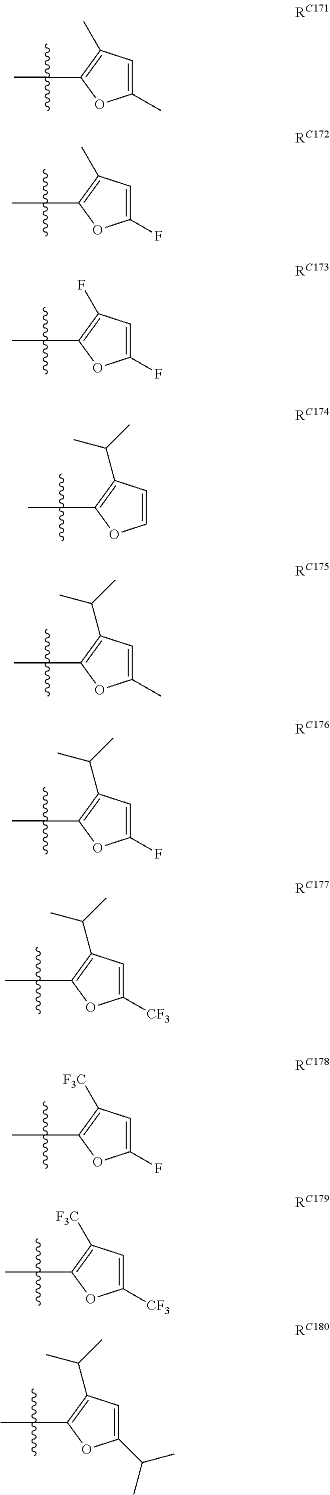

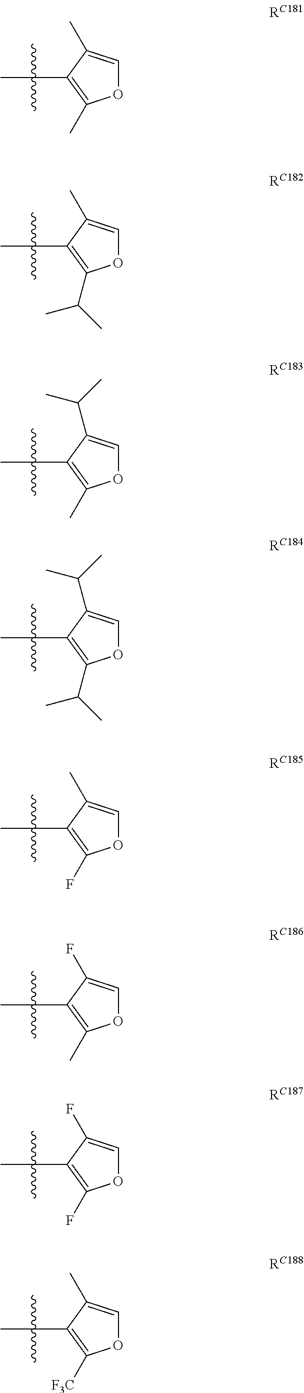

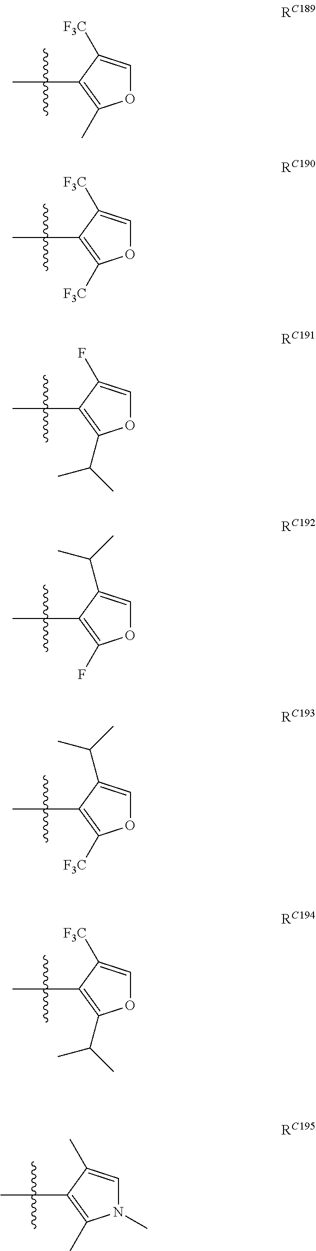

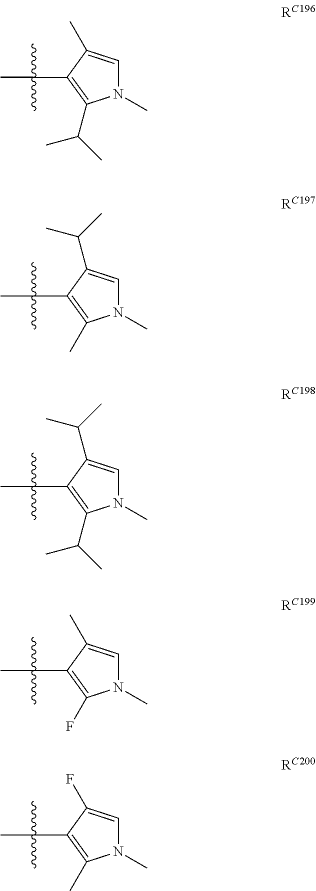

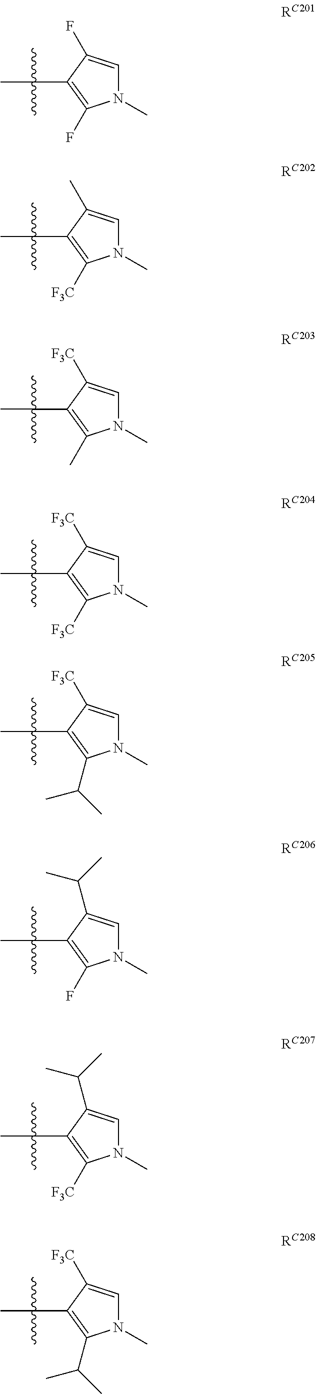

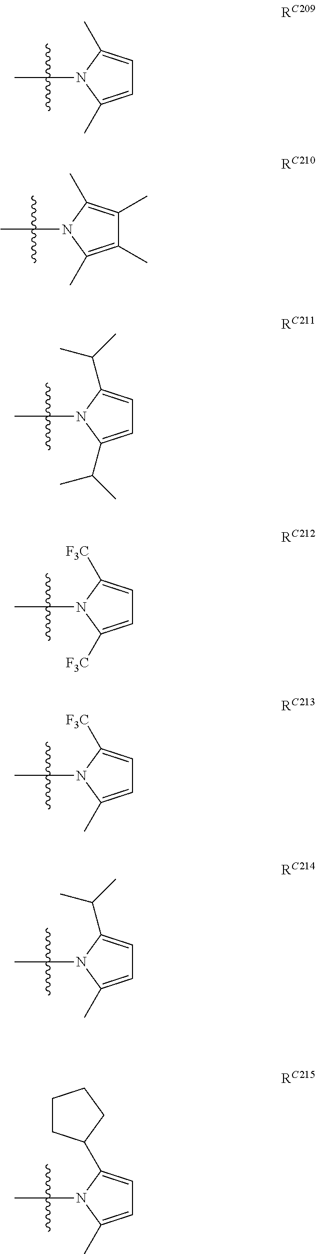

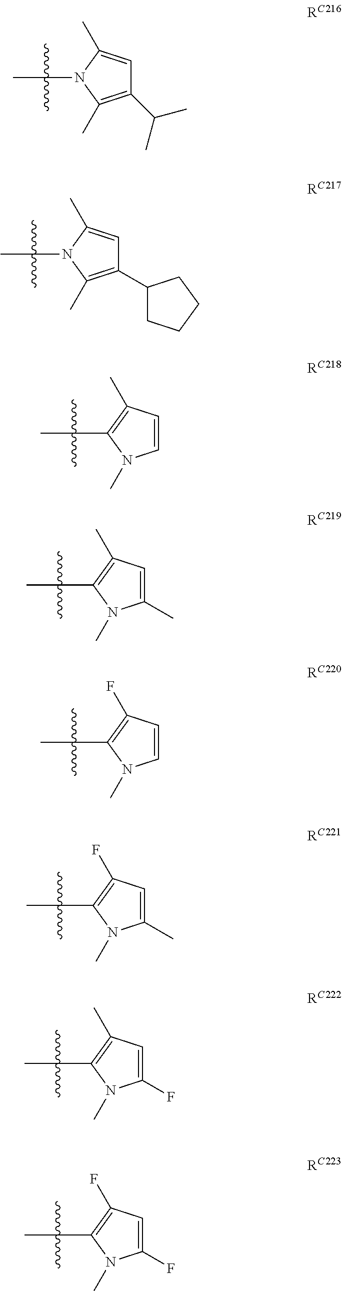

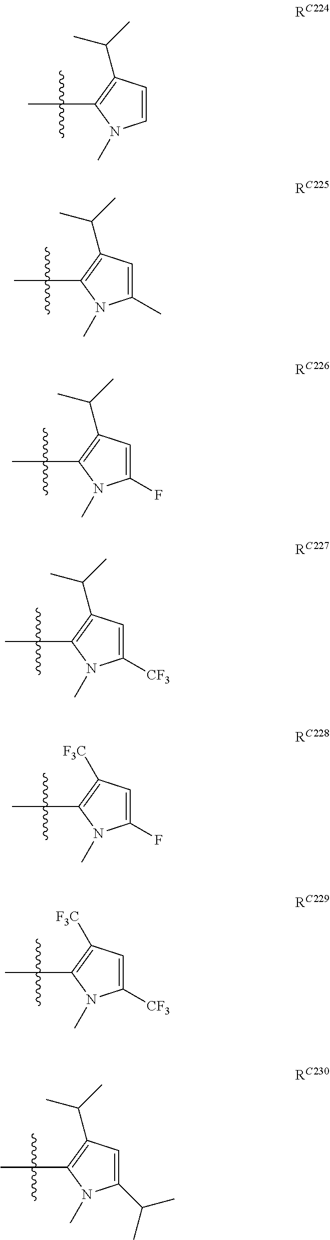

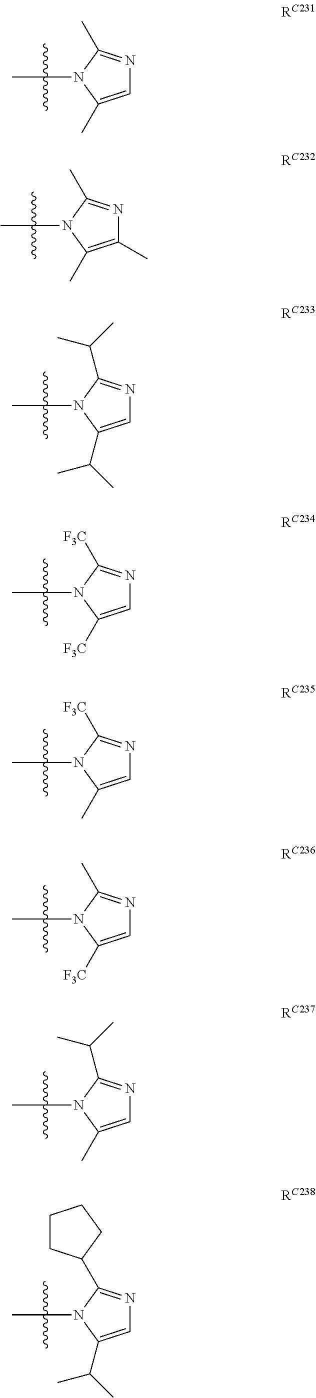

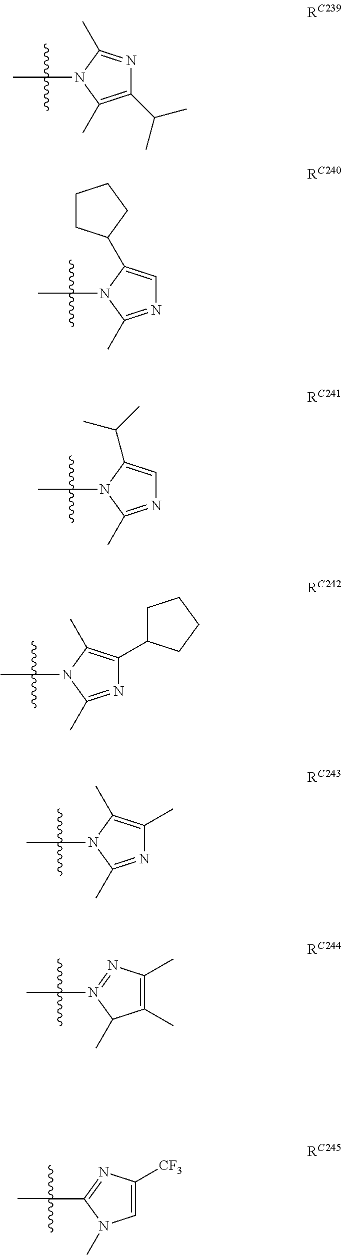

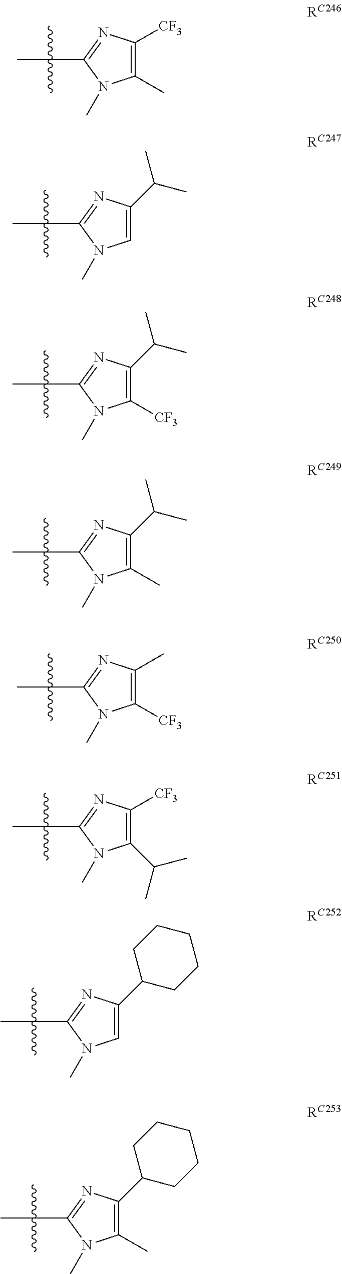

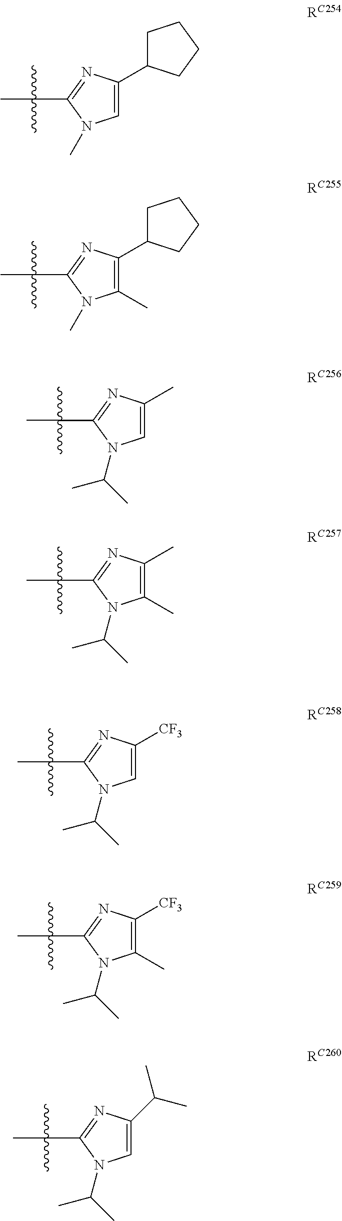

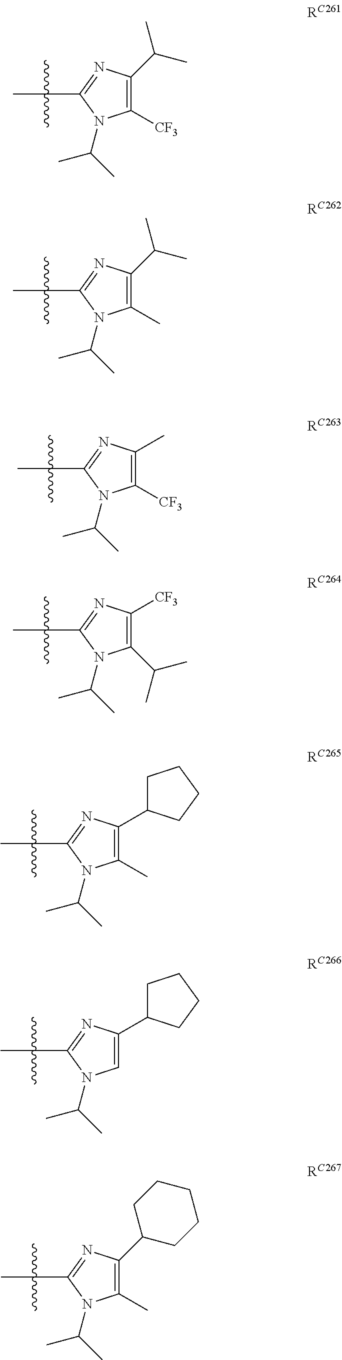

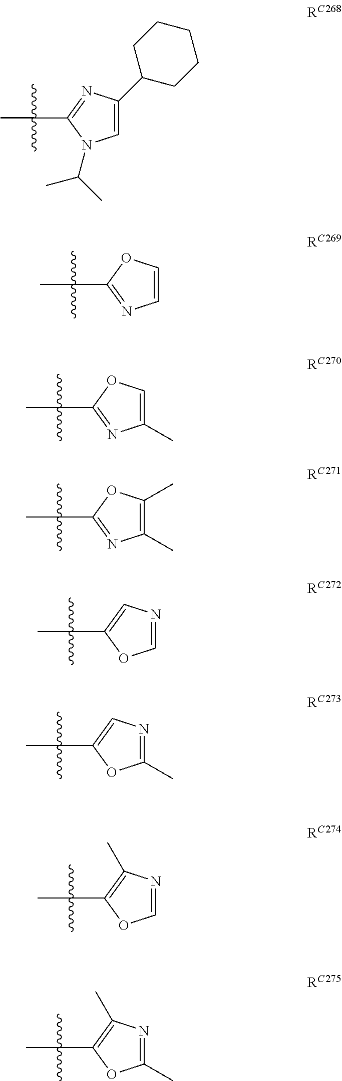

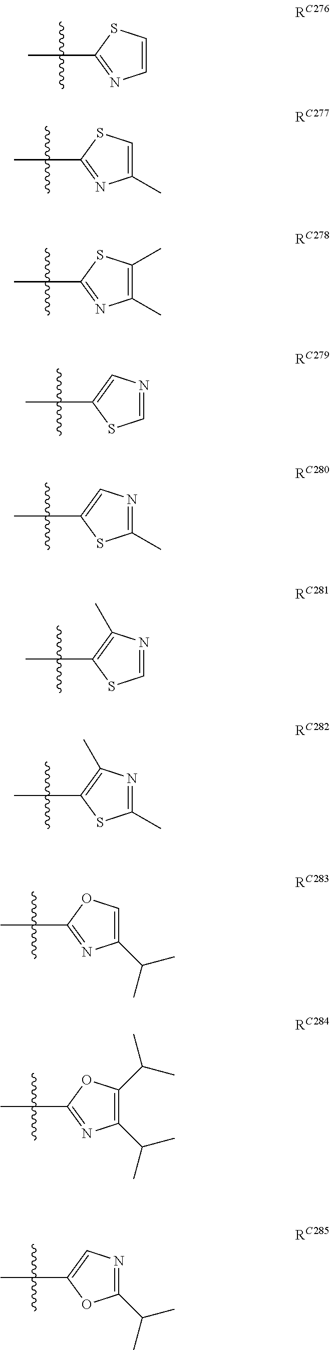

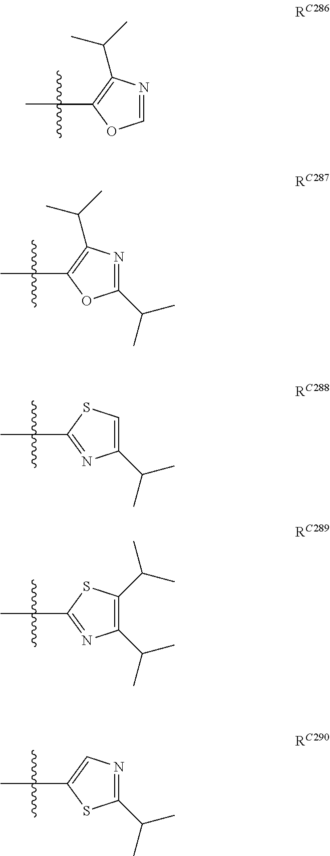

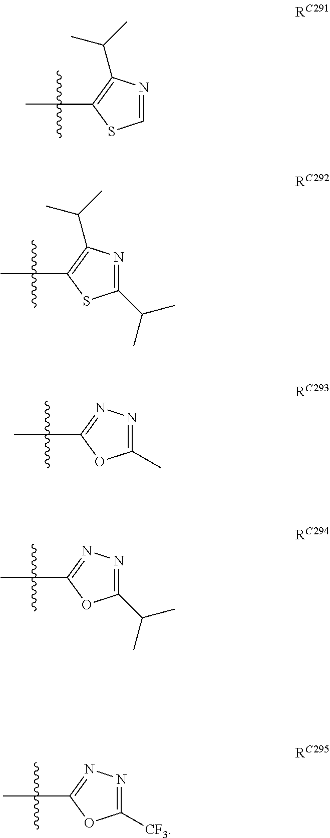

Further, the metal complex has a chemical formula of Ir(LA)(LB)₂, Ir(LA)₂(LB) or Ir(LA)₃, wherein the LB is selected from the group consisting of LB1-LB432, and the LB1-LB432 have specific structures as follows:

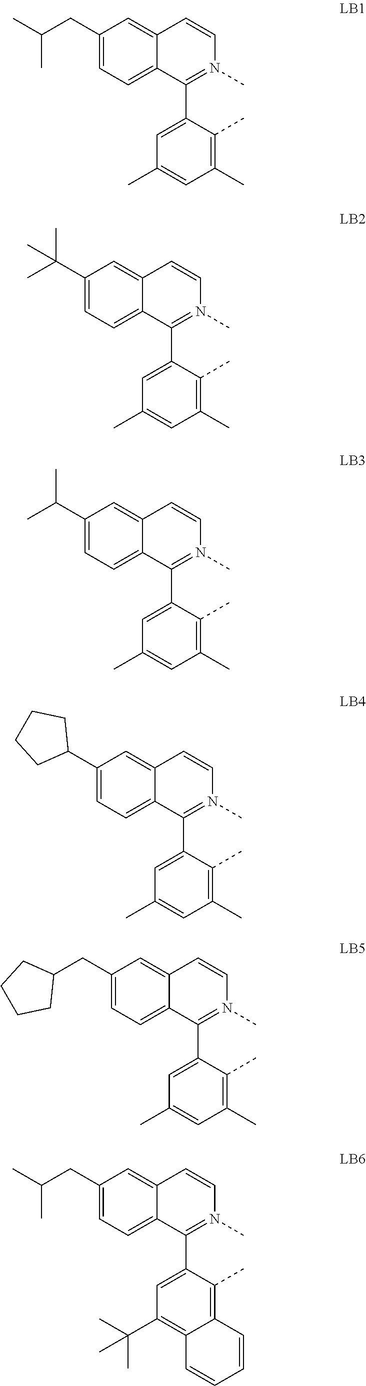

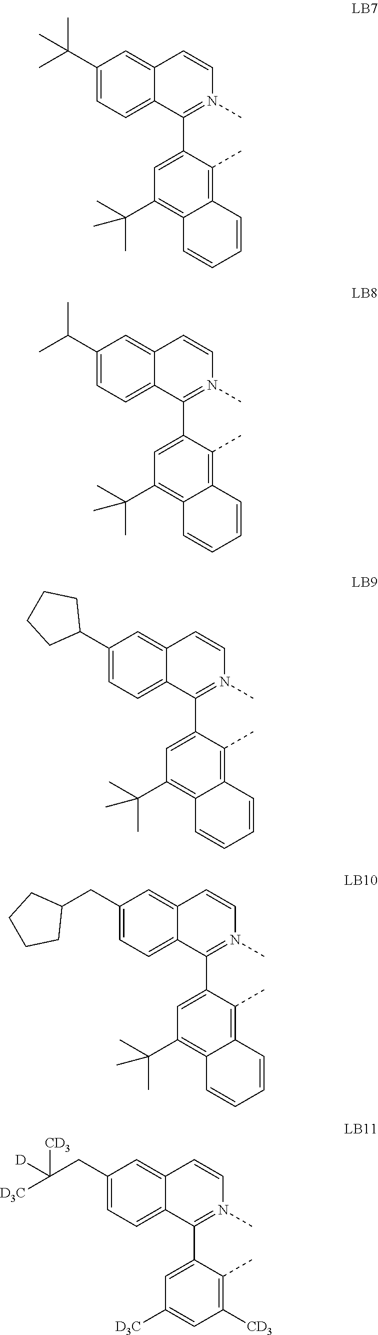

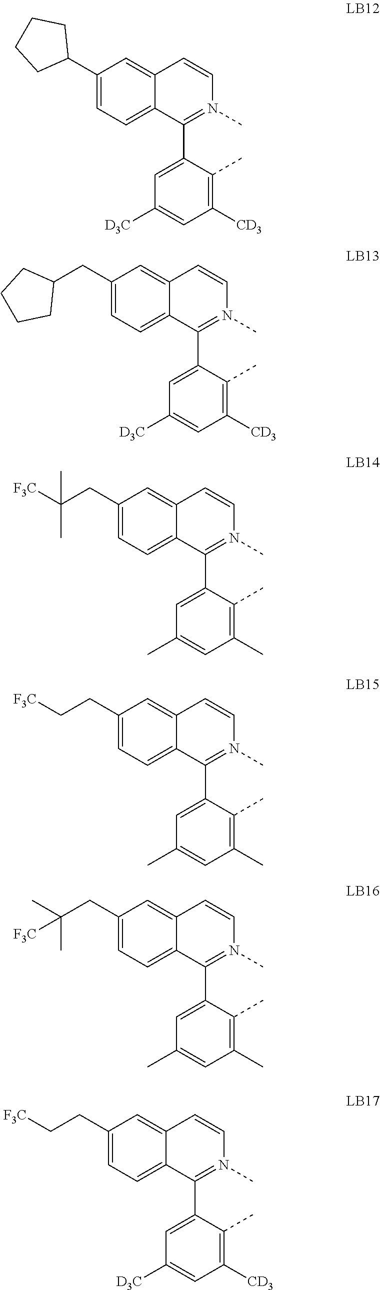

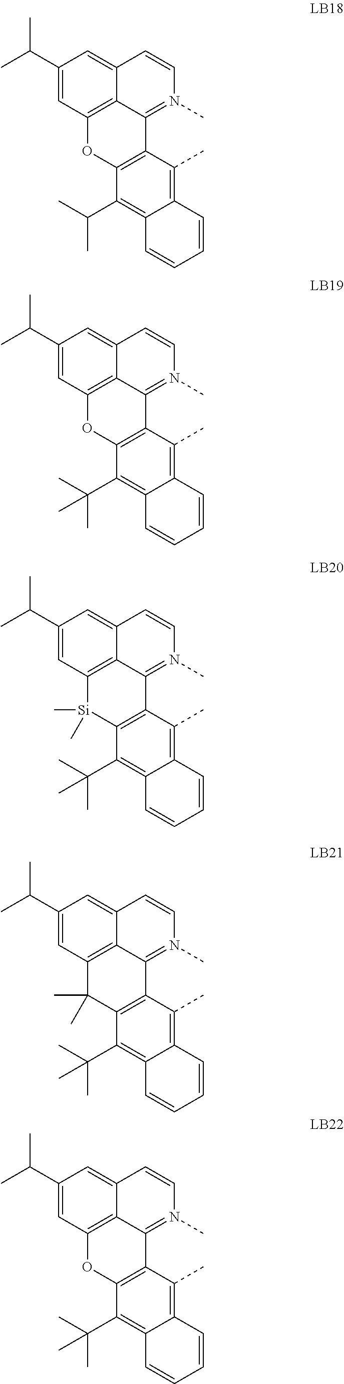

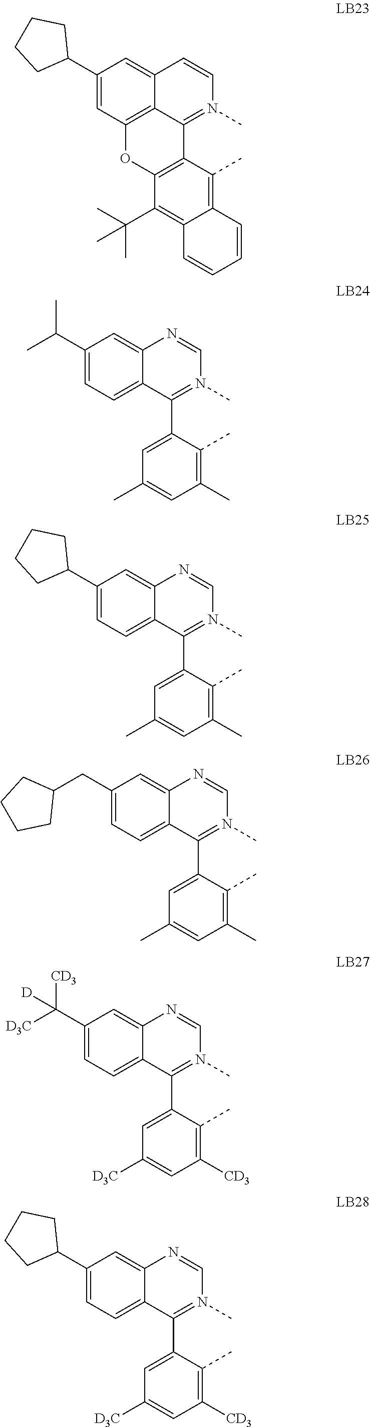

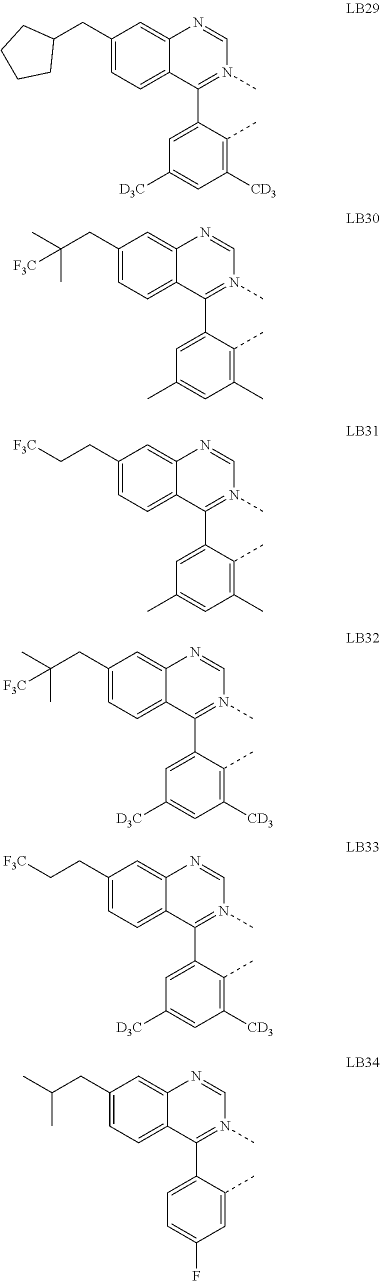

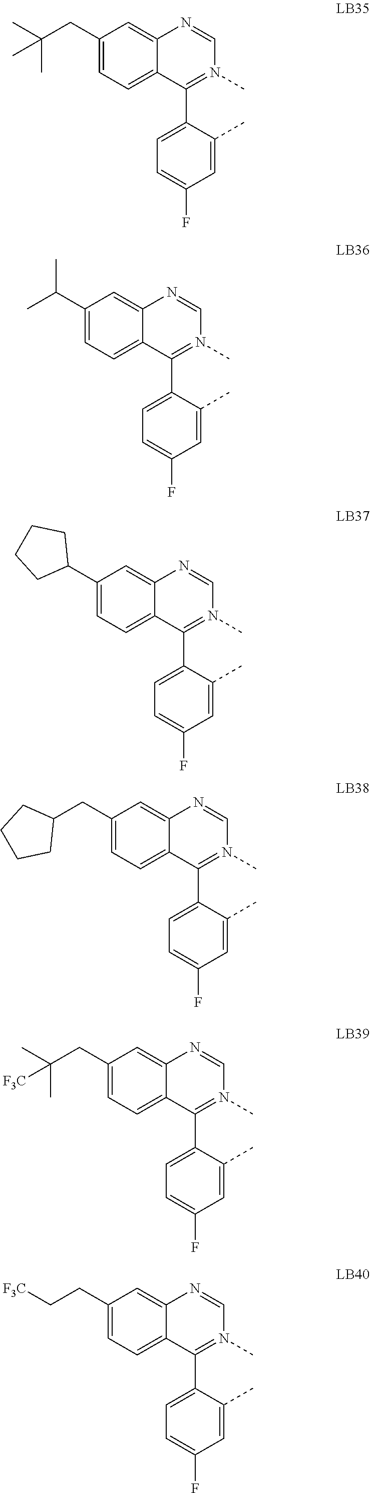

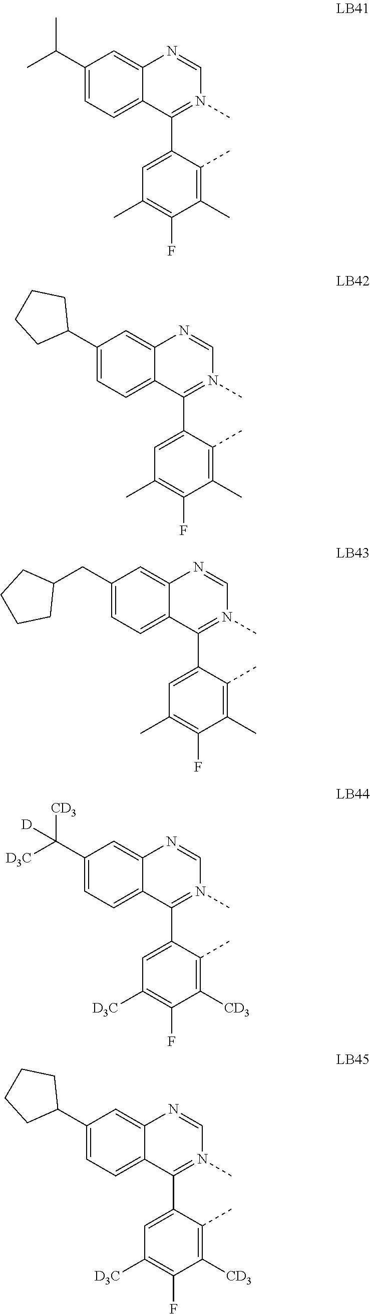

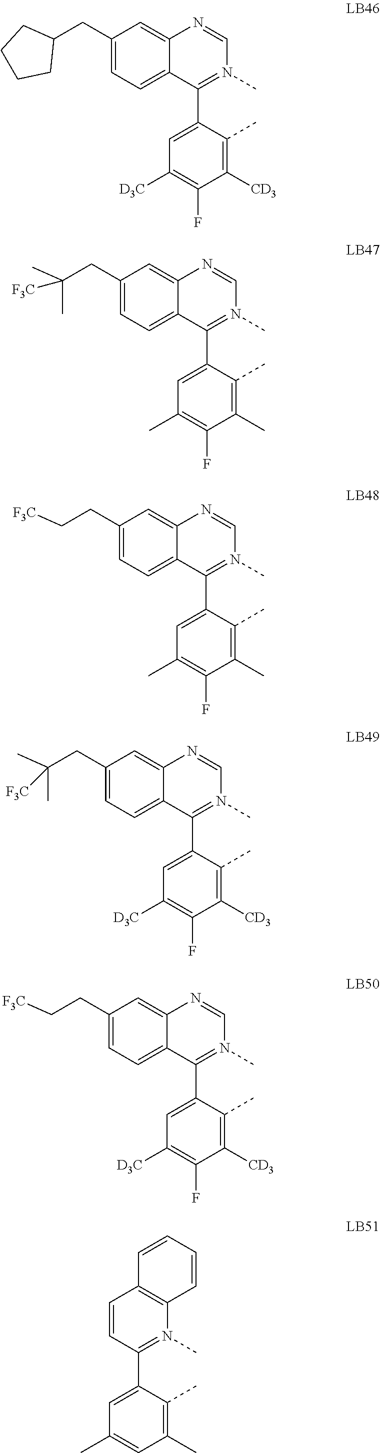

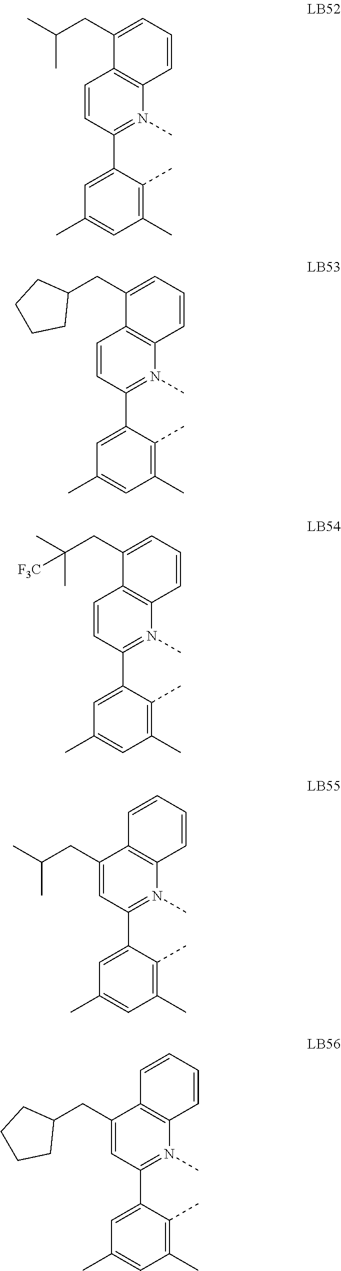

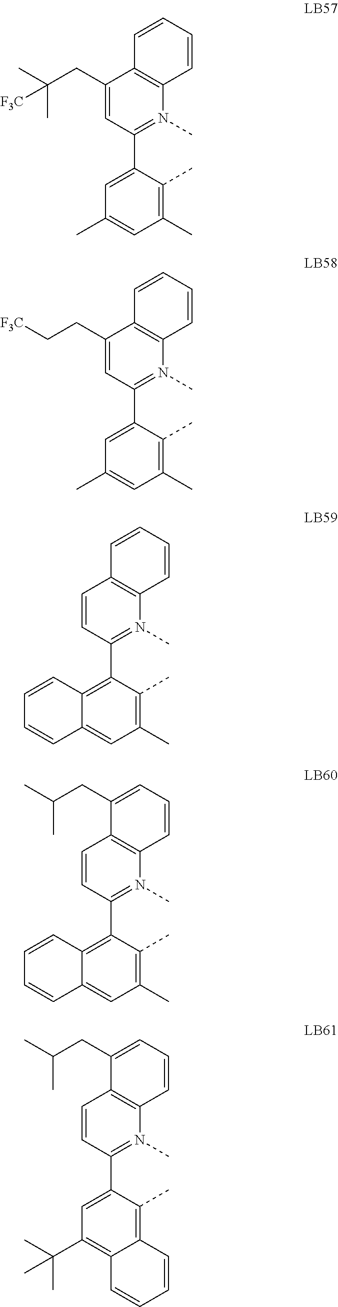

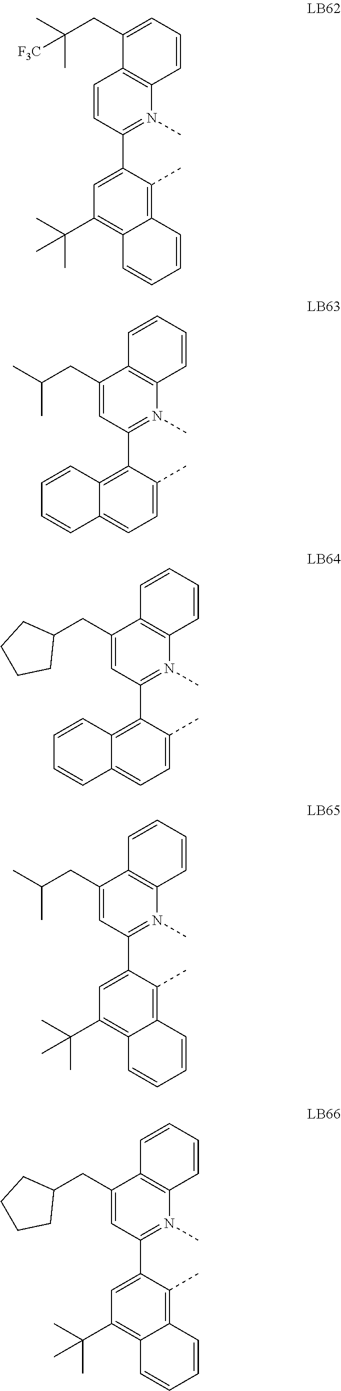

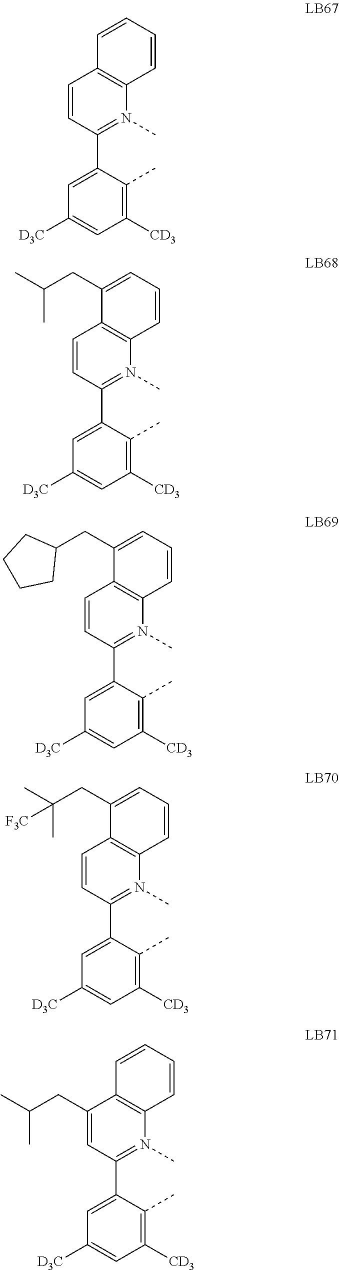

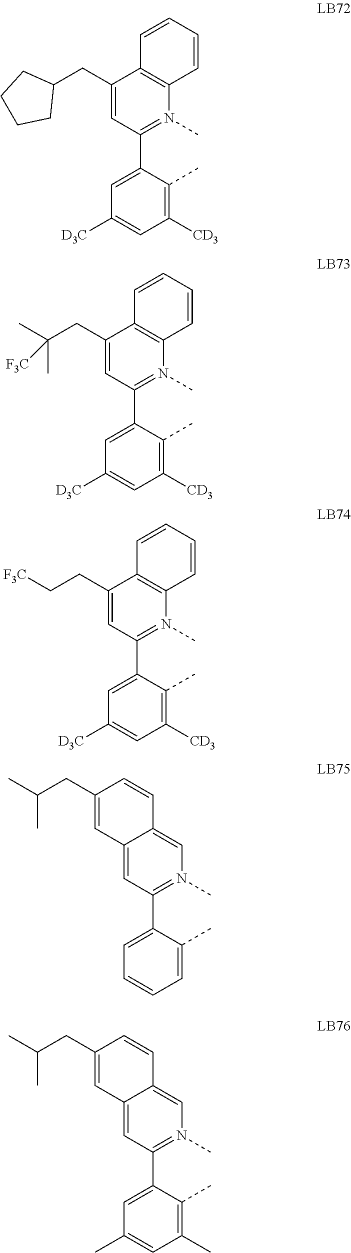

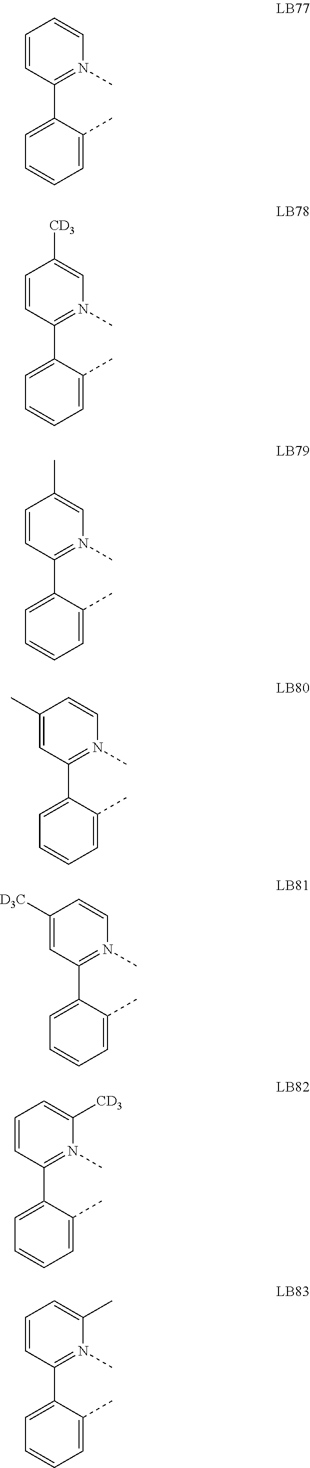

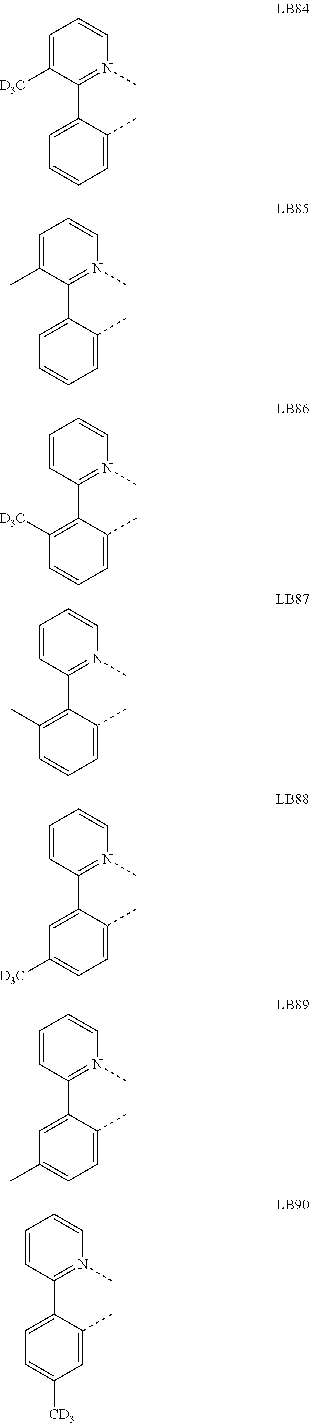

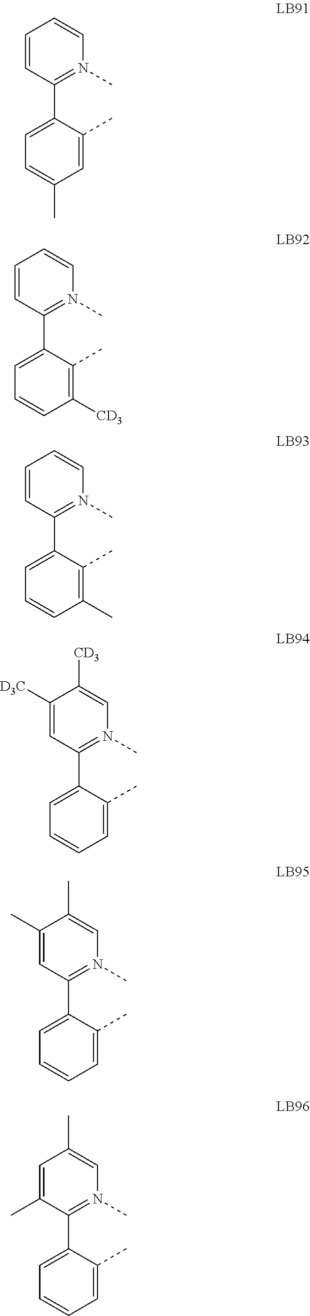

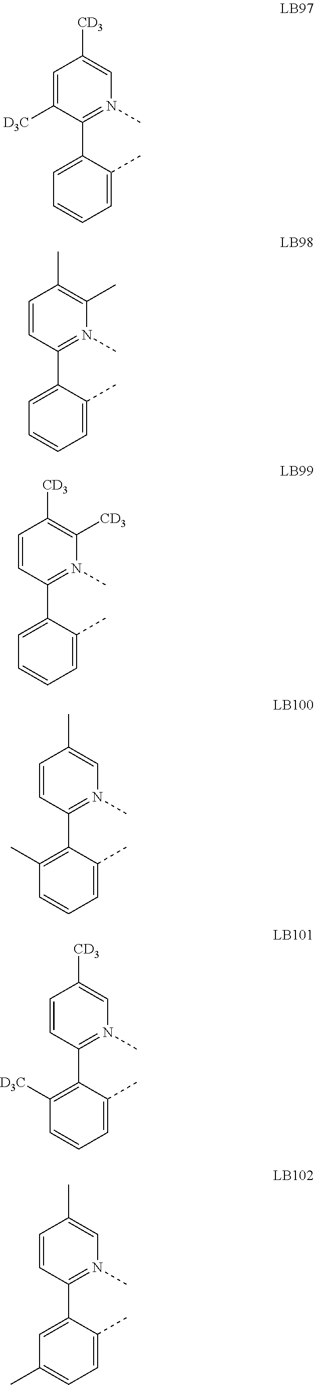

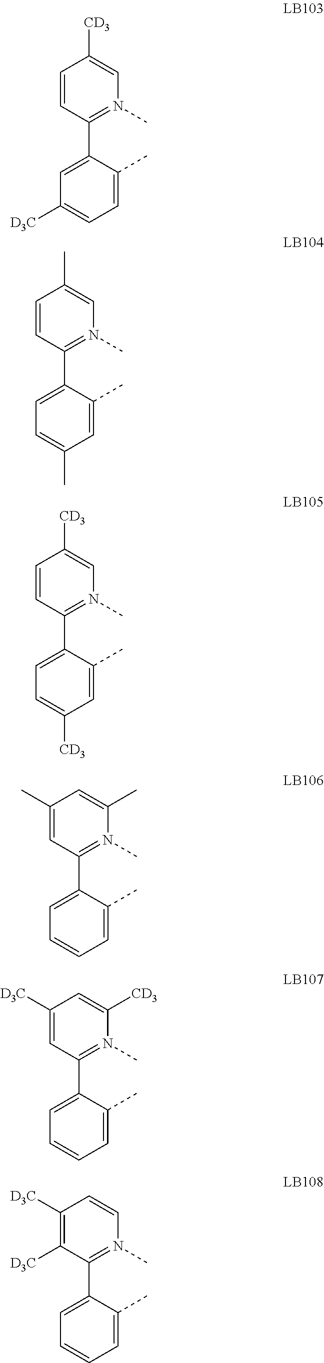

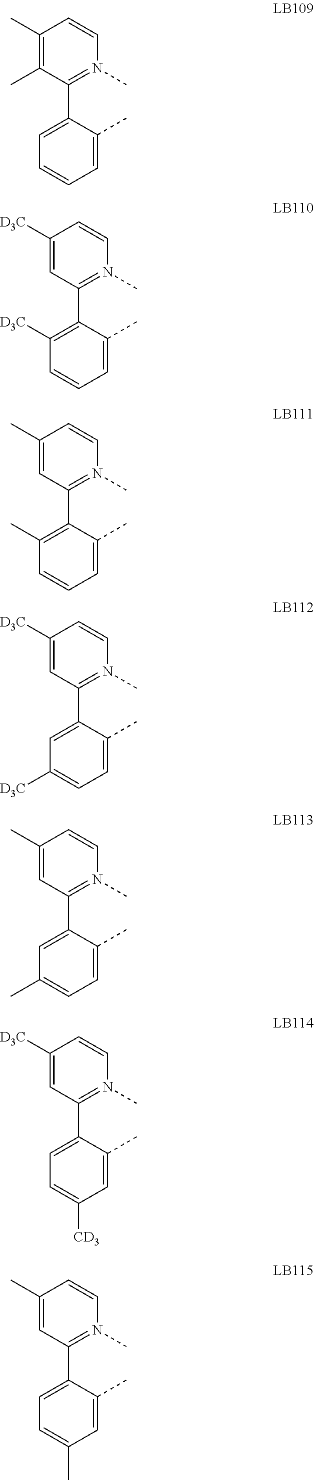

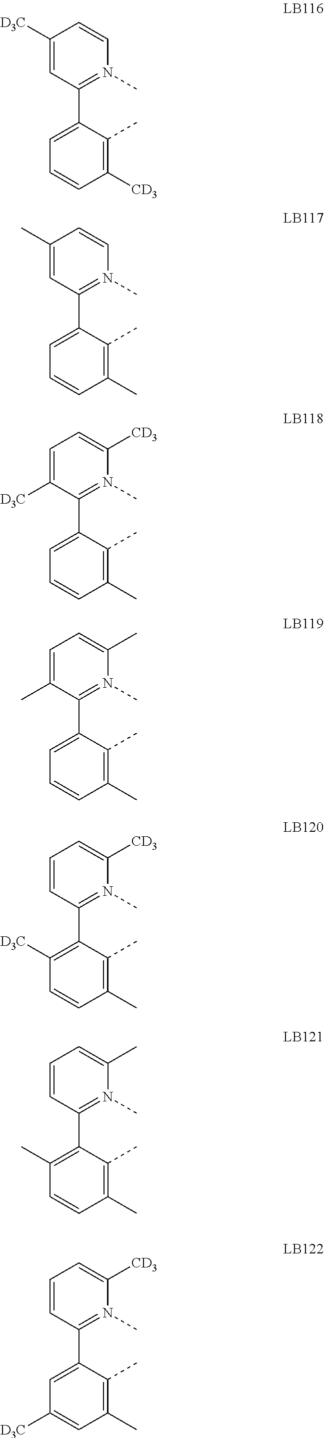

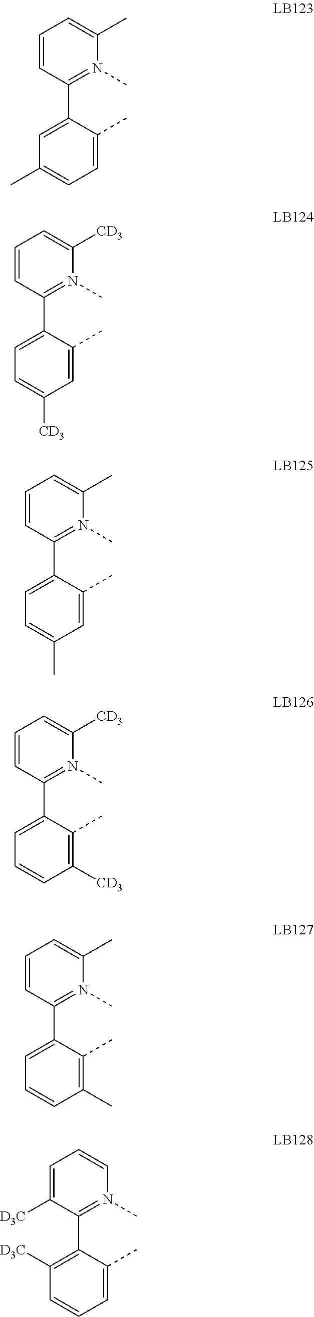

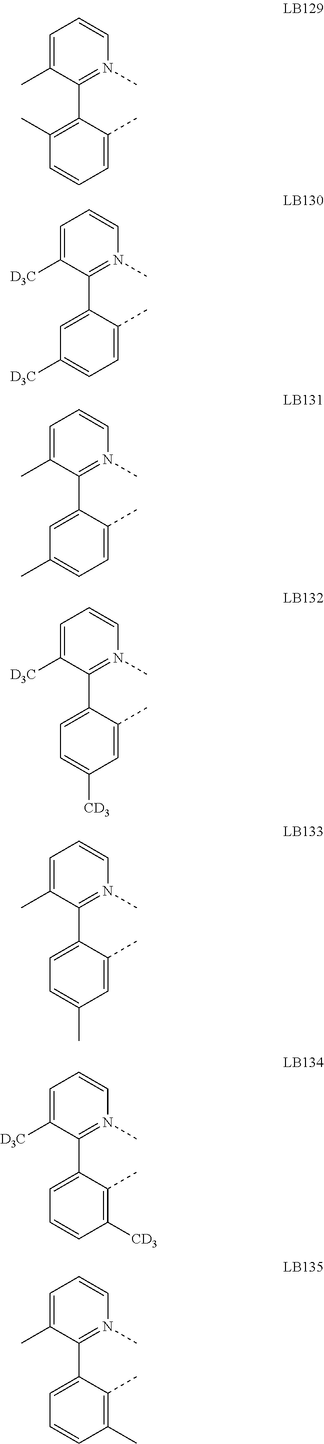

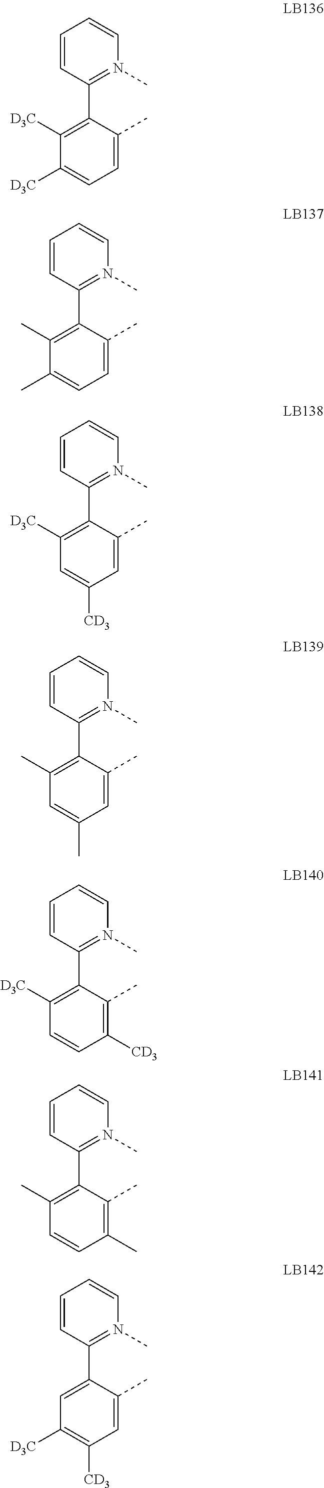

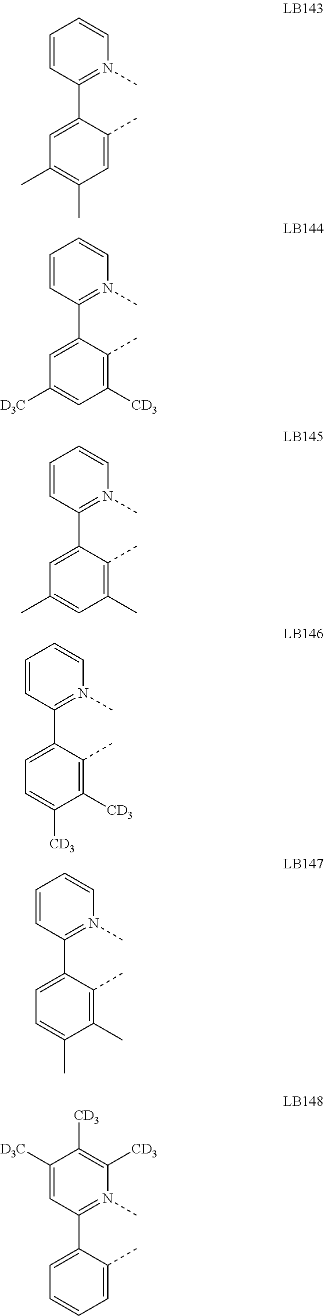

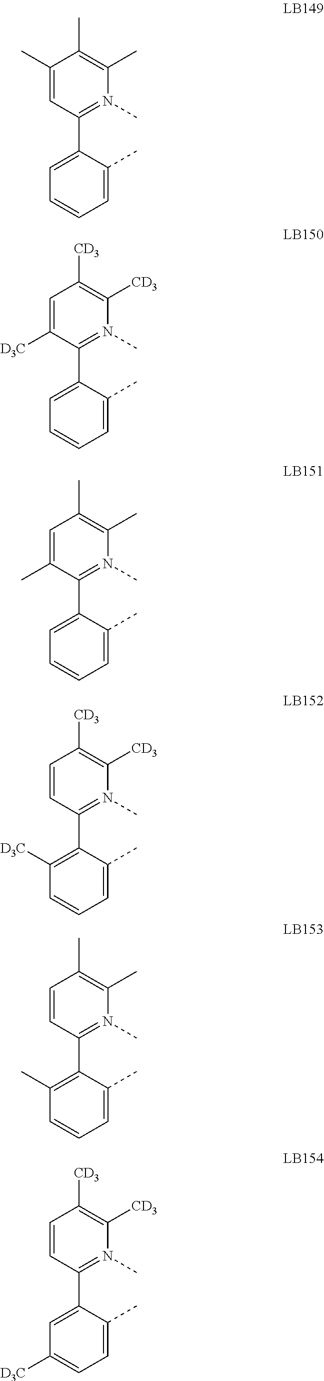

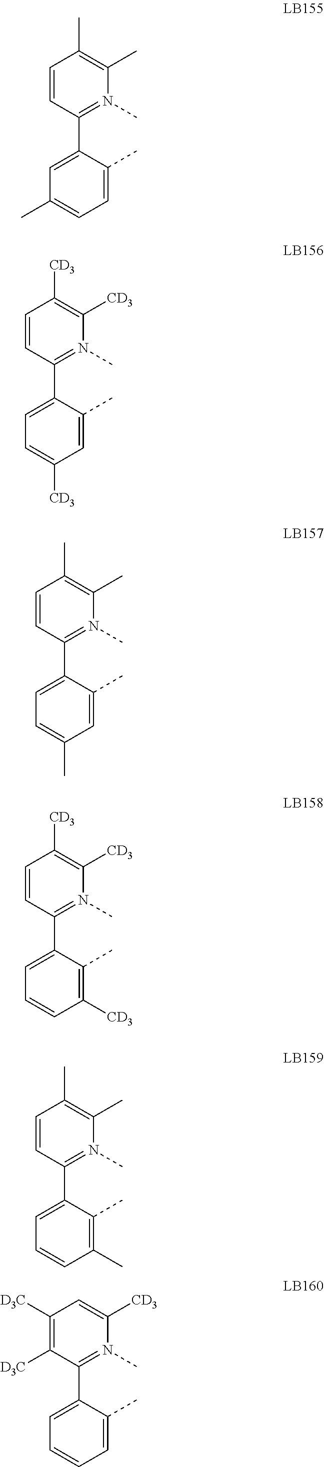

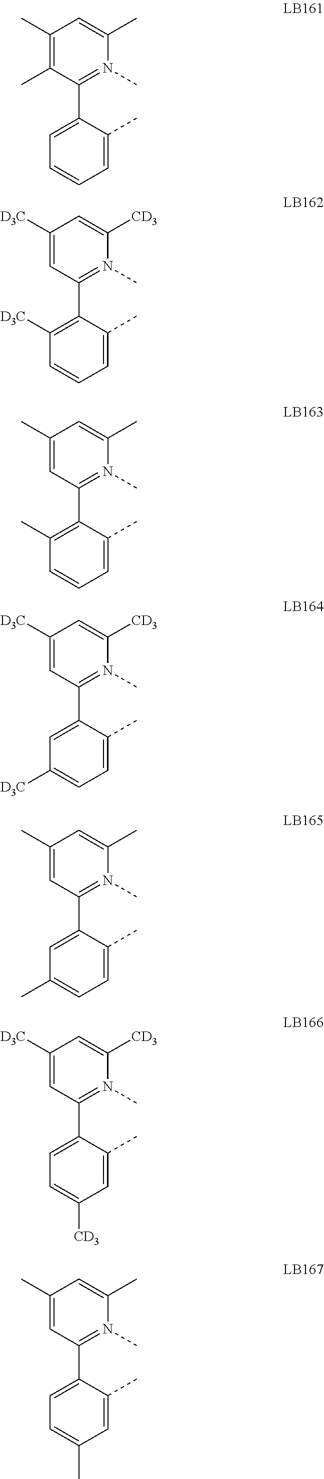

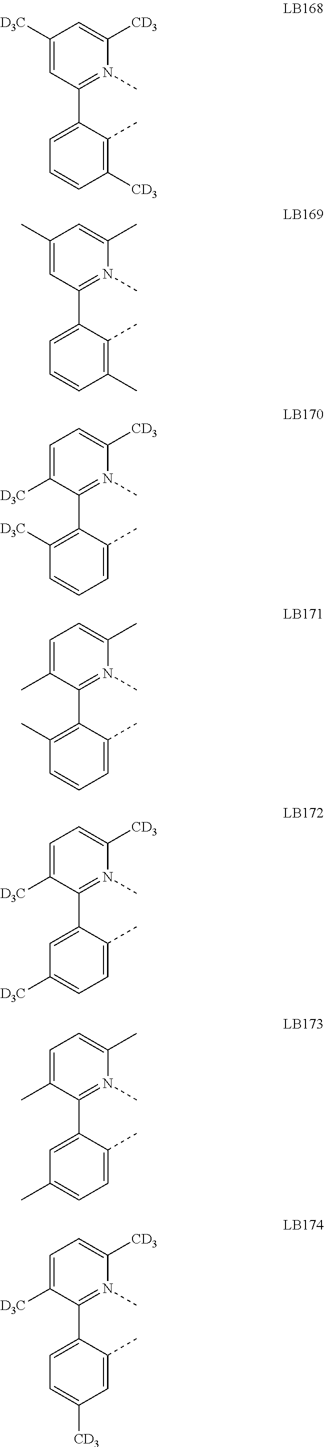

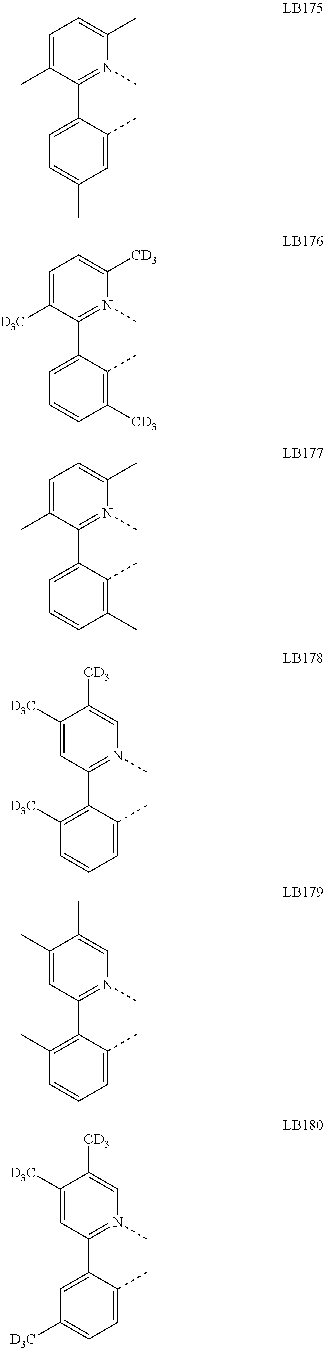

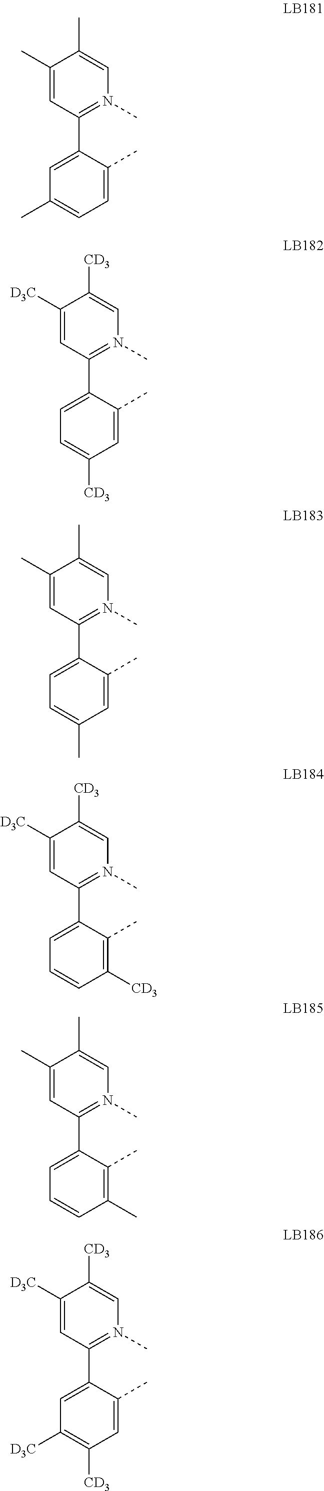

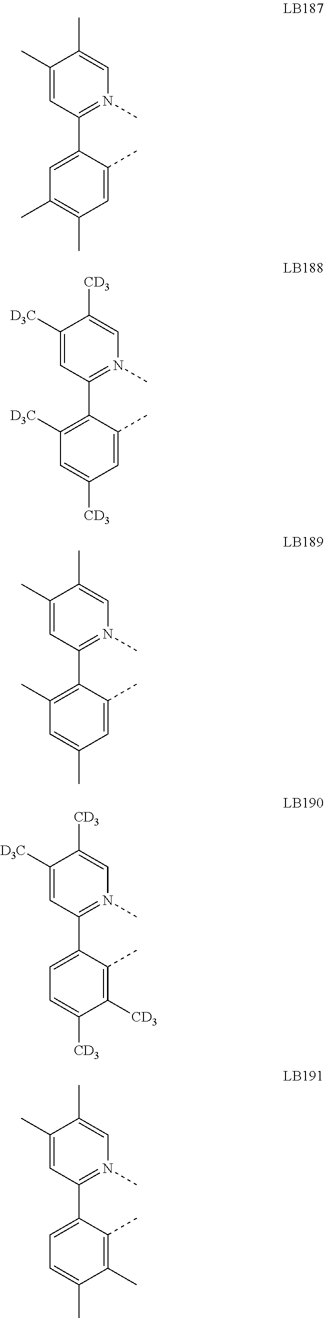

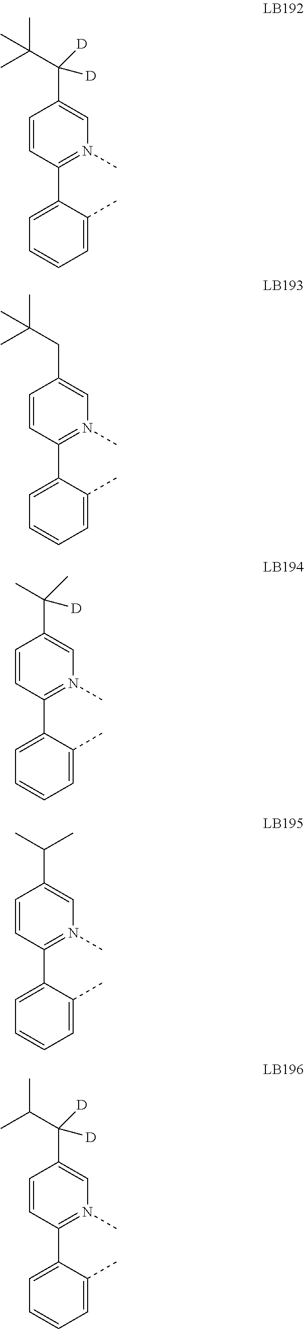

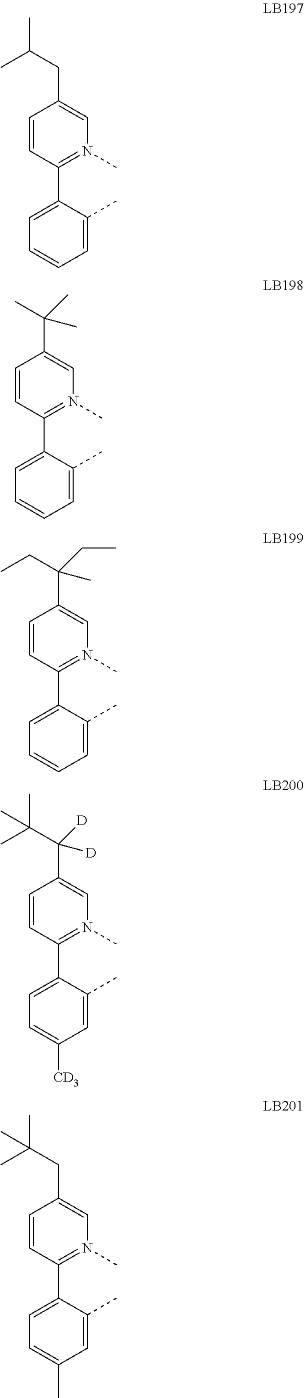

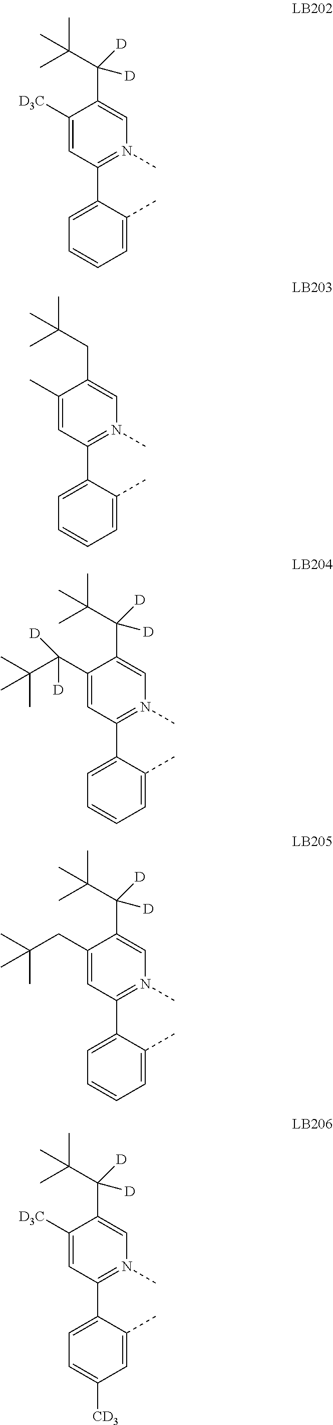

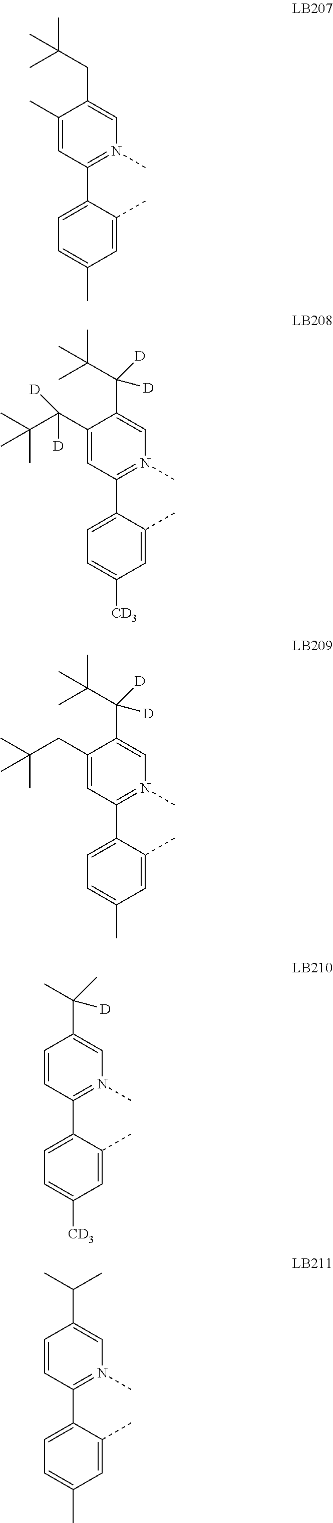

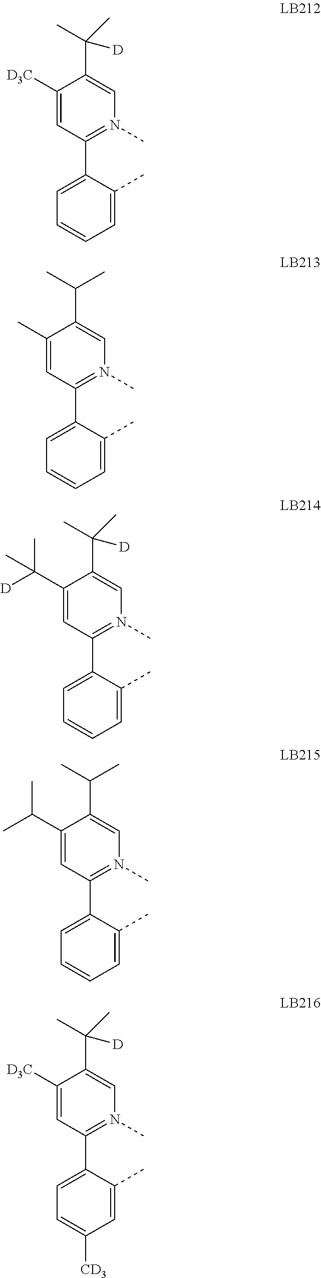

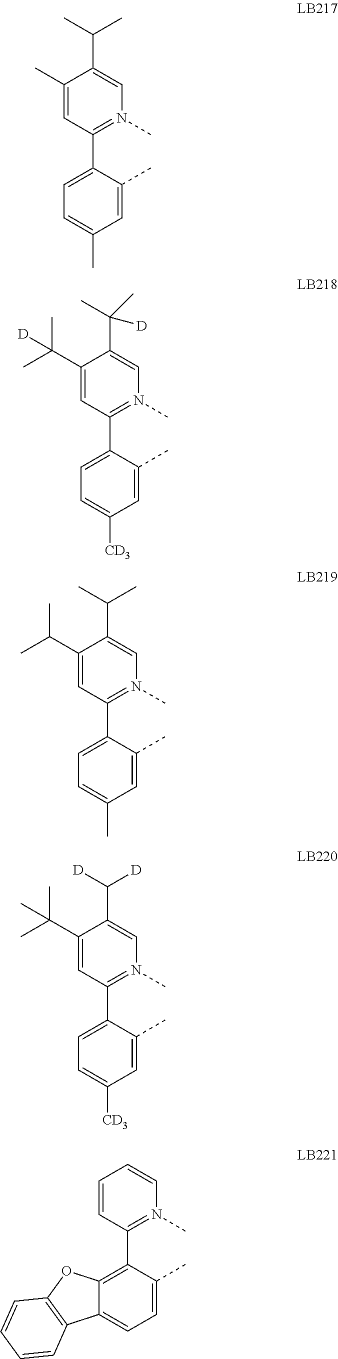

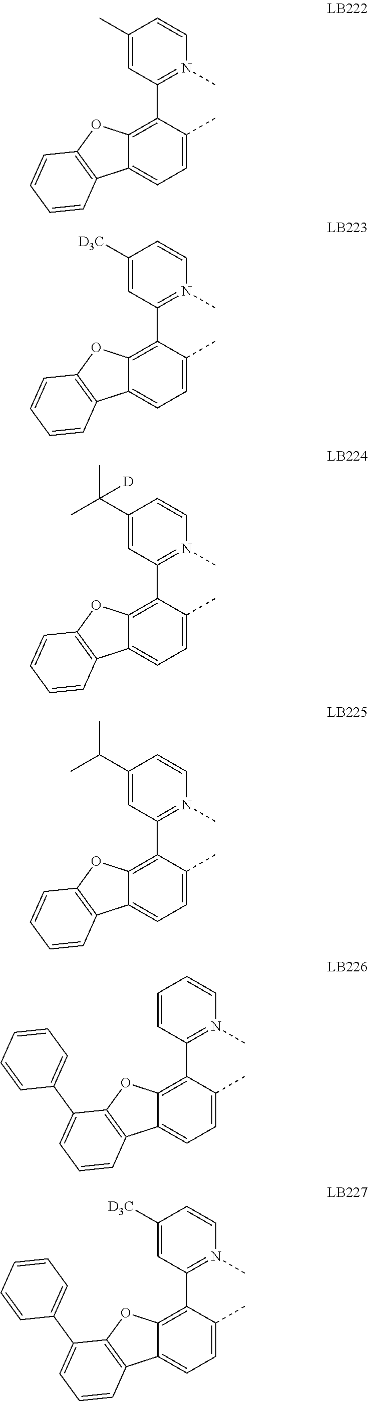

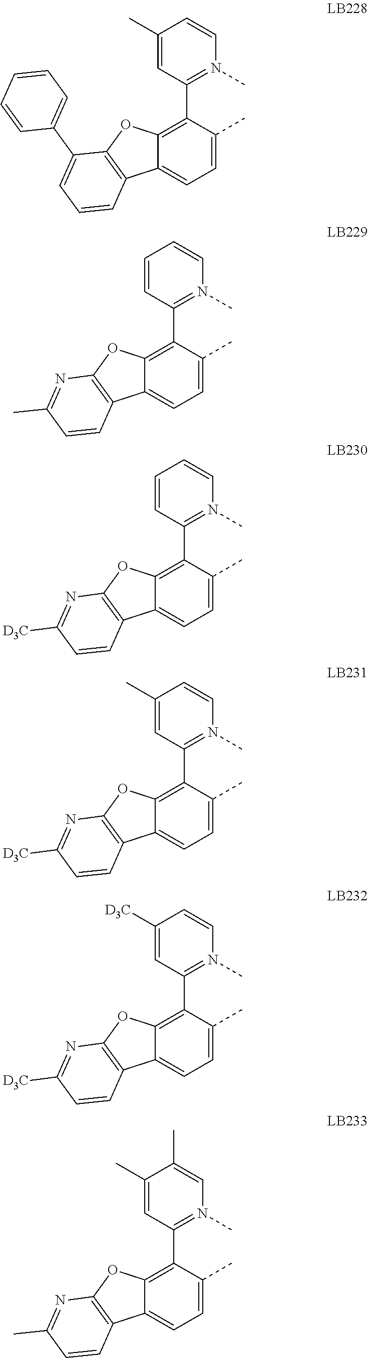

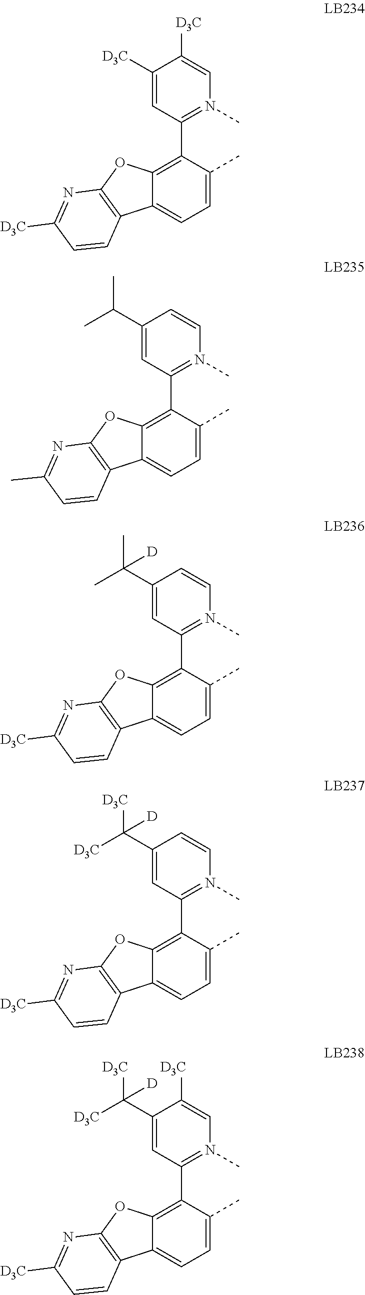

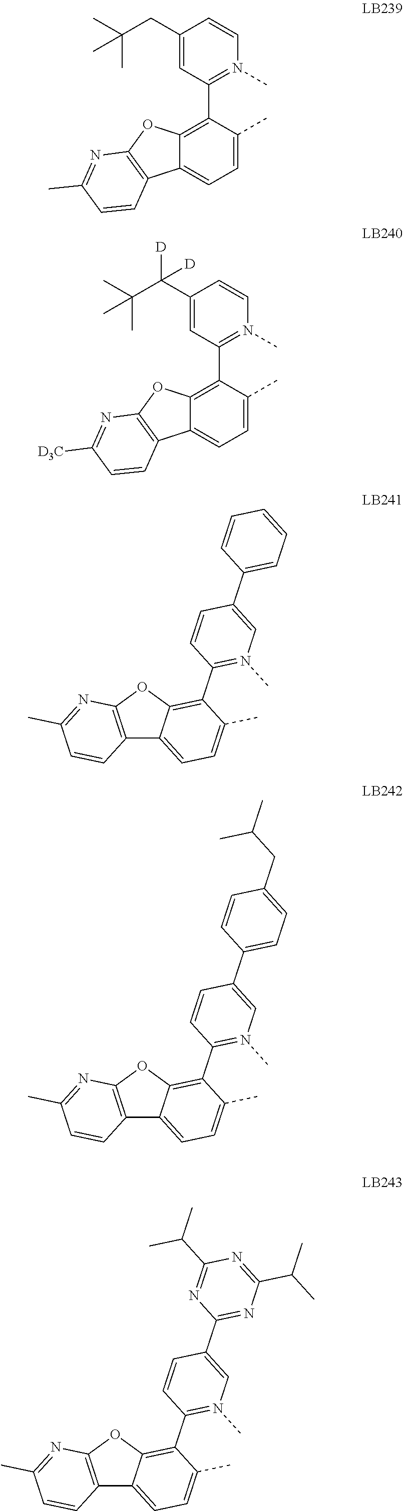

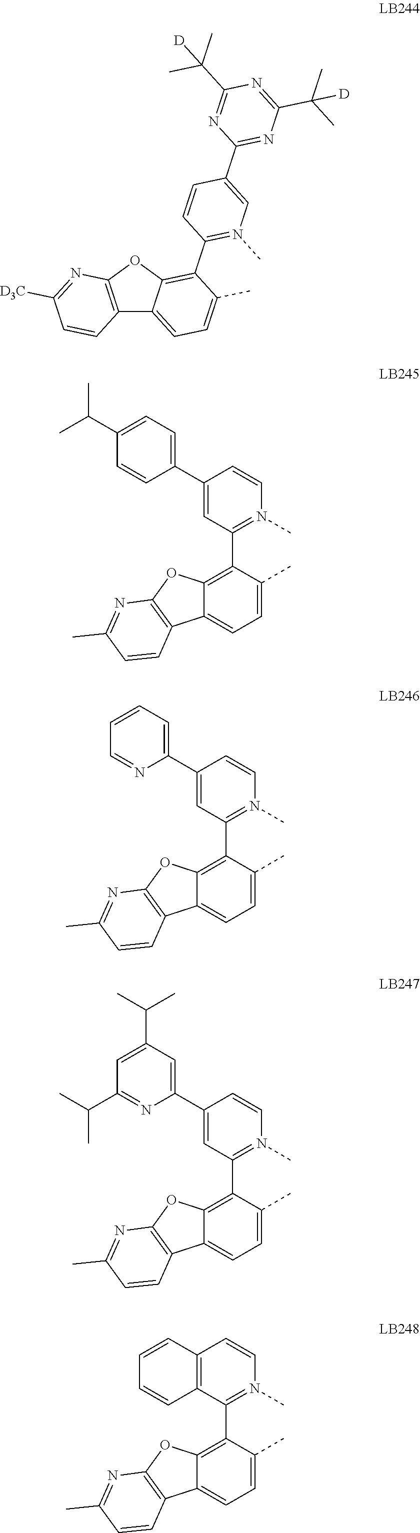

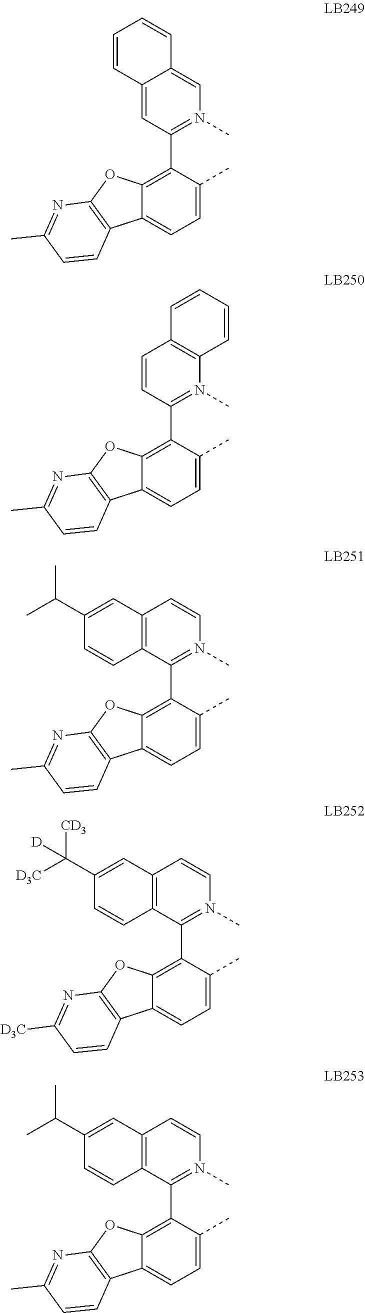

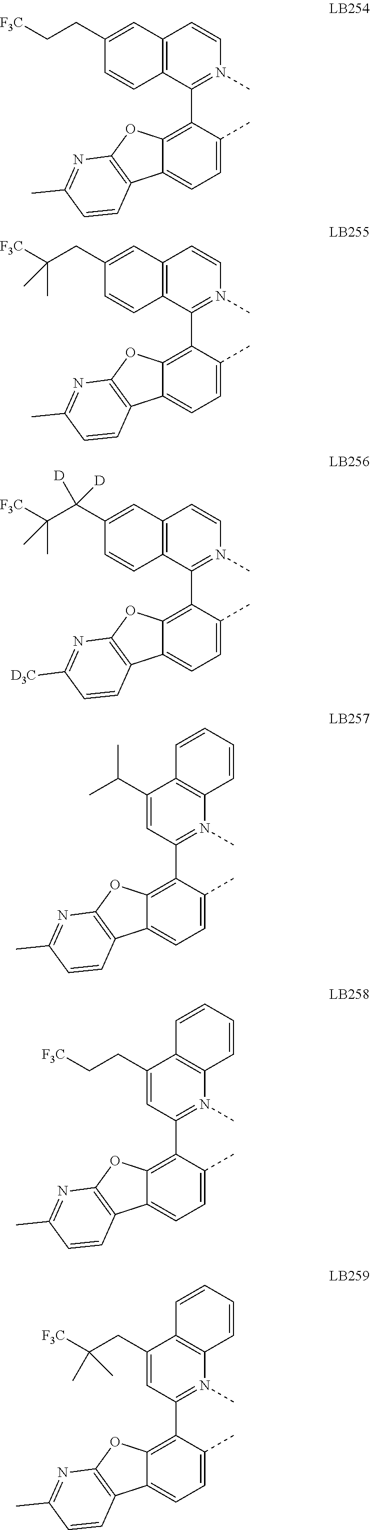

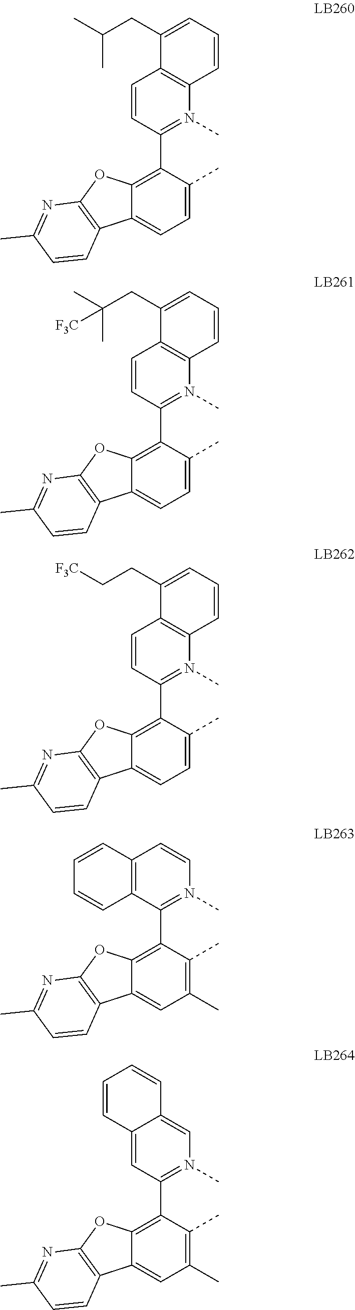

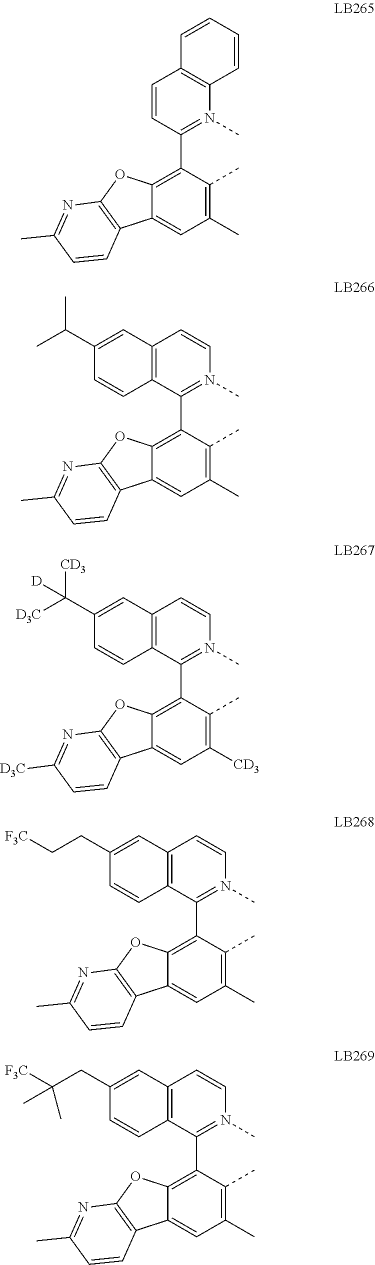

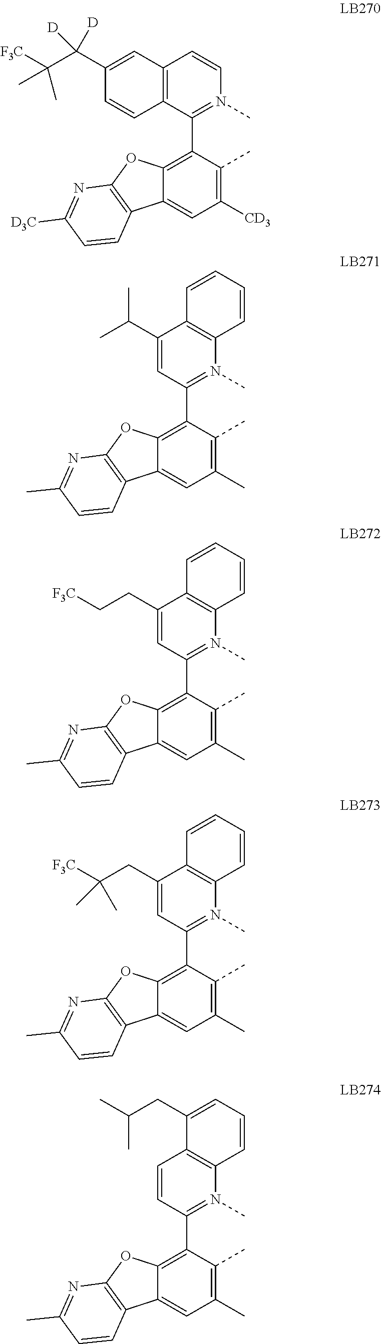

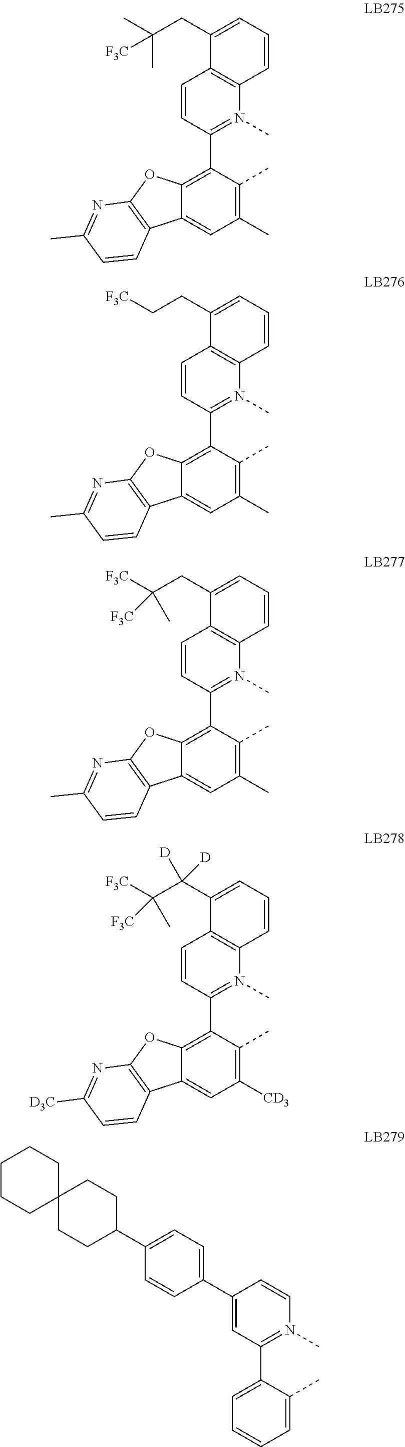

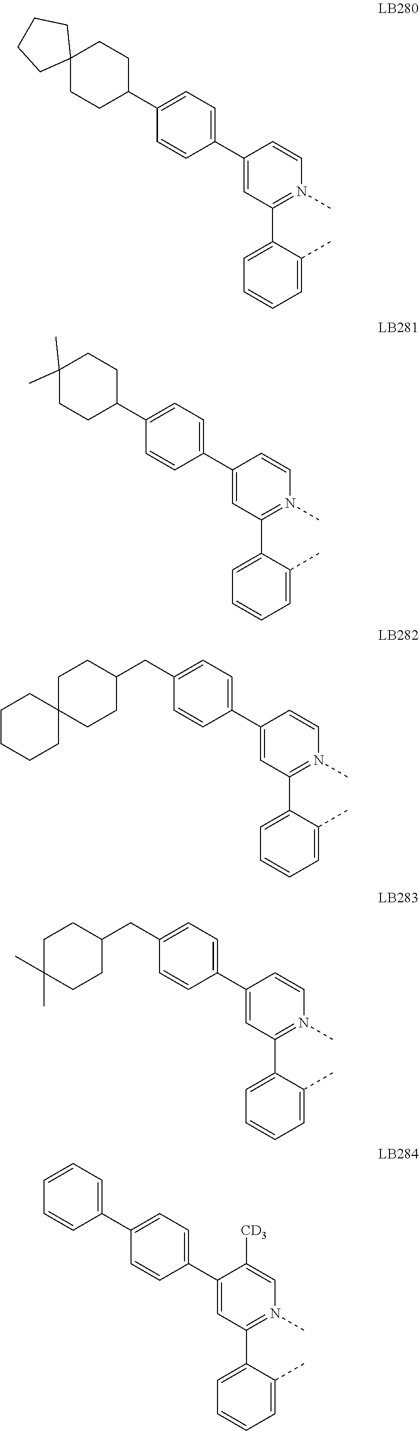

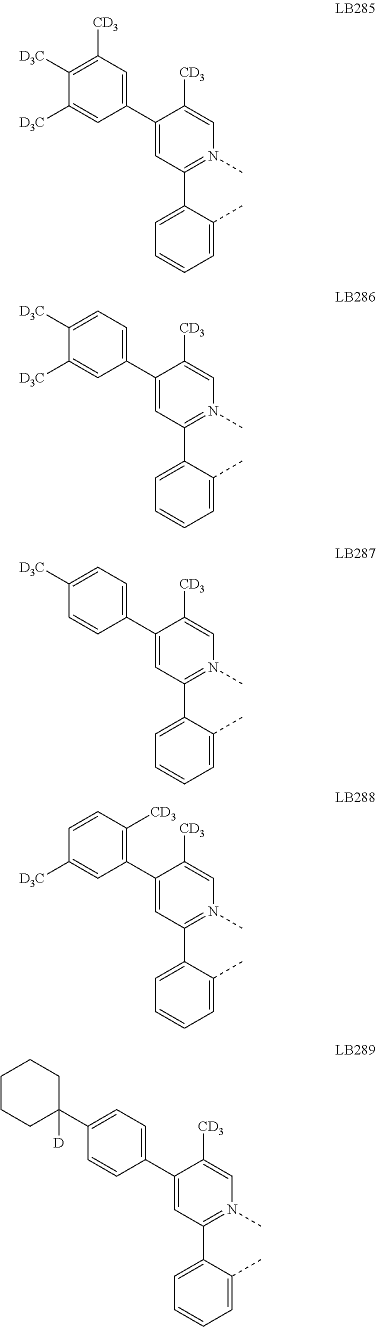

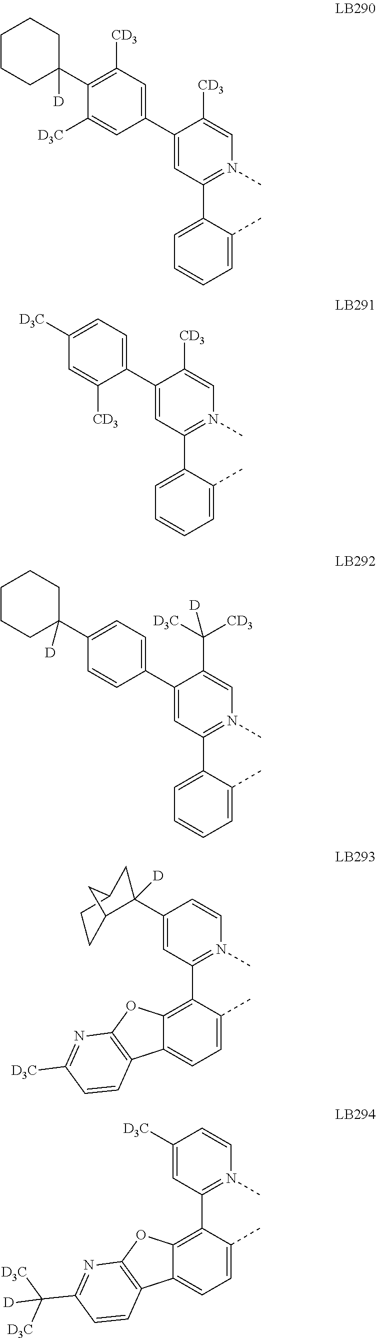

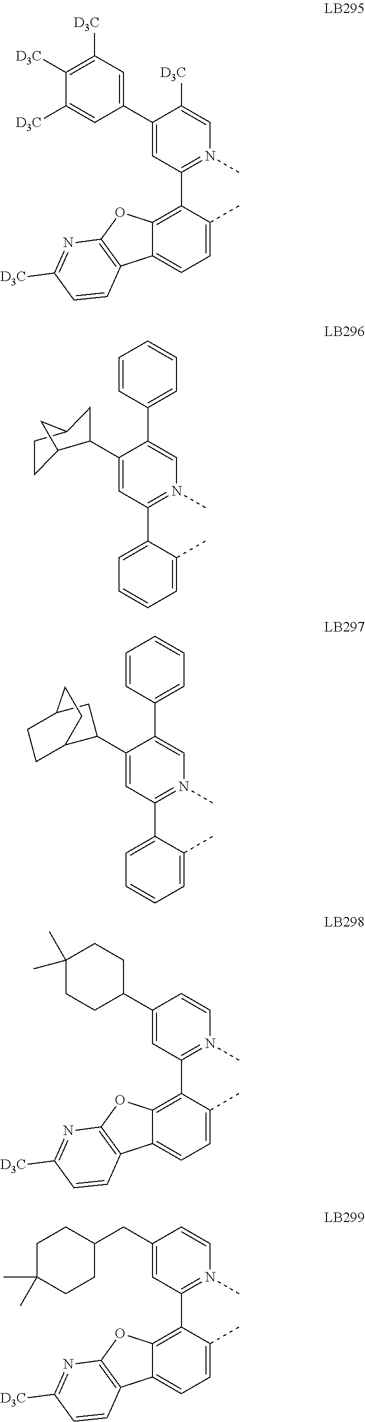

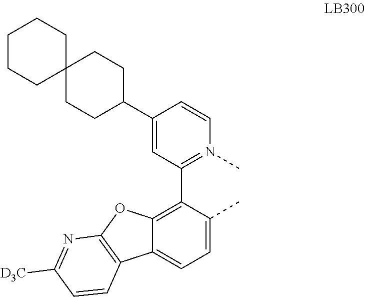

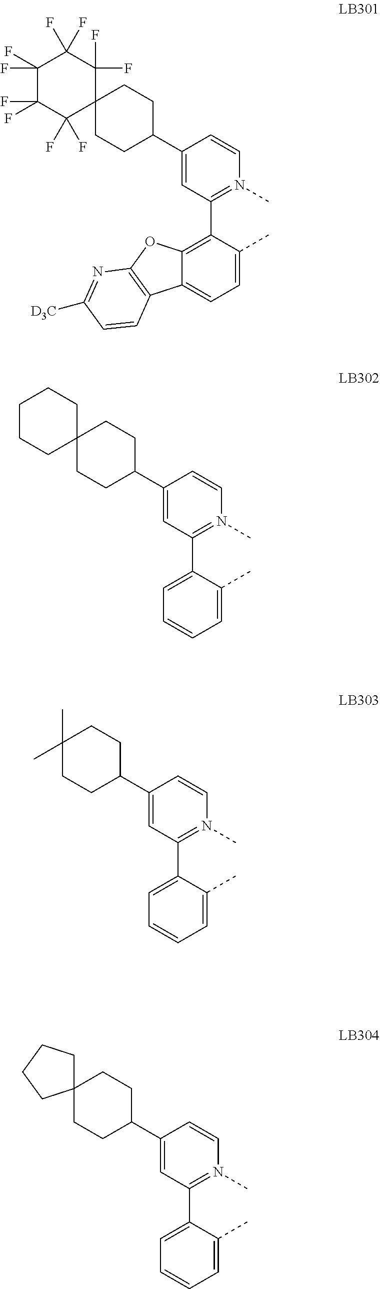

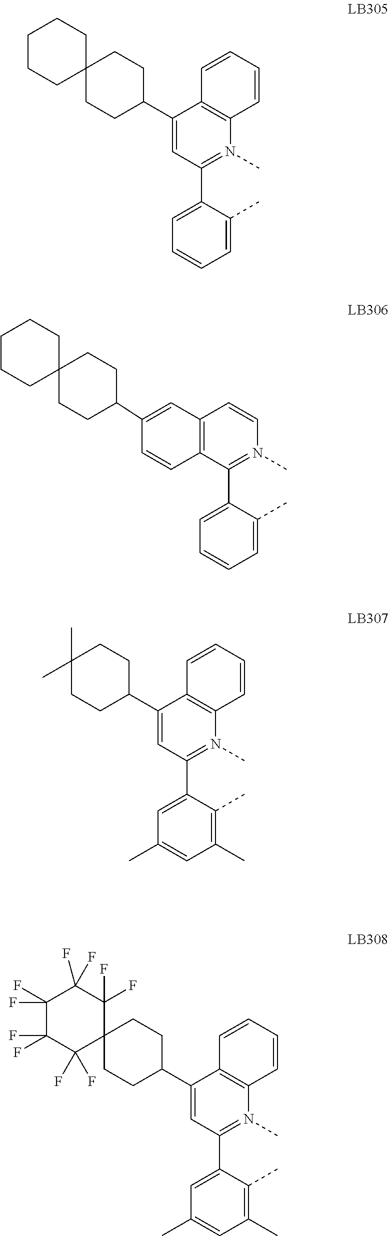

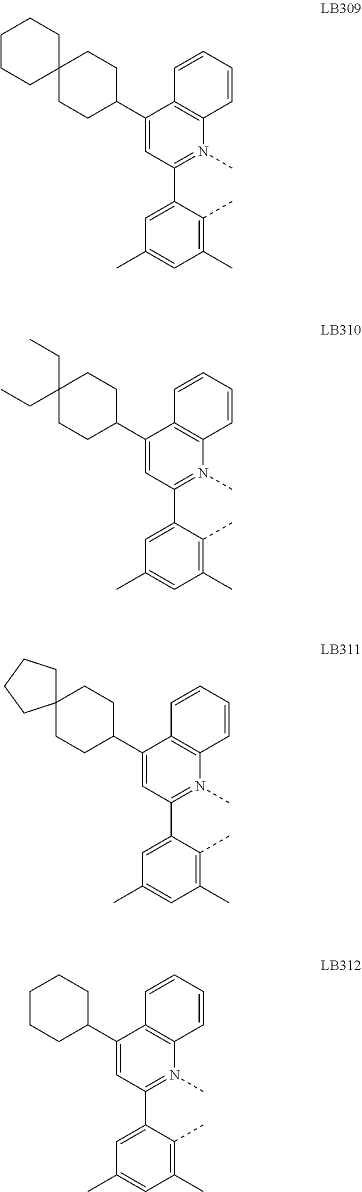

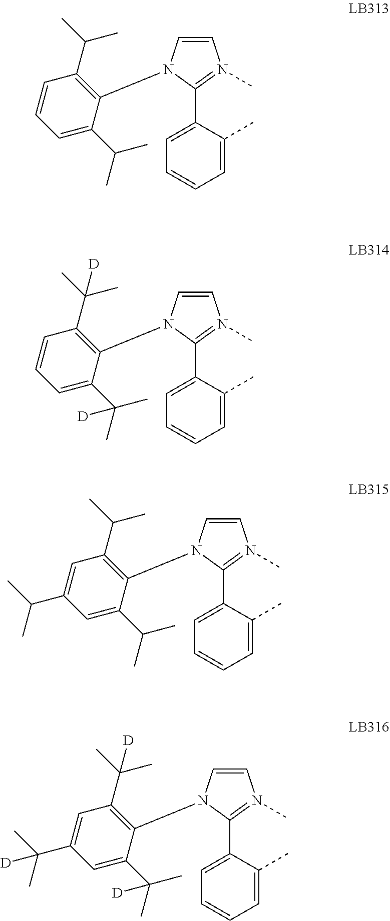

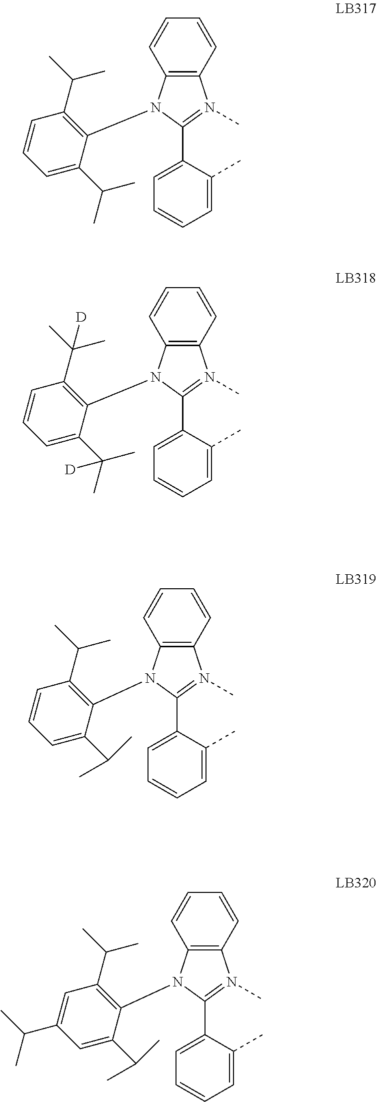

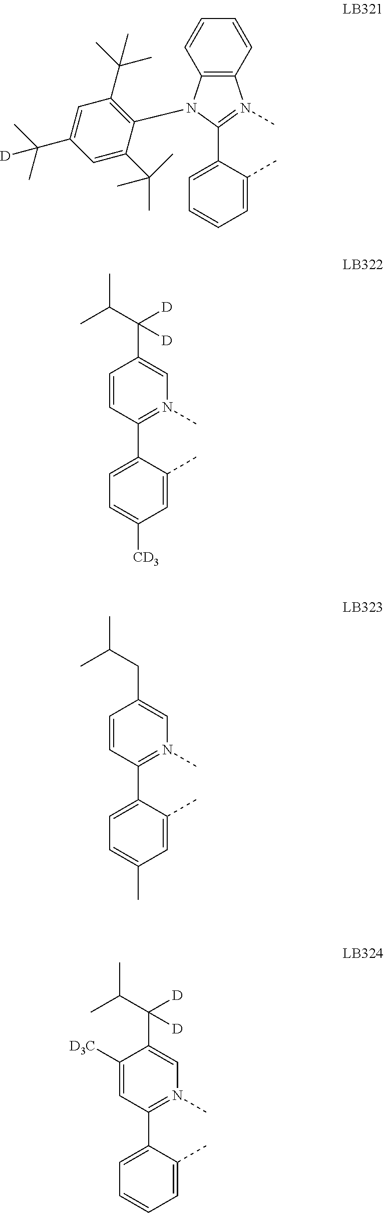

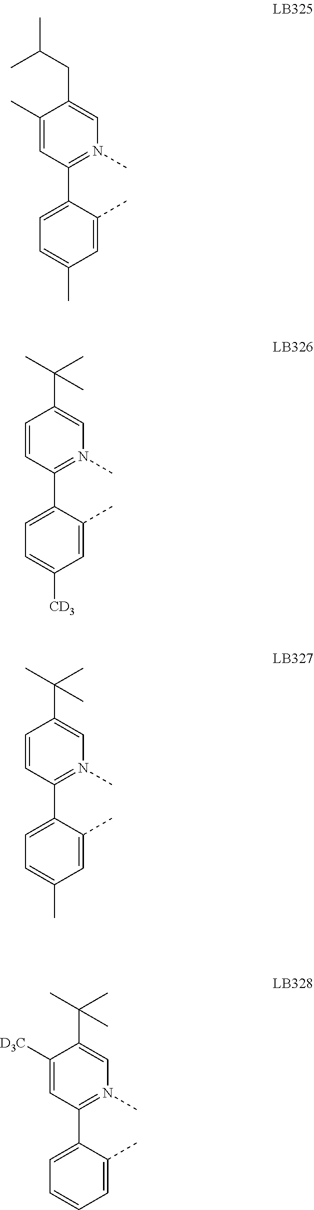

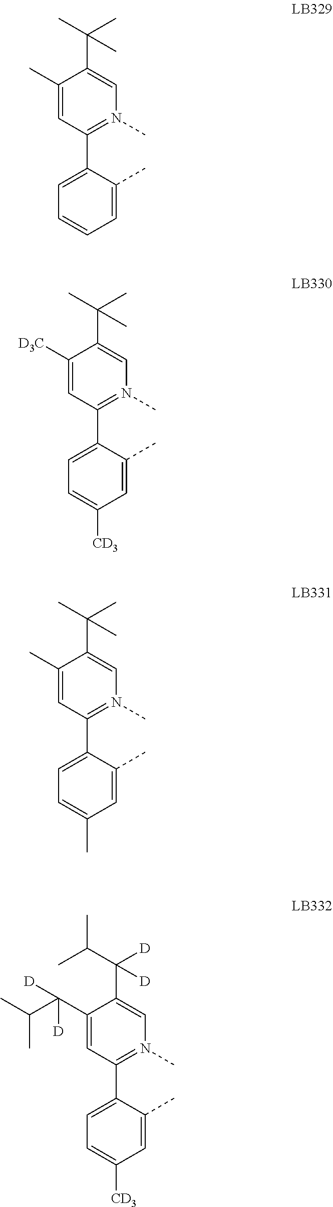

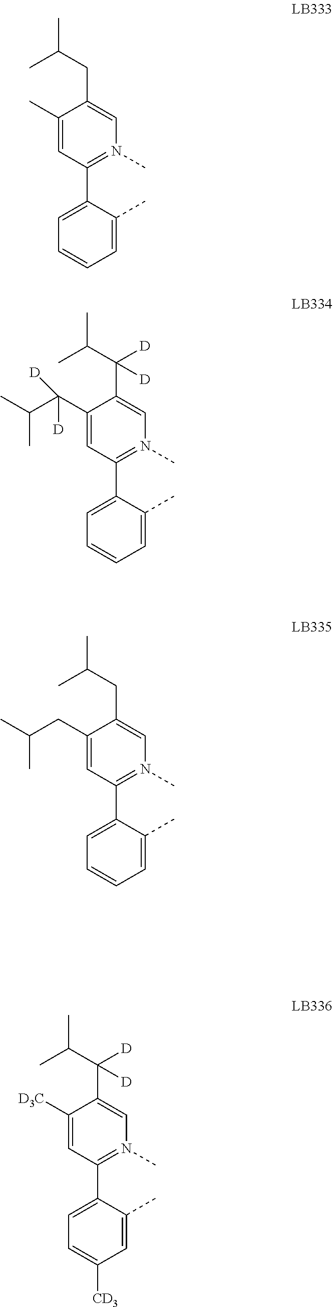

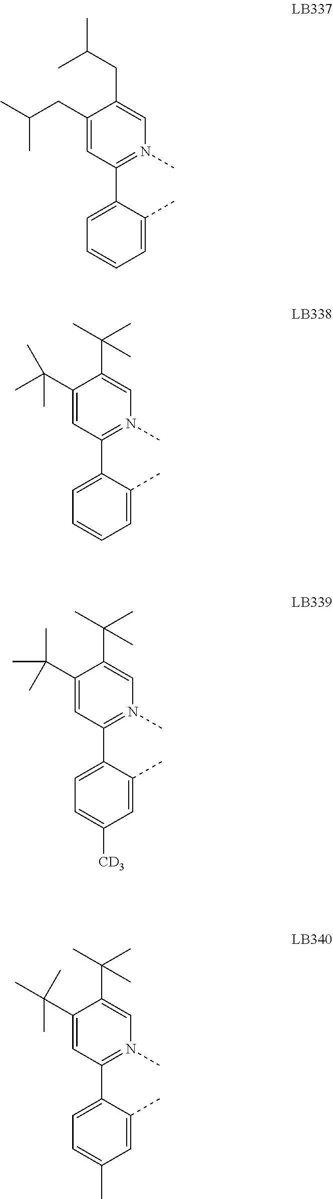

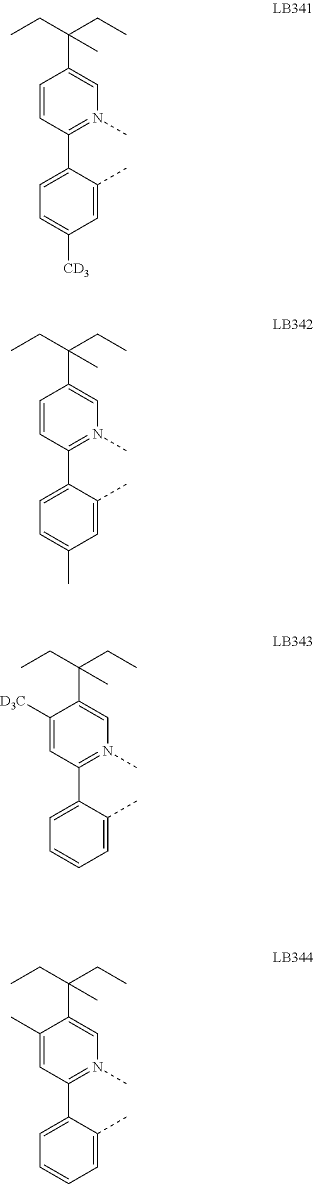

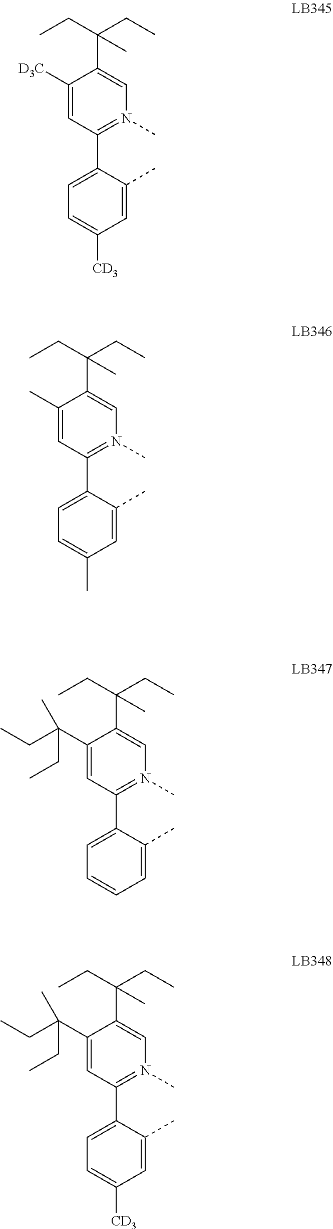

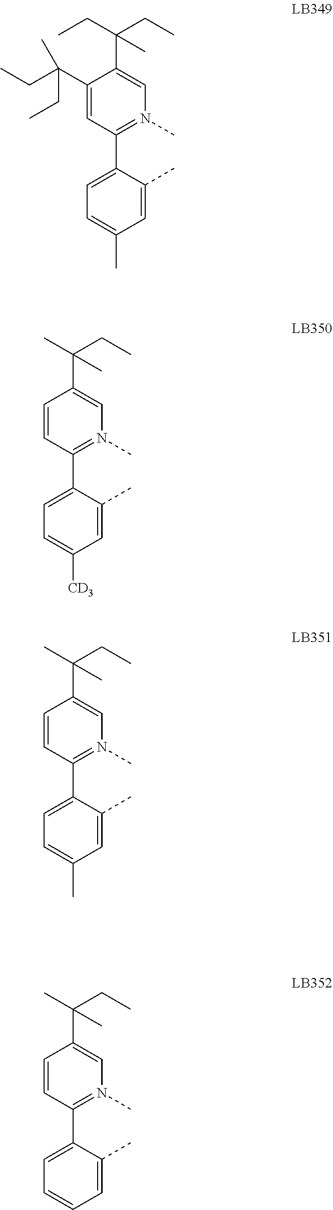

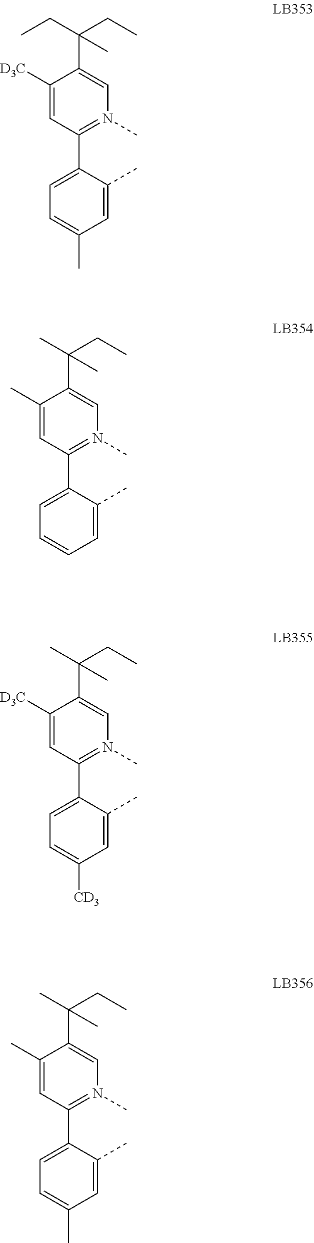

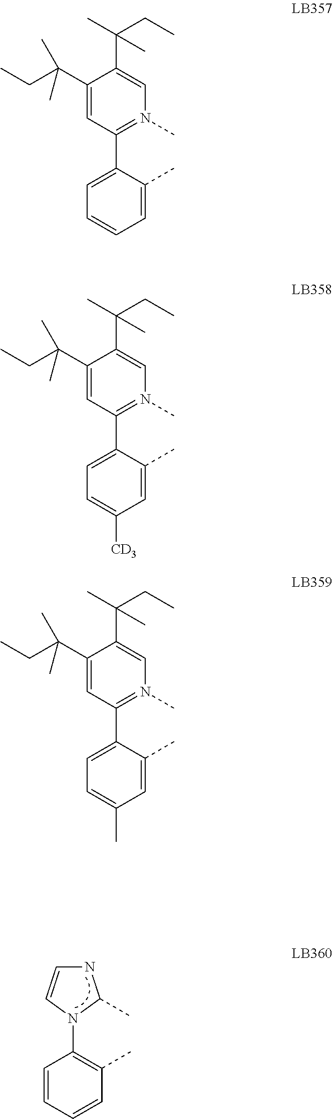

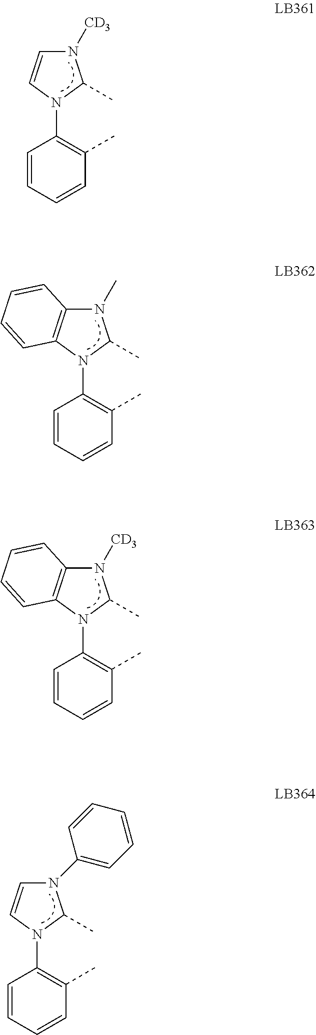

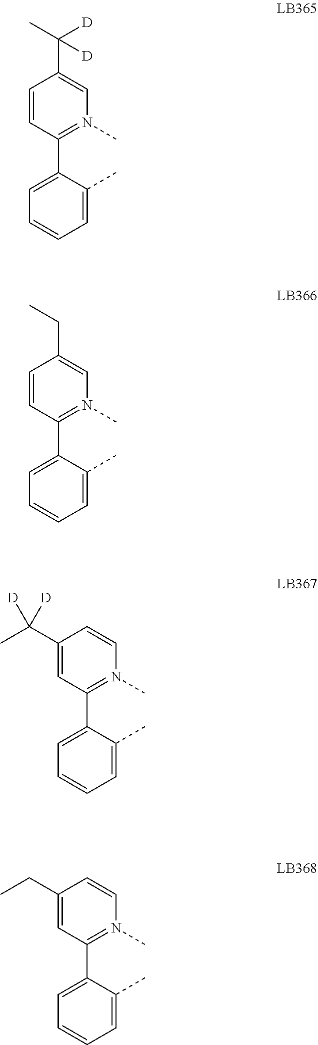

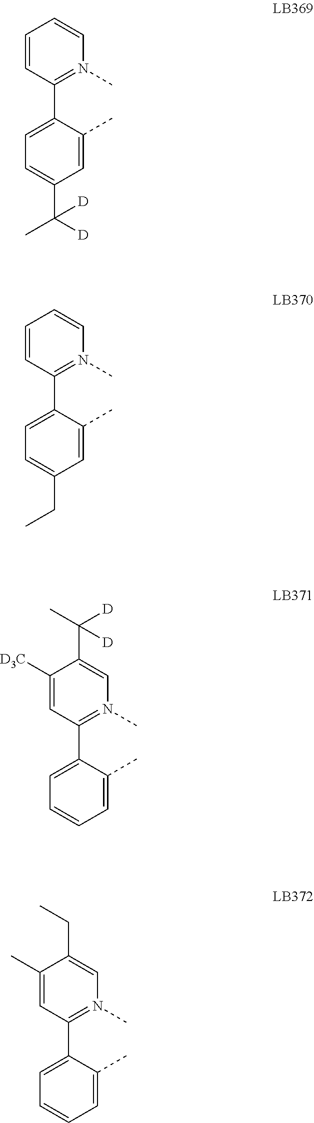

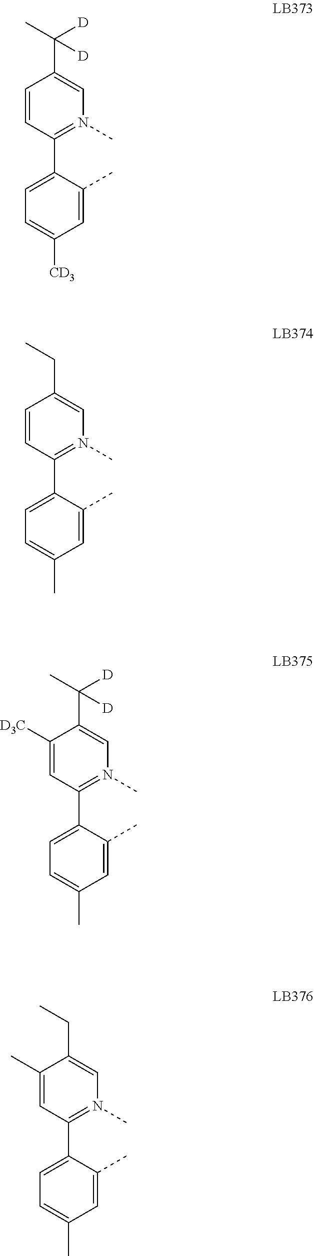

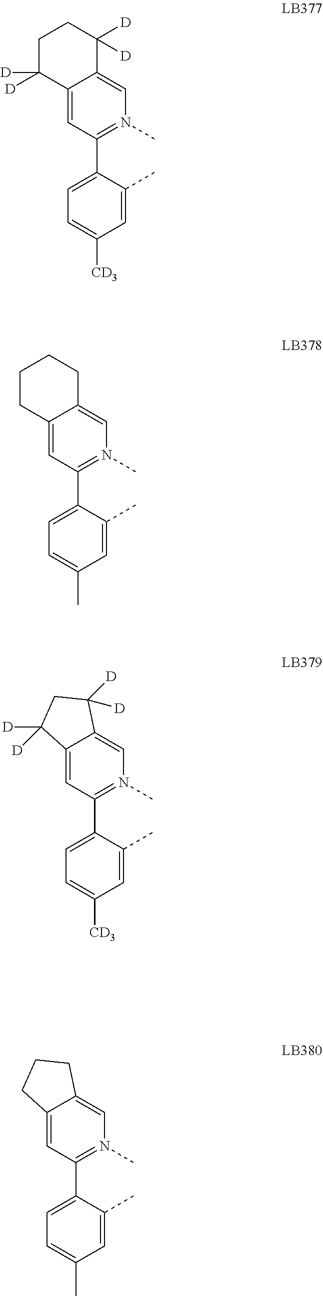

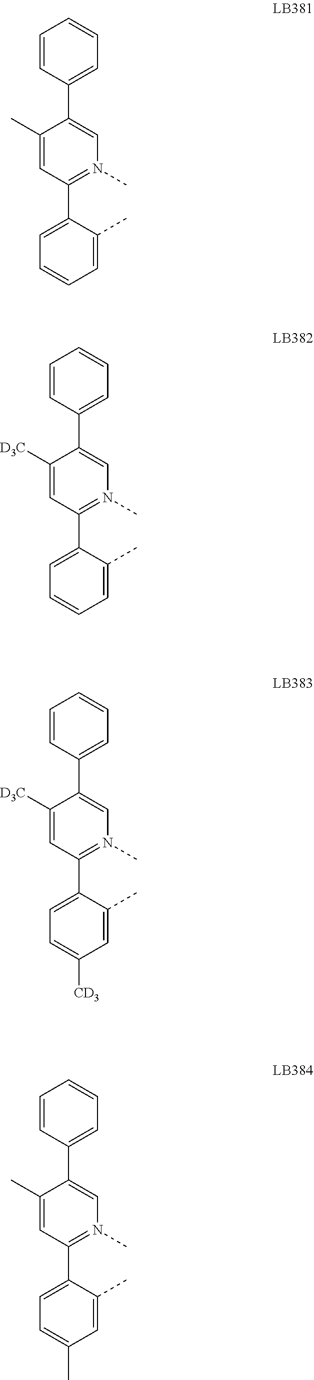

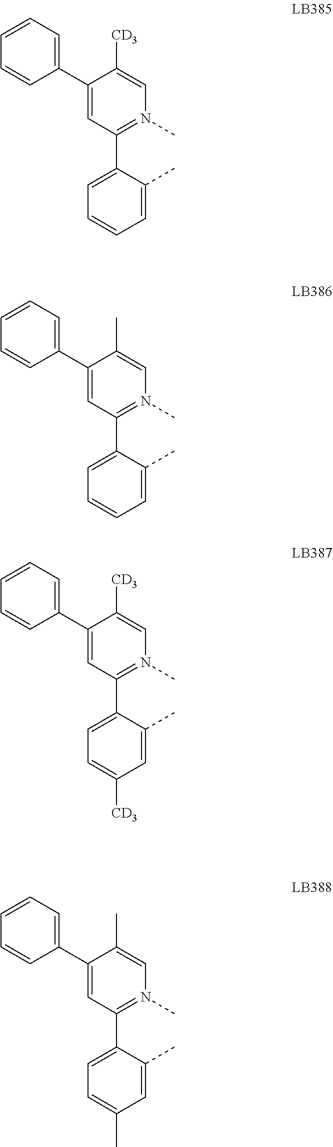

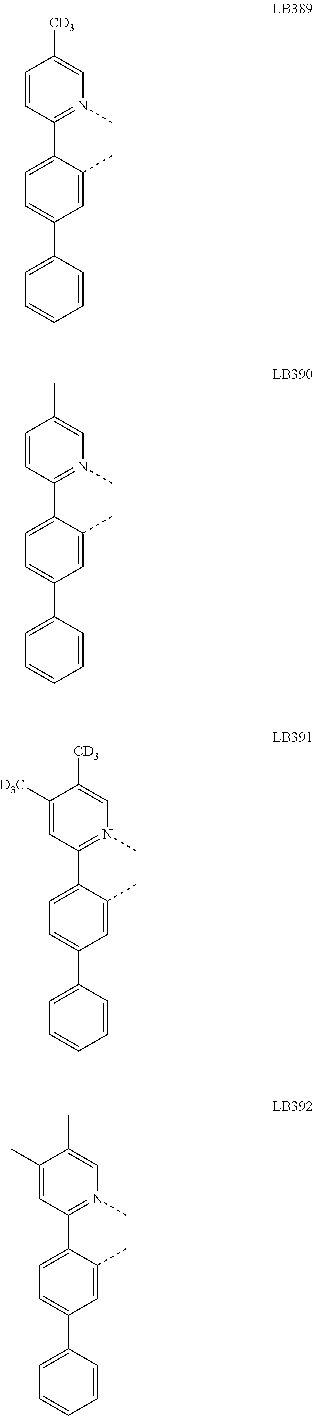

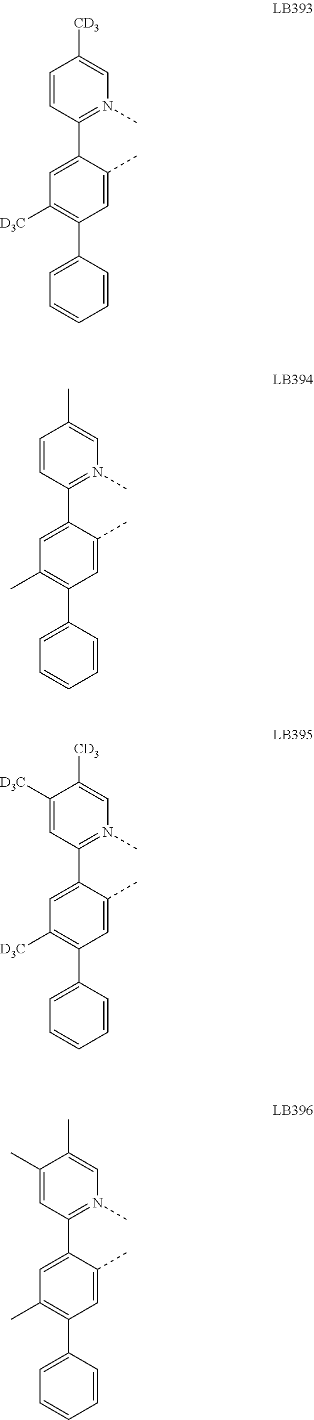

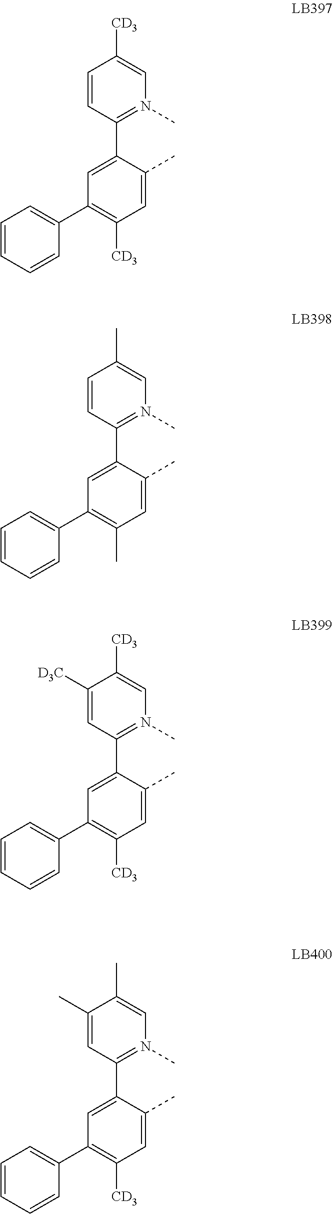

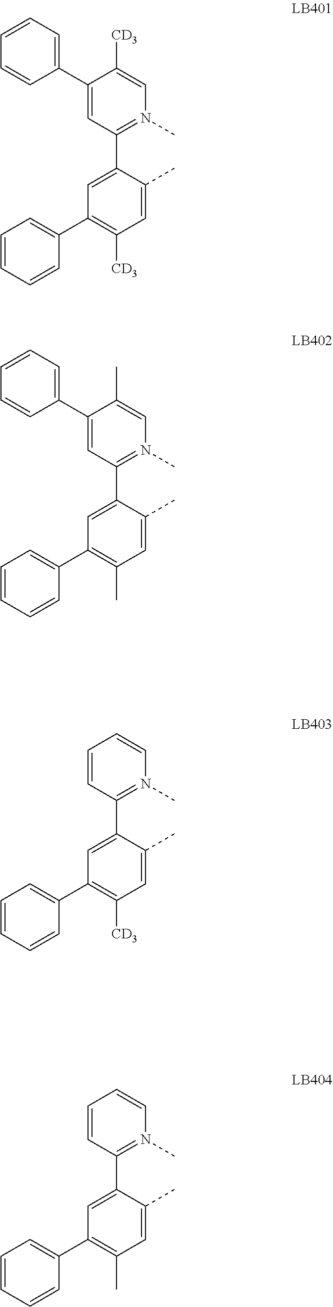

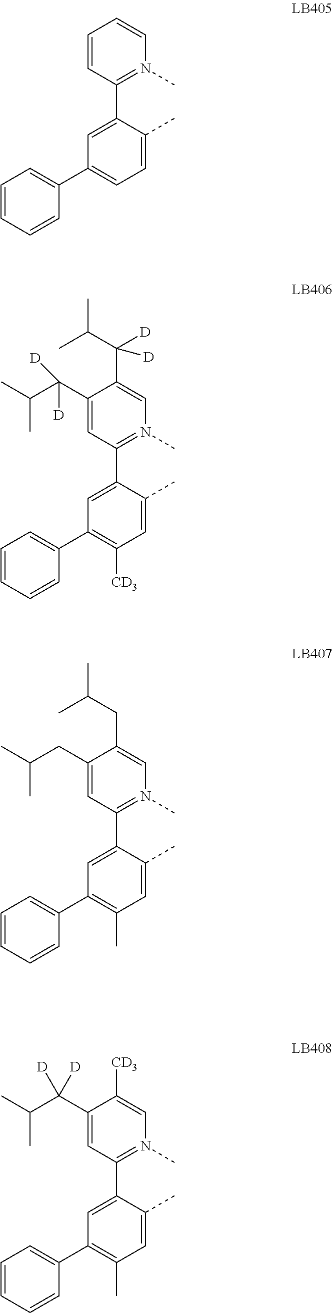

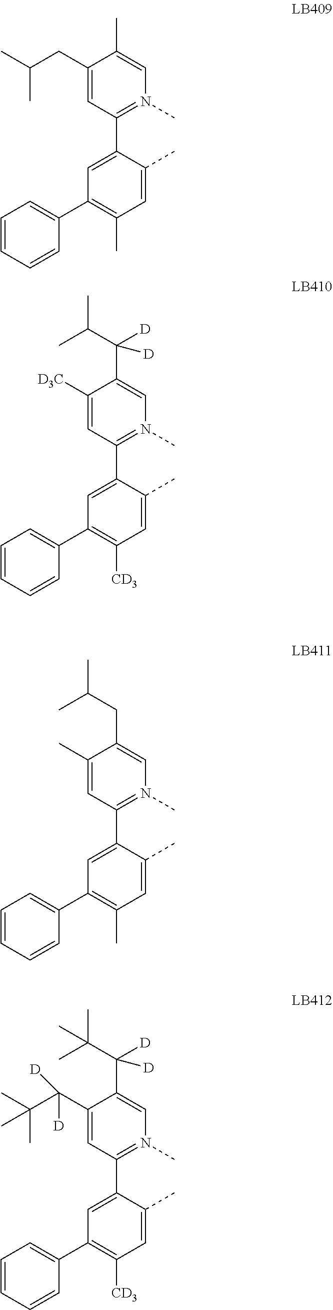

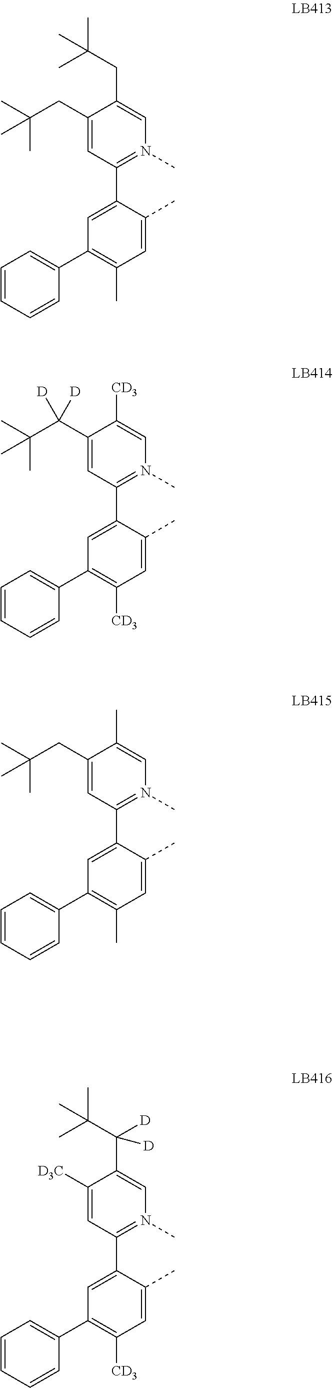

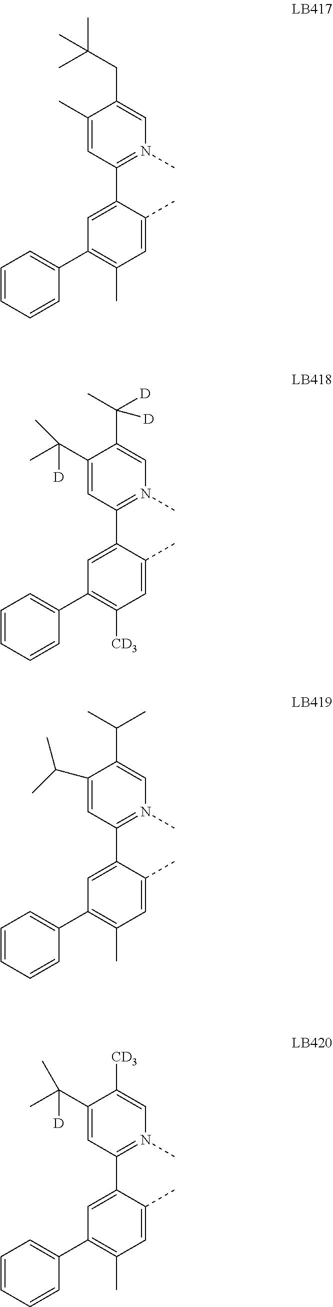

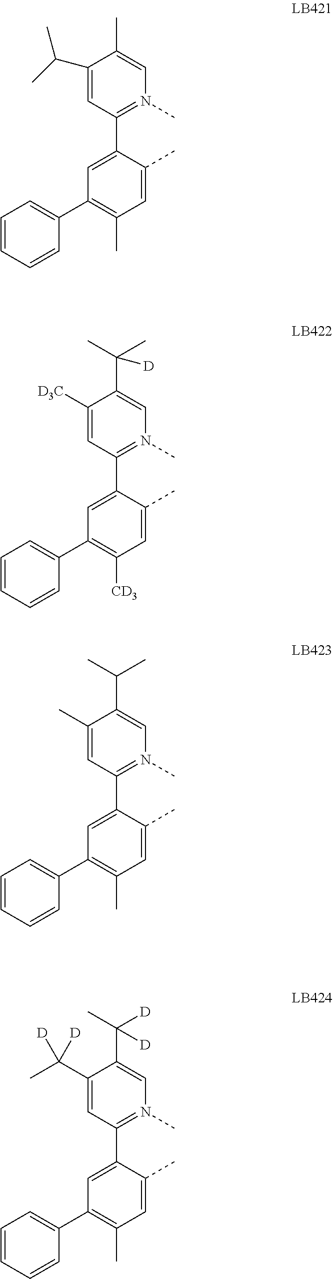

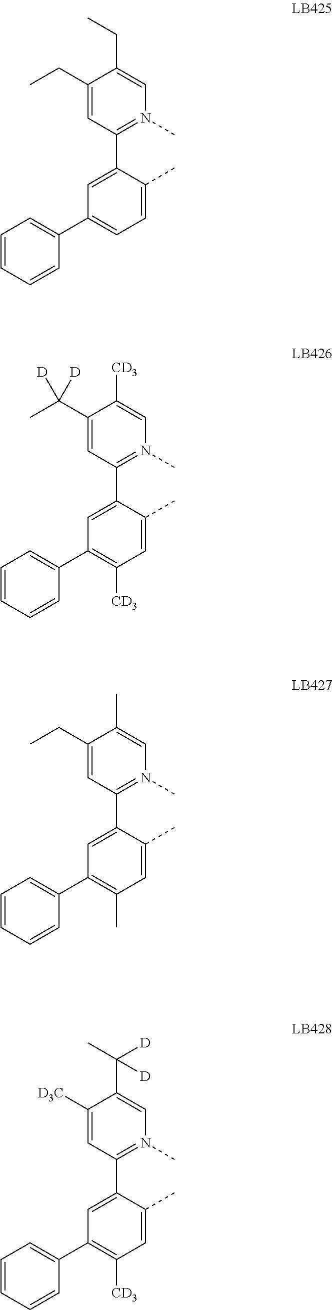

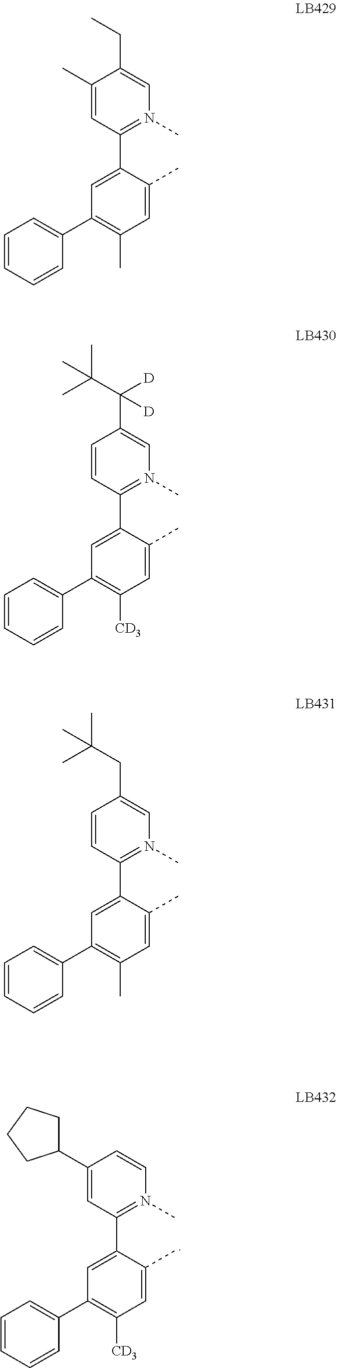

Further, the M is selected from one of Ir, Pd or Pt.

Further, the formula (LA) comprises one of LA1-LA208, and the LA1-LA208 have specific structures as follows:

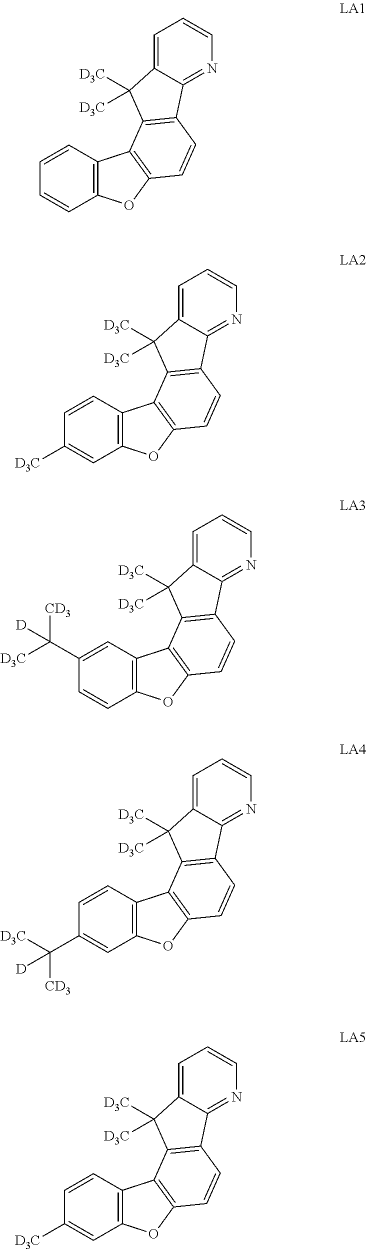 [SMILES: [2H]C([2H])([2H])C1(C([2H])([2H])[2H])c2cccnc2-c2ccc3oc4ccccc4c3c21 ; [2H]C([2H])([2H])c1ccc2c(c1)oc1ccc3c(c12)C(C([2H])([2H])[2H])(C([2H])([2H])[2H])c1cccnc1-3 ; [2H]C([2H])([2H])C([2H])(c1ccc2oc3ccc4c(c3c2c1)C(C([2H])([2H])[2H])(C([2H])([2H])[2H])c1cccnc1-4)C([2H])([2H])[2H] ; [2H]C([2H])([2H])C([2H])(c1ccc2c(c1)oc1ccc3c(c12)C(C([2H])([2H])[2H])(C([2H])([2H])[2H])c1cccnc1-3)C([2H])([2H])[2H] ; [2H]C([2H])([2H])c1ccc2c(c1)oc1ccc3c(c12)C(C([2H])([2H])[2H])(C([2H])([2H])[2H])c1cccnc1-3]

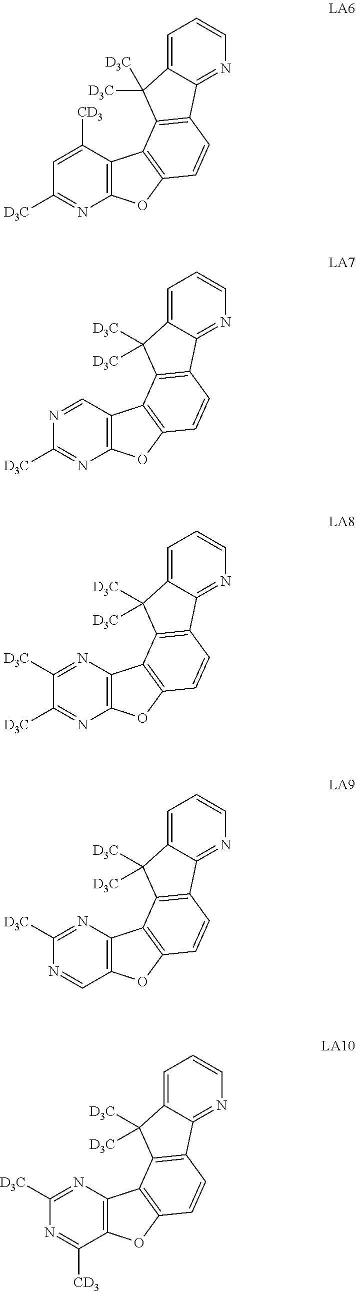

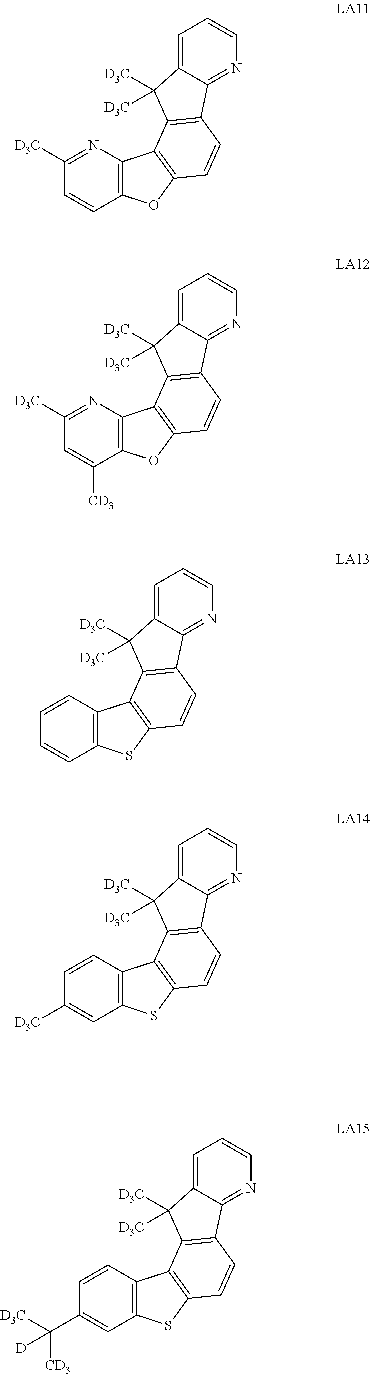 [SMILES: [2H]C([2H])([2H])c1ccc2oc3ccc4c(c3c2n1)C(C([2H])([2H])[2H])(C([2H])([2H])[2H])c1cccnc1-4 ; [2H]C([2H])([2H])c1cc(C([2H])([2H])[2H])c2oc3ccc4c(c3c2n1)C(C([2H])([2H])[2H])(C([2H])([2H])[2H])c1cccnc1-4 ; [2H]C([2H])([2H])C1(C([2H])([2H])[2H])c2cccnc2-c2ccc3sc4ccccc4c3c21 ; [2H]C([2H])([2H])c1ccc2c(c1)sc1ccc3c(c12)C(C([2H])([2H])[2H])(C([2H])([2H])[2H])c1cccnc1-3 ; [2H]C([2H])([2H])C([2H])(c1ccc2c(c1)sc1ccc3c(c12)C(C([2H])([2H])[2H])(C([2H])([2H])[2H])c1cccnc1-3)C([2H])([2H])[2H]]

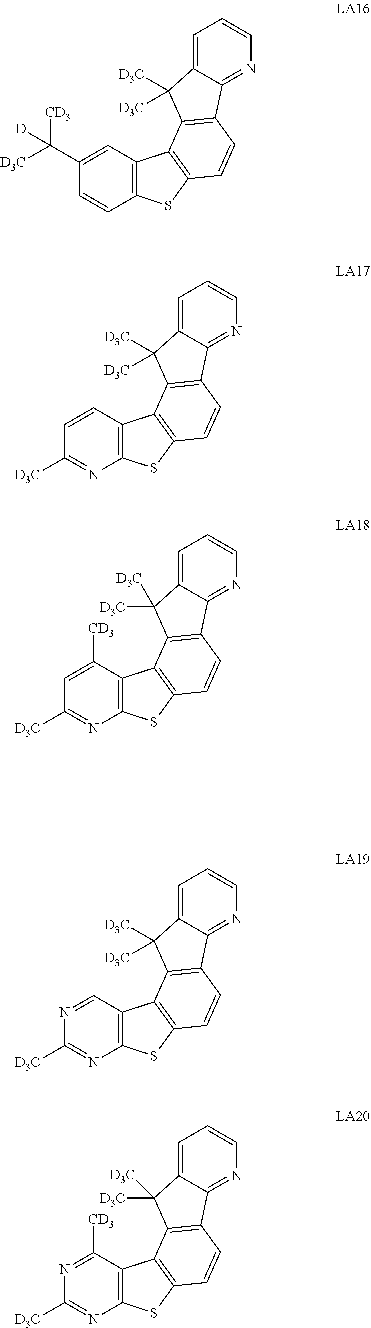

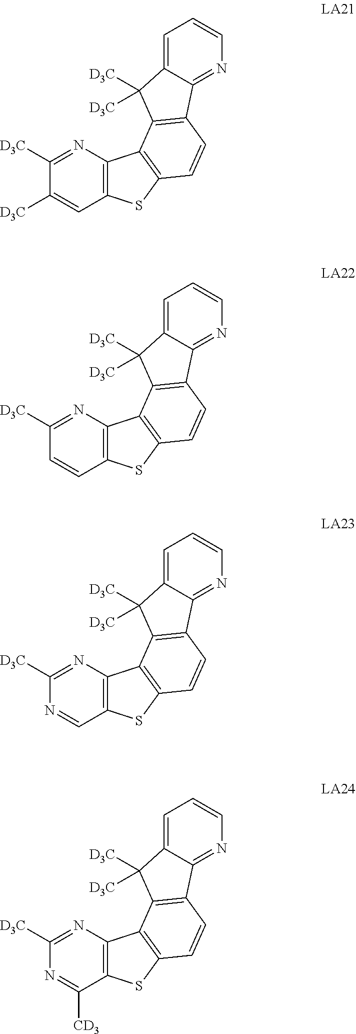 [SMILES: [2H]C([2H])([2H])c1cc2sc3ccc4c(c3c2nc1C([2H])([2H])[2H])C(C([2H])([2H])[2H])(C([2H])([2H])[2H])c1cccnc1-4 ; [2H]C([2H])([2H])c1ccc2sc3ccc4c(c3c2n1)C(C([2H])([2H])[2H])(C([2H])([2H])[2H])c1cccnc1-4 ; [2H]C([2H])([2H])c1ncc2sc3ccc4c(c3c2n1)C(C([2H])([2H])[2H])(C([2H])([2H])[2H])c1cccnc1-4 ; [2H]C([2H])([2H])c1nc(C([2H])([2H])[2H])c2sc3ccc4c(c3c2n1)C(C([2H])([2H])[2H])(C([2H])([2H])[2H])c1cccnc1-4]

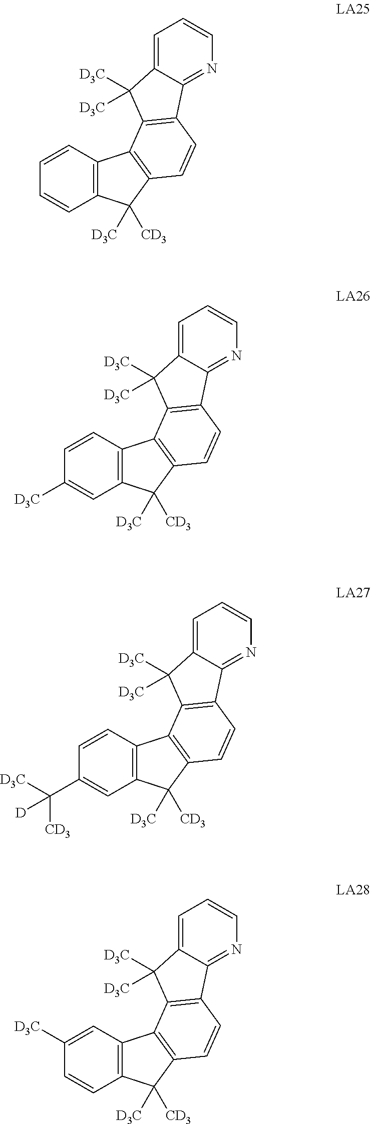

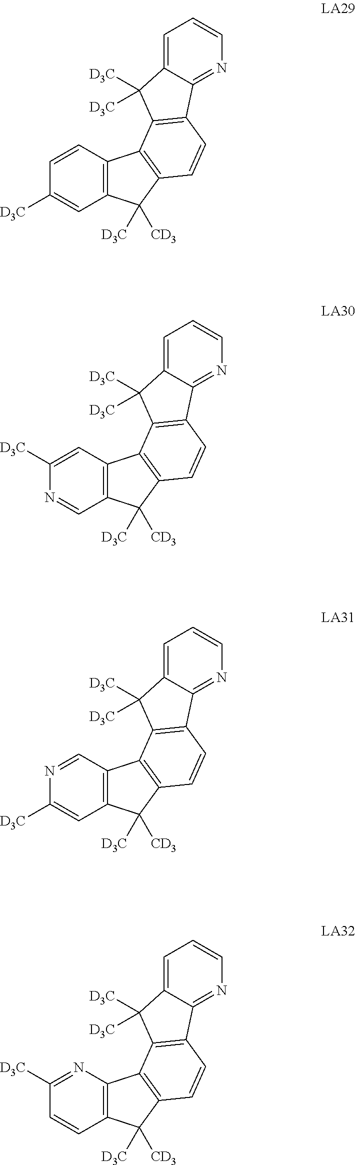

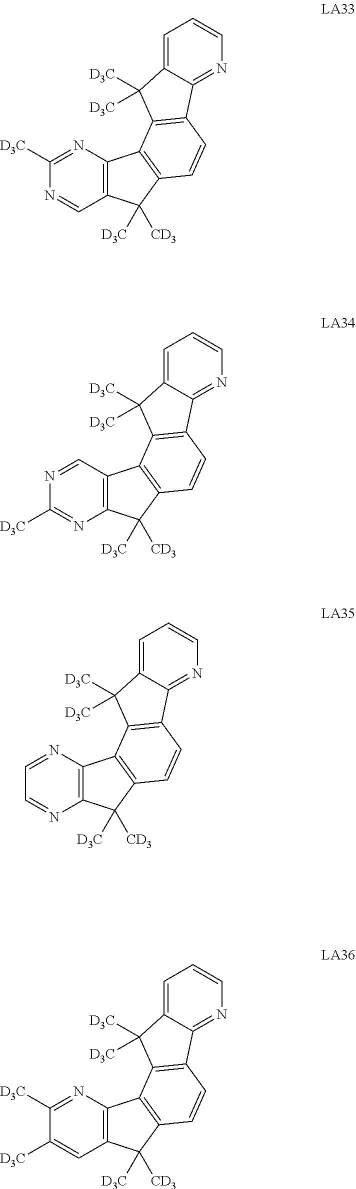

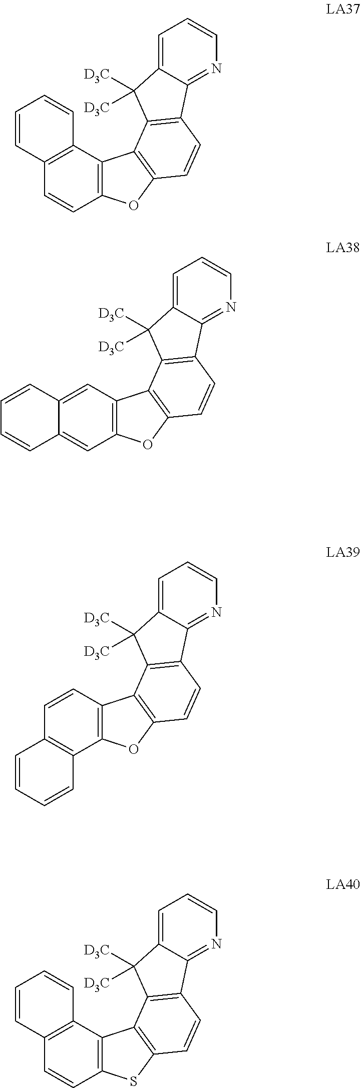 [SMILES: [2H]C([2H])([2H])C1(C([2H])([2H])[2H])c2cccnc2-c2ccc3oc4ccc5ccccc5c4c3c21 ; [2H]C([2H])([2H])C1(C([2H])([2H])[2H])c2cccnc2-c2ccc3oc4cc5ccccc5cc4c3c21 ; [2H]C([2H])([2H])C1(C([2H])([2H])[2H])c2cccnc2-c2ccc3oc4c5ccccc5ccc4c3c21 ; [2H]C([2H])([2H])C1(C([2H])([2H])[2H])c2cccnc2-c2ccc3sc4ccc5ccccc5c4c3c21]

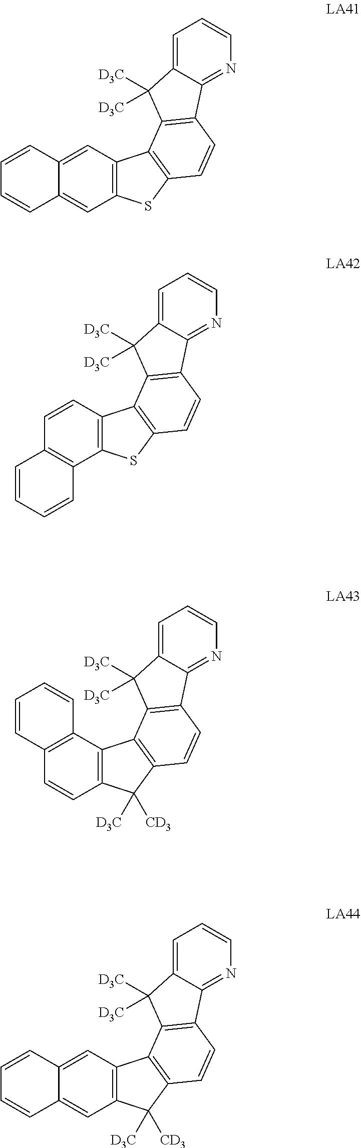 [SMILES: [2H]C([2H])([2H])C1(C([2H])([2H])[2H])c2cccnc2-c2ccc3sc4cc5ccccc5cc4c3c21 ; [2H]C([2H])([2H])C1(C([2H])([2H])[2H])c2cccnc2-c2ccc3sc4c5ccccc5ccc4c3c21 ; [2H]C([2H])([2H])C1(C([2H])([2H])[2H])c2ccc3c(c2-c2c1ccc1ccccc21)C(C([2H])([2H])[2H])(C([2H])([2H])[2H])c1cccnc1-3 ; [2H]C([2H])([2H])C1(C([2H])([2H])[2H])c2cc3ccccc3cc2-c2c1ccc1c2C(C([2H])([2H])[2H])(C([2H])([2H])[2H])c2cccnc2-1]

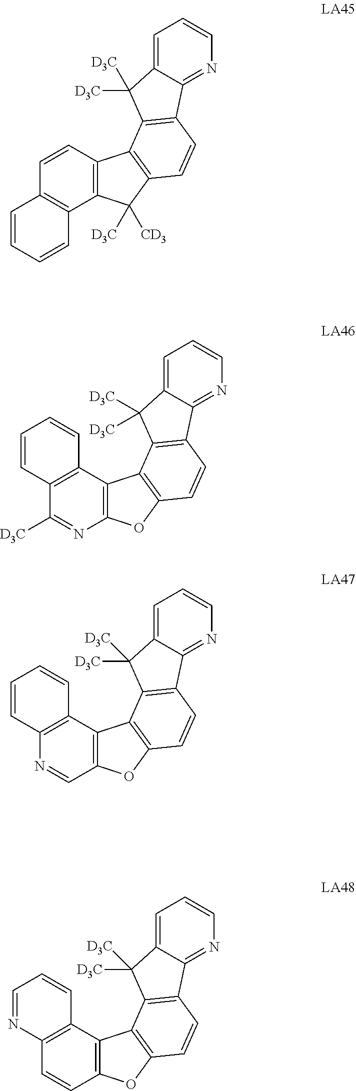 [SMILES: [2H]C([2H])([2H])C1(C([2H])([2H])[2H])c2cccnc2-c2ccc3c(c21)-c1ccc2ccccc2c1C3(C([2H])([2H])[2H])C([2H])([2H])[2H] ; [2H]C([2H])([2H])c1nc2oc3ccc4c(c3c2c2ccccc12)C(C([2H])([2H])[2H])(C([2H])([2H])[2H])c1cccnc1-4 ; [2H]C([2H])([2H])C1(C([2H])([2H])[2H])c2cccnc2-c2ccc3oc4cnc5ccccc5c4c3c21 ; [2H]C([2H])([2H])C1(C([2H])([2H])[2H])c2cccnc2-c2ccc3oc4ccc5ncccc5c4c3c21]

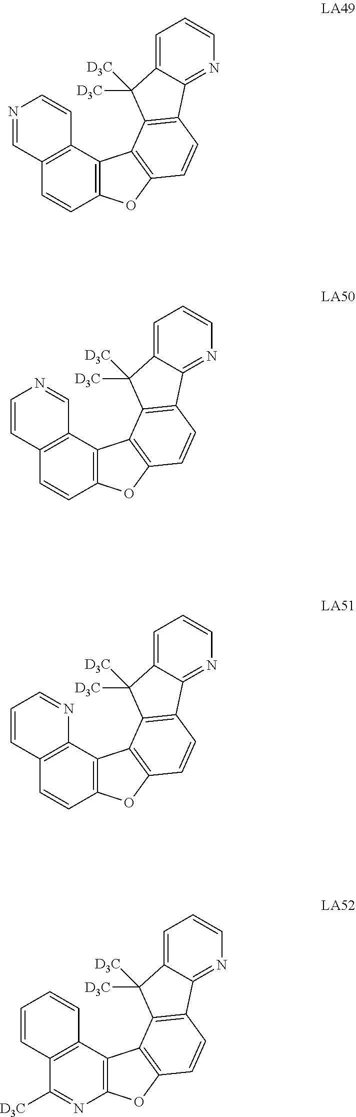 [SMILES: [2H]C([2H])([2H])C1(C([2H])([2H])[2H])c2cccnc2-c2ccc3oc4ccc5cnccc5c4c3c21 ; [2H]C([2H])([2H])C1(C([2H])([2H])[2H])c2cccnc2-c2ccc3oc4ccc5ccncc5c4c3c21 ; [2H]C([2H])([2H])C1(C([2H])([2H])[2H])c2cccnc2-c2ccc3oc4ccc5cccnc5c4c3c21 ; [2H]C([2H])([2H])c1nc2oc3ccc4c(c3c2c2ccccc12)C(C([2H])([2H])[2H])(C([2H])([2H])[2H])c1cccnc1-4]

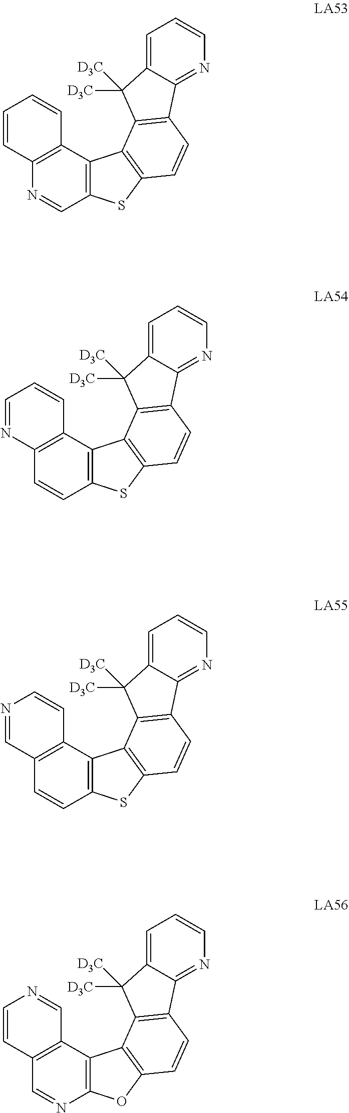 [SMILES: [2H]C([2H])([2H])C1(C([2H])([2H])[2H])c2cccnc2-c2ccc3sc4cnc5ccccc5c4c3c21 ; [2H]C([2H])([2H])C1(C([2H])([2H])[2H])c2cccnc2-c2ccc3sc4ccc5ncccc5c4c3c21 ; [2H]C([2H])([2H])C1(C([2H])([2H])[2H])c2cccnc2-c2ccc3sc4ccc5cnccc5c4c3c21 ; [2H]C([2H])([2H])C1(C([2H])([2H])[2H])c2cccnc2-c2ccc3oc4ncc5ccncc5c4c3c21]

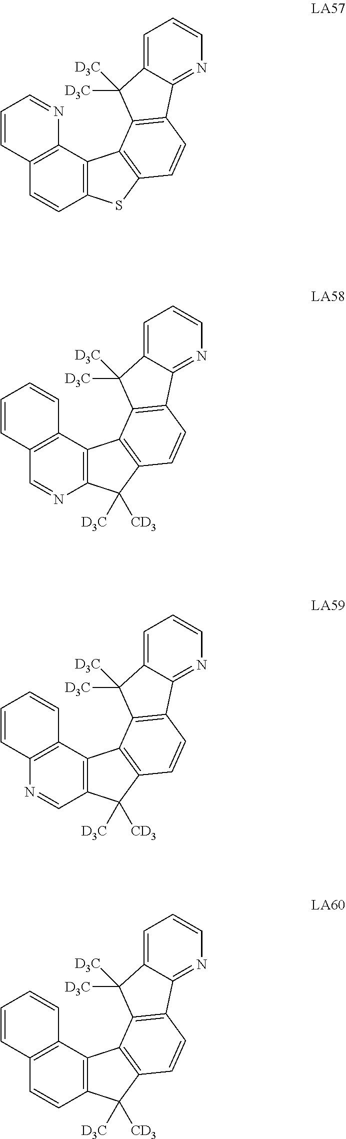 [SMILES: [2H]C([2H])([2H])C1(C([2H])([2H])[2H])c2cccnc2-c2ccc3sc4ccc5cccnc5c4c3c21 ; [2H]C([2H])([2H])C1(C([2H])([2H])[2H])c2ccc3c(c2-c2c1ncc1ccccc21)C(C([2H])([2H])[2H])(C([2H])([2H])[2H])c1cccnc1-3 ; [2H]C([2H])([2H])C1(C([2H])([2H])[2H])c2ccc3c(c2-c2c1cnc1ccccc21)C(C([2H])([2H])[2H])(C([2H])([2H])[2H])c1cccnc1-3 ; [2H]C([2H])([2H])C1(C([2H])([2H])[2H])c2ccc3c(c2-c2c1ccc1ccccc21)C(C([2H])([2H])[2H])(C([2H])([2H])[2H])c1cccnc1-3]

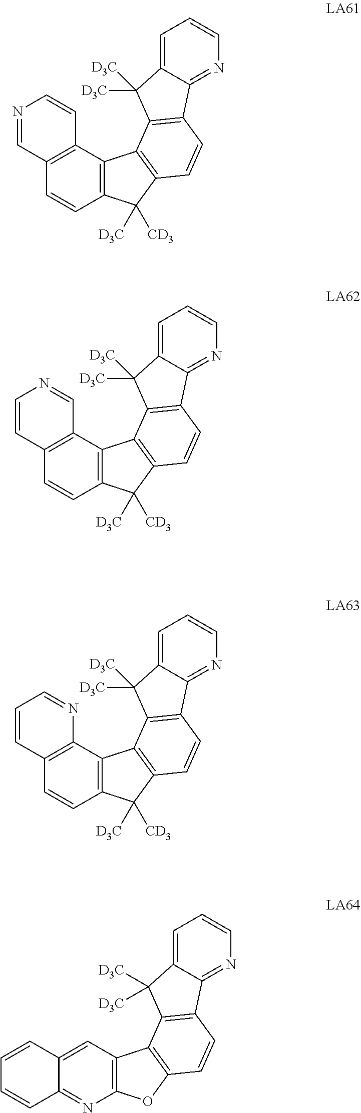 [SMILES: [2H]C([2H])([2H])C1(C([2H])([2H])[2H])c2ccc3c(c2-c2c1ccc1cnccc21)C(C([2H])([2H])[2H])(C([2H])([2H])[2H])c1cccnc1-3 ; [2H]C([2H])([2H])C1(C([2H])([2H])[2H])c2ccc3c(c2-c2c1ccc1ccncc21)C(C([2H])([2H])[2H])(C([2H])([2H])[2H])c1cccnc1-3 ; [2H]C([2H])([2H])C1(C([2H])([2H])[2H])c2ccc3c(c2-c2c1ccc1cccnc21)C(C([2H])([2H])[2H])(C([2H])([2H])[2H])c1cccnc1-3 ; [2H]C([2H])([2H])C1(C([2H])([2H])[2H])c2cccnc2-c2ccc3oc4nc5ccccc5cc4c3c21]

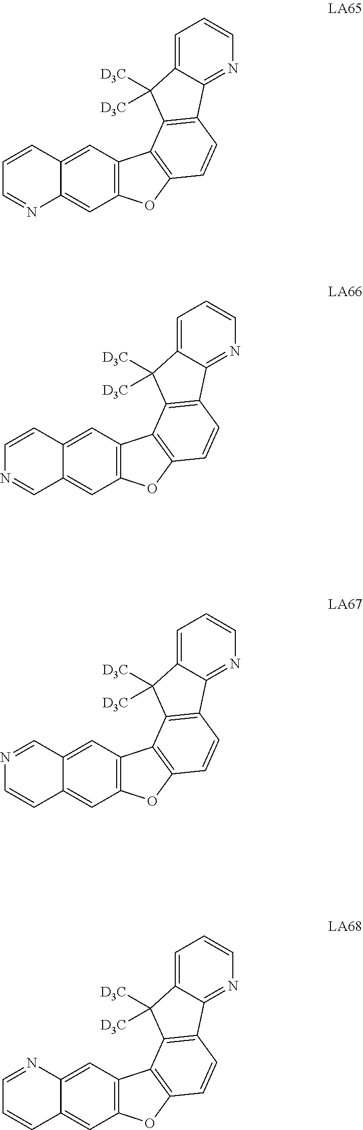 [SMILES: [2H]C([2H])([2H])C1(C([2H])([2H])[2H])c2cccnc2-c2ccc3oc4cc5ncccc5cc4c3c21 ; [2H]C([2H])([2H])C1(C([2H])([2H])[2H])c2cccnc2-c2ccc3oc4cc5cnccc5cc4c3c21 ; [2H]C([2H])([2H])C1(C([2H])([2H])[2H])c2cccnc2-c2ccc3oc4cc5ccncc5cc4c3c21 ; [2H]C([2H])([2H])C1(C([2H])([2H])[2H])c2cccnc2-c2ccc3oc4cc5cccnc5cc4c3c21]

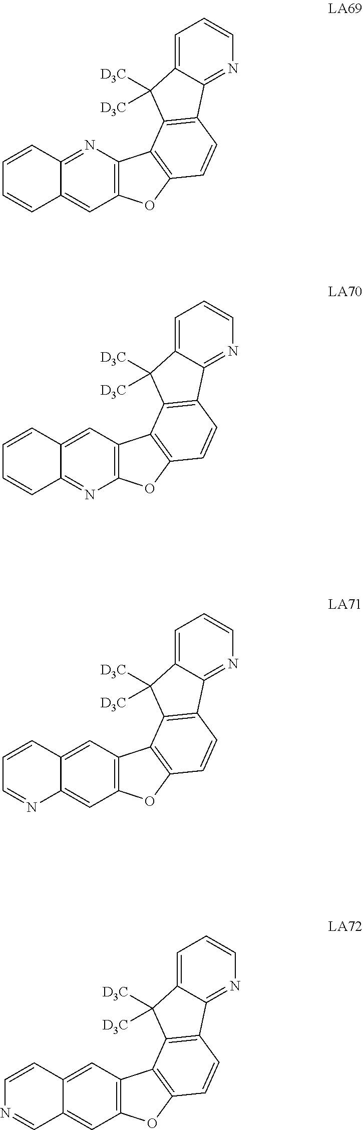 [SMILES: [2H]C([2H])([2H])C1(C([2H])([2H])[2H])c2cccnc2-c2ccc3oc4cc5ccccc5nc4c3c21 ; [2H]C([2H])([2H])C1(C([2H])([2H])[2H])c2cccnc2-c2ccc3oc4nc5ccccc5cc4c3c21 ; [2H]C([2H])([2H])C1(C([2H])([2H])[2H])c2cccnc2-c2ccc3oc4cc5ncccc5cc4c3c21 ; [2H]C([2H])([2H])C1(C([2H])([2H])[2H])c2cccnc2-c2ccc3oc4cc5cnccc5cc4c3c21]

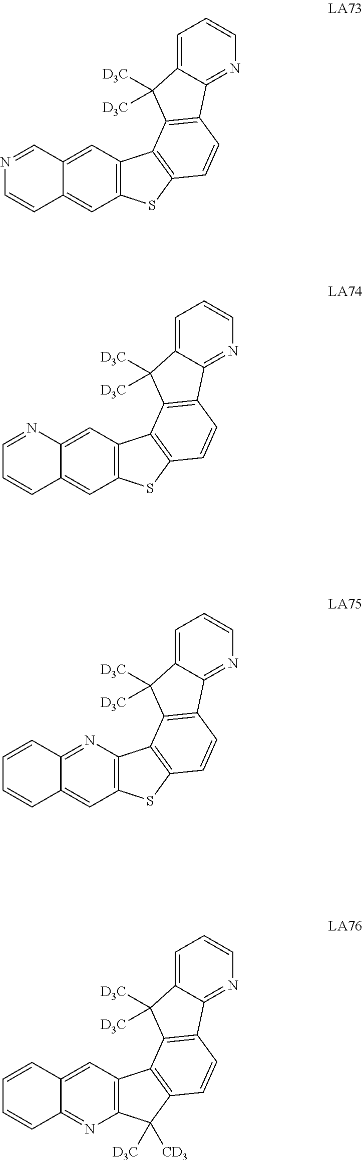 [SMILES: [2H]C([2H])([2H])C1(C([2H])([2H])[2H])c2cccnc2-c2ccc3sc4cc5ccncc5cc4c3c21 ; [2H]C([2H])([2H])C1(C([2H])([2H])[2H])c2cccnc2-c2ccc3sc4cc5cccnc5cc4c3c21 ; [2H]C([2H])([2H])C1(C([2H])([2H])[2H])c2cccnc2-c2ccc3sc4cc5ccccc5nc4c3c21 ; [2H]C([2H])([2H])C1(C([2H])([2H])[2H])c2ccc3c(c2-c2cc4ccccc4nc21)C(C([2H])([2H])[2H])(C([2H])([2H])[2H])c1cccnc1-3]

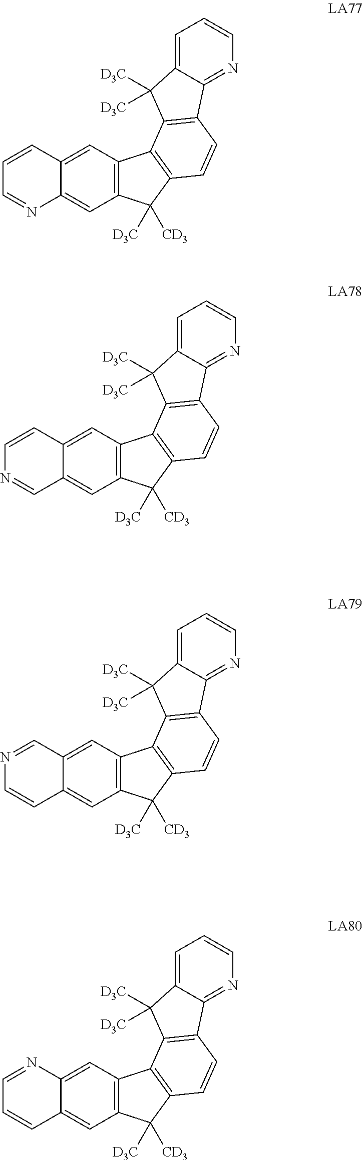 [SMILES: [2H]C([2H])([2H])C1(C([2H])([2H])[2H])c2cc3ncccc3cc2-c2c1ccc1c2C(C([2H])([2H])[2H])(C([2H])([2H])[2H])c2cccnc2-1 ; [2H]C([2H])([2H])C1(C([2H])([2H])[2H])c2cc3cnccc3cc2-c2c1ccc1c2C(C([2H])([2H])[2H])(C([2H])([2H])[2H])c2cccnc2-1 ; [2H]C([2H])([2H])C1(C([2H])([2H])[2H])c2cc3ccncc3cc2-c2c1ccc1c2C(C([2H])([2H])[2H])(C([2H])([2H])[2H])c2cccnc2-1 ; [2H]C([2H])([2H])C1(C([2H])([2H])[2H])c2cc3cccnc3cc2-c2c1ccc1c2C(C([2H])([2H])[2H])(C([2H])([2H])[2H])c2cccnc2-1]

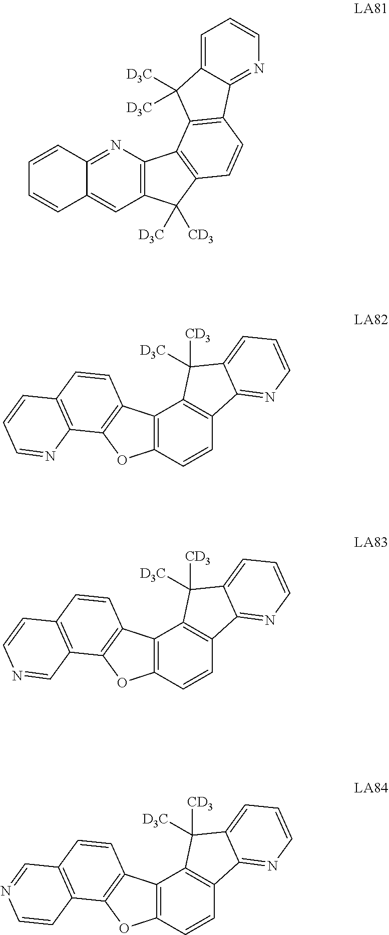 [SMILES: [2H]C([2H])([2H])C1(C([2H])([2H])[2H])c2cc3ccccc3nc2-c2c1ccc1c2C(C([2H])([2H])[2H])(C([2H])([2H])[2H])c2cccnc2-1 ; [2H]C([2H])([2H])C1(C([2H])([2H])[2H])c2cccnc2-c2ccc3oc4c(ccc5cccnc54)c3c21 ; [2H]C([2H])([2H])C1(C([2H])([2H])[2H])c2cccnc2-c2ccc3oc4c5cnccc5ccc4c3c21 ; [2H]C([2H])([2H])C1(C([2H])([2H])[2H])c2cccnc2-c2ccc3oc4c5ccncc5ccc4c3c21]

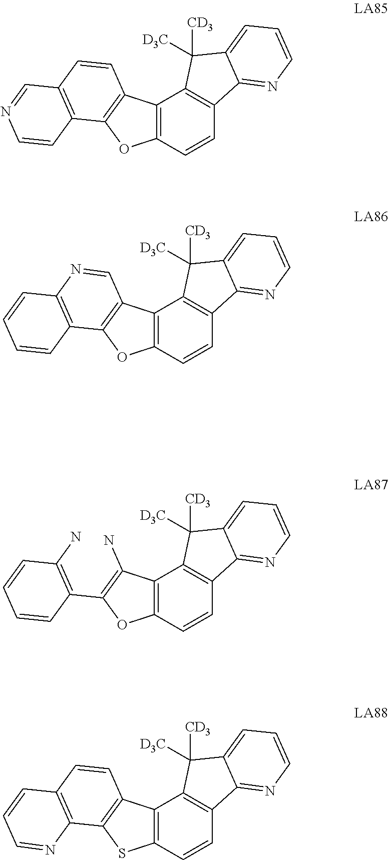 [SMILES: [2H]C([2H])([2H])C1(C([2H])([2H])[2H])c2cccnc2-c2ccc3oc4c5ccncc5ccc4c3c21 ; [2H]C([2H])([2H])C1(C([2H])([2H])[2H])c2cccnc2-c2ccc3oc4c5ccccc5ncc4c3c21 ; [2H]C([2H])([2H])C1(C([2H])([2H])[2H])c2cccnc2-c2ccc3oc(-c4ccccc4N)c(N)c3c21 ; [2H]C([2H])([2H])C1(C([2H])([2H])[2H])c2cccnc2-c2ccc3sc4c(ccc5cccnc54)c3c21]

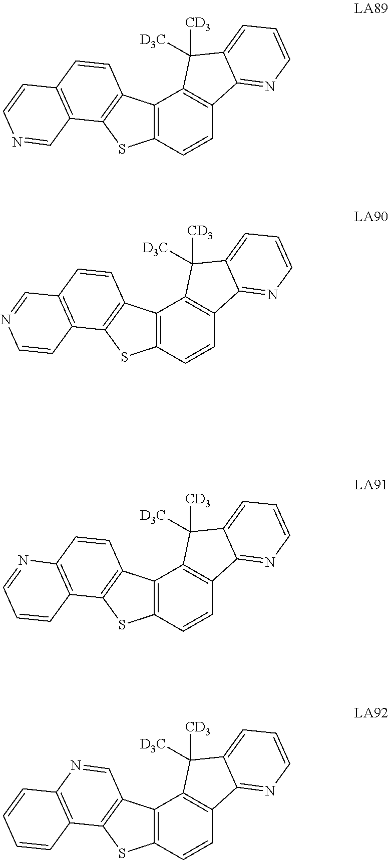 [SMILES: [2H]C([2H])([2H])C1(C([2H])([2H])[2H])c2cccnc2-c2ccc3sc4c5cnccc5ccc4c3c21 ; [2H]C([2H])([2H])C1(C([2H])([2H])[2H])c2cccnc2-c2ccc3sc4c5ccncc5ccc4c3c21 ; [2H]C([2H])([2H])C1(C([2H])([2H])[2H])c2cccnc2-c2ccc3sc4c5cccnc5ccc4c3c21 ; [2H]C([2H])([2H])C1(C([2H])([2H])[2H])c2cccnc2-c2ccc3sc4c5ccccc5ncc4c3c21]

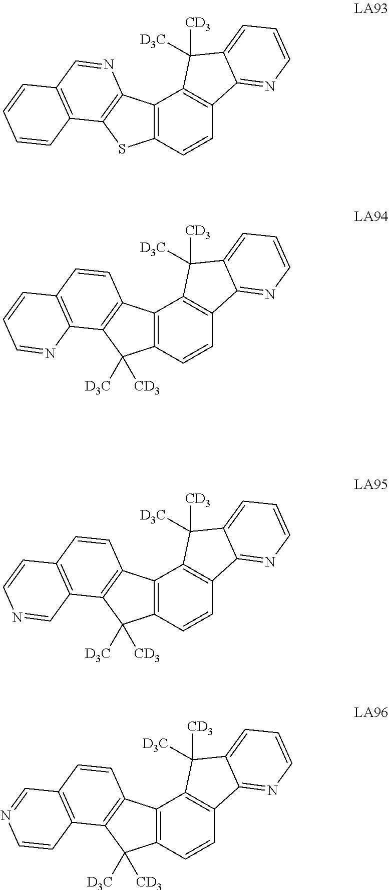 [SMILES: [2H]C([2H])([2H])C1(C([2H])([2H])[2H])c2cccnc2-c2ccc3sc4c5ccccc5cnc4c3c21 ; [2H]C([2H])([2H])C1(C([2H])([2H])[2H])c2cccnc2-c2ccc3c(c21)-c1ccc2cccnc2c1C3(C([2H])([2H])[2H])C([2H])([2H])[2H] ; [2H]C([2H])([2H])C1(C([2H])([2H])[2H])c2cccnc2-c2ccc3c(c21)-c1ccc2ccncc2c1C3(C([2H])([2H])[2H])C([2H])([2H])[2H] ; [2H]C([2H])([2H])C1(C([2H])([2H])[2H])c2cccnc2-c2ccc3c(c21)-c1ccc2cnccc2c1C3(C([2H])([2H])[2H])C([2H])([2H])[2H]]

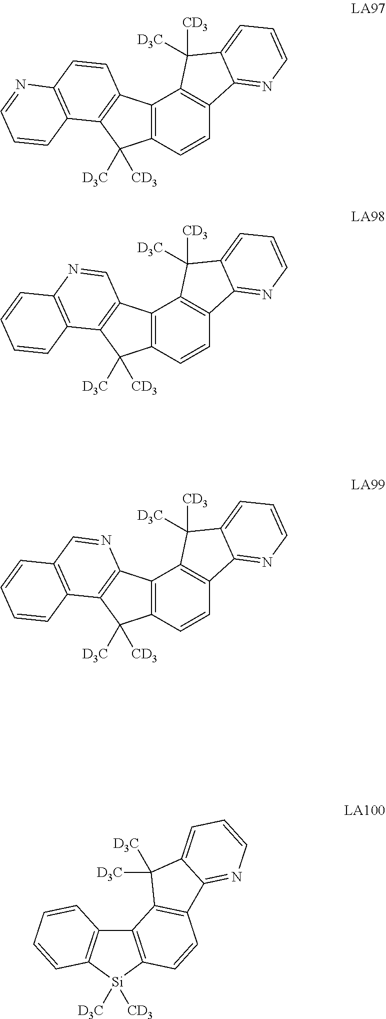 [SMILES: [2H]C([2H])([2H])C1(C([2H])([2H])[2H])c2cccnc2-c2ccc3c(c21)-c1ccc2ncccc2c1C3(C([2H])([2H])[2H])C([2H])([2H])[2H] ; [2H]C([2H])([2H])C1(C([2H])([2H])[2H])c2cccnc2-c2ccc3c(c21)-c1cnc2ccccc2c1C3(C([2H])([2H])[2H])C([2H])([2H])[2H] ; [2H]C([2H])([2H])C1(C([2H])([2H])[2H])c2cccnc2-c2ccc3c(c21)-c1ncc2ccccc2c1C3(C([2H])([2H])[2H])C([2H])([2H])[2H] ; [2H]C([2H])([2H])C1(C([2H])([2H])[2H])c2cccnc2-c2ccc3c(c21)-c1ccccc1[Si]3(C([2H])([2H])[2H])C([2H])([2H])[2H]]

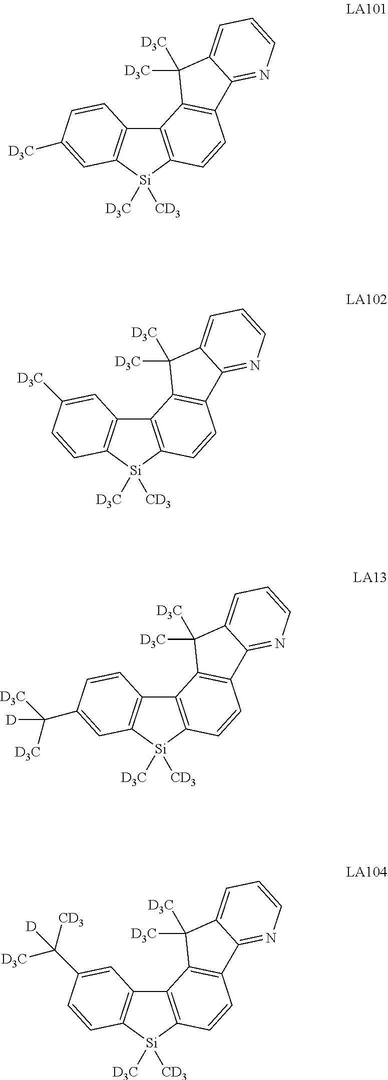

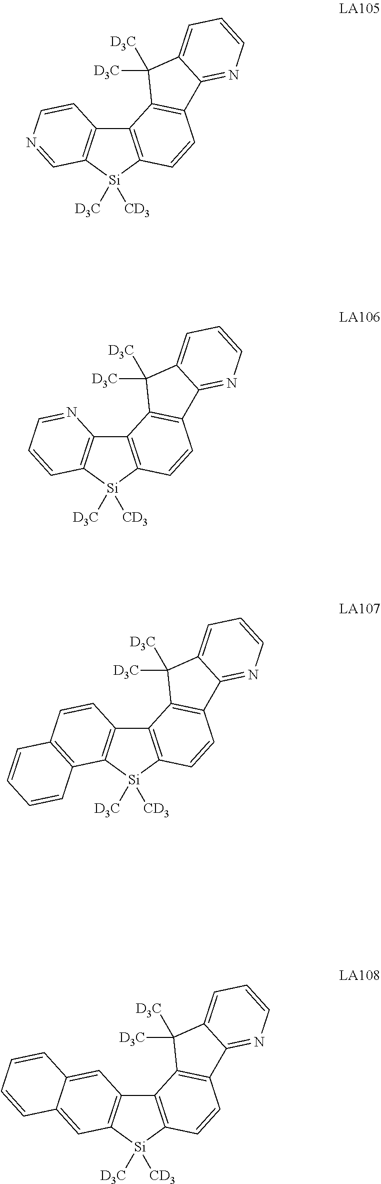 [SMILES: [2H]C([2H])([2H])C1(C([2H])([2H])[2H])c2cccnc2-c2ccc3c(c21)-c1ccncc1[Si]3(C([2H])([2H])[2H])C([2H])([2H])[2H] ; [2H]C([2H])([2H])C1(C([2H])([2H])[2H])c2cccnc2-c2ccc3c(c21)-c1ncccc1[Si]3(C([2H])([2H])[2H])C([2H])([2H])[2H] ; [2H]C([2H])([2H])C1(C([2H])([2H])[2H])c2cccnc2-c2ccc3c(c21)-c1ccc2ccccc2c1[Si]3(C([2H])([2H])[2H])C([2H])([2H])[2H] ; [2H]C([2H])([2H])C1(C([2H])([2H])[2H])c2cccnc2-c2ccc3c(c21)-c1cc2ccccc2cc1[Si]3(C([2H])([2H])[2H])C([2H])([2H])[2H]]

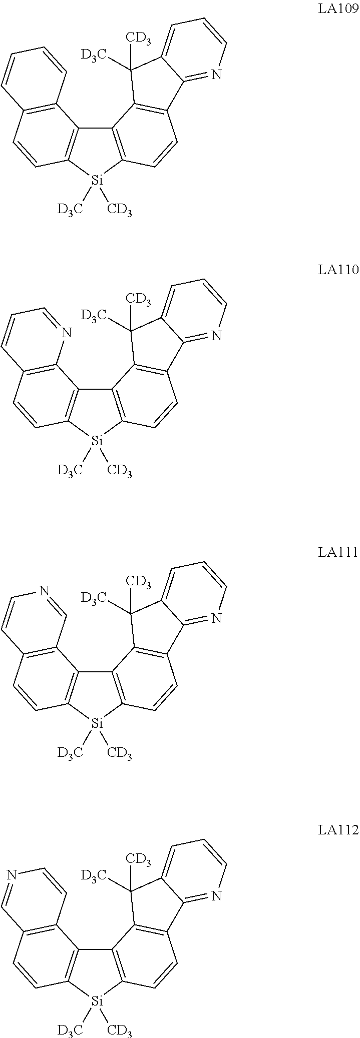 [SMILES: [2H]C([2H])([2H])C1(C([2H])([2H])[2H])c2cccnc2-c2ccc3c(c21)-c1c(ccc2ccccc12)[Si]3(C([2H])([2H])[2H])C([2H])([2H])[2H] ; [2H]C([2H])([2H])C1(C([2H])([2H])[2H])c2cccnc2-c2ccc3c(c21)-c1c(ccc2cccnc12)[Si]3(C([2H])([2H])[2H])C([2H])([2H])[2H] ; [2H]C([2H])([2H])C1(C([2H])([2H])[2H])c2cccnc2-c2ccc3c(c21)-c1c(ccc2ccncc12)[Si]3(C([2H])([2H])[2H])C([2H])([2H])[2H] ; [2H]C([2H])([2H])C1(C([2H])([2H])[2H])c2cccnc2-c2ccc3c(c21)-c1c(ccc2cnccc12)[Si]3(C([2H])([2H])[2H])C([2H])([2H])[2H]]

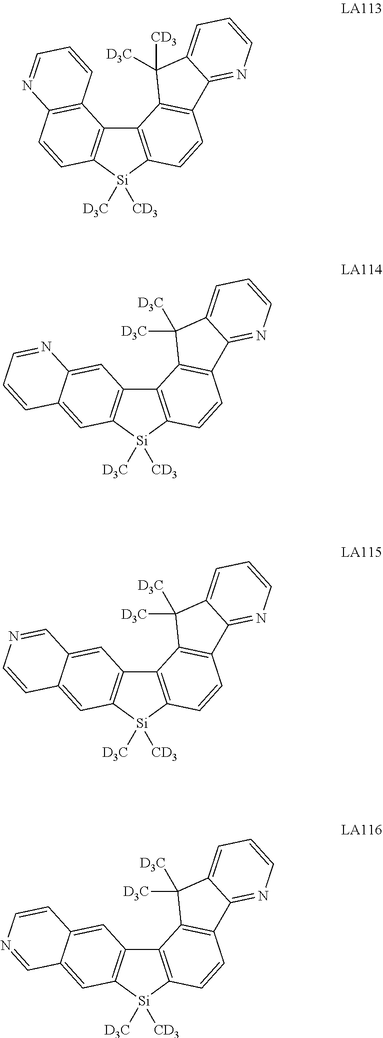 [SMILES: [2H]C([2H])([2H])C1(C([2H])([2H])[2H])c2cccnc2-c2ccc3c(c21)-c1c(ccc2ncccc12)[Si]3(C([2H])([2H])[2H])C([2H])([2H])[2H] ; [2H]C([2H])([2H])C1(C([2H])([2H])[2H])c2cccnc2-c2ccc3c(c21)-c1cc2ncccc2cc1[Si]3(C([2H])([2H])[2H])C([2H])([2H])[2H] ; [2H]C([2H])([2H])C1(C([2H])([2H])[2H])c2cccnc2-c2ccc3c(c21)-c1cc2cnccc2cc1[Si]3(C([2H])([2H])[2H])C([2H])([2H])[2H] ; [2H]C([2H])([2H])C1(C([2H])([2H])[2H])c2cccnc2-c2ccc3c(c21)-c1cc2ccncc2cc1[Si]3(C([2H])([2H])[2H])C([2H])([2H])[2H]]

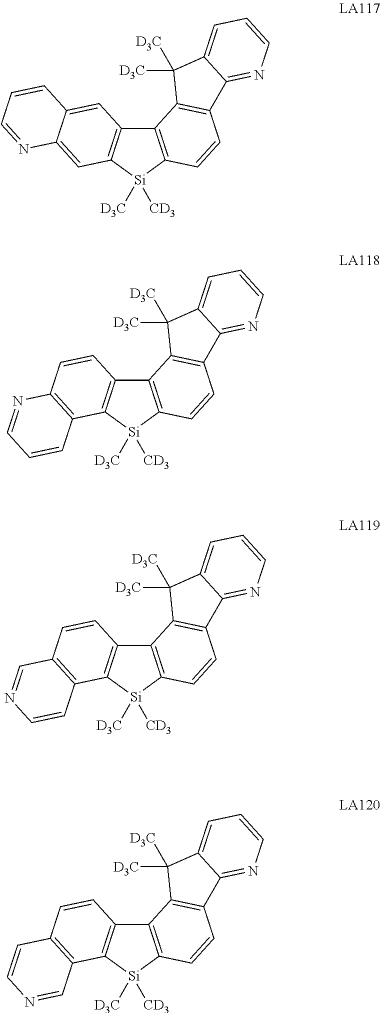 [SMILES: [2H]C([2H])([2H])C1(C([2H])([2H])[2H])c2cccnc2-c2ccc3c(c21)-c1cc2cccnc2cc1[Si]3(C([2H])([2H])[2H])C([2H])([2H])[2H] ; [2H]C([2H])([2H])C1(C([2H])([2H])[2H])c2cccnc2-c2ccc3c(c21)-c1ccc2ncccc2c1[Si]3(C([2H])([2H])[2H])C([2H])([2H])[2H] ; [2H]C([2H])([2H])C1(C([2H])([2H])[2H])c2cccnc2-c2ccc3c(c21)-c1ccc2cnccc2c1[Si]3(C([2H])([2H])[2H])C([2H])([2H])[2H] ; [2H]C([2H])([2H])C1(C([2H])([2H])[2H])c2cccnc2-c2ccc3c(c21)-c1ccc2ccncc2c1[Si]3(C([2H])([2H])[2H])C([2H])([2H])[2H]]

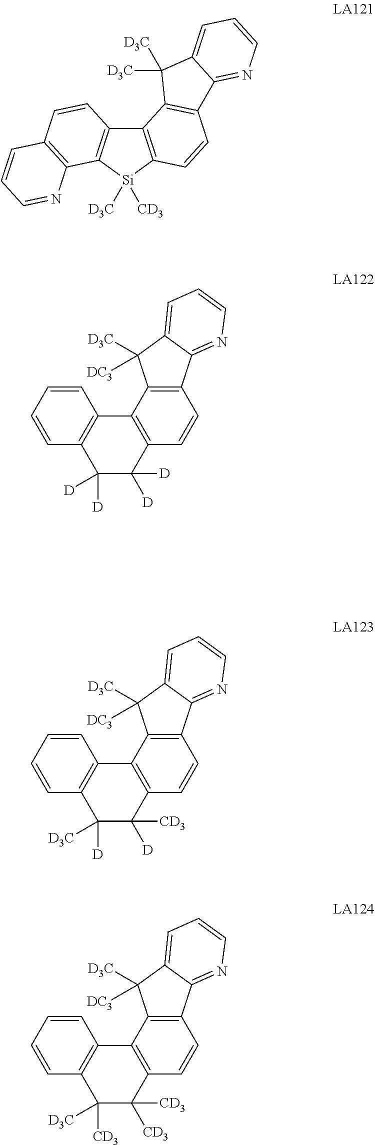

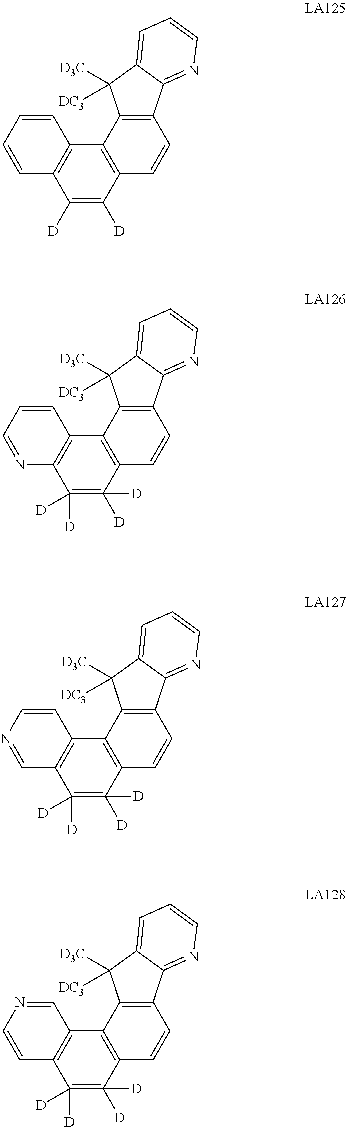

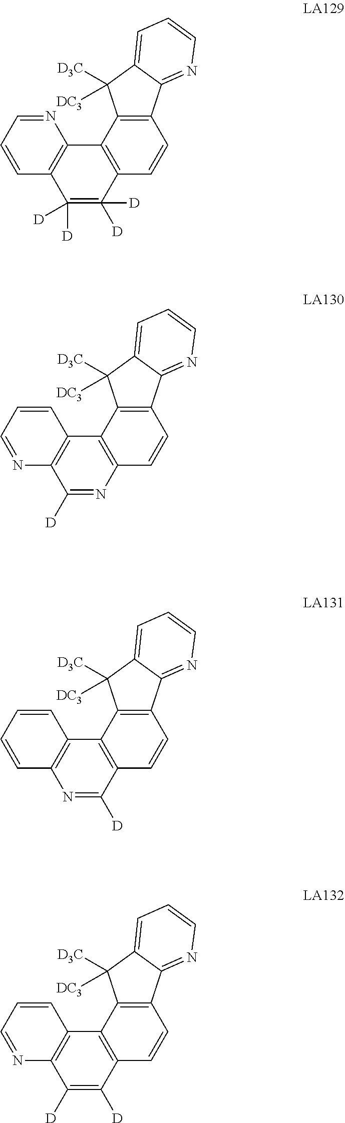

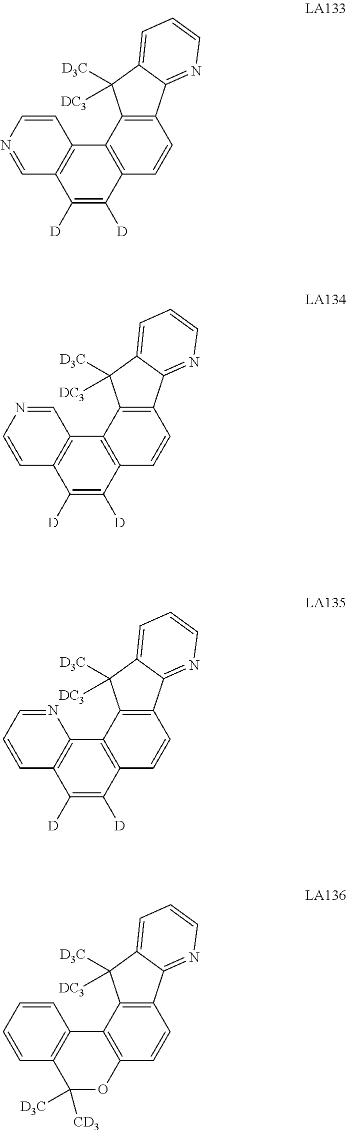

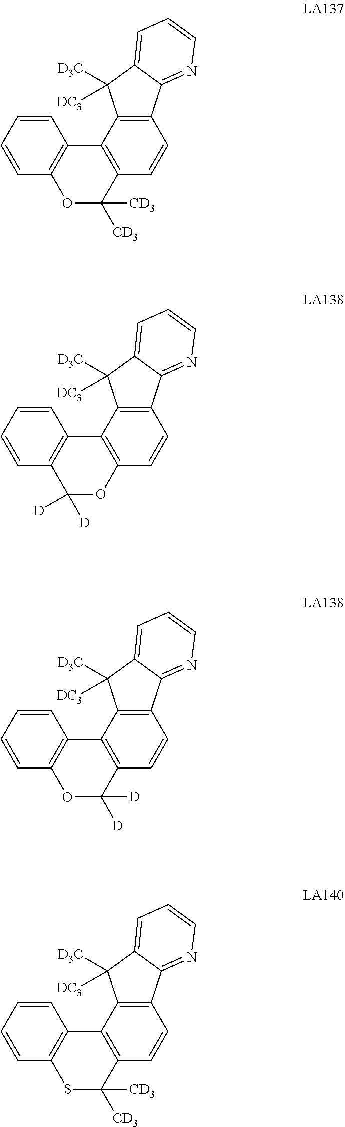

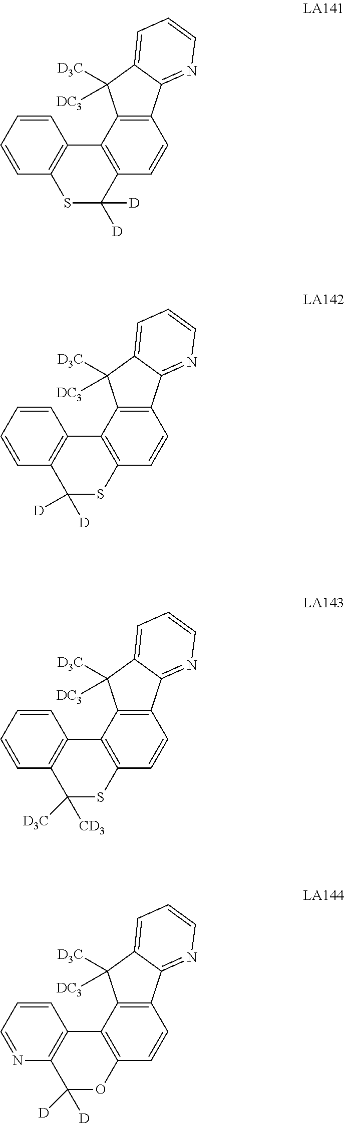

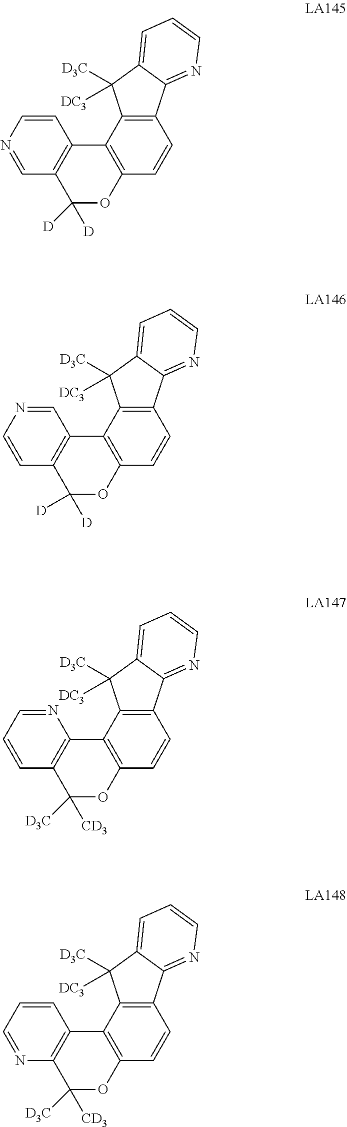

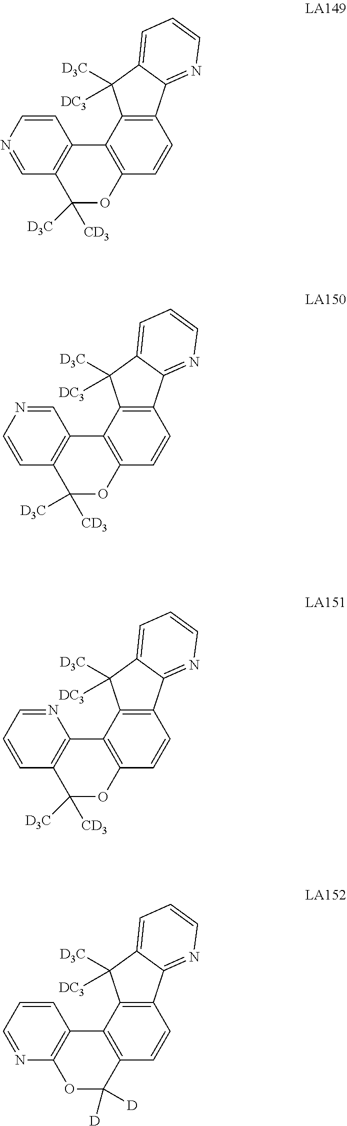

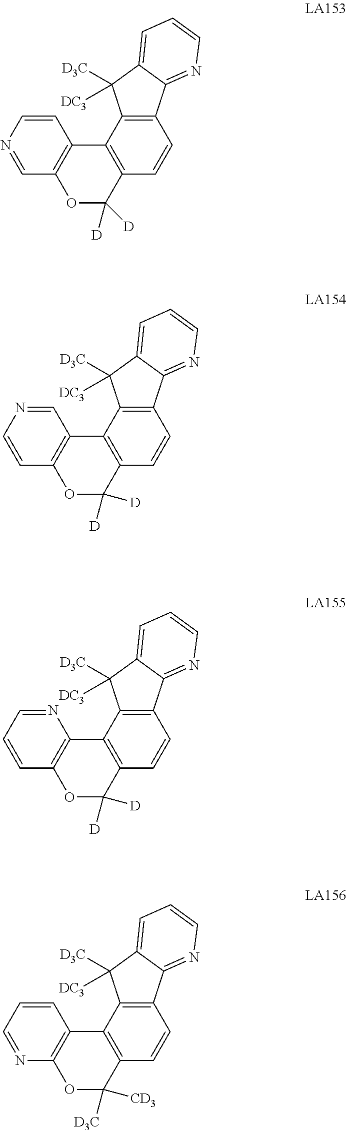

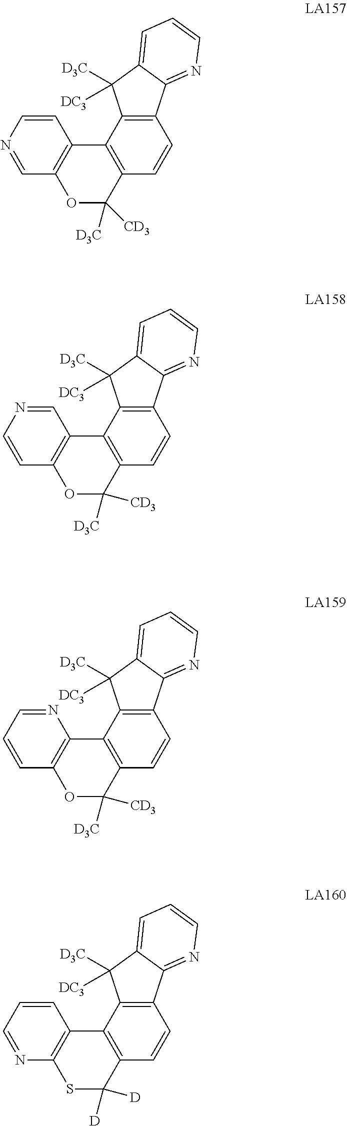

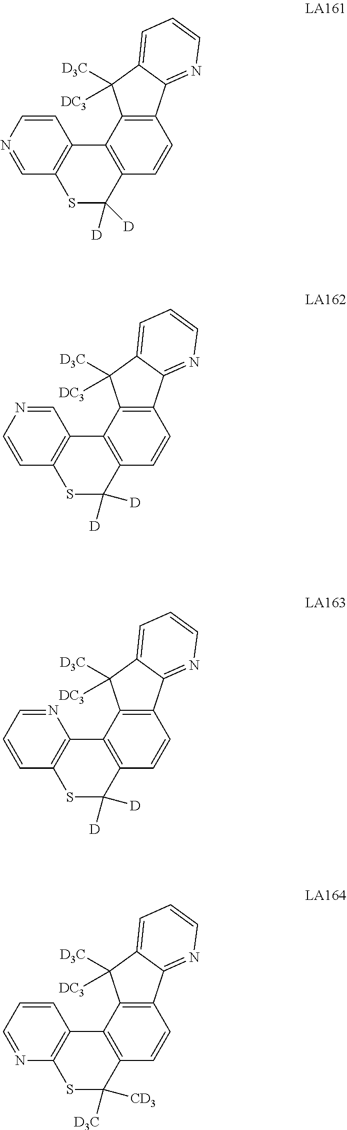

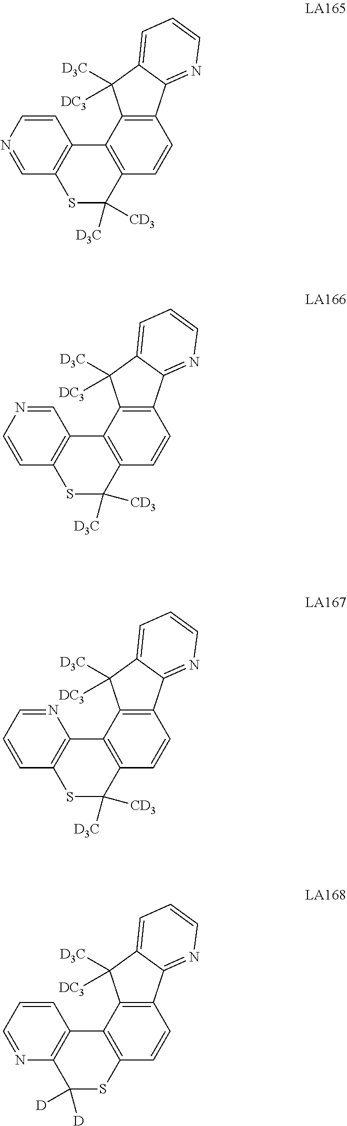

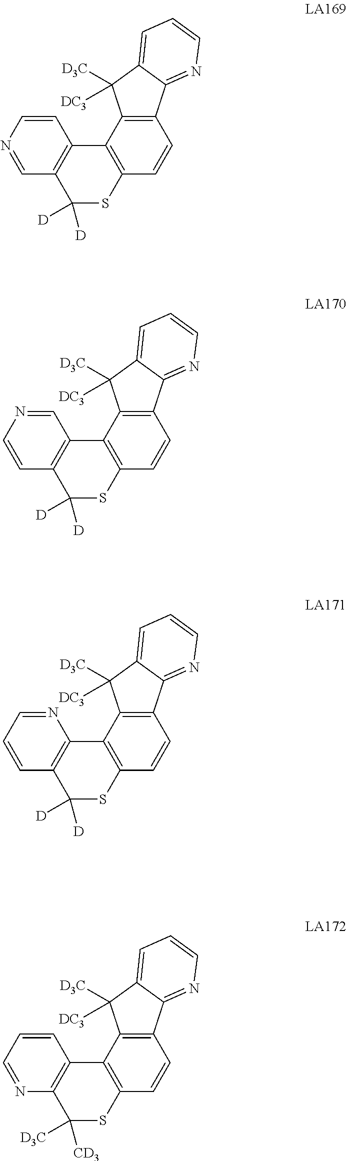

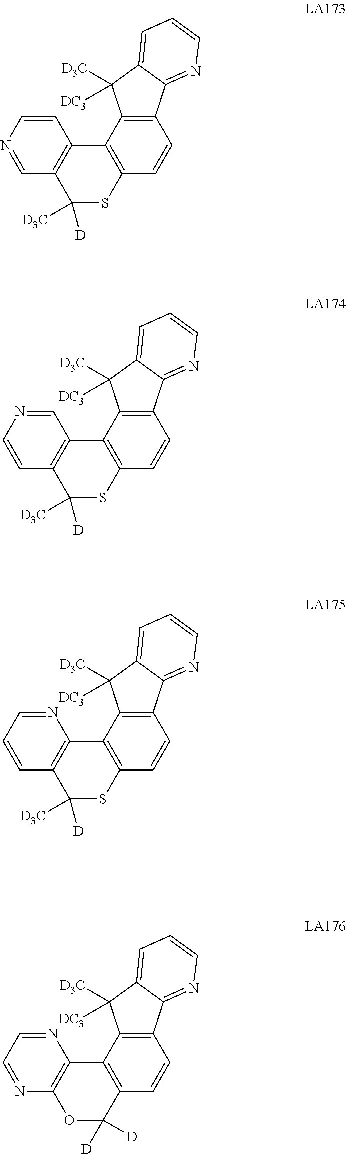

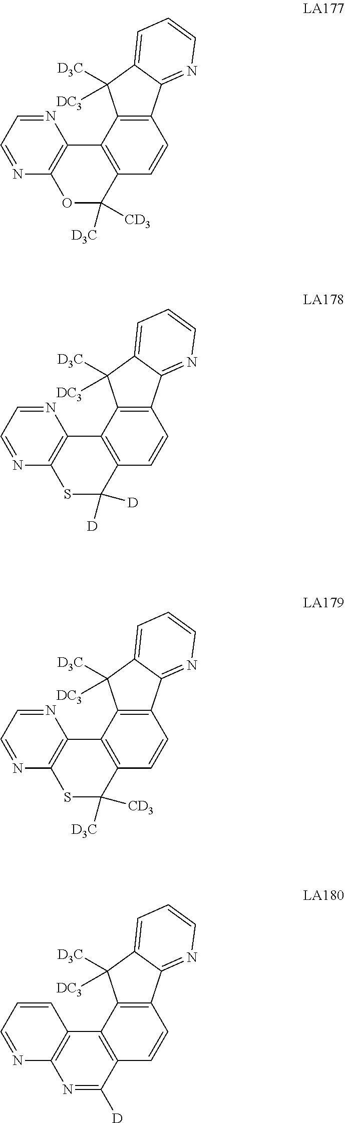

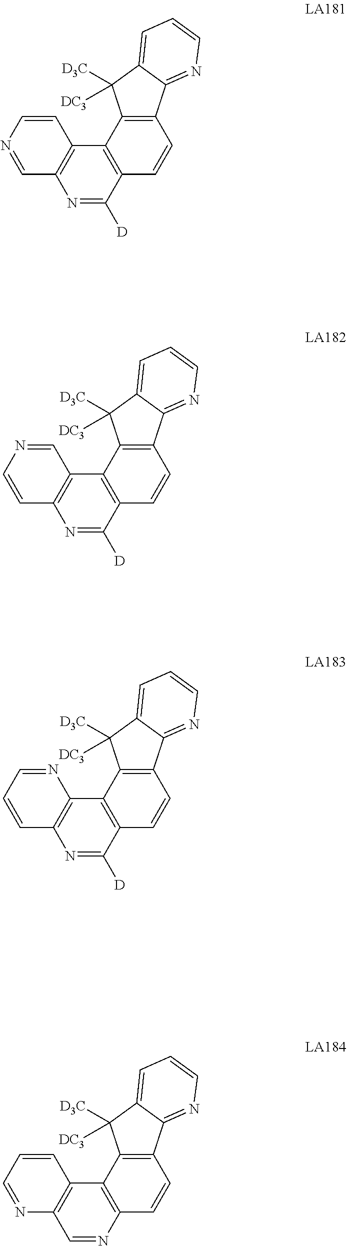

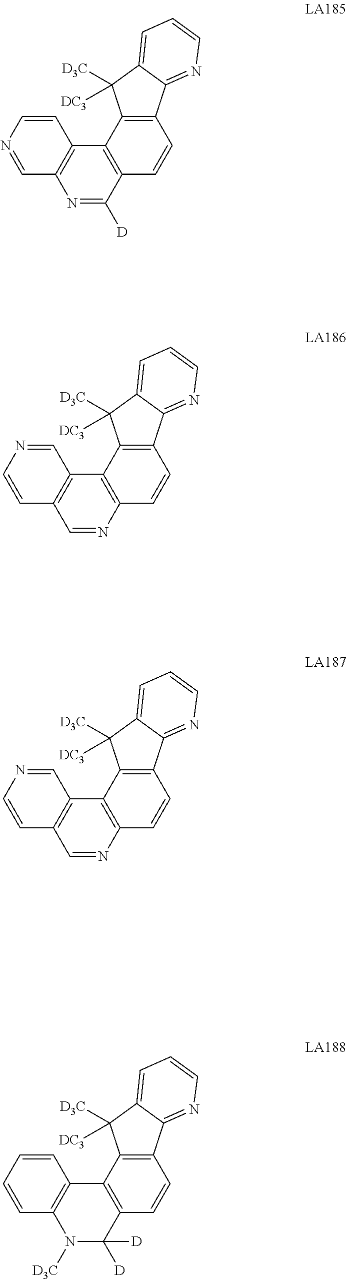

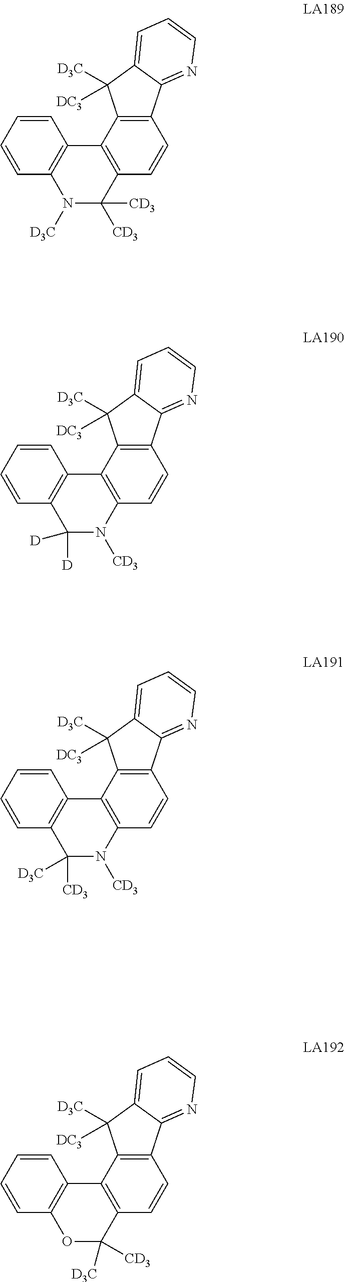

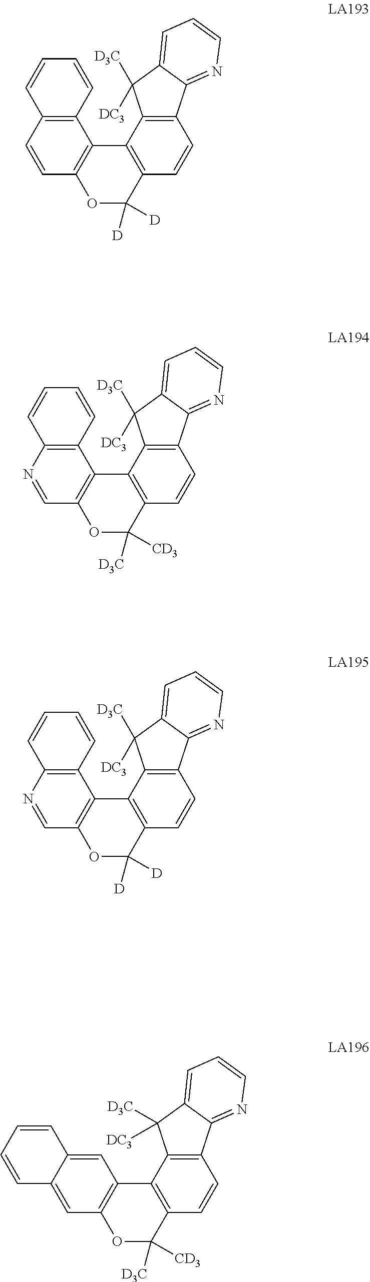

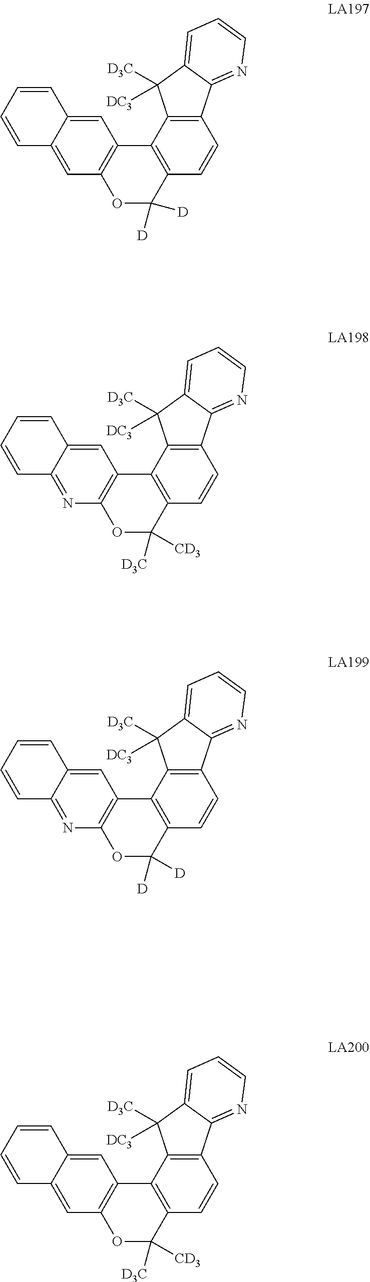

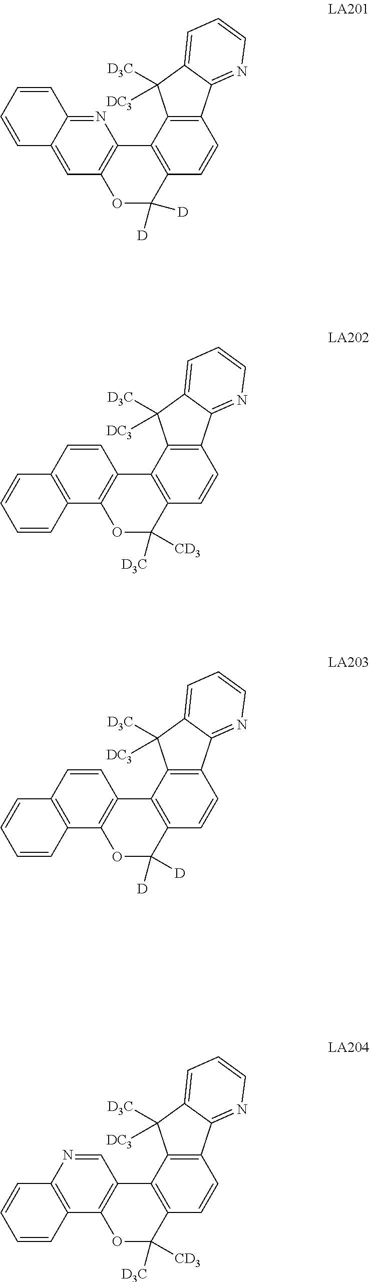

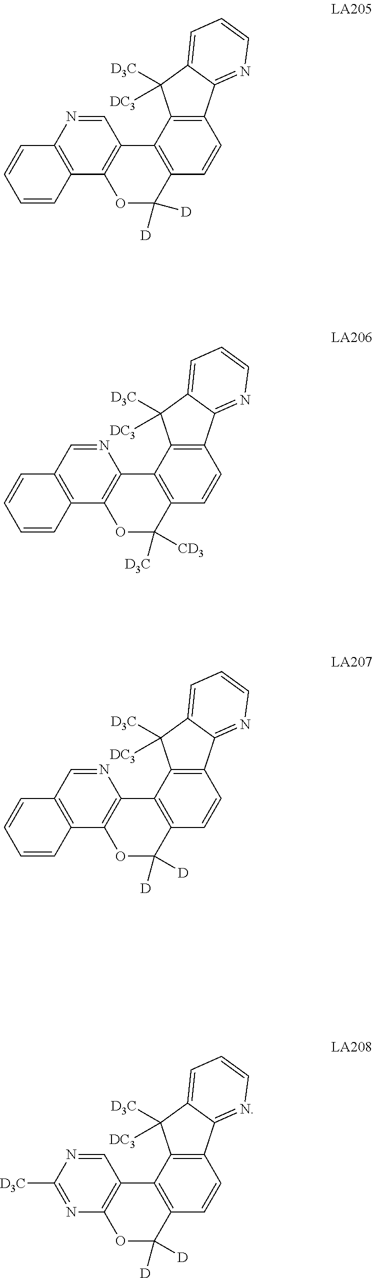

Further, the metal complex has a chemical formula of Ir(LAi)(LBj)₂, Ir(LAi)₂(LBj) or Ir(LAi)₃, wherein the i is an integer of 1-208 and the j is an integer of 1-432, and

the LA1-LA208 and the LB1-LB432 have structures as shown above.

The organic electroluminescent material of the present invention comprises one or more of the metal complexes of the present invention. The organic electroluminescent material of the present invention may be formed only by one or more of the metal complexes of the present invention and may also contain materials other than the metal complex of the present invention.

By containing the metal complex of the present invention in the organic electroluminescent material of the present invention, the organic electroluminescent material having an electroluminescence of a green light and an improved luminous efficiency may be obtained. In addition, the organic electroluminescent material of the present invention is an organic electroluminescent material with good thermal stability.

An organic electroluminescent element comprises a first electrode, a second electrode, and an organic layer arranged between the first electrode and the second electrode. The organic layer comprises the metal complex.

Further, the organic layer further comprises a host material comprising the following chemical groups: the group consisting of triphenylene, carbazole, dibenzothiophene, dibenzofuran, dibenzoselenophene, azatriphenylene, azacarbazole, azadibenzothiophene, azadibenzofuran, and azadibenzoselenophene.

Any substituent in the host is a non-fused substituent independently selected from the group consisting of: CₙH₂ₙ₊₁, OCₙH₂ₙ₊₁, OAr¹, N(CₙH₂ₙ₊₁)₂, N(Ar¹)(Ar²), CH ═CH—CₙH₂ₙ₊₁, C≡CCₙH₂ₙ₊₁, Ar¹, Ar¹-Ar², CₙH₂ₙ—Ar¹ or non-substituent, wherein n is an integer of 1-10. The Ar¹ and Ar² are independently selected from the group consisting of: benzene, biphenyl, naphthalene, triphenylene, carbazole, and a heteroaromatic analog thereof.

In the organic electroluminescent element of the present invention, one layer may be a layer containing the metal complex of the present invention, or two or more layers may contain the metal complex of the present invention.

The organic layer may be an emission layer and the metal complex as described herein may be an emitting dopant or a non-emitting dopant.

A consumer product made from the organic electroluminescent element.

The consumer product in the present invention may be one of the following products: a flat-panel display, a computer monitor, a medical monitor, a television, a billboard, a lamp for interior or exterior lighting and/or signaling, a head-up display, a fully or partially transparent display, a flexible display, a laser printer, a telephone, a cell phone, a tablet computer, a phablet, a personal digital assistant (PDA), a wearable device, a laptop computer, a digital camera, a video camera, a viewfinder, a microdisplay with a diagonal less than 2 inches, a 3-D display, a virtual reality or augmented reality display, a vehicle, a video wall containing multiple displays tiled together, a theater or stadium screen, a phototherapy device, and a direction board.

Compared with the prior art, the beneficial effects of the present invention are:

The metal complex of the present invention, by forming an aza-bifluorene rigid structure ligand by connecting pyridine and fluorene, effectively prevents the energy loss between the pyridine and aryl due to the conjugated free rotation of a single bond, and improves a quantum efficiency. The metal complex has good thermal stability, an increased conjugate area, improved molecule film-forming and exciton transmission properties, a reduced material sublimation temperature, and may be used as a luminescent material to obtain a green phosphorescent material with a high luminescent efficiency. An electronic device comprising the organic electroluminescent element of the present invention can result sin a consumer product having a narrow emission spectrum, a high stability, and a high efficiency may be obtained.

### BRIEF DESCRIPTION OF THE DRAWINGS

In order to describe the technical solution in examples of the present invention or the prior art more clearly, the drawings which need to be used in the description of the examples or the prior art will be simply introduced below. Obviously, the accompanying drawings in the following description show merely some examples of the present invention, and a person of ordinary skill in the art may still derive other drawings according to these drawings without creative efforts.

FIG. 1 is a schematic diagram of an organic electroluminescent element of the present invention; and

FIG. 2 is a structural diagram of an inverted organic electroluminescent element of the present invention.

### LIST OF REFERENCE NUMERALS

110—substrate, 115—anode layer, 120—hole injection layer, 125—hole transport layer, 130—electron blocking layer, 135—organic emission layer, 140—hole blocking layer, 145—electron transport layer, 150—electron injection layer, 155—protective layer, 160—cathode layer, 162—first conductive layer, 164—second conductive layer, and 170—encapsulation layer.

### DETAILED DESCRIPTION OF EMBODIMENTS

In the organic electroluminescent element of the present invention, the composition of the layer other than the layer containing the metal complex of the present invention is not limited at all. A person skilled in the art may determine the composition of other layers of the organic electroluminescent element as necessary based on the common knowledge of the art.

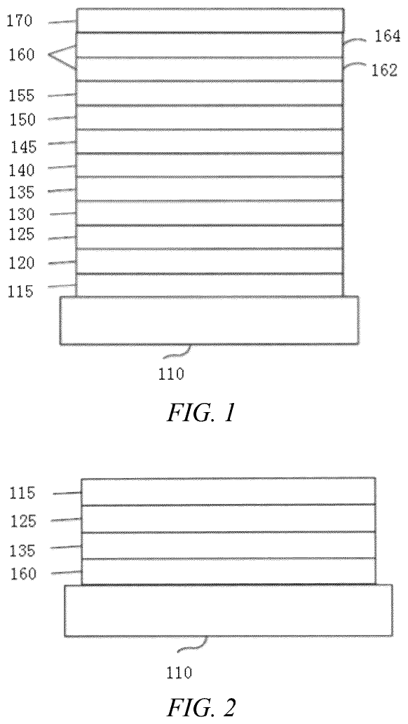

In FIG. 1, a substrate 110 is successively provided with an anode layer 115, a hole injection layer 120, a hole transport layer 125, an electron blocking layer 130, an organic emission layer 135, a hole blocking layer 140, an electron transport layer 145, an electron injection layer 150, a protective layer 155, a cathode layer 160, and an encapsulation layer 170. The organic emission layer contains the metal complex of the present invention. When the organic electroluminescent device of the present invention is connected with an external power supply and applied with a voltage, the metal complex in the organic emission layer 135 emits light in an electroluminescent manner, and the emitted light has a wavelength range of 520-650 nm. The cathode layer 160 is a composite cathode having a first conductive layer 162 and a second conductive layer 164. The device may be manufactured by depositing the layers in sequence.

FIG. 2 comprises the substrate 110, the cathode 160, the organic emission layer 135, the hole transport layer 125, and the anode layer 115. The device may be manufactured by depositing the various layers in sequence. Since a most common OLED is provided with a cathode arranged above an anode, while the device is provided with the cathode layer 160 arranged under the anode layer 115, the device may be referred as inverted. A material similar to the material of the device may be used in the corresponding layer of the device. FIG. 2 provides an example of how some layers may be omitted from a structure of the device of FIG. 1.

The simple layered structures illustrated in FIGS. 1 and 2 are provided as non-limiting examples. Besides, it should be understood that examples of the present invention may be used in conjunction with a wide variety of other structures. The particular materials and structures described are essentially exemplary. Besides, other materials and structures may be used. The functional OLED may be realized by combining the various layers described in different ways or several layers may be completely omitted, based on design, performance and cost factors. Other layers not specifically described may also be included. A material other than those specifically described may be used. Although many of the examples provided herein describe the various layers as comprising a single material, it is understood that a combination of the materials may be used, such as a mixture of a matrix and a dopant, or more generally, a mixture. Besides, the layer may contain various sub-layers. The name given to the each layer herein is not intended to be strictly limiting. For example, in FIG. 2, the hole transport layer 125 transports holes and injects the holes into the organic emission layer 135, and may be described as a hole transport layer or a hole injection layer. In one example, the OLED may be described as having an organic layer arranged between a cathode and an anode. The organic layer may comprise a single layer or may further comprise multiple layers of different organic materials as described in FIGS. 1 and 2.

Structures and materials not specifically described, such as PLED comprising polymeric materials, may further be used. As another example, the OLED having a single organic layer or multiple stacks may be used. The OLED structure may depart from the simple layered structure illustrated in FIGS. 1 and 2. For example, the substrate may comprise an angled reflective surface to improve the optical coupling.

Any one of the layers of the various examples may be deposited by any suitable method, unless otherwise specified. With regard to the organic layer, a preferred method comprises applying one or more layers by means of thermal evaporation and an organic vapor deposition method or by means of carrier gas sublimation, wherein the material is applied at a pressure between 10⁻⁵ mbar and 1 bar. A particular example of the method is an organic vapor jet printing method, wherein the material is applied directly through a nozzle and is therefore structured. One or more layers are produced by means of other suitable deposition methods including, for example, spin coating, or by means of any desired printing method such as screen printing, flexography, lithography, photo-initiated thermal imaging, heat transfer printing, inkjet printing, or nozzle printing. Soluble compounds are obtained, for example, by means of appropriate substitution. These methods are also particularly suitable for oligomers, dendrimers and polymers. In addition, a hybrid method is feasible, in which for example one or more additional layers are applied from a solution and one or more layers are applied by means of vapor deposition.

The device manufactured according to the examples of the present invention may further optionally comprise a barrier layer. One use of the barrier layer is to protect the electrodes and the organic layer from damage due to exposure to harmful substances in the environment, including moisture, vapor, and/or gas. The barrier layer may be deposited on, under or beside the substrate and the electrodes, or any other part of the device, including an edge. The barrier layer may comprise a single layer or multiple layers. The barrier layer may be formed by various known chemical vapor deposition technologies and may comprise a composition having a single phase and a compositions having multiple phases. Any suitable material or material combination may be used for the barrier layer. The barrier layer may be incorporated with inorganic or organic compounds or both. Preferably, the barrier layer comprises a mixture of polymeric and non-polymeric materials. To be considered as a mixture, the polymeric and non-polymeric materials that constitute the barrier layer should be deposited under the same condition and/or at the same time. The weight ratio of the polymeric material to the non-polymeric material may be in a range of 95/5 to 5/95. In one example, the mixture of the polymeric and non-polymeric materials essentially consists of polymeric silicon and inorganic silicon.

In any of the compounds used in each layer of the OLED device, the hydrogen atom may be partially or fully deuterated. Therefore, any of the specifically listed substituents, such as (but not limited to) methyl, phenyl, pyridyl, and the like, may be in non-deuterated, partially deuterated, and fully deuterated forms thereof. Similarly, the substituent (such as, but not limited to, alkyl, aryl, cycloalkyl, heteroaryl, and the like) may also be in a class of non-deuterated, partially-deuterated, or fully-deuterated forms thereof.

The materials and the structures described herein may be used in a device other than the OLED. For example, the materials and the structures may be used in other optoelectronic devices such as an organic solar cell and an organic photodetector. Further, the materials and the structures may be used in an organic device such as an organic transistor.

These methods are generally known to a person of ordinary skill in the art and may be used in an organic electroluminescent device containing the compound according to the present invention without involving any inventive effort.

According to one example, a novel ligand for the metal complex is disclosed. The present inventor has discovered that the incorporation of these ligands unexpectedly narrows the emission spectrum, lowers the sublimation temperature, and increases the luminescent efficiency of the device.

As a method for preparing the organic electroluminescent element of the present invention, the following preparation methods may be listed, but are not limited thereto. A person skilled in the art may make various changes according to the technical knowledge in the art. The preparation method comprises the following processes:
cleaning procedure: cleaning a glass substrate with an ITO by using a cleaning agent, deionized water, an organic solvent, and the like;
procedure for forming a hole injection layer: forming the hole injection layer containing the metal complex of the present invention on the substrate, by vacuum-evaporating a hole injection layer-forming material containing the metal complex of the present invention on the anode layer by vacuum evaporation;
procedure for forming a hole transport layer: forming a hole transport layer on the hole injection layer by vacuum evaporation;
procedure for forming an organic emission layer: forming an organic emission layer containing the metal complex of the present invention on the hole transport layer, by vacuum-evaporating an organic emission layer-forming material containing the material of the present invention on the hole transport layer;
procedure for forming an electron transport layer: forming an electron transport layer containing the metal complex of the present invention on the organic emission layer by vacuum-evaporating an electron transport layer-forming material containing the metal complex of the present invention on the organic emission layer; and
procedure for forming a cathode layer: forming a cathode layer by evaporating, sputtering or spin-coating a cathode-forming material on the electron transport layer.

In the examples of the present invention, detection conditions of properties of the prepared electroluminescent device are as follows:
Luminance and chromaticity coordinates: tested using spectral scanner PhotoResearch PR-715;
Current density and lighting voltage: tested using digital source meter Keithley 2420;
Power efficiency: tested using NEWPORT 1931-C;
Lifetime test: using LTS-1004AC lifetime test device.

### Example 1

### Preparation of Metal Complex Ir(LA5)(LB105)₂

Step 1: Preparation of Compound Int-1

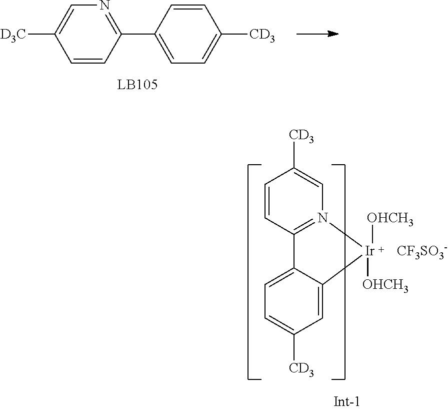

10.0 g of a compound LB105 and 9.5 g of IrCl₃·3H₂O are dispersed in 150 mL of glycol ether and 50 mL of water, under the protection of nitrogen, the mixture is heated and reacted under refluxing for 24 hours, the reaction solution is cooled to room temperature and filtered, the filter cake is washed with water and ethanol, and dried in vacuum to obtain 14.8 g of a yellow solid, the obtained yellow solid is dissolved in 250 mL of dichloromethane and 25 mL of methanol, 6.5 g of silver trifluoromethanesulfonate is added, the mixture is stirred and reacted for 24 hours, the reaction solution is filtered, and the filtrate is concentrated under reduced pressure to dryness to obtain a compound Int-1 with a yield of 83%.

Step 2: Preparation of Metal Complex Ir(LA5)(LB105)₂

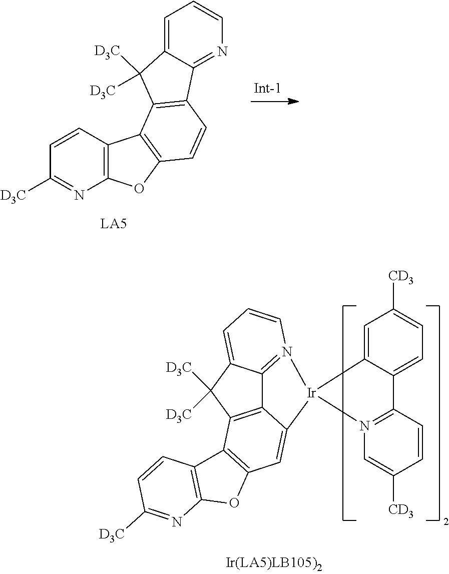

4.8 mmol of a compound LA5 and 2.3 mmol of the intermediate Int-1 are dispersed in 50 mL of glycol ether and 50 mL of DMF, under the protection of nitrogen, the mixture is heated to 100° C., stirred, and reacted for 7 days, the reaction solution is cooled room temperature and concentrated under reduced pressure to dryness, and the residue is separated and purified by a silica gel column, and eluted with dichloromethane-n-hexane to obtain a metal complex Ir(LA5)(LB105)₂, a dark yellow solid, with a yield of 52%.

Referring to the above synthesis method, the following metal complex is prepared: Ir(LAi)(LBj)₂, wherein the i is an integer of 1-208 and the j is an integer of 1-432.

Specific synthesis steps are as follows:

Step 1: referring to the synthesis method of the step 1, a trifluoromethanesulfonate of a bisLBj iridium complex is prepared:

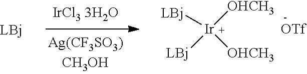

Step 2: referring to the synthesis method of the step 2, a metal complex is prepared by a coordination reaction of only the trifluoromethanesulfonate intermediate of the bisLBj iridium complex prepared in step 1 with excess LAi: Ir(LAi)(LBj)₂, and

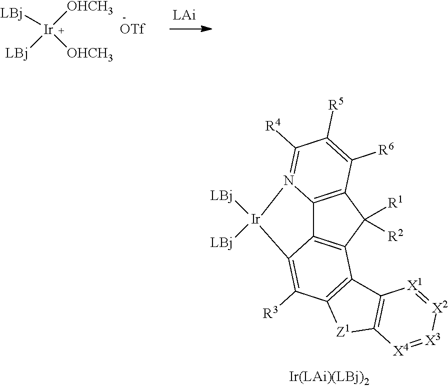

the LA1-LA208 and the LB1-LB432 are the same as the definition.

### Example 2

### Preparation of Metal Complex Ir(LA25)₂(LB77)

Step 1: Preparation of Compound Int-2

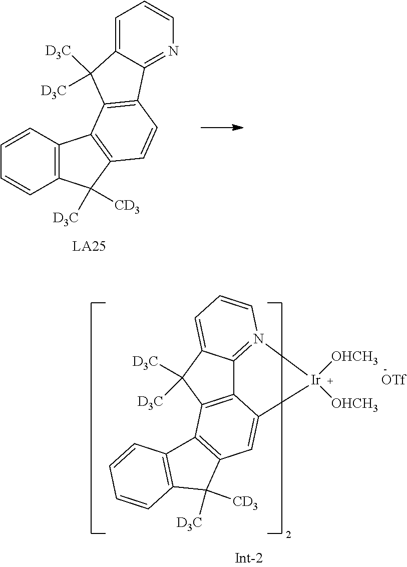

10.0 g of a compound LA25 and 4.5 mmol of IrCl₃·3H₂O are dispersed in 60 mL of glycol ether and 20 mL of water, under the protection of nitrogen, the mixture is heated and reacted under refluxing for 24 hours, the reaction solution is cooled to room temperature and filtered, the filter cake is washed with water and ethanol, and dried in vacuum to obtain a yellow solid, the obtained yellow solid is dissolved in 50 mL of dichloromethane and 5 mL of methanol, 20.0 mmol of silver trifluoromethanesulfonate is added, the mixture is stirred and reacted for 24 hours, the reaction solution is filtered, and the filtrate is concentrated under reduced pressure to dryness to obtain a compound Int-2, a yellow solid, with a yield of 85%.

### Step 2: Preparation of Metal Complex Ir(LA25)₂(LB77)

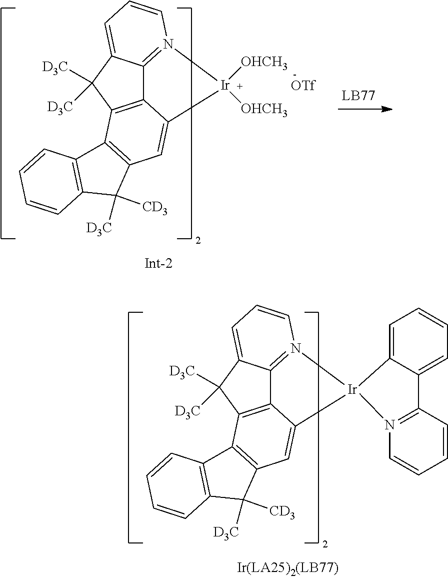

5.0 mmol of a compound LB77 and 2.5 mmol of the intermediate Int-2 are dispersed in 15 mL of glycol ether and 15 mL of DMF, under the protection of nitrogen, the mixture is heated to 100° C., stirred, and reacted for 7 days, the reaction solution is cooled room temperature, poured into 250 mL of ice water, and extracted with dichloromethane, the organic phase is collected, dried, and filtered, the filtrate is concentrated under reduced pressure to dryness, and the residue is separated and purified by a silica gel column, and eluted with dichloromethane-n-hexane to obtain a metal complex Ir(LA25)₂(LB77), a dark yellow solid, with a yield of 48%.

Referring to the above synthesis method, the following metal complex is prepared: Ir(LAi)₂(LBj), wherein the i is an integer of 1-208 and the j is an integer of 1-432.

Specific synthesis steps are as follows:

Step 1: referring to the synthesis method of the step 1, a trifluoromethanesulfonate of a bisLAi iridium complex is prepared:

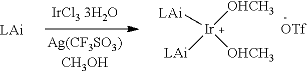

Step 2: referring to the synthesis method of the step 2, a metal complex is prepared by a coordination reaction of only the trifluoromethanesulfonate intermediate of the bisLAi iridium complex prepared in step 1 with excess LBj: Ir(LAi)₂(LBj),

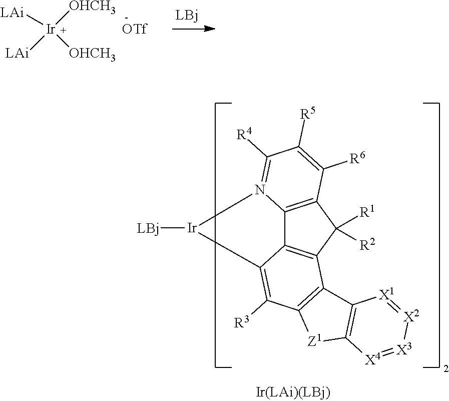

the LA1-LA208 and the LB1-LB432 are the same as the definition.

### Example 3

### Preparation of Metal Complex Ir(LA139)₃

Step 1: Preparation of Compound Int-3

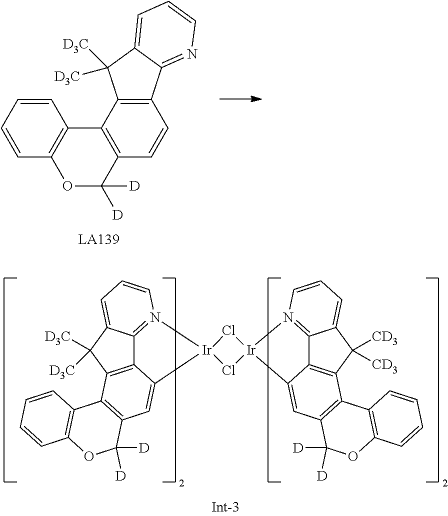

9.5 mmol of a compound LA139 and 4.5 mmol of IrCl₃·3H₂O are dispersed in 60 mL of glycol ether and 20 mL of water, under the protection of nitrogen, the mixture is heated and reacted under refluxing for 24 hours, the reaction solution is cooled to room temperature and filtered, and the filter cake is washed with water and ethanol, and dried in vacuum to obtain a compound Int-3, a yellow solid, with a yield of 72%.

Step 2: Preparation of Metal Complex Ir(LA139)₃

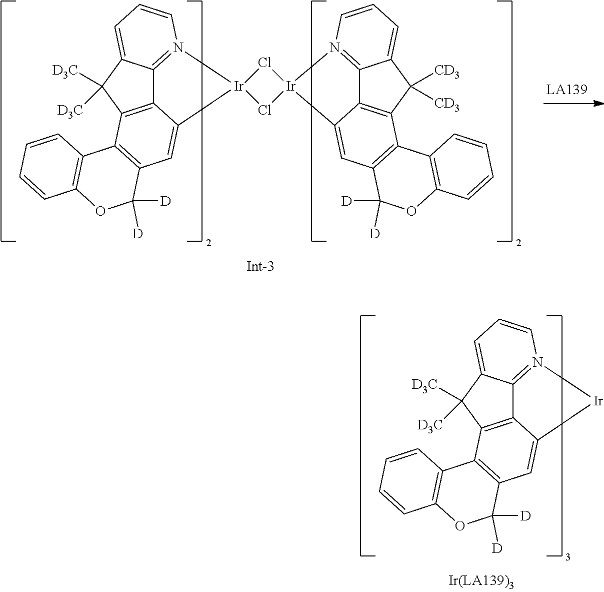

5.0 mmol of the Int-3 prepared in step 1, 10.0 mmol of silver trifluoromethanesulfonate, and 12.0 mmol of LA139 are dispersed in 20 mL of glycol ether, under the protection of nitrogen, the mixture is heated, and reacted under refluxing and stirring for 24 hours, the reaction solution is cooled room temperature and filtered, the filter cake is dissolved with dichloromethane, and the residues is separated and purified by a silica gel column to obtain a metal complex Ir(LA139)₃, a yellow solid, with a yield of 45%.

Referring to the above synthesis method, the following metal complex is prepared:

Ir(LAi)₃, wherein the i is an integer of 1-208.

Specific synthesis steps are as follows:

Step 1: referring to the synthesis method of the step 1, an LAi iridium chloride bridge complex is prepared:

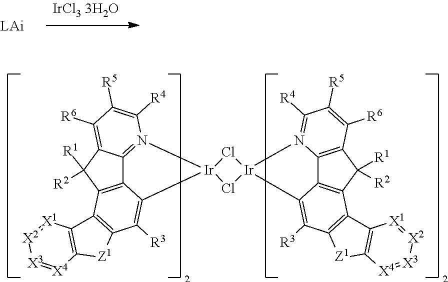

Step 2: referring to the synthesis method of the step 2, a metal complex is prepared by a coordination reaction of only the LAi iridium chloride bridge complex intermediate prepared in step 1 with excess LAi: Ir(LAi)₃, and

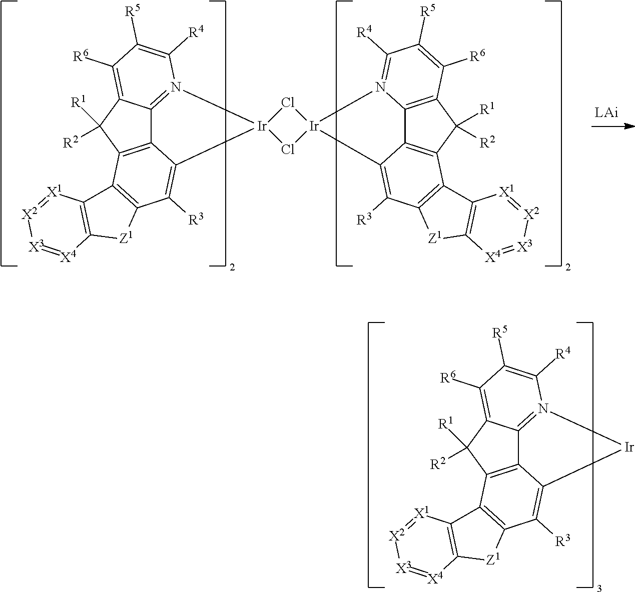

the LA1-LA208 are the same as the definition.

### Example 4

### Preparation of Organic Electroluminescent Element

(1) ultrasonically treating a glass substrate coated with an ITO conductive layer in a cleaning agent for 30 minutes, washing the glass substrate in deionized water, ultrasonically treating the glass substrate in an acetone/ethanol mixed solvent for 30 minutes, baking the glass substrate in a clean environment until complete dryness, irradiating the glass substrate for 10 minutes by an ultraviolet light cleaning machine, and bombarding a surface of the glass substrate by a low-energy cation beam;
(2) placing the treated ITO glass substrate in a vacuum chamber, vacuumizing same to 1×10⁻⁵-9×10⁻³ Pa, and continuously and respectively evaporating a compound HATCN as a hole injection layer on the anode layer film, wherein the evaporated film has a thickness of 1,200 Å; and continuously evaporating HTM on the hole injection layer film as a hole transport layer, wherein the evaporated film has a thickness of 1,100 Å;
(3) evaporating EBM on the hole transport layer as an electron blocking layer, wherein the evaporated film has a thickness of 500 Å;
(4) evaporating an organic emission layer on the electron blocking layer, wherein the emission layer contains H1 as a host and 3% by mass of the metal complex prepared by the present invention as a doped material, and the evaporated film has a thickness of 300 Å;
(5) further continuously evaporating a layer of LiQ and ETM on the organic emission layer as an electron transport layer of an element, wherein LiQ is 50% by mass of ETM, and an evaporated film has a thickness of 150 Å;
(6) continuously evaporating a layer of LiF on the emission layer as electron injection layer of a device, and the evaporated film has a thickness of 10 Å; and
(7) evaporating a metal aluminum on the electron injection layer as a cathode layer of the element, and the evaporated film has a thickness of 1,500 Å.

### Comparative Example 1

The compound shown as GD-1 is used to replace the metal complex in example 4, other steps are the same as those in example 4, and a comparative element 1 is manufactured.

### Comparative Example 2

The compound shown as GD-2 is used to replace the metal complex in example 4, other steps are the same as those in example 4, and a comparative element 2 is manufactured.

The HATCN, the HTM, the EBM, the H1, the LiQ, the GD-1, the GD-2, and the ETM have structural formulas shown below:

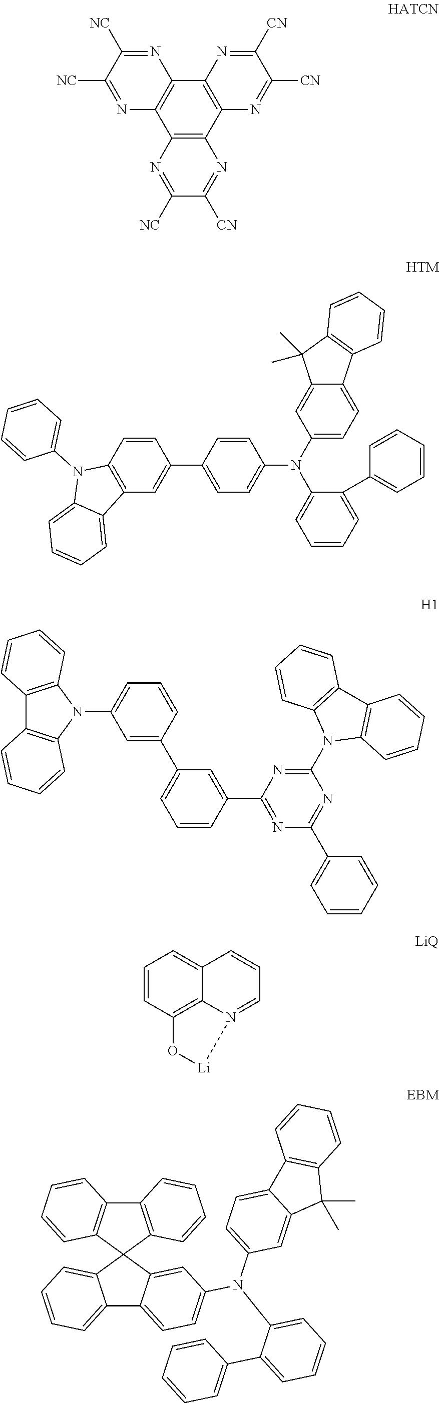

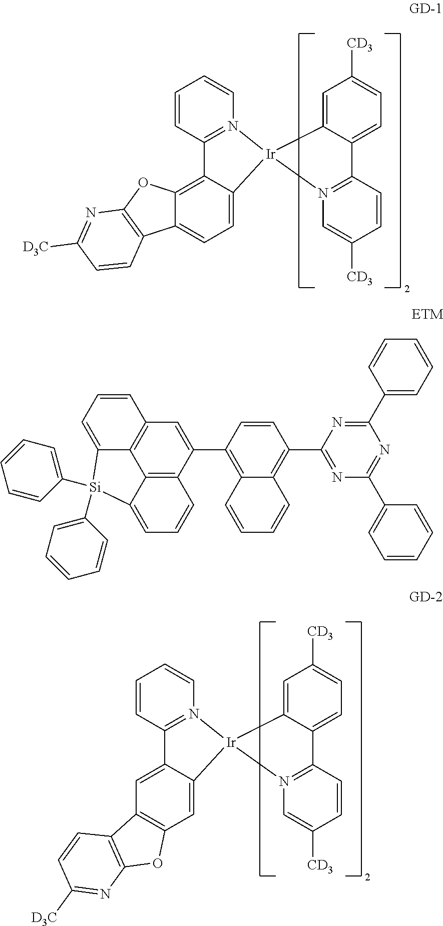

According to the same method in example 4, the metal complex of the present invention is used as a doping material of the organic emission layer to manufacture the organic electroluminescent element. Structure and performance data are summarized in Table 1. The complexes Ir(LAi-LA208)(LB105)₂ are only taken as an example in the table. *data are normalized compared with the comparative element 1.

TABLE 1

| | | @10 mA/cm² | | | |
|---|---|---|---|---|---|
| | | | | Full width | |
| | | | | at half | (@ 50 mA/cm²) |
| Element | | Voltage | EQE | maximum | LT95% |
| No. | Metal complex | (V)* | (%)* | (nm)* | (h)* |
| Comparative | GD-1 | 1.00 | 1.00 | 1.00 | 1.00 |
| element 1 | | | | | |
| Comparative | GD-2 | 1.08 | 0.92 | 1.02 | 0.90 |
| element 2 | | | | | |
| Element 1 | Ir(LA1)(LB105)₂ | 0.92 | 1.04 | 0.98 | 1.17 |
| Element 2 | Ir(LA2)(LB105)₂ | 0.90 | 1.09 | 0.98 | 1.64 |
| Element 3 | Ir(LA3)(LB105)₂ | 0.95 | 1.05 | 0.98 | 2.01 |
| Element 4 | Ir(LA4)(LB105)₂ | 0.97 | 1.12 | 0.98 | 3.25 |
| Element 5 | Ir(LA5)(LB105)₂ | 0.95 | 1.19 | 0.98 | 2.24 |
| Element 6 | Ir(LA6)(LB105)₂ | 0.92 | 1.11 | 0.98 | 1.22 |
| Element 7 | Ir(LA7)(LB105)₂ | 0.99 | 1.05 | 0.98 | 1.48 |
| Element 8 | Ir(LA8)(LB105)₂ | 0.97 | 1.08 | 0.98 | 2.62 |
| Element 9 | Ir(LA9)(LB105)₂ | 0.90 | 1.14 | 0.98 | 1.52 |
| Element 10 | Ir(LA10)(LB105)₂ | 0.92 | 1.12 | 0.98 | 2.74 |
| Element 11 | Ir(LA11)(LB105)₂ | 0.91 | 1.05 | 0.98 | 2.41 |
| Element 12 | Ir(LA12)(LB105)₂ | 0.95 | 1.12 | 0.98 | 2.37 |
| Element 13 | Ir(LA13)(LB105)₂ | 0.90 | 1.09 | 0.99 | 1.57 |
| Element 14 | Ir(LA14)(LB105)₂ | 0.94 | 1.03 | 0.98 | 1.38 |
| Element 15 | Ir(LA15)(LB105)₂ | 0.98 | 1.10 | 0.98 | 2.44 |
| Element 16 | Ir(LA16)(LB105)₂ | 0.95 | 1.08 | 0.98 | 1.26 |
| Element 17 | Ir(LA17)(LB105)₂ | 0.90 | 1.11 | 0.98 | 2.35 |
| Element 18 | Ir(LA18)(LB105)₂ | 0.96 | 1.12 | 0.98 | 1.95 |
| Element 19 | Ir(LA19)(LB105)₂ | 0.95 | 1.11 | 0.98 | 2.19 |
| Element 20 | Ir(LA20)(LB105)₂ | 0.99 | 1.12 | 0.98 | 2.43 |
| Element 21 | Ir(LA21)(LB105)₂ | 0.97 | 1.21 | 0.98 | 1.97 |
| Element 22 | Ir(LA22)(LB105)₂ | 0.92 | 1.09 | 0.98 | 2.08 |
| Element 23 | Ir(LA23)(LB105)₂ | 0.93 | 1.14 | 0.98 | 2.13 |
| Element 24 | Ir(LA24)(LB105)₂ | 0.95 | 1.07 | 0.99 | 2.59 |
| Element 25 | Ir(LA25)(LB105)₂ | 0.91 | 1.17 | 0.98 | 2.04 |
| Element 26 | Ir(LA26)(LB105)₂ | 0.97 | 1.15 | 0.98 | 1.82 |
| Element 27 | Ir(LA27)(LB105)₂ | 0.95 | 1.11 | 0.99 | 2.94 |
| Element 28 | Ir(LA28)(LB105)₂ | 0.92 | 1.05 | 0.98 | 1.47 |
| Element 29 | Ir(LA29)(LB105)₂ | 0.90 | 1.08 | 0.98 | 1.13 |
| Element 30 | Ir(LA30)(LB105)₂ | 0.95 | 1.14 | 0.98 | 2.08 |
| Element 31 | Ir(LA31)(LB105)₂ | 0.97 | 1.12 | 0.98 | 3.16 |
| Element 32 | Ir(LA32)(LB105)₂ | 0.95 | 1.05 | 0.98 | 2.59 |
| Element 33 | Ir(LA33)(LB105)₂ | 0.92 | 1.12 | 0.98 | 1.24 |
| Element 34 | Ir(LA34)(LB105)₂ | 0.99 | 1.15 | 0.98 | 3.22 |
| Element 35 | Ir(LA35)(LB105)₂ | 0.97 | 1.10 | 0.98 | 2.08 |
| Element 36 | Ir(LA36)(LB105)₂ | 0.90 | 1.13 | 0.98 | 3.32 |
| Element 37 | Ir(LA37)(LB105)₂ | 0.92 | 1.13 | 0.97 | 2.25 |
| Element 38 | Ir(LA38)(LB105)₂ | 0.91 | 1.12 | 0.99 | 2.94 |
| Element 39 | Ir(LA39)(LB105)₂ | 0.95 | 1.05 | 0.99 | 1.86 |
| Element 40 | Ir(LA40)(LB105)₂ | 0.90 | 1.10 | 0.99 | 2.56 |
| Element 41 | Ir(LA41)(LB105)₂ | 0.96 | 1.21 | 0.99 | 1.55 |
| Element 42 | Ir(LA42)(LB105)₂ | 0.95 | 1.11 | 0.99 | 2.49 |
| Element 43 | Ir(LA43)(LB105)₂ | 0.99 | 1.08 | 0.99 | 2.27 |
| Element 44 | Ir(LA44)(LB105)₂ | 0.97 | 1.05 | 1.00 | 3.58 |
| Element 45 | Ir(LA45)(LB105)₂ | 0.92 | 1.13 | 0.98 | 3.04 |
| Element 46 | Ir(LA46)(LB105)₂ | 0.93 | 1.04 | 0.98 | 2.66 |
| Element 47 | Ir(LA47)(LB105)₂ | 0.95 | 1.10 | 0.98 | 3.79 |
| Element 48 | Ir(LA48)(LB105)₂ | 0.91 | 1.11 | 0.98 | 2.83 |
| Element 49 | Ir(LA49)(LB105)₂ | 0.99 | 1.11 | 0.98 | 2.79 |
| Element 50 | Ir(LA50)(LB105)₂ | 0.97 | 1.08 | 0.98 | 1.91 |
| Element 51 | Ir(LA51)(LB105)₂ | 0.92 | 1.05 | 0.98 | 2.54 |
| Element 52 | Ir(LA52)(LB105)₂ | 0.94 | 1.13 | 0.98 | 2.47 |
| Element 53 | Ir(LA53)(LB105)₂ | 0.97 | 1.11 | 0.98 | 1.68 |
| Element 54 | Ir(LA54)(LB105)₂ | 0.90 | 1.08 | 0.98 | 2.17 |
| Element 55 | Ir(LA55)(LB105)₂ | 0.96 | 1.17 | 0.98 | 2.70 |
| Element 56 | Ir(LA56)(LB105)₂ | 0.91 | 1.08 | 0.98 | 1.25 |
| Element 57 | Ir(LA57)(LB105)₂ | 0.98 | 1.08 | 0.99 | 1.46 |
| Element 58 | Ir(LA58)(LB105)₂ | 0.99 | 1.16 | 0.98 | 2.92 |
| Element 59 | Ir(LA59)(LB105)₂ | 0.95 | 1.15 | 0.98 | 3.53 |
| Element 60 | Ir(LA60)(LB105)₂ | 0.90 | 1.10 | 0.98 | 1.95 |
| Element 61 | Ir(LA61)(LB105)₂ | 0.91 | 1.12 | 0.98 | 2.60 |
| Element 62 | Ir(LA62)(LB105)₂ | 0.98 | 1.03 | 0.98 | 2.07 |
| Element 63 | Ir(LA63)(LB105)₂ | 0.99 | 1.16 | 0.98 | 3.45 |
| Element 64 | Ir(LA64)(LB105)₂ | 0.95 | 1.11 | 0.98 | 2.32 |
| Element 65 | Ir(LA65)(LB105)₂ | 0.90 | 1.11 | 0.98 | 3.20 |
| Element 66 | Ir(LA66)(LB105)₂ | 0.99 | 1.16 | 0.98 | 1.78 |
| Element 67 | Ir(LA67)(LB105)₂ | 0.96 | 1.18 | 0.98 | 2.56 |
| Element 68 | Ir(LA68)(LB105)₂ | 0.91 | 1.12 | 0.99 | 2.30 |
| Element 69 | Ir(LA69)(LB105)₂ | 0.92 | 1.15 | 0.98 | 2.25 |
| Element 70 | Ir(LA70)(LB105)₂ | 0.93 | 1.18 | 0.98 | 3.82 |
| Element 71 | Ir(LA71)(LB105)₂ | 0.93 | 1.05 | 0.98 | 2.77 |
| Element 72 | Ir(LA72)(LB105)₂ | 0.90 | 1.16 | 0.98 | 2.02 |
| Element 73 | Ir(LA73)(LB105)₂ | 0.95 | 1.02 | 0.98 | 1.93 |
| Element 74 | Ir(LA74)(LB105)₂ | 0.91 | 1.05 | 0.98 | 1.58 |
| Element 75 | Ir(LA75)(LB105)₂ | 0.97 | 1.09 | 0.97 | 2.06 |
| Element 76 | Ir(LA76)(LB105)₂ | 0.93 | 1.18 | 0.98 | 1.22 |
| Element 77 | Ir(LA77)(LB105)₂ | 0.91 | 1.15 | 0.98 | 2.52 |
| Element 78 | Ir(LA78)(LB105)₂ | 0.97 | 1.12 | 0.98 | 2.17 |
| Element 79 | Ir(LA79)(LB105)₂ | 0.94 | 1.11 | 0.99 | 1.29 |
| Element 80 | Ir(LA80)(LB105)₂ | 0.98 | 1.13 | 0.99 | 2.12 |
| Element 81 | Ir(LA81)(LB105)₂ | 0.95 | 1.06 | 0.98 | 3.40 |
| Element 82 | Ir(LA82)(LB105)₂ | 0.97 | 1.11 | 0.98 | 2.35 |
| Element 83 | Ir(LA83)(LB105)₂ | 0.93 | 1.13 | 0.98 | 2.85 |
| Element 84 | Ir(LA84)(LB105)₂ | 0.91 | 1.08 | 0.98 | 2.96 |
| Element 85 | Ir(LA85)(LB105)₂ | 0.97 | 1.11 | 0.98 | 2.33 |
| Element 86 | Ir(LA86)(LB105)₂ | 0.94 | 1.07 | 0.98 | 1.58 |
| Element 87 | Ir(LA87)(LB105)₂ | 0.98 | 1.09 | 0.98 | 2.06 |
| Element 88 | Ir(LA88)(LB105)₂ | 0.95 | 1.16 | 0.98 | 2.71 |
| Element 89 | Ir(LA89)(LB105)₂ | 0.97 | 1.26 | 0.98 | 1.58 |
| Element 90 | Ir(LA90)(LB105)₂ | 0.96 | 1.13 | 0.99 | 2.84 |
| Element 91 | Ir(LA91)(LB105)₂ | 0.93 | 1.22 | 0.98 | 2.15 |
| Element 92 | Ir(LA92)(LB105)₂ | 0.97 | 1.07 | 0.99 | 2.83 |
| Element 93 | Ir(LA93)(LB105)₂ | 0.96 | 1.22 | 0.98 | 2.71 |
| Element 94 | Ir(LA94)(LB105)₂ | 0.93 | 1.20 | 0.98 | 2.04 |
| Element 95 | Ir(LA95)(LB105)₂ | 0.89 | 1.19 | 0.98 | 2.80 |
| Element 96 | Ir(LA96)(LB105)₂ | 0.93 | 1.16 | 0.98 | 1.16 |
| Element 97 | Ir(LA97)(LB105)₂ | 0.97 | 1.18 | 0.99 | 1.39 |
| Element 98 | Ir(LA98)(LB105)₂ | 0.96 | 1.16 | 0.99 | 2.42 |
| Element 99 | Ir(LA99)(LB105)₂ | 0.93 | 1.15 | 0.98 | 3.55 |
| Element 100 | Ir(LA100)(LB105)₂ | 0.89 | 1.18 | 0.99 | 2.96 |
| Element 101 | Ir(LA101)(LB105)₂ | 0.91 | 1.21 | 0.98 | 3.20 |
| Element 102 | Ir(LA102)(LB105)₂ | 0.95 | 1.12 | 0.98 | 3.08 |
| Element 103 | Ir(LA103)(LB105)₂ | 0.97 | 1.17 | 0.98 | 2.95 |
| Element 104 | Ir(LA104)(LB105)₂ | 0.92 | 1.04 | 0.97 | 2.02 |
| Element 105 | Ir(LA105)(LB105)₂ | 0.88 | 1.13 | 0.98 | 3.00 |
| Element 106 | Ir(LA106)(LB105)₂ | 0.98 | 1.09 | 0.99 | 2.61 |
| Element 107 | Ir(LA107)(LB105)₂ | 0.94 | 1.10 | 0.99 | 3.10 |
| Element 108 | Ir(LA108)(LB105)₂ | 0.93 | 1.14 | 1.00 | 2.28 |
| Element 109 | Ir(LA109)(LB105)₂ | 0.88 | 1.04 | 0.98 | 3.05 |
| Element 110 | Ir(LA110)(LB105)₂ | 0.98 | 1.16 | 0.98 | 2.16 |
| Element 111 | Ir(LA111)(LB105)₂ | 0.94 | 1.07 | 0.98 | 2.05 |
| Element 112 | Ir(LA112)(LB105)₂ | 0.93 | 1.09 | 0.99 | 3.16 |
| Element 113 | Ir(LA113)(LB105)₂ | 0.97 | 1.17 | 0.98 | 2.17 |
| Element 114 | Ir(LA114)(LB105)₂ | 0.96 | 1.16 | 0.99 | 2.05 |
| Element 115 | Ir(LA115)(LB105)₂ | 0.92 | 1.22 | 0.98 | 2.46 |
| Element 116 | Ir(LA116)(LB105)₂ | 0.95 | 1.14 | 0.98 | 2.83 |
| Element 117 | Ir(LA117)(LB105)₂ | 0.92 | 1.10 | 0.99 | 1.60 |
| Element 118 | Ir(LA118)(LB105)₂ | 0.97 | 1.09 | 0.99 | 2.45 |
| Element 119 | Ir(LA119)(LB105)₂ | 0.95 | 1.19 | 0.98 | 2.08 |
| Element 120 | Ir(LA120)(LB105)₂ | 0.99 | 1.10 | 0.98 | 1.25 |
| Element 121 | Ir(LA121)(LB105)₂ | 0.93 | 1.14 | 0.99 | 2.87 |
| Element 122 | Ir(LA122)(LB105)₂ | 0.90 | 1.15 | 0.99 | 2.44 |
| Element 123 | Ir(LA123)(LB105)₂ | 0.93 | 1.06 | 0.99 | 2.66 |
| Element 124 | Ir(LA124)(LB105)₂ | 0.95 | 1.12 | 0.97 | 3.34 |
| Element 125 | Ir(LA125)(LB105)₂ | 0.98 | 1.07 | 0.98 | 2.67 |
| Element 126 | Ir(LA126)(LB105)₂ | 0.89 | 1.22 | 1.00 | 2.45 |
| Element 127 | Ir(LA127)(LB105)₂ | 0.95 | 1.14 | 0.98 | 2.16 |
| Element 128 | Ir(LA128)(LB105)₂ | 0.97 | 1.10 | 0.98 | 2.30 |
| Element 129 | Ir(LA129)(LB105)₂ | 0.92 | 1.14 | 0.98 | 2.14 |
| Element 130 | Ir(LA130)(LB105)₂ | 0.88 | 1.10 | 0.98 | 1.25 |
| Element 131 | Ir(LA131)(LB105)₂ | 0.98 | 1.21 | 0.98 | 2.27 |
| Element 132 | Ir(LA132)(LB105)₂ | 0.94 | 1.11 | 0.98 | 2.20 |
| Element 133 | Ir(LA133)(LB105)₂ | 0.93 | 1.08 | 0.98 | 2.61 |
| Element 134 | Ir(LA134)(LB105)₂ | 0.90 | 1.05 | 0.98 | 2.29 |
| Element 135 | Ir(LA135)(LB105)₂ | 0.94 | 1.13 | 0.98 | 3.13 |
| Element 136 | Ir(LA136)(LB105)₂ | 0.93 | 1.02 | 0.99 | 3.08 |
| Element 137 | Ir(LA137)(LB105)₂ | 0.90 | 1.07 | 0.99 | 2.52 |
| Element 138 | Ir(LA138)(LB105)₂ | 0.95 | 1.13 | 0.99 | 2.26 |
| Element 139 | Ir(LA139)(LB105)₂ | 0.99 | 1.11 | 0.98 | 3.11 |
| Element 140 | Ir(LA140)(LB105)₂ | 0.94 | 1.10 | 0.98 | 2.98 |
| Element 141 | Ir(LA141)(LB105)₂ | 0.97 | 1.08 | 0.98 | 2.74 |
| Element 142 | Ir(LA142)(LB105)₂ | 0.93 | 1.05 | 0.98 | 2.58 |
| Element 143 | Ir(LA143)(LB105)₂ | 0.93 | 1.13 | 0.98 | 2.08 |
| Element 144 | Ir(LA144)(LB105)₂ | 0.92 | 1.03 | 0.98 | 2.65 |
| Element 145 | Ir(LA145)(LB105)₂ | 0.99 | 1.14 | 0.98 | 2.15 |
| Element 146 | Ir(LA146)(LB105)₂ | 0.95 | 1.05 | 0.98 | 2.01 |
| Element 147 | Ir(LA147)(LB105)₂ | 0.91 | 1.24 | 0.98 | 1.96 |
| Element 148 | Ir(LA148)(LB105)₂ | 0.99 | 1.13 | 0.98 | 2.26 |
| Element 149 | Ir(LA149)(LB105)₂ | 0.91 | 1.18 | 0.99 | 1.88 |
| Element 150 | Ir(LA150)(LB105)₂ | 0.94 | 1.15 | 0.99 | 2.43 |
| Element 151 | Ir(LA151)(LB105)₂ | 0.99 | 1.09 | 0.98 | 1.86 |
| Element 152 | Ir(LA152)(LB105)₂ | 0.99 | 1.21 | 0.98 | 2.09 |
| Element 153 | Ir(LA153)(LB105)₂ | 0.88 | 1.10 | 0.98 | 2.27 |
| Element 154 | Ir(LA154)(LB105)₂ | 0.92 | 1.06 | 0.98 | 2.95 |
| Element 155 | Ir(LA155)(LB105)₂ | 0.99 | 1.16 | 0.98 | 2.37 |
| Element 156 | Ir(LA156)(LB105)₂ | 0.92 | 1.04 | 0.98 | 3.02 |
| Element 157 | Ir(LA157)(LB105)₂ | 0.99 | 1.20 | 0.98 | 3.18 |
| Element 158 | Ir(LA158)(LB105)₂ | 0.99 | 1.15 | 0.98 | 2.95 |
| Element 159 | Ir(LA159)(LB105)₂ | 0.97 | 1.08 | 0.99 | 1.77 |
| Element 160 | Ir(LA160)(LB105)₂ | 0.98 | 1.10 | 0.98 | 1.90 |
| Element 161 | Ir(LA161)(LB105)₂ | 0.96 | 1.04 | 0.98 | 3.59 |
| Element 162 | Ir(LA162)(LB105)₂ | 1.00 | 1.23 | 0.98 | 2.23 |
| Element 163 | Ir(LA163)(LB105)₂ | 0.92 | 1.24 | 0.99 | 2.27 |
| Element 164 | Ir(LA164)(LB105)₂ | 0.97 | 1.19 | 0.98 | 2.35 |
| Element 165 | Ir(LA165)(LB105)₂ | 0.92 | 1.18 | 0.99 | 2.31 |
| Element 166 | Ir(LA166)(LB105)₂ | 0.99 | 1.22 | 0.99 | 2.26 |
| Element 167 | Ir(LA167)(LB105)₂ | 0.91 | 1.24 | 0.98 | 2.20 |
| Element 168 | Ir(LA168)(LB105)₂ | 0.93 | 1.06 | 0.98 | 1.75 |
| Element 169 | Ir(LA169)(LB105)₂ | 0.92 | 1.16 | 0.98 | 2.19 |
| Element 170 | Ir(LA170)(LB105)₂ | 0.96 | 1.04 | 0.99 | 3.06 |
| Element 171 | Ir(LA171)(LB105)₂ | 0.94 | 1.20 | 0.99 | 2.87 |
| Element 172 | Ir(LA172)(LB105)₂ | 0.97 | 1.17 | 0.99 | 2.36 |
| Element 173 | Ir(LA173)(LB105)₂ | 0.96 | 1.08 | 0.98 | 2.59 |
| Element 174 | Ir(LA174)(LB105)₂ | 0.90 | 1.10 | 0.98 | 1.67 |
| Element 175 | Ir(LA175)(LB105)₂ | 0.92 | 1.03 | 0.98 | 2.52 |
| Element 176 | Ir(LA176)(LB105)₂ | 0.98 | 1.14 | 0.98 | 2.46 |
| Element 177 | Ir(LA177)(LB105)₂ | 0.95 | 1.10 | 0.98 | 2.87 |
| Element 178 | Ir(LA178)(LB105)₂ | 0.98 | 1.12 | 0.98 | 2.56 |
| Element 179 | Ir(LA179)(LB105)₂ | 0.97 | 1.08 | 0.98 | 1.97 |
| Element 180 | Ir(LA180)(LB105)₂ | 0.91 | 1.09 | 0.98 | 2.06 |
| Element 181 | Ir(LA181)(LB105)₂ | 0.90 | 1.11 | 0.98 | 2.63 |
| Element 182 | Ir(LA182)(LB105)₂ | 0.89 | 1.17 | 0.98 | 1.95 |
| Element 183 | Ir(LA183)(LB105)₂ | 0.91 | 1.13 | 0.98 | 2.18 |
| Element 184 | Ir(LA184)(LB105)₂ | 0.92 | 1.09 | 0.98 | 2.49 |
| Element 185 | Ir(LA185)(LB105)₂ | 0.90 | 1.06 | 0.98 | 2.42 |
| Element 186 | Ir(LA186)(LB105)₂ | 0.91 | 1.10 | 0.98 | 2.36 |
| Element 187 | Ir(LA187)(LB105)₂ | 0.93 | 1.11 | 0.98 | 1.27 |
| Element 188 | Ir(LA188)(LB105)₂ | 0.94 | 1.17 | 0.98 | 1.24 |
| Element 189 | Ir(LA189)(LB105)₂ | 0.99 | 1.16 | 0.99 | 2.60 |
| Element 190 | Ir(LA190)(LB105)₂ | 0.90 | 1.06 | 0.99 | 2.93 |
| Element 191 | Ir(LA191)(LB105)₂ | 0.95 | 1.04 | 0.99 | 2.55 |
| Element 192 | Ir(LA192)(LB105)₂ | 0.92 | 1.20 | 0.98 | 2.48 |
| Element 193 | Ir(LA193)(LB105)₂ | 0.96 | 1.15 | 0.99 | 1.76 |
| Element 194 | Ir(LA194)(LB105)₂ | 0.91 | 1.08 | 0.98 | 2.86 |
| Element 195 | Ir(LA195)(LB105)₂ | 0.95 | 1.10 | 0.98 | 1.65 |
| Element 196 | Ir(LA196)(LB105)₂ | 0.97 | 1.04 | 0.98 | 1.47 |
| Element 197 | Ir(LA197)(LB105)₂ | 0.92 | 1.05 | 0.98 | 1.89 |
| Element 198 | Ir(LA198)(LB105)₂ | 0.93 | 1.10 | 0.98 | 2.18 |
| Element 199 | Ir(LA199)(LB105)₂ | 0.94 | 1.14 | 0.98 | 1.67 |
| Element 200 | Ir(LA200)(LB105)₂ | 0.95 | 1.10 | 0.98 | 1.85 |
| Element 201 | Ir(LA201)(LB105)₂ | 0.92 | 1.16 | 0.99 | 2.06 |
| Element 202 | Ir(LA202)(LB105)₂ | 0.94 | 1.08 | 0.99 | 2.17 |
| Element 203 | Ir(LA203)(LB105)₂ | 0.93 | 1.19 | 0.98 | 2.25 |
| Element 204 | Ir(LA204)(LB105)₂ | 0.90 | 1.14 | 0.98 | 1.86 |
| Element 205 | Ir(LA205)(LB105)₂ | 0.95 | 1.12 | 0.99 | 1.45 |
| Element 206 | Ir(LA206)(LB105)₂ | 0.99 | 1.13 | 0.98 | 1.28 |
| Element 207 | Ir(LA207)(LB105)₂ | 0.94 | 1.08 | 0.98 | 1.94 |
| Element 208 | Ir(LA208)(LB105)₂ | 0.97 | 1.06 | 0.98 | 1.31 |

It can be seen from Table 1 that the metal complex of the present invention, as a doping material of an emission layer, has a driving voltage lower than that in comparative example 1, and especially has greater advantages in terms of external quantum efficiency and LT95% service life.

Differences between the compound GD-2 in comparative example 2 and the compounds of the present invention lie in that pyridine is connected with a substituted benzene through a single bond, and thus the plane conjugation ability is weak; since the free rotation vibration of the pyridine and the substituted benzene is in a distorted state, an energy loss is caused and a metal-ligand charge transfer property is reduced; the metal complex ligand of the present invention forms a fluorene ring rigid structure by the pyridine and the substituted benzene, a large conjugate plane is formed, the rotation of the two conjugate planes is avoided, such that the metal complex ligand has an excellent property in terms of charge transfer, the metal-ligand charge transfer property is improved, the charge transfer in the element is more balanced, and the element performance is improved.

Table 1 only lists the properties of some metal complexes. The present inventor also performs the tests on other metal complexes. The results are basically consistent. Due to a limited space, the properties of other metal complexes are not further listed.

To make the objects, technical solutions, and advantages of the present invention clearer, the following describes in detail the technical solutions of the present invention. Apparently, the described examples are merely some rather than all of the examples of the present invention. All other examples obtained by a person of ordinary skill in the art based on the examples of the present invention without creative efforts should fall within the protection scope of the present invention.

The foregoing descriptions are merely specific embodiments of the present invention, but the protection scope of the present invention is not limited thereto. Any modification or replacement easily conceived by a person skilled in the art within the technical scope of the present invention should fall within the protection scope of the present invention. Therefore, the protection scope of the present invention shall be the protection scope of the claims.

1. A metal complex, wherein the metal complex comprises a ligand shown in a formula (LA): 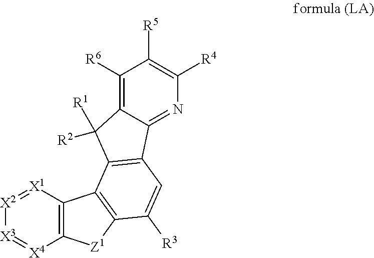
wherein X¹, X², X³, and X⁴ are each independently selected from N or CR⁷;
Z¹ is selected from O, S, CR⁸R⁹, NR⁸, SiR⁸R⁹, C(R⁸R⁹)—C(R⁸R⁹), C(R⁸)═C(R⁹), N═CR⁹, CR⁸═N, NR⁸—CR⁸R⁹, CR⁸R⁹—NR⁹, OCR⁸R⁹, SCR⁸R⁹, CR⁸R⁹O, CR⁸R⁹S, or GeR⁸R⁹;
R¹-R⁹ are identically or differently, at each occurrence, selected from the group consisting of hydrogen, deuterium, a halogen atom, C₁-C₄₀ alkyl, C₃-C₄₀ cycloalkyl, C₁-C₄₀ heteroalkyl, C₃-C₄₀ heterocycloalkyl, C₆-C₆₀ aralkyl, C₁-C₄₀ alkoxy, C₆-C₆₀ aryloxy, amino, C₃-C₄₀ silyl, C₂-C₄₀ alkenyl, C₅-C₄₀ cycloalkenyl, C₃-C₄₀ heteroalkenyl, C₂-C₄₀ alkynyl, C₆-C₆₀ aryl, C₂-C₆₀ heteroaryl, C₁-C₄₀ acyl, a carboxylic acid group, ether, an ester group, a nitrile group, an isonitrile group, thio, sulfinyl, sulfonyl, and phosphino; any two or more adjacent substituents are optionally joined or fused together to form a substituted or unsubstituted five-membered, six-membered or multiple-membered ring;
the metal complex is a five-membered chelate ring formed by the coordination of the ligand shown in the formula (LA) with a metal of M;
the metal complex further comprises other ligands and the ligand shown in the formula (LA) is connected with other ligands to form a tridentate, tetradentate, pentadentate or hexadentate ligand; and
the M is selected from one of Os, Ir, Pd, Pt, Cu, Ag, and Au, and preferably, the M is selected from one of Ir, Pd or Pt.

2. The metal complex according to claim 1, wherein the formula (LA) comprises one of the following structures LAI-LAXV: 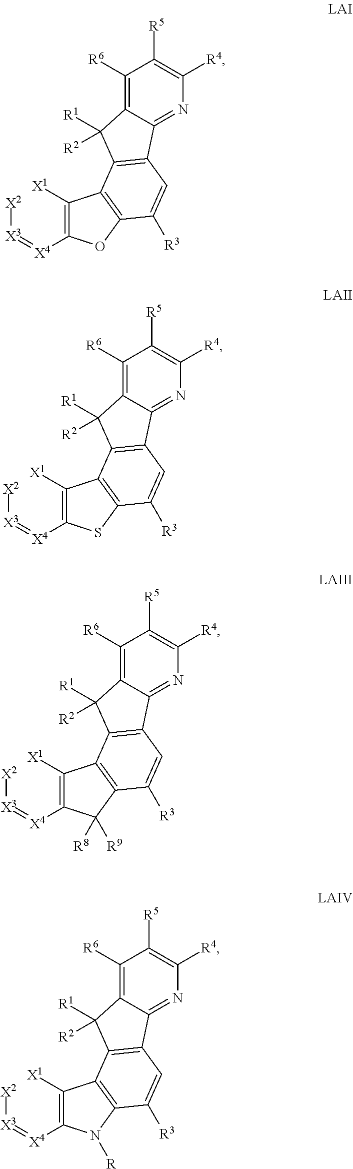 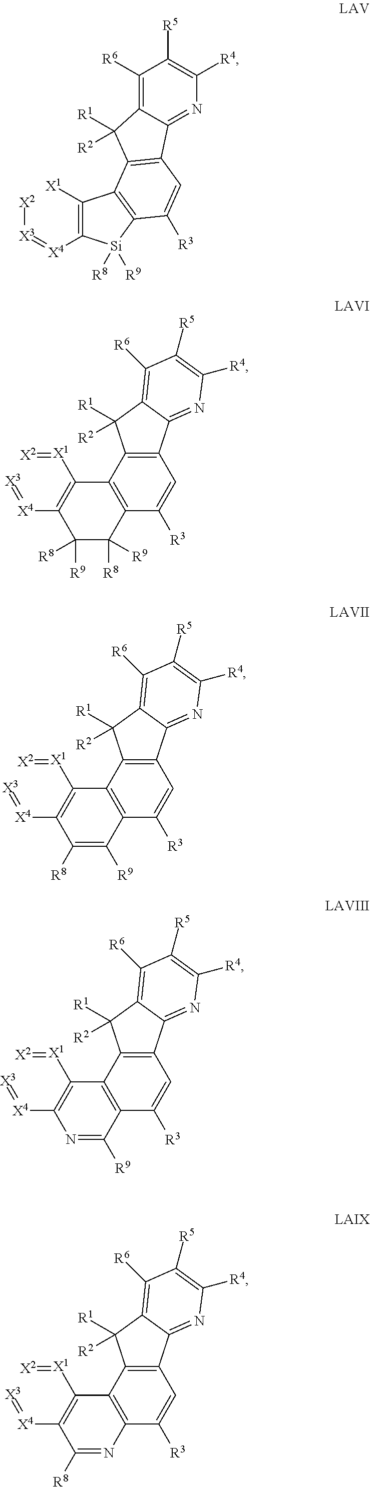 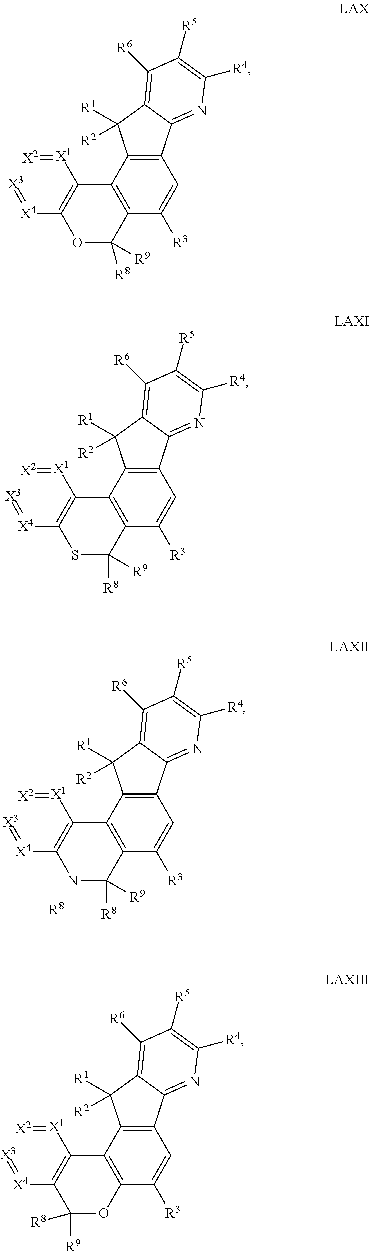 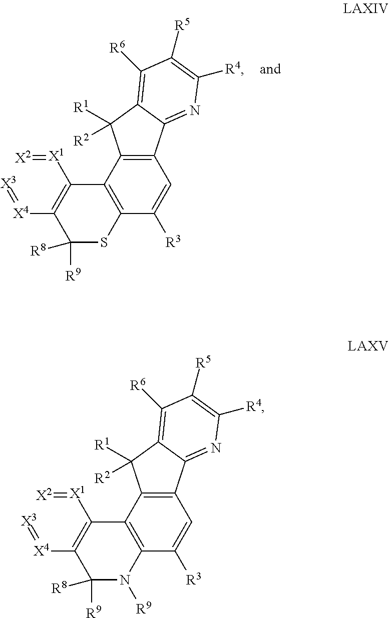
wherein R⁸ and R⁹ are each the same or different.

3. The metal complex according to claim 1, wherein the metal complex has a chemical formula of M(LA)ₚ(LB)_{q}, wherein the LB is a bidentate ligand, the p is 1, 2 or 3, the q is 0, 1 or 2, and p+q is equal to the oxidation state of the metal M, and the LB is selected from one of the following structures: 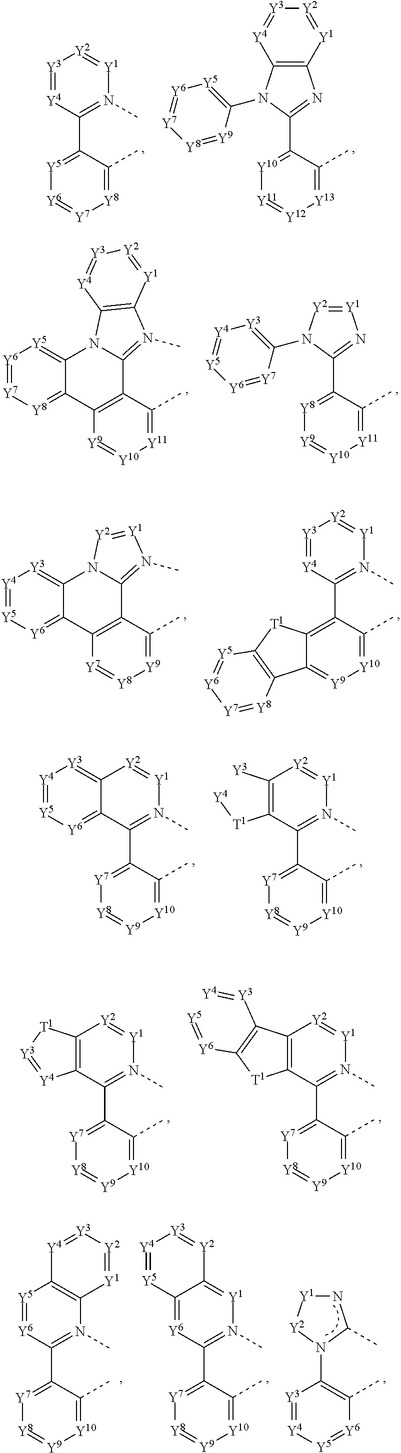 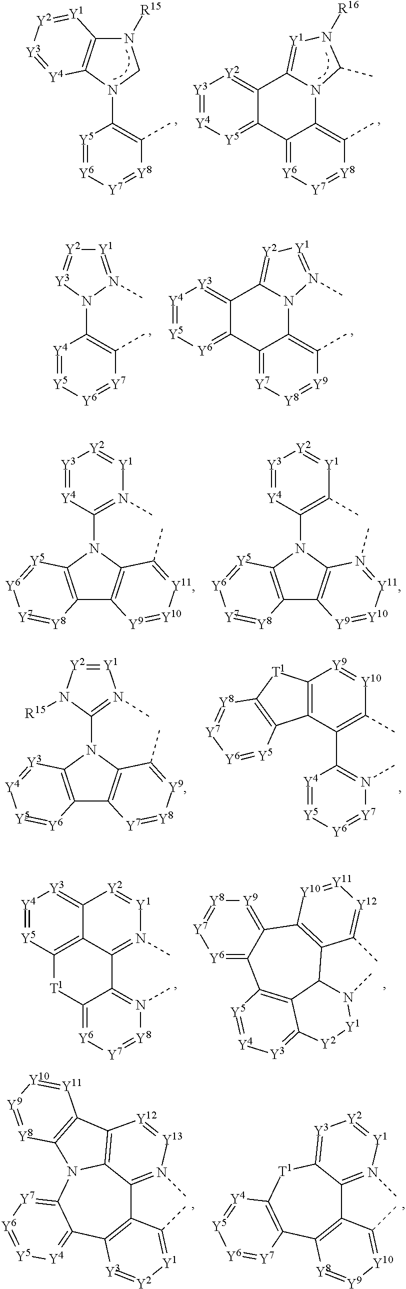 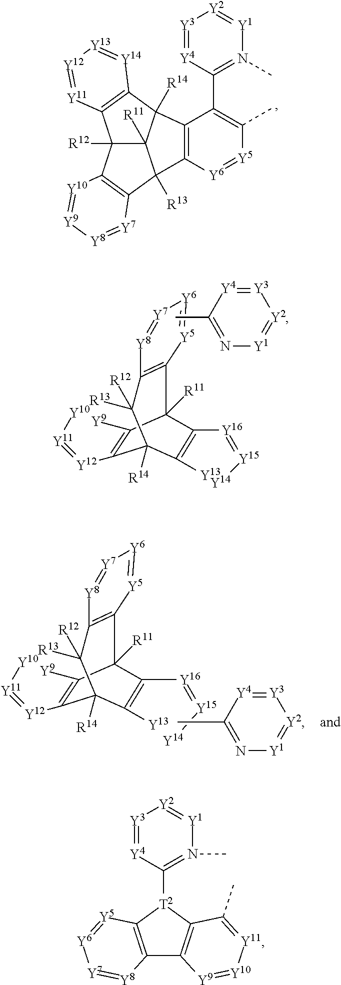
wherein Y¹-Y¹⁶ are each independently selected from N or CR¹⁰, T¹ is selected from one of BR¹², NR¹³, PR¹⁴, O, S, Se, C═O, S═O, SO², CR¹²R¹³, SiR¹²R¹³, and GeR¹²R¹³, and the R¹² and the R¹³ is arbitrarily joined or fused to form a ring: T² is selected from N, B, SiR¹², P or P═O;
the R¹⁰, R¹¹, the R¹², the R¹³, the R¹⁴, R¹⁵, and R¹⁶ are each independently selected from the group consisting of hydrogen, deuterium, a halogen atom, C₁-C₄₀ alkyl, C₃-C₄₀ cycloalkyl, C₁-C₄₀ heteroalkyl, C₃-C₄₀ heterocycloalkyl, C₆-C₆₀ aralkyl, C₁-C₄₀ alkoxy, C₆-C₆₀ aryloxy, amino, C₃-C₄₀ silyl, C₂-C₄₀ alkenyl, C₅-C₄₀ cycloalkenyl, C₃-C₄₀ heteroalkenyl, C₂-C₄₀ alkynyl, C₆-C₆₀ aryl, C₂-C₆₀ heteroaryl, C₁-C₄₀ acyl, a carboxylic acid group, ether, an ester group, a nitrile group, an isonitrile group, thio, sulfinyl, sulfonyl, and phosphino; and any two or more adjacent substituents are optionally joined or fused together to form a substituted or unsubstituted five-membered, six-membered or multiple-membered ring.

4. The metal complex according to claim 1, wherein the R¹, the R², the R³, the R⁴, the R⁵, the R⁶, the R⁷, the R⁸, the R⁹, the R¹⁰, the R¹¹, the R¹², the R¹³, the R¹⁴, the R¹⁵, and the R¹⁶, at each occurrence, are each independently selected from the group consisting of a hydrogen atom, a deuterium atom, a fluorine atom, a nitrile group, R^{A1}-R^{A55}, R^{B1}-R^{B45}, and R^{C1}-R^{C295};
wherein the R^{A1}-R^{A55} have structural formulas as follows: 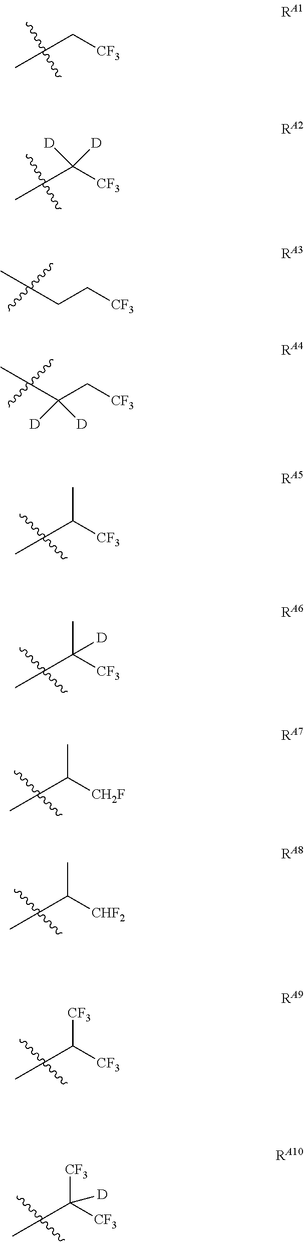 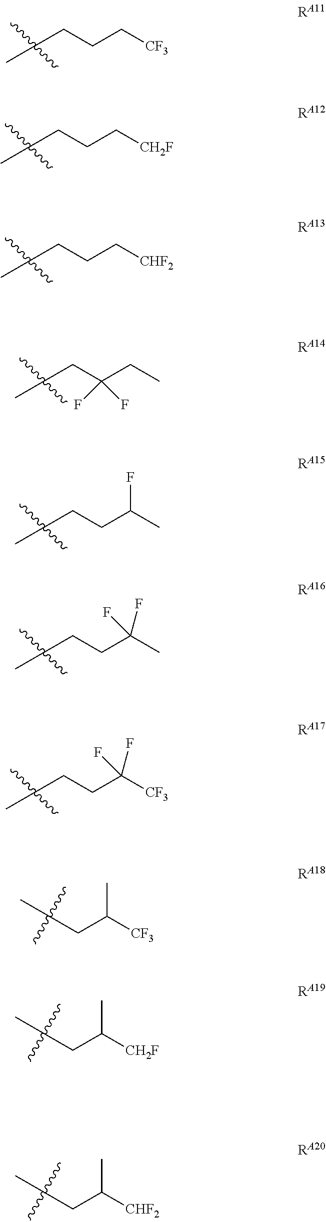 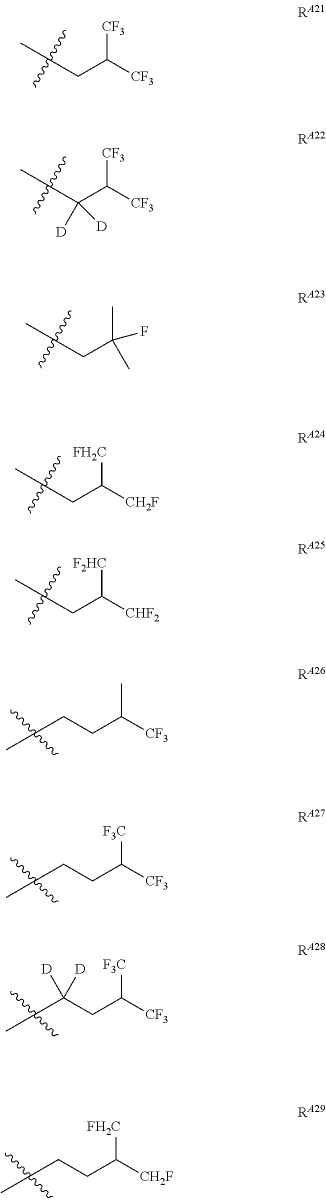 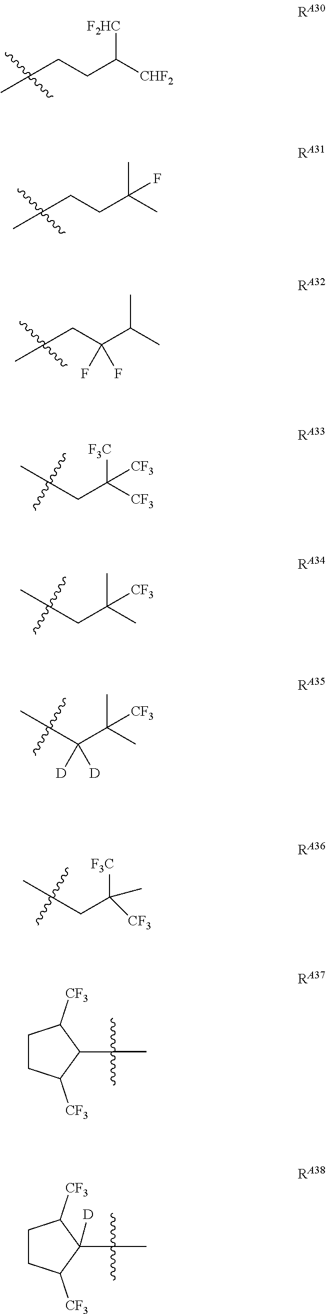 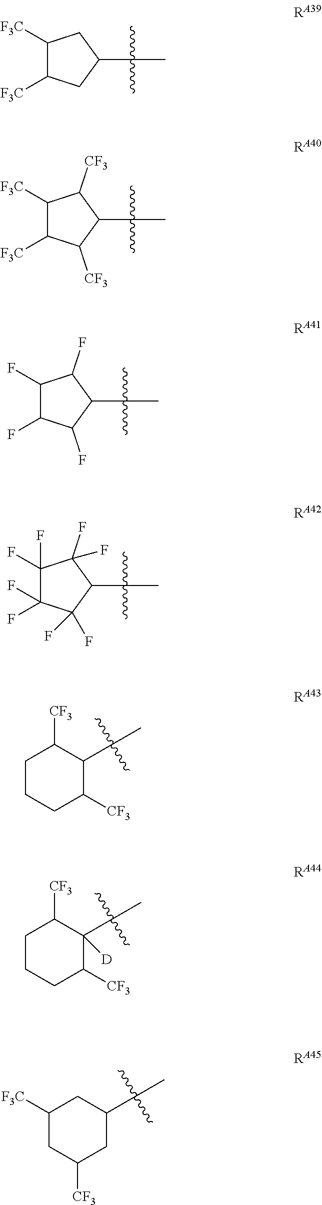 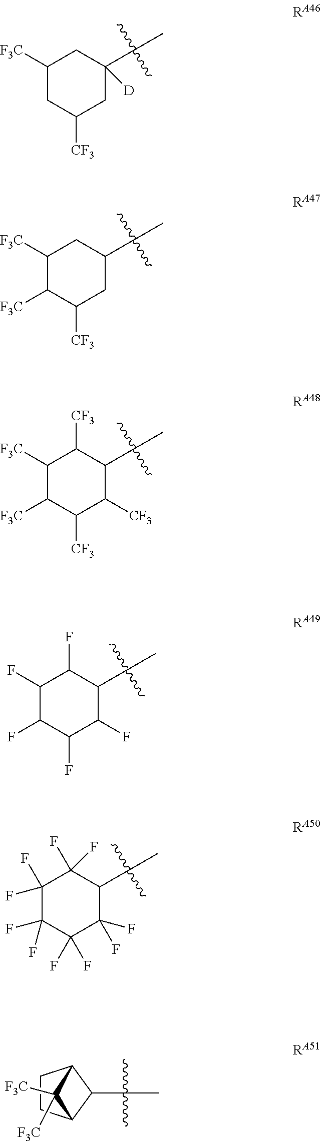 [SMILES: *C1([2H])CC(C(F)(F)F)CC(C(F)(F)F)C1 ; *C1CC(C(F)(F)F)C(C(F)(F)F)C(C(F)(F)F)C1 ; *C1C(C(F)(F)F)C(C(F)(F)F)C(C(F)(F)F)C(C(F)(F)F)C1C(F)(F)F ; *C1C(F)C(F)C(F)C(F)C1F ; *C1C(F)(F)C(F)(F)C(F)(F)C(F)(F)C1(F)F ; *C1[C@H]2CC[C@@H]1C2(C(F)(F)F)C(F)(F)F] 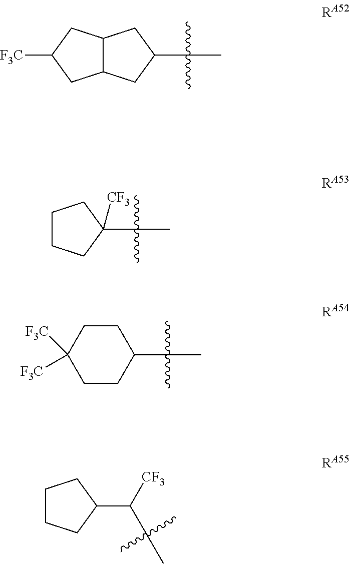 [SMILES: *C1CC2CC(C(F)(F)F)CC2C1 ; *C1(C(F)(F)F)CCCC1 ; *C1CCC(C(F)(F)F)(C(F)(F)F)CC1 ; *C(C1CCCC1)C(F)(F)F]
the R^{B1}-R^{B45} have structural formulas as follows: 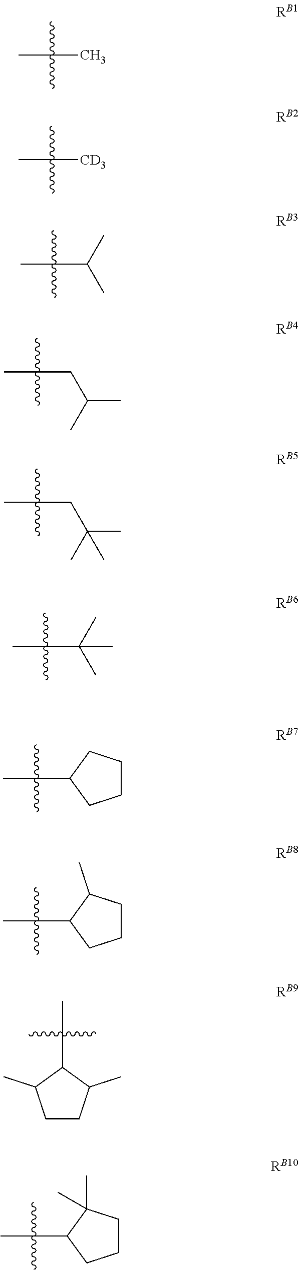 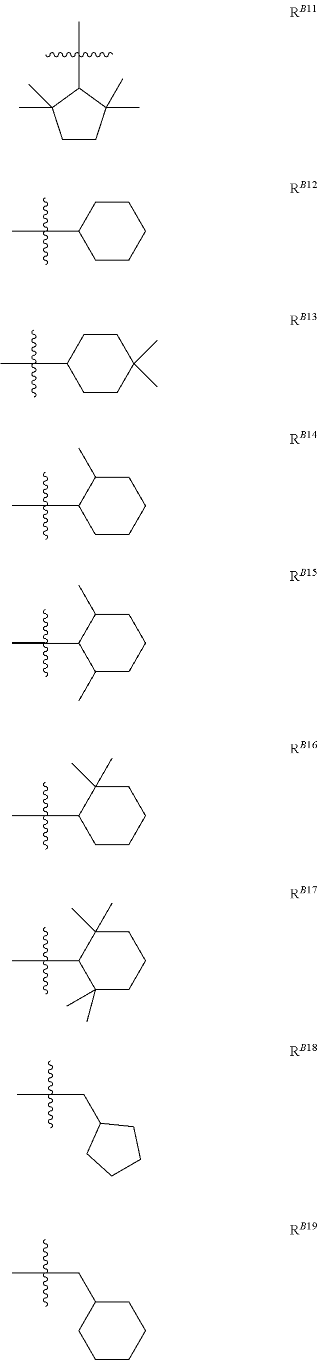 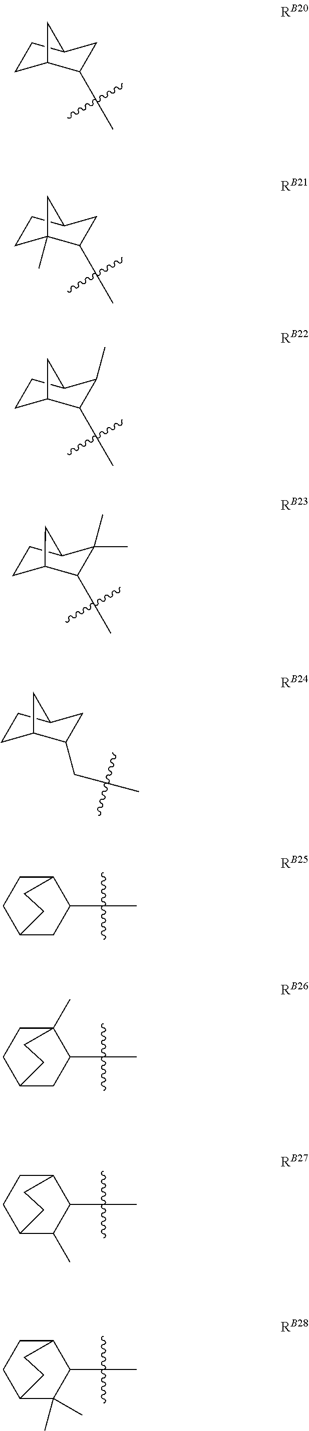 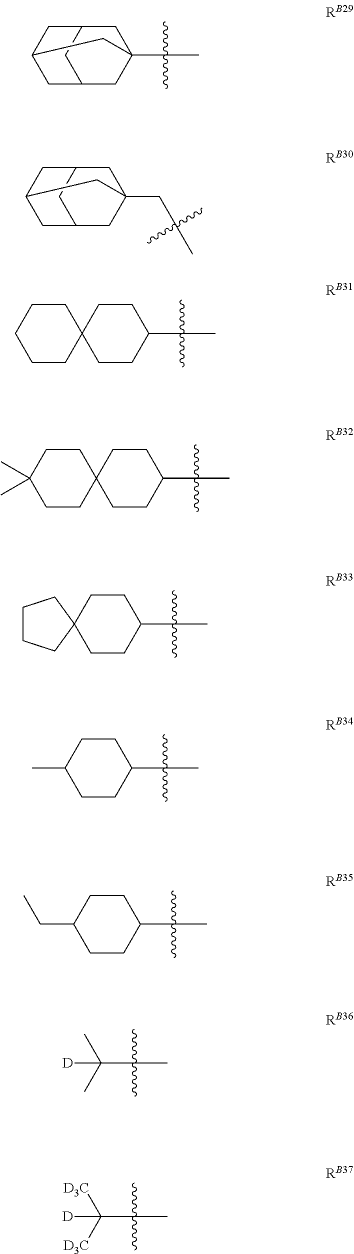 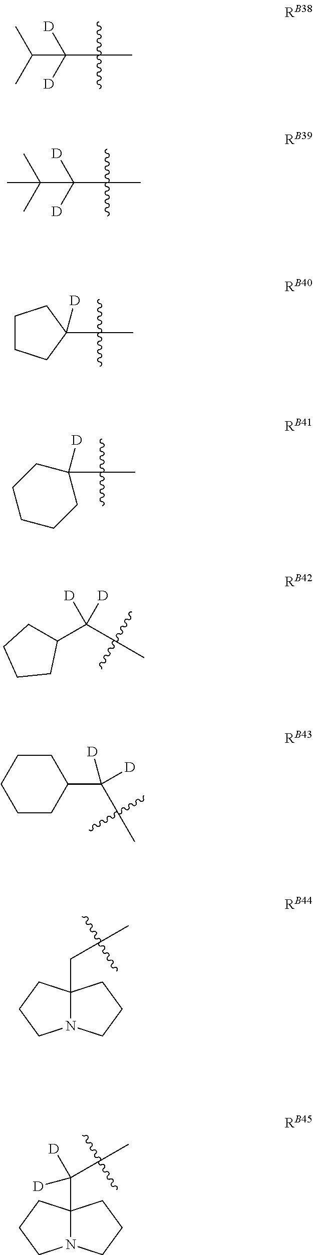
the R^{C1}-R^{C295} have structural formulas as follows:

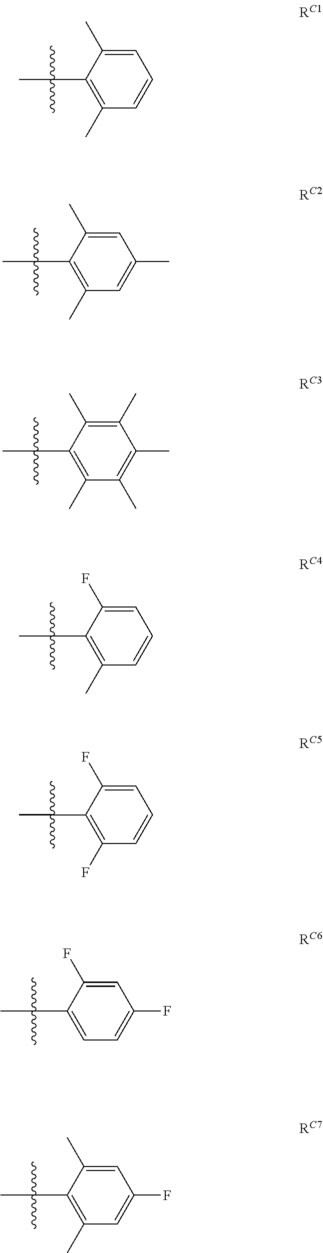

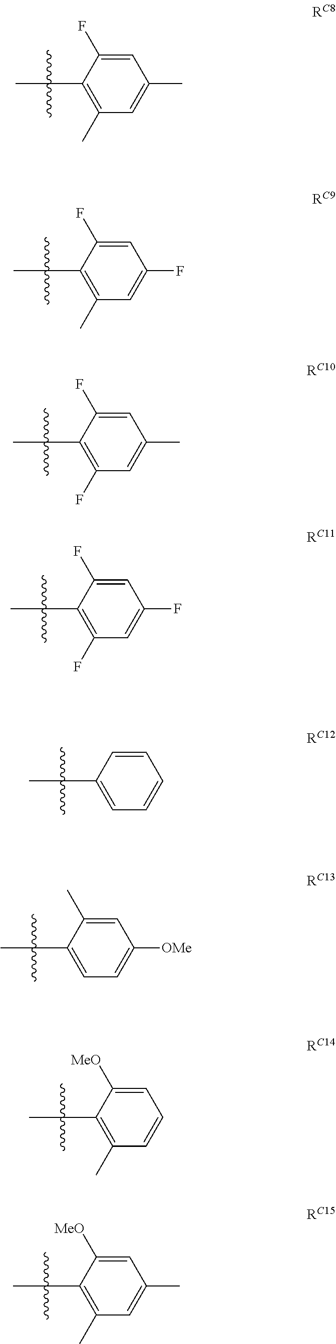

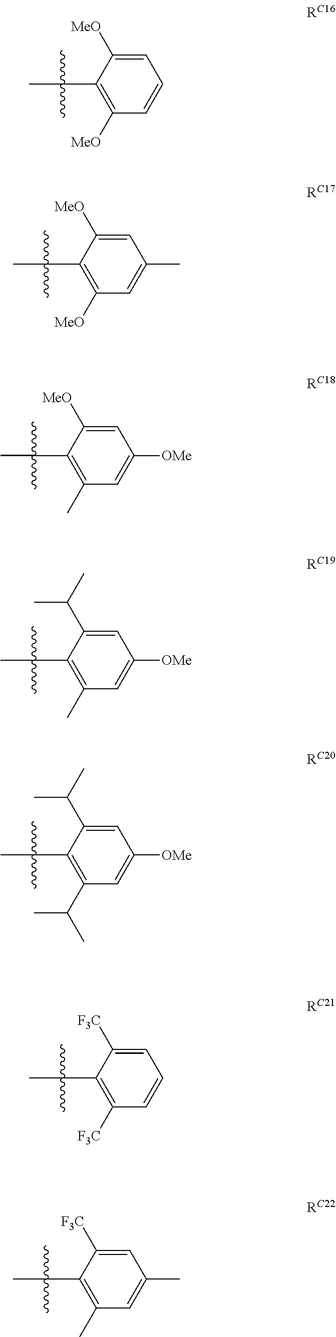

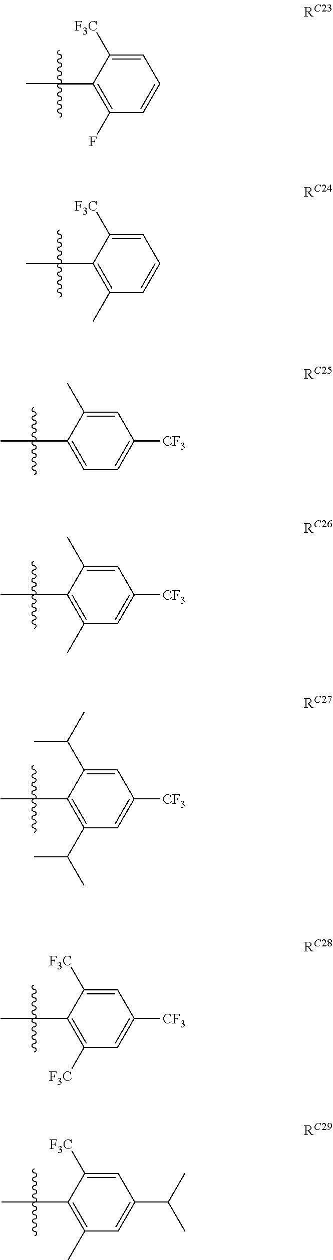

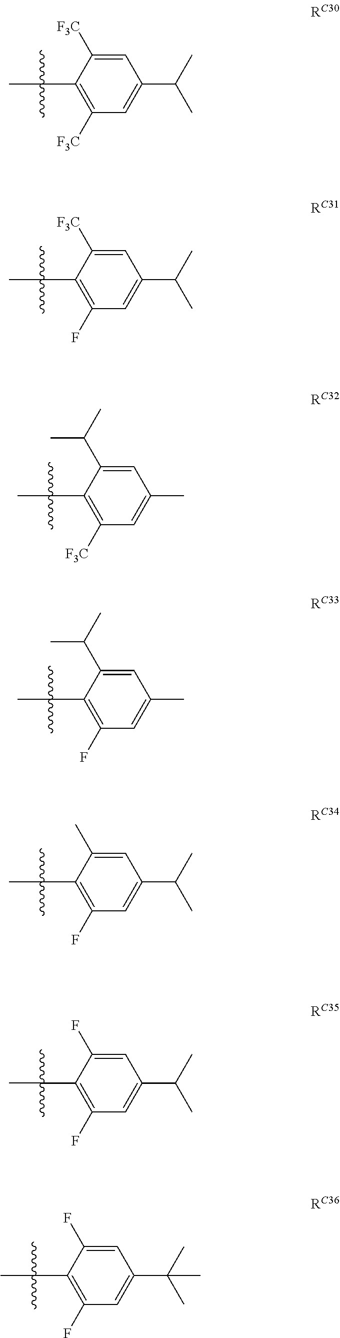

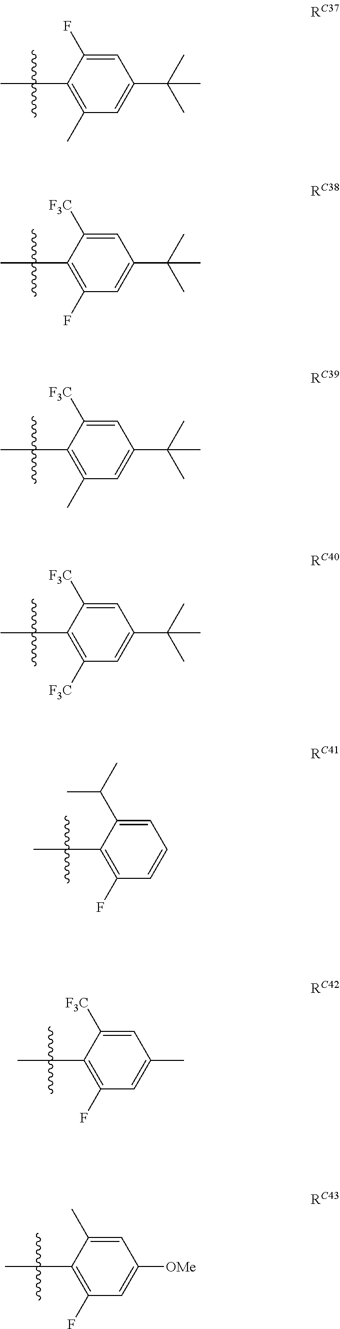

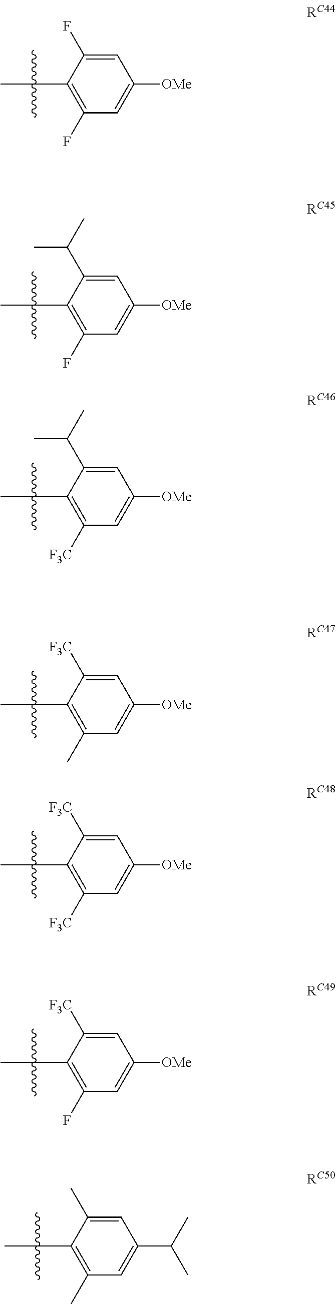

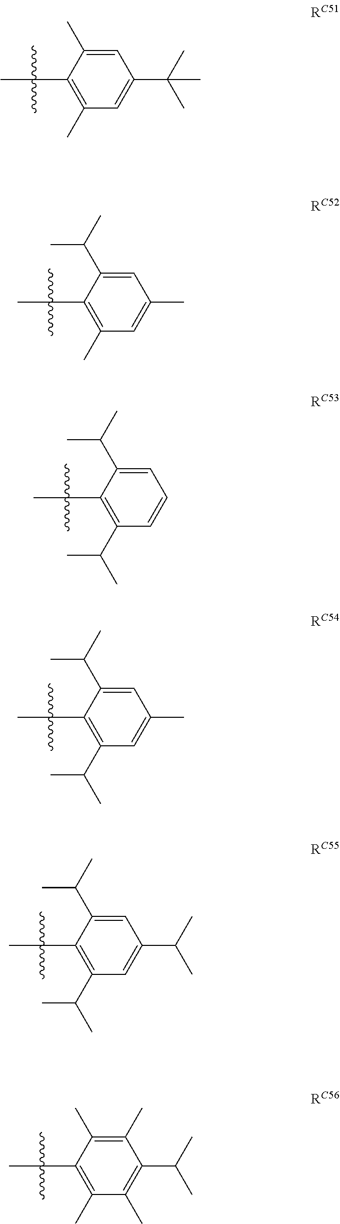 [SMILES: *c1c(C)cc(C(C)(C)C)cc1C ; *c1c(C)cc(C)cc1C(C)C ; *c1c(C(C)C)cccc1C(C)C ; *c1c(C(C)C)cc(C)cc1C(C)C ; *c1c(C(C)C)cc(C(C)C)cc1C(C)C ; *c1c(C)c(C)c(C(C)C)c(C)c1C]

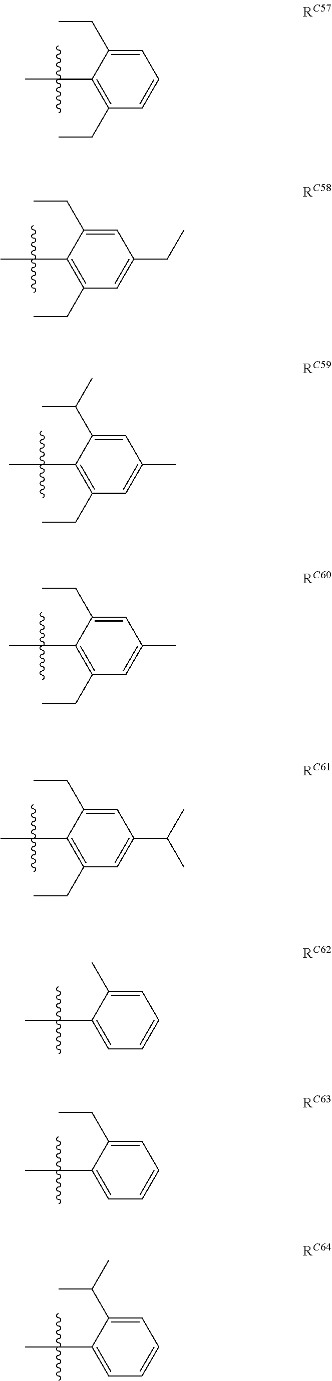

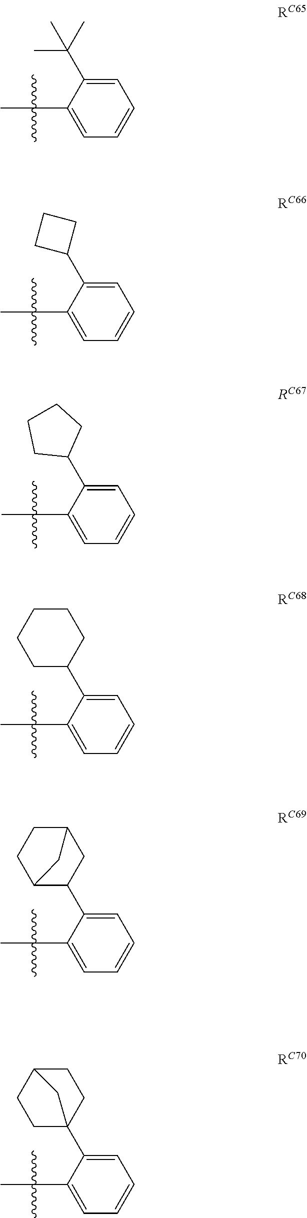 [SMILES: *c1ccccc1C(C)(C)C ; *c1ccccc1C1CCC1 ; *c1ccccc1C1CCCC1 ; *c1ccccc1C1CCCCC1 ; *c1ccccc1C1CC2CCC1C2 ; *c1ccccc1C12CCC(CC1)C2]

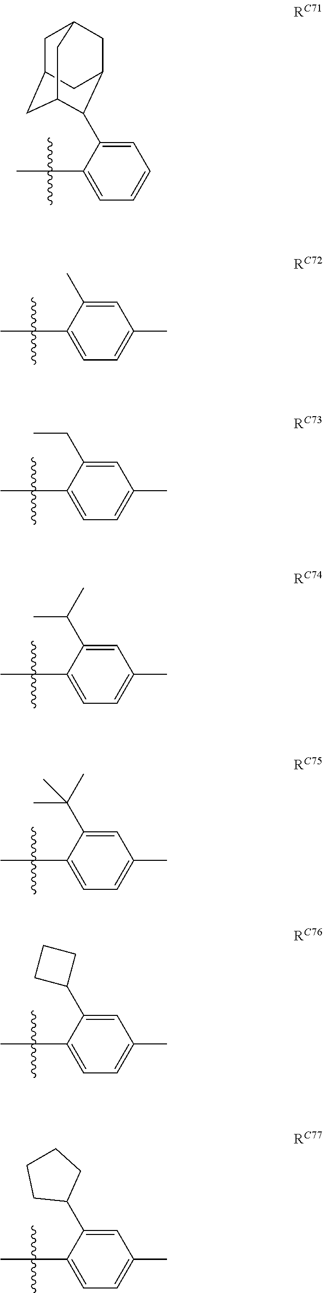

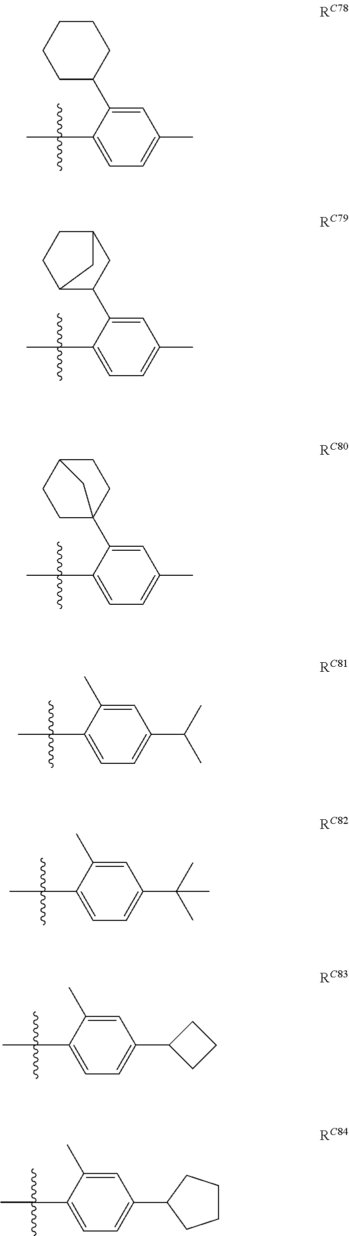

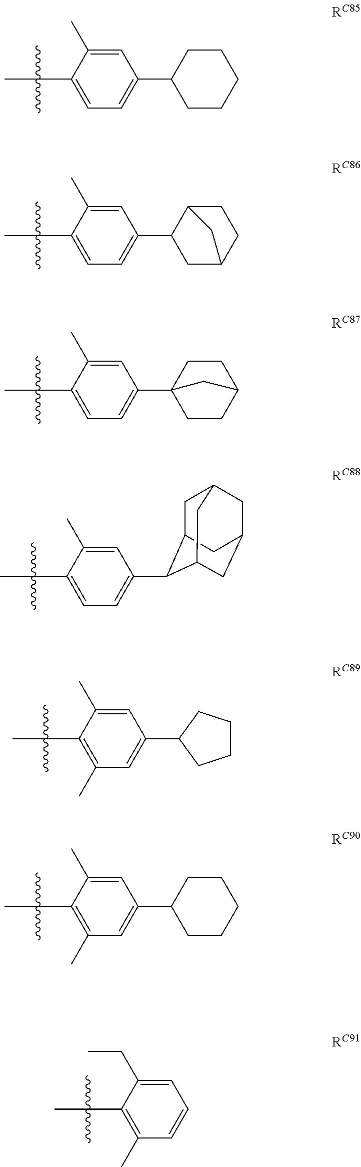

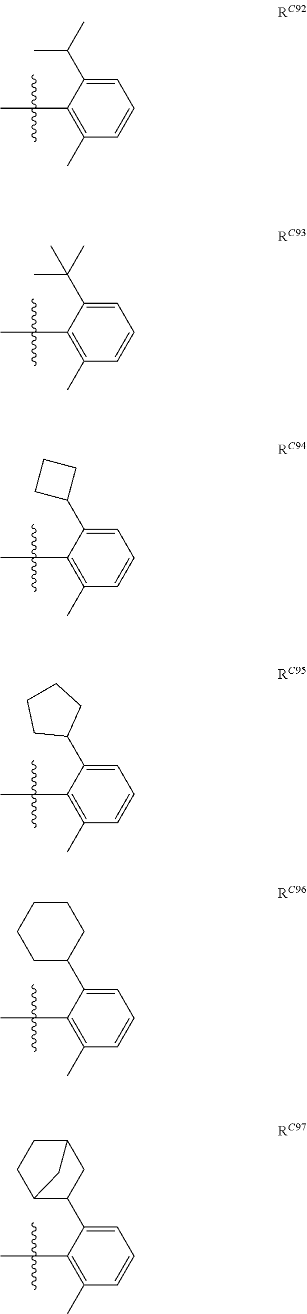 [SMILES: *c1c(C)cccc1C(C)C ; *c1c(C)cccc1C(C)(C)C ; *c1c(C)cccc1C1CCC1 ; *c1c(C)cccc1C1CCCC1 ; *c1c(C)cccc1C1CCCCC1 ; *c1c(C)cccc1C1CC2CCC1C2]

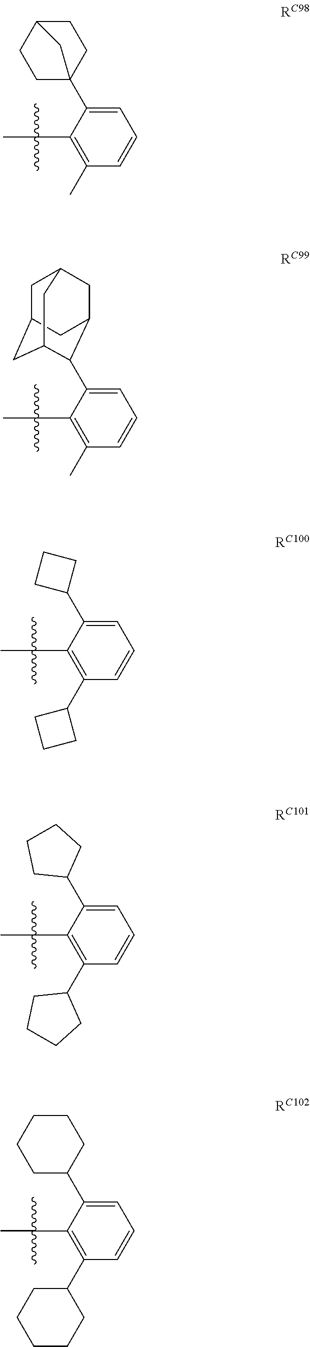 [SMILES: *c1c(C)cccc1C12CCC(CC1)C2 ; *c1c(C)cccc1C1C2CC3CC(C2)CC1C3 ; *c1c(C2CCC2)cccc1C1CCC1 ; *c1c(C2CCCC2)cccc1C1CCCC1 ; *c1c(C2CCCCC2)cccc1C1CCCCC1]

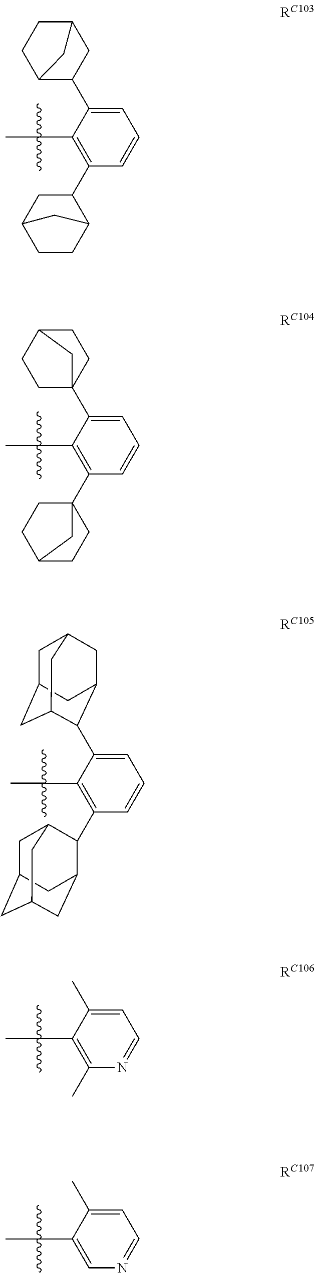

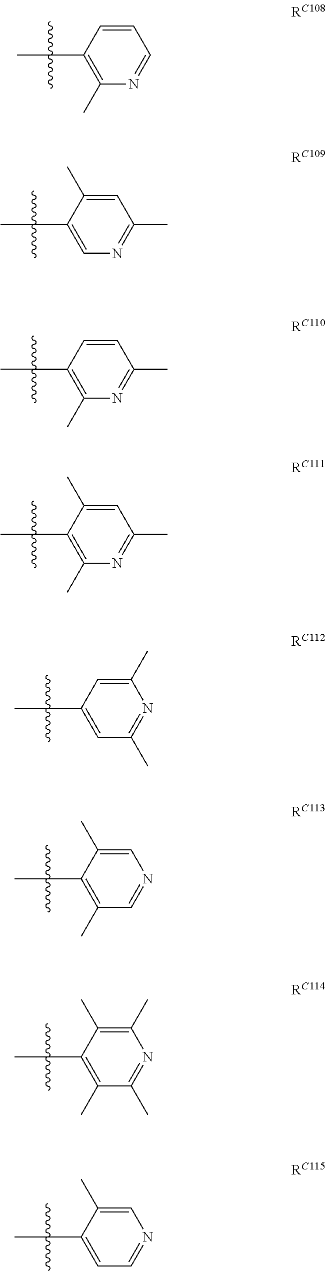

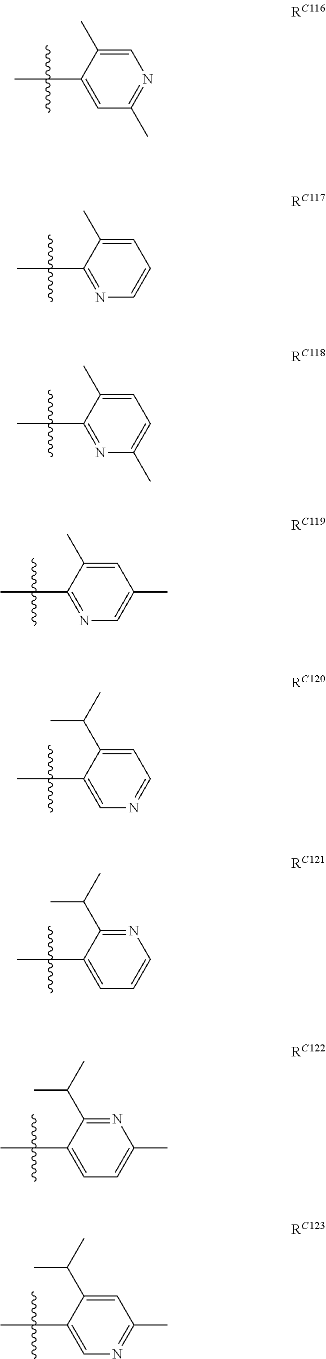

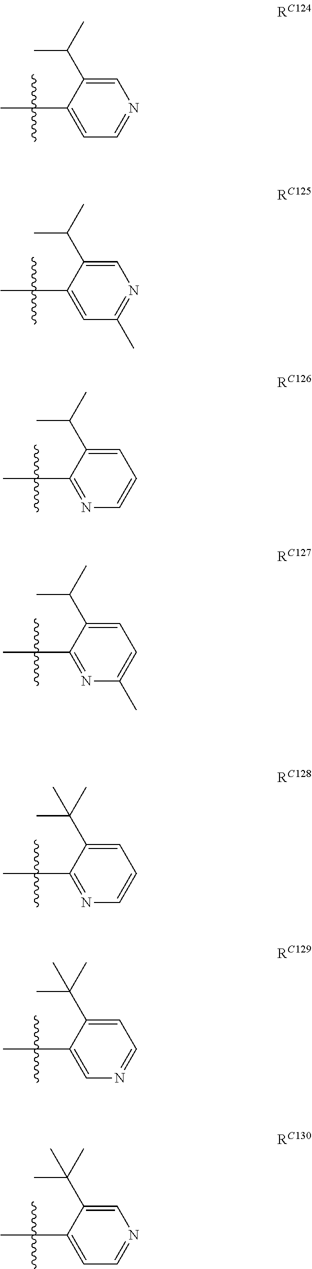

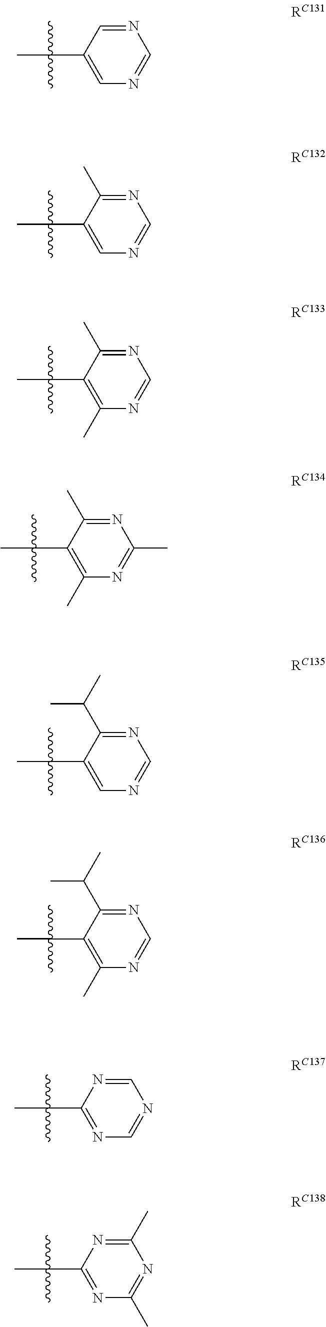

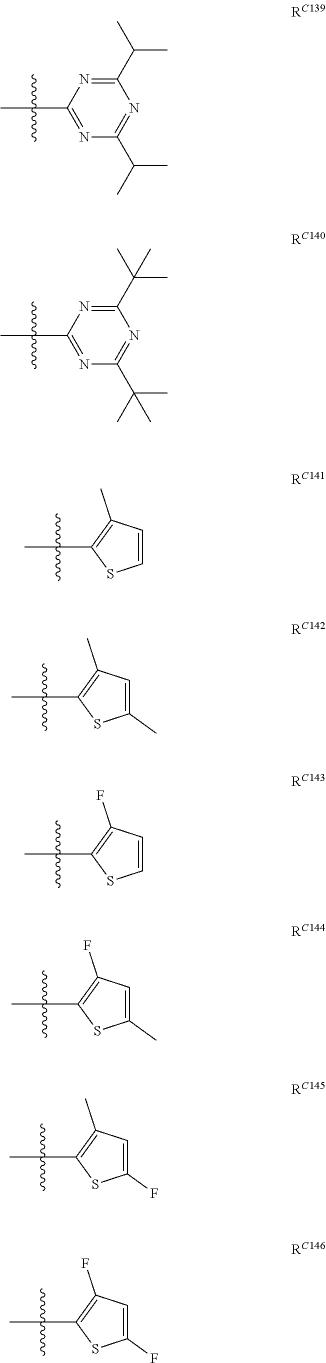

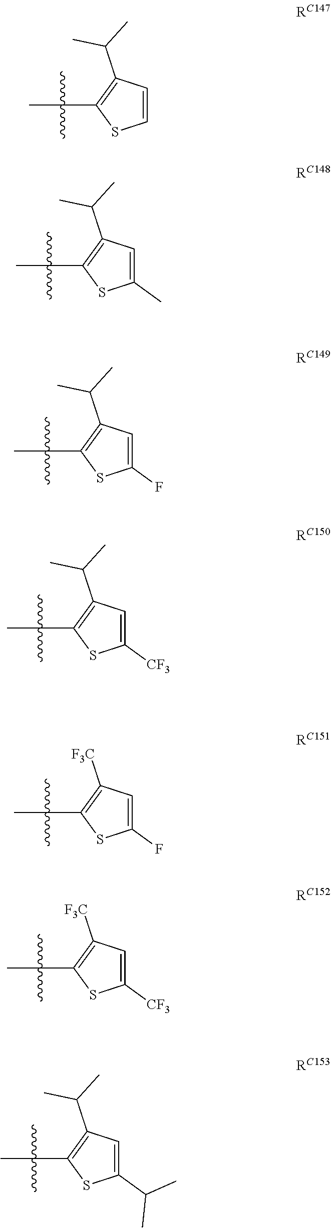

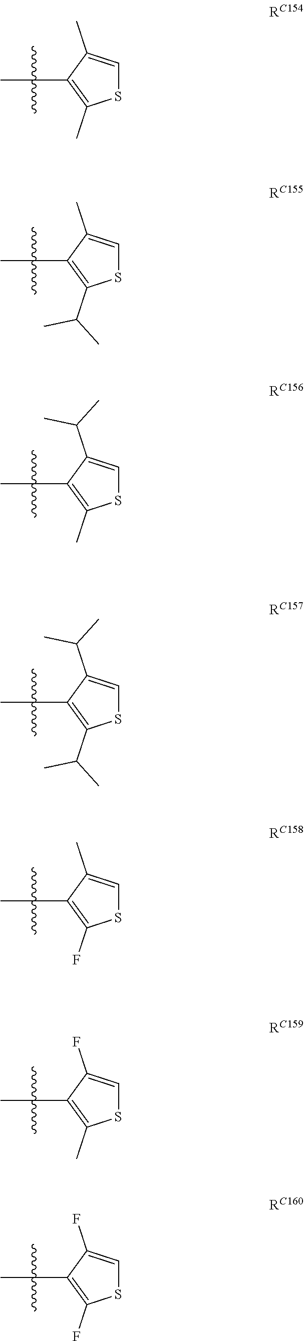

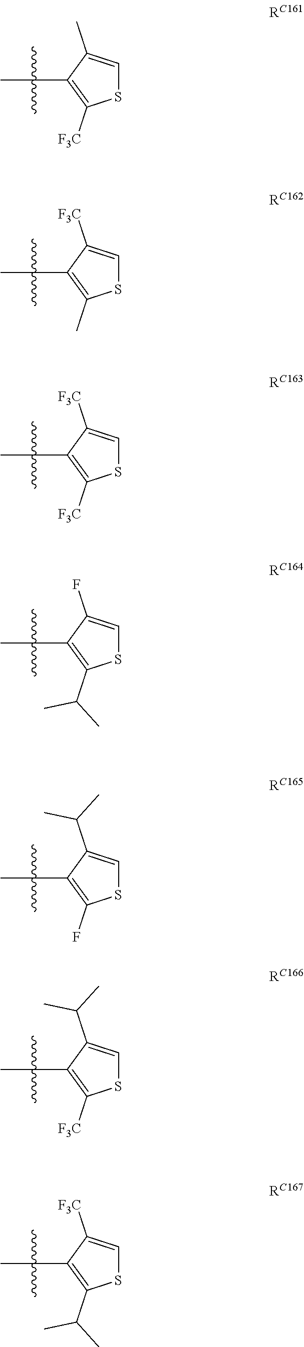

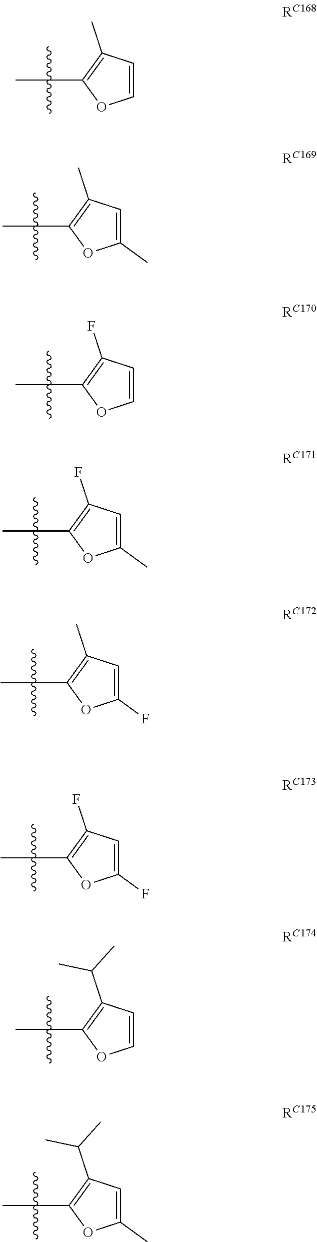

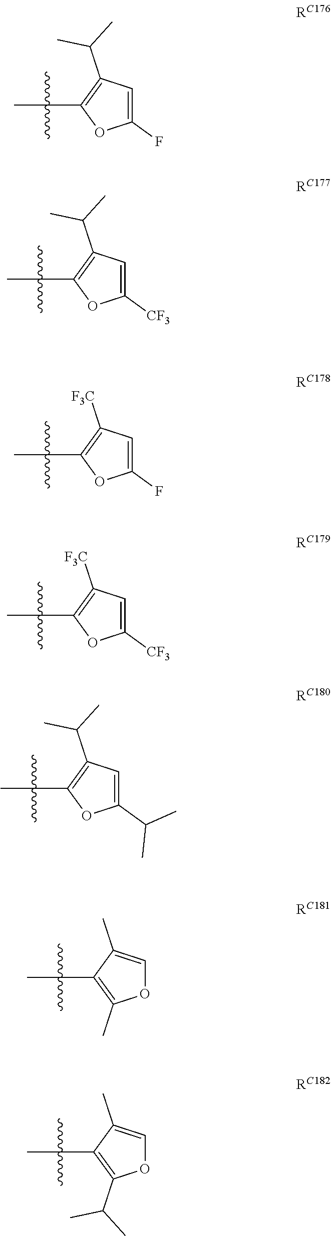

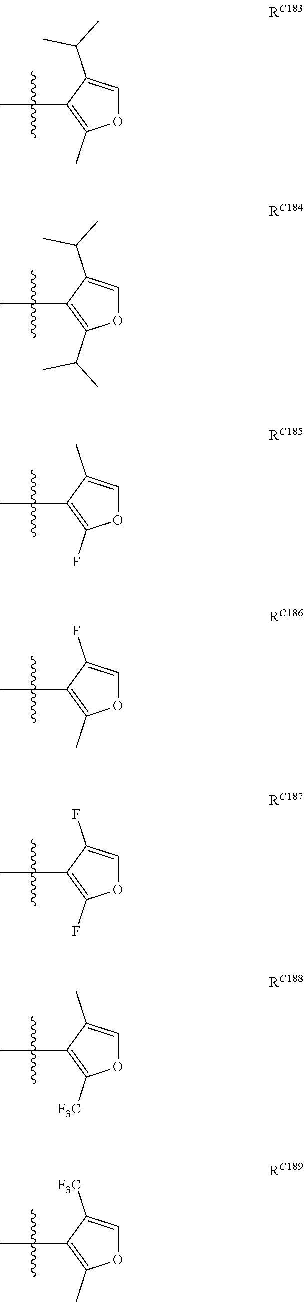

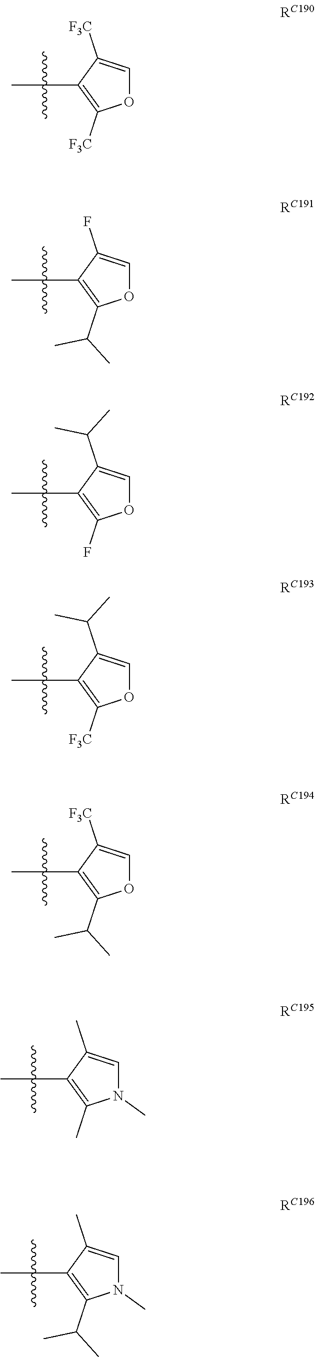

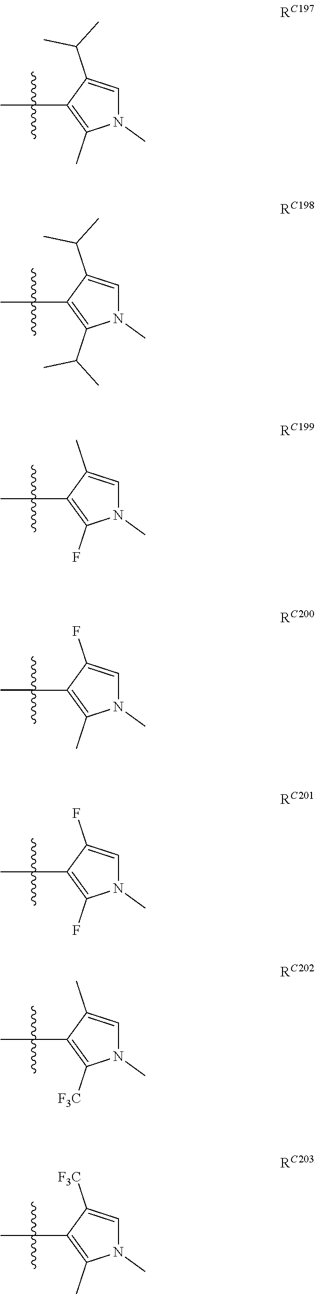

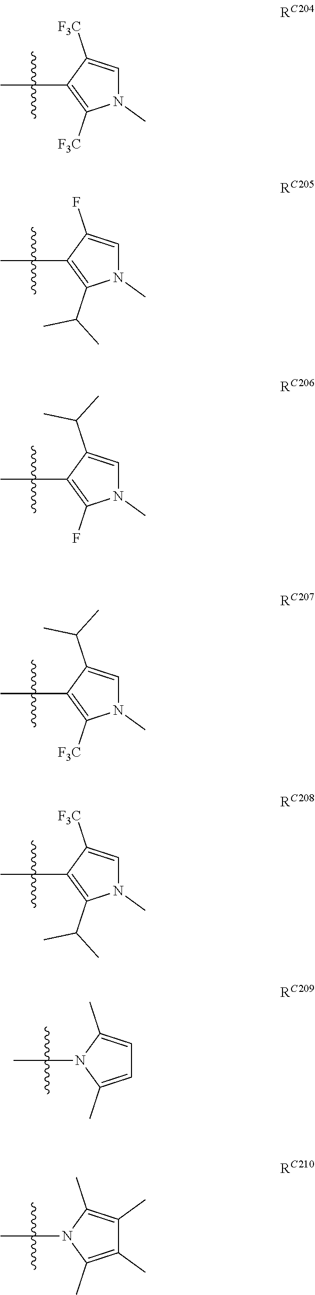

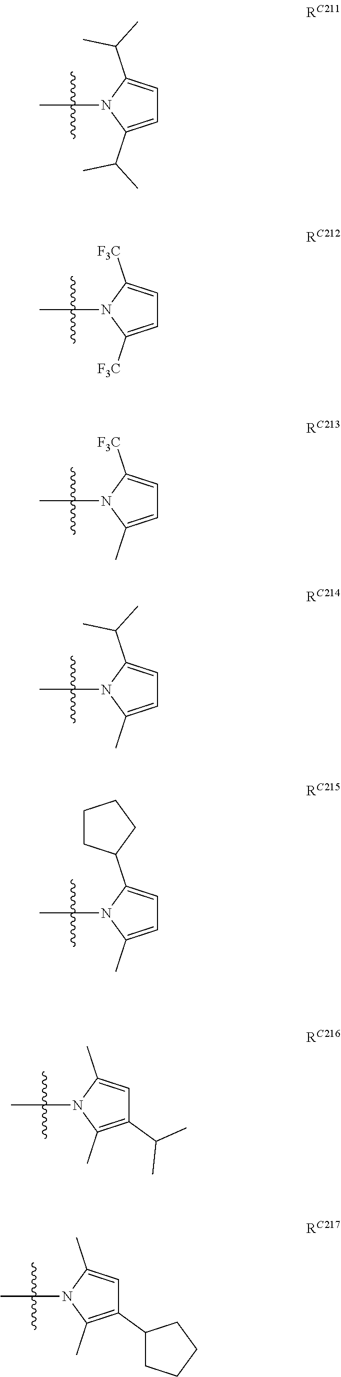

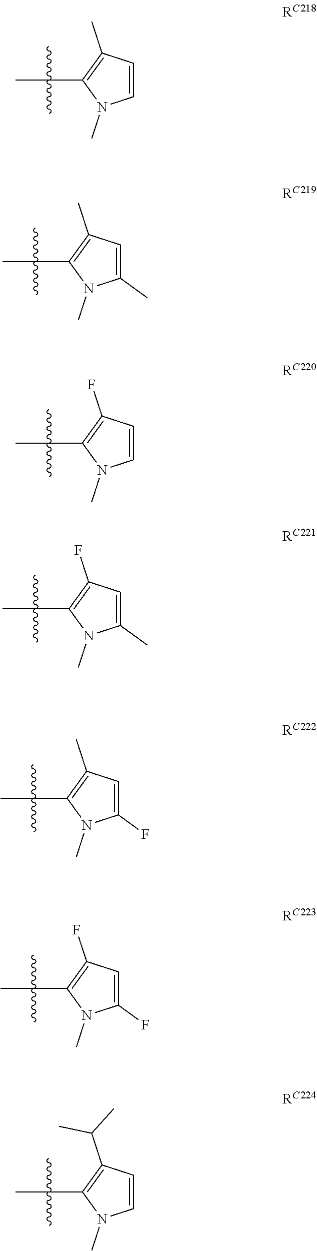

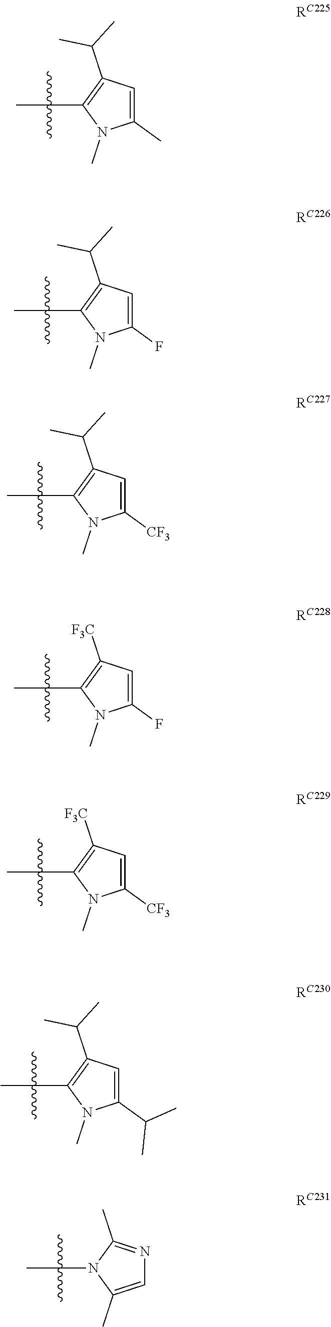

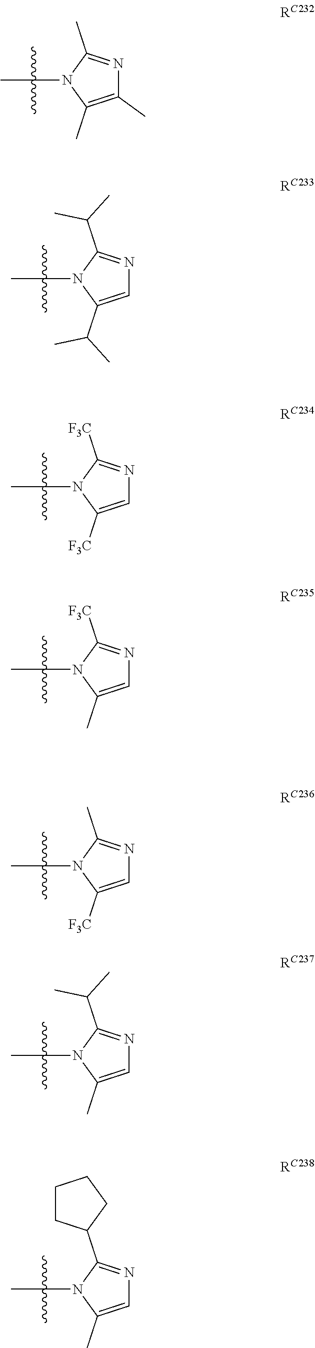

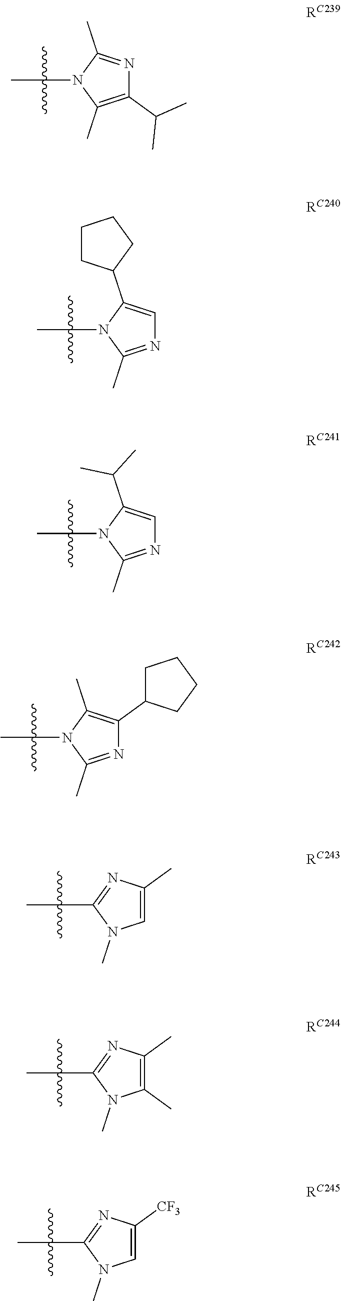

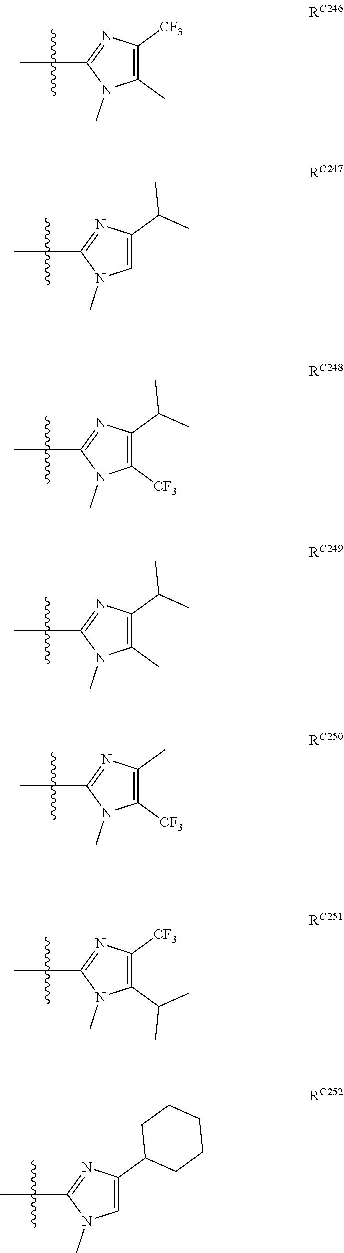

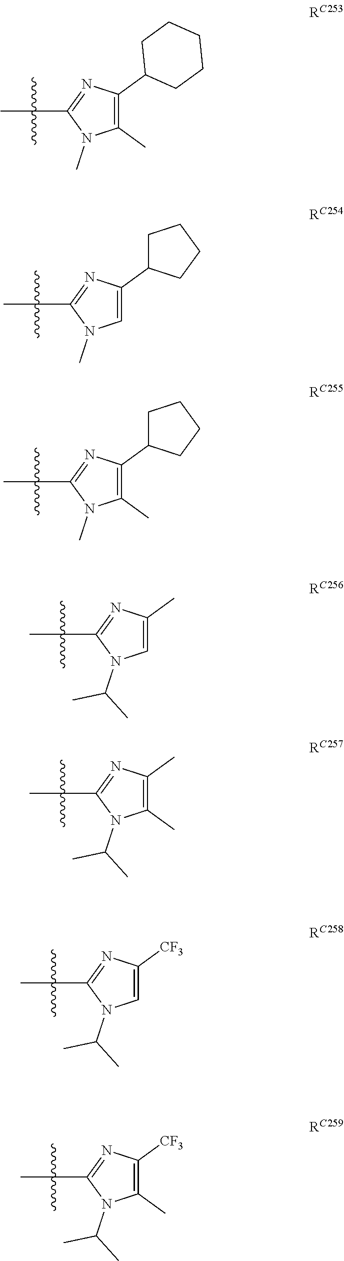

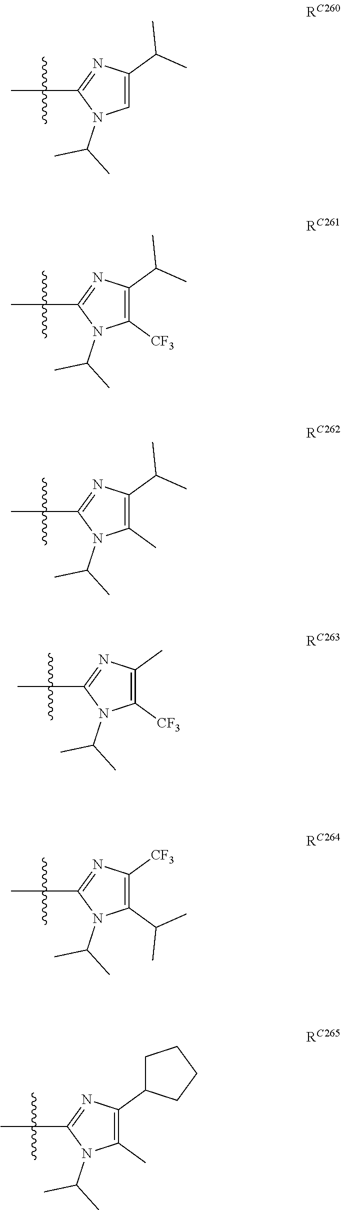 [SMILES: *c1nc(C(C)C)cn1C(C)C ; *c1nc(C(C)C)c(C(F)(F)F)n1C(C)C ; *c1nc(C(C)C)c(C)n1C(C)C ; *c1nc(C)c(C(F)(F)F)n1C(C)C ; *c1nc(C(F)(F)F)c(C(C)C)n1C(C)C ; *c1nc(C2CCCC2)c(C)n1C(C)C]

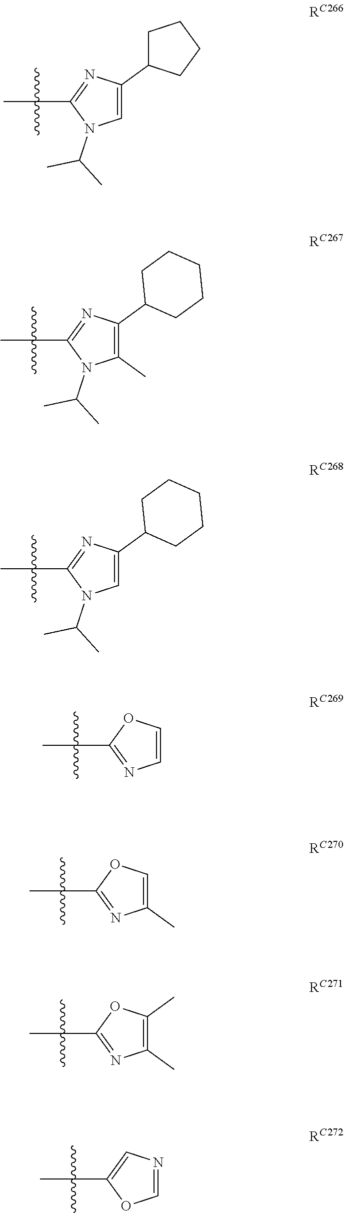

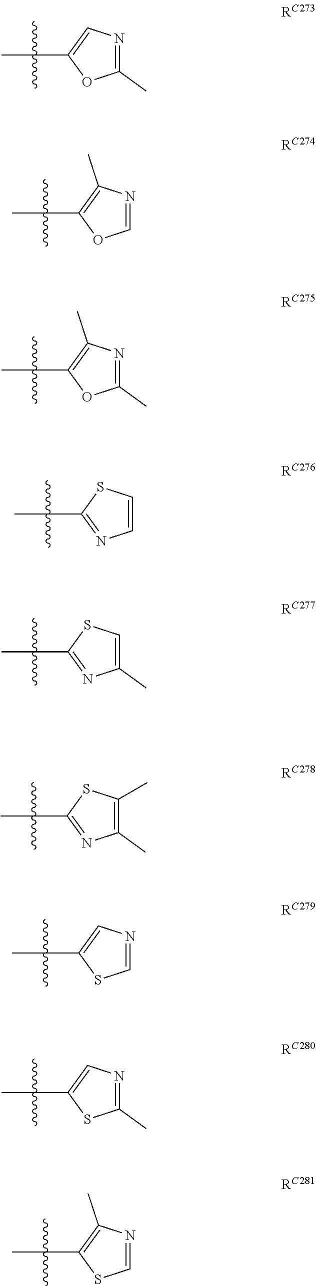

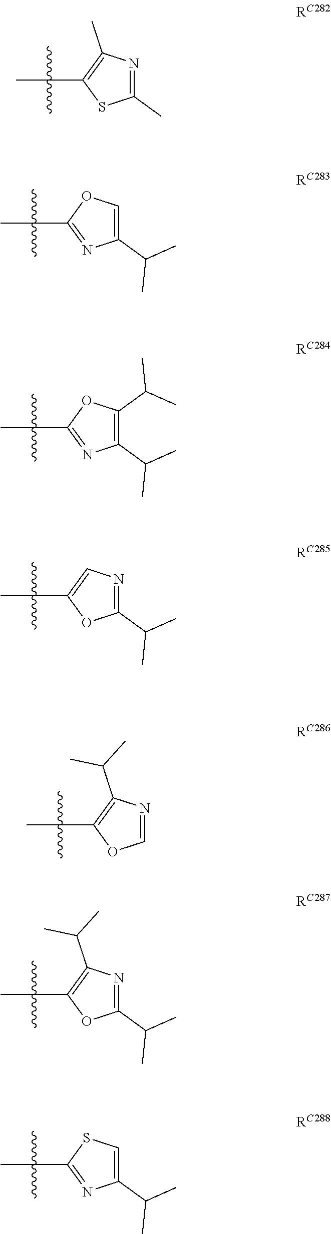

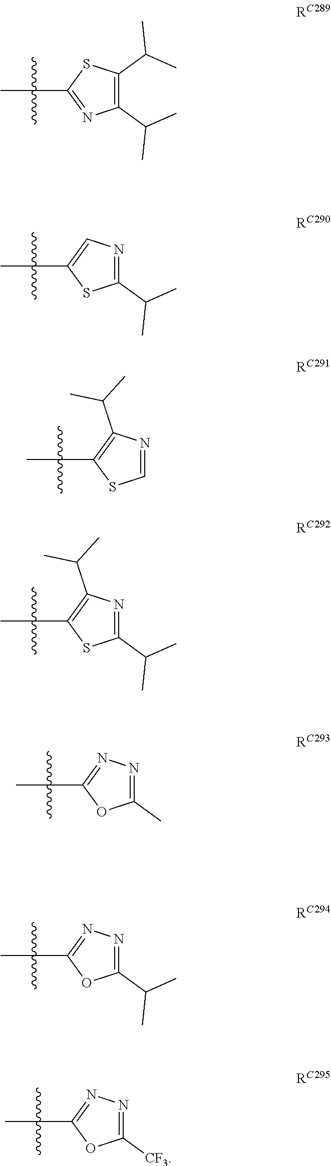

5. The metal complex according to claim 1, wherein the metal complex has a chemical formula of Ir(LA)(LB)₂, Ir(LA)₂(LB) or Ir(LA)₃, wherein the LB is selected from the group consisting of LB1-LB432, and the LB1-LB432 have specific structures as follows:

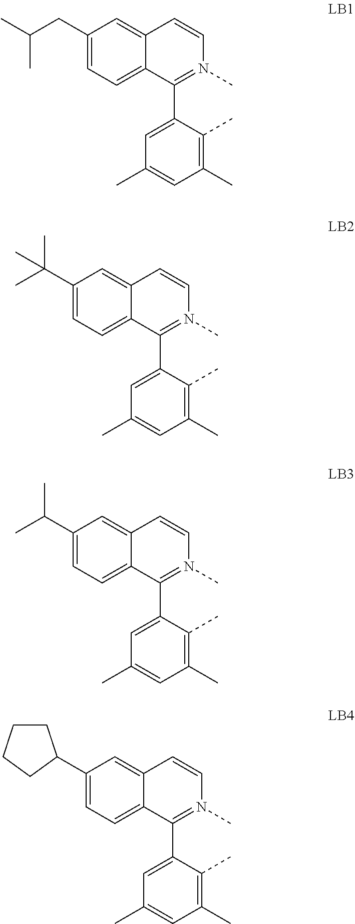

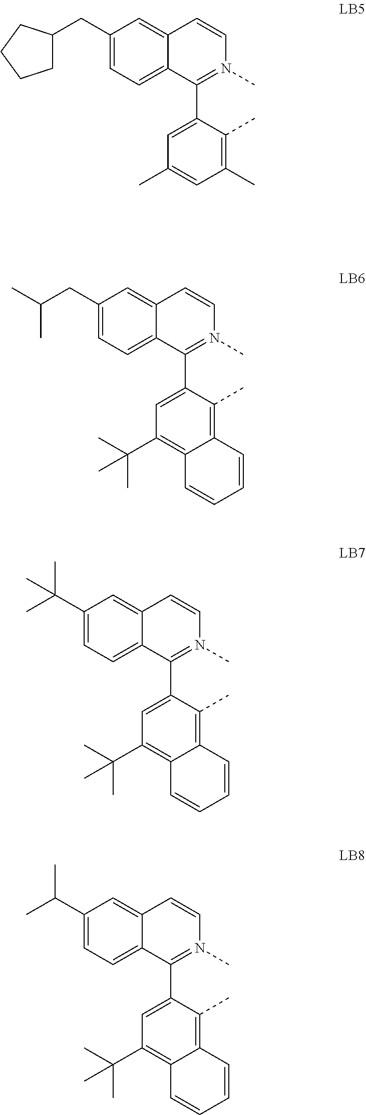

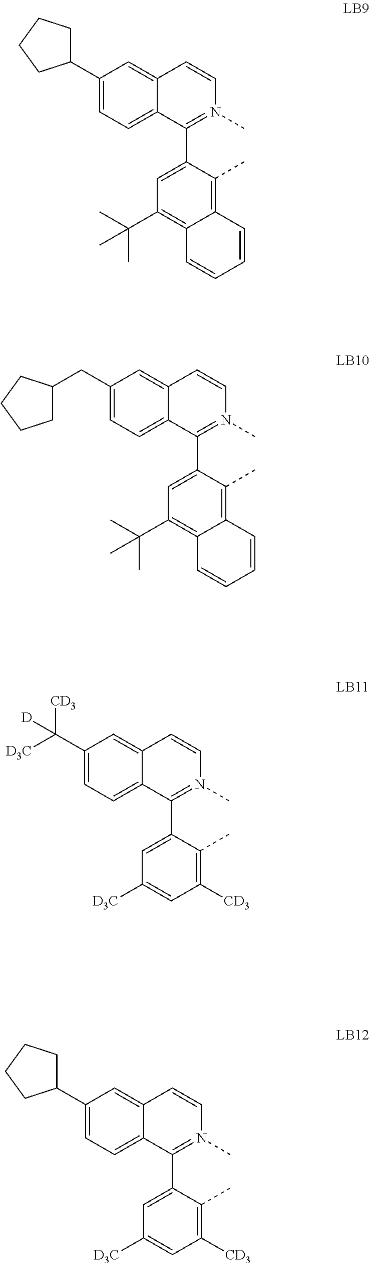

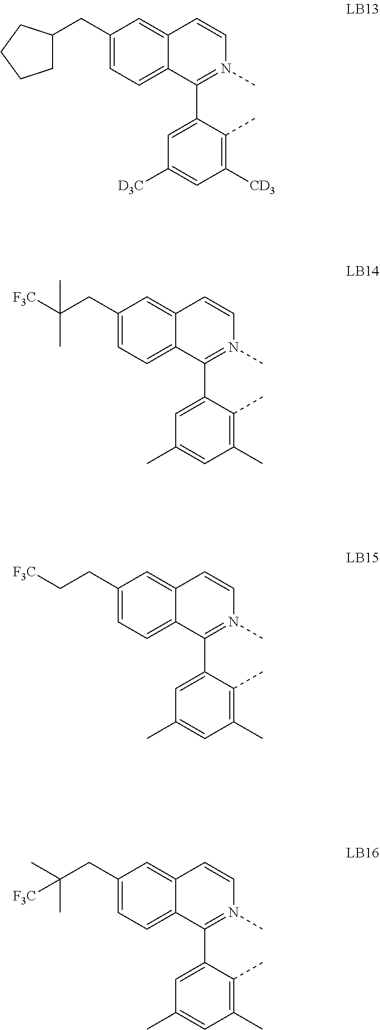

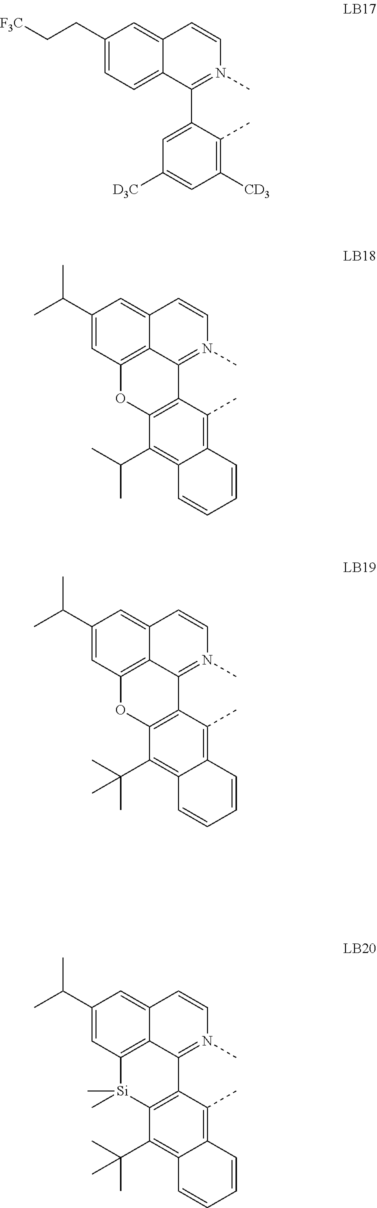

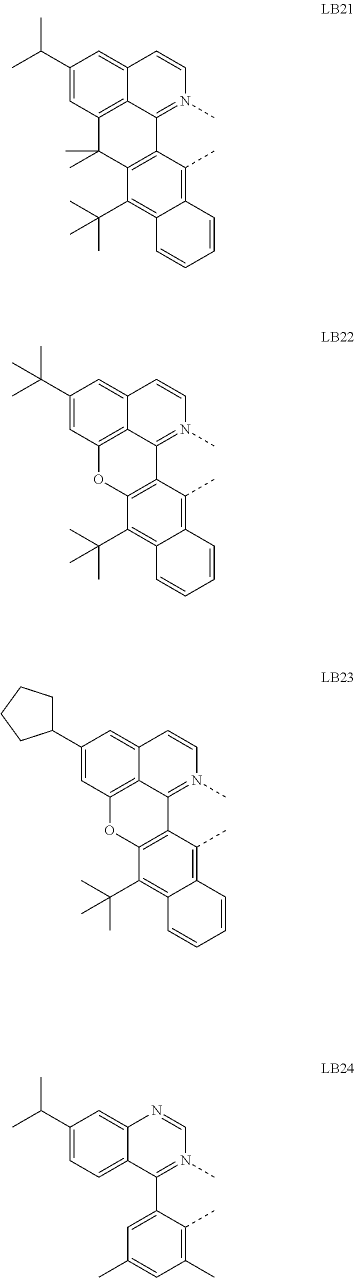

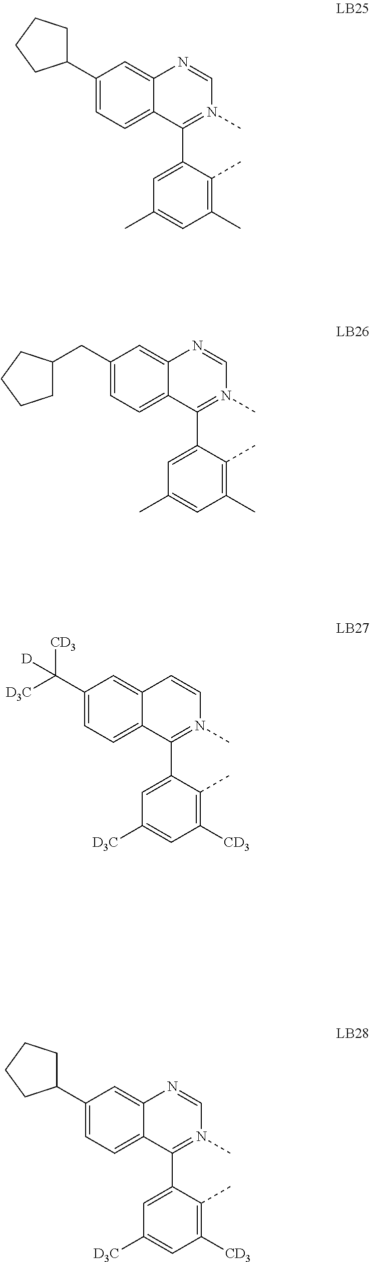

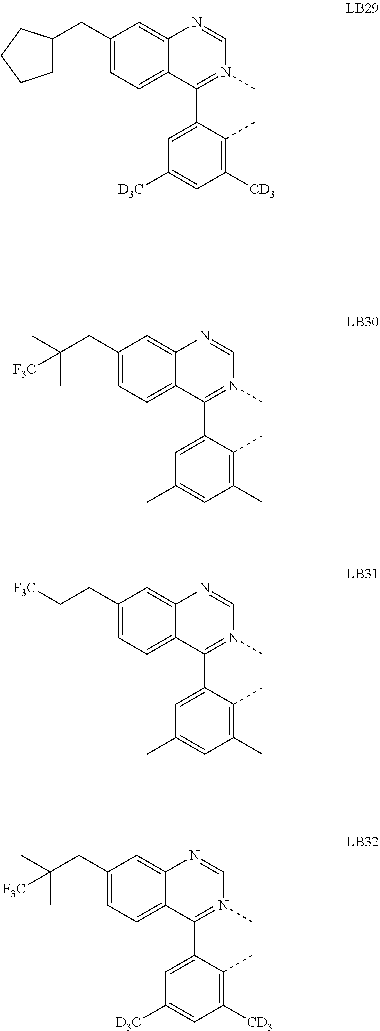

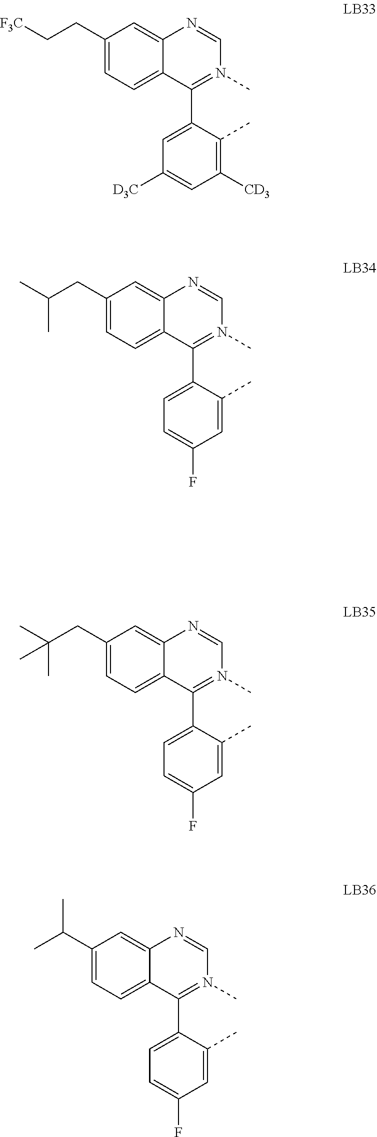

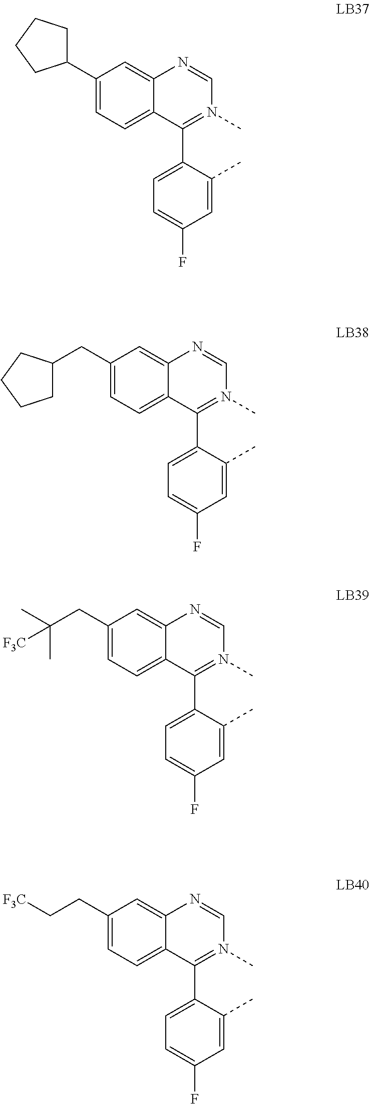

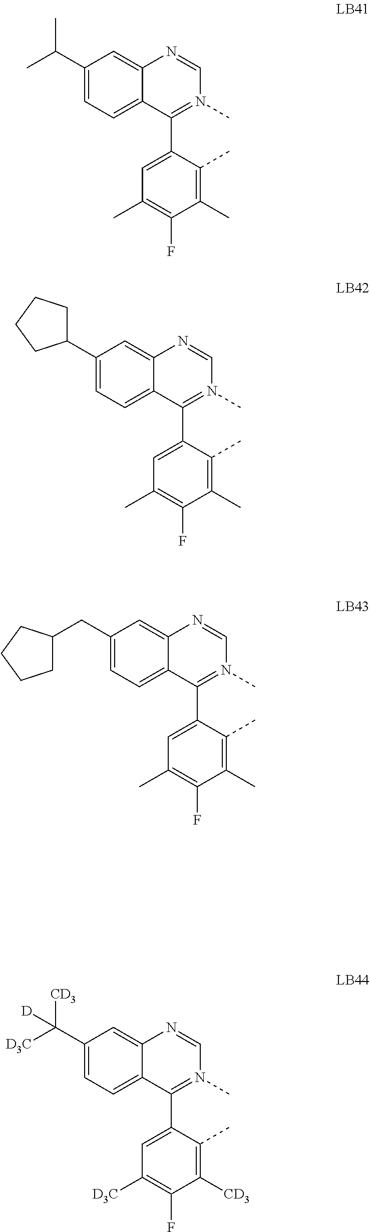

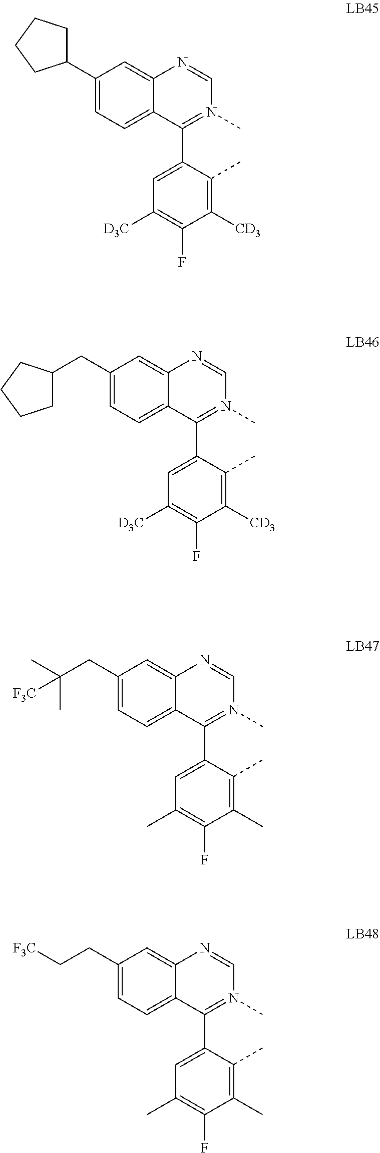

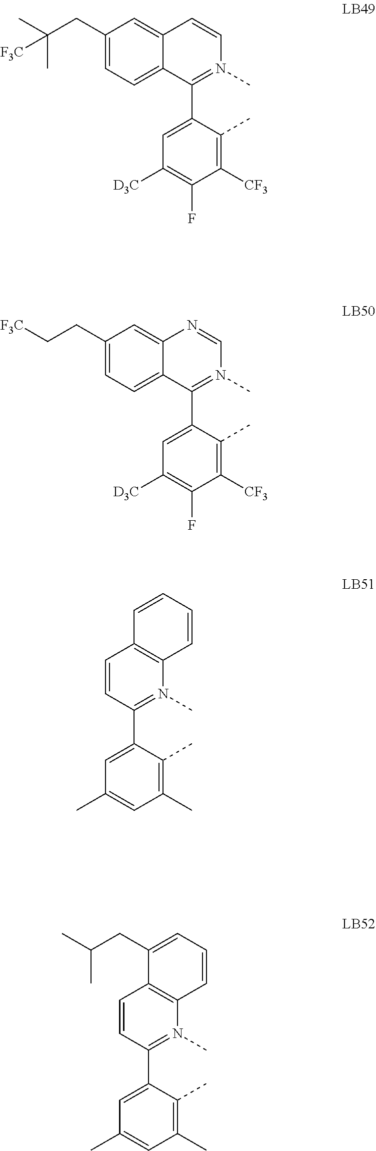

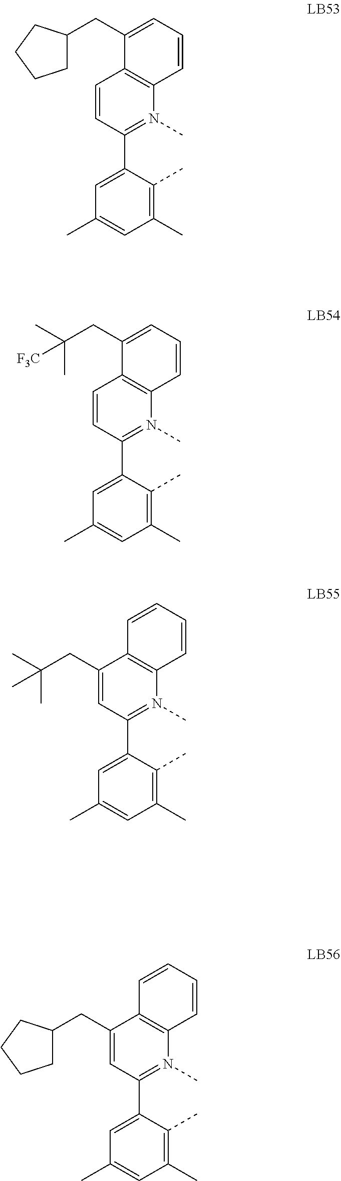

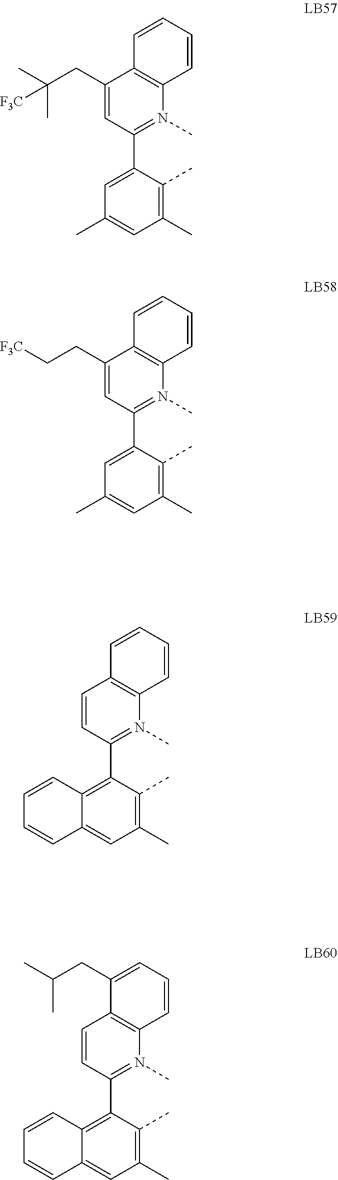

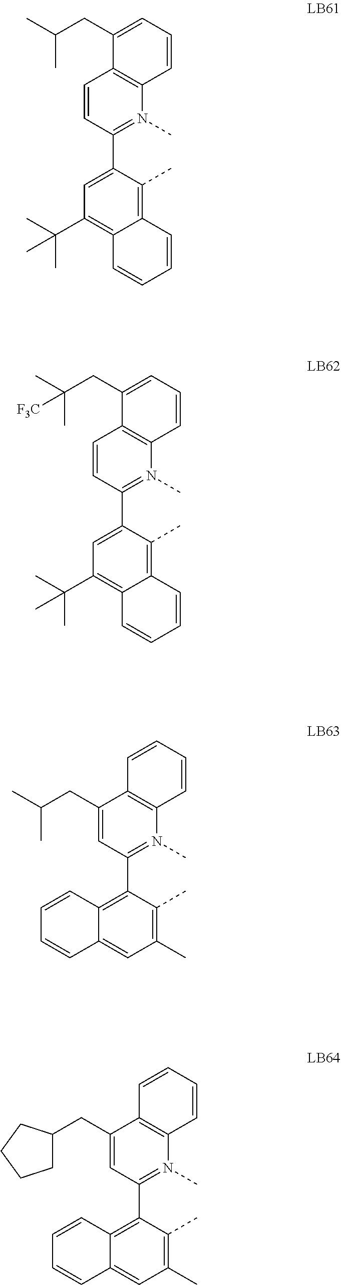

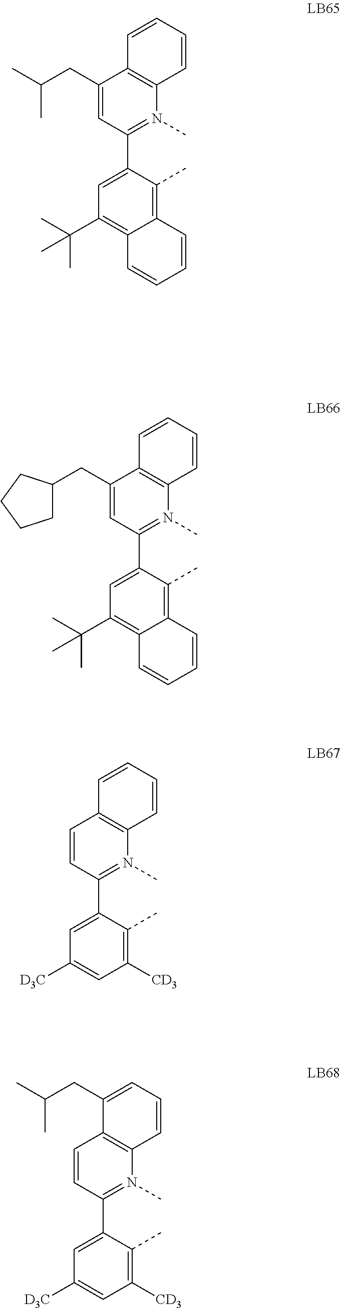

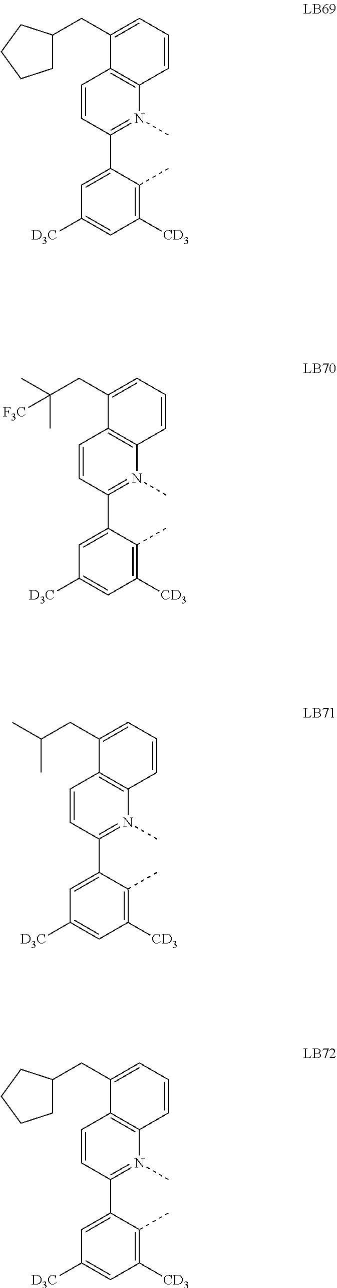

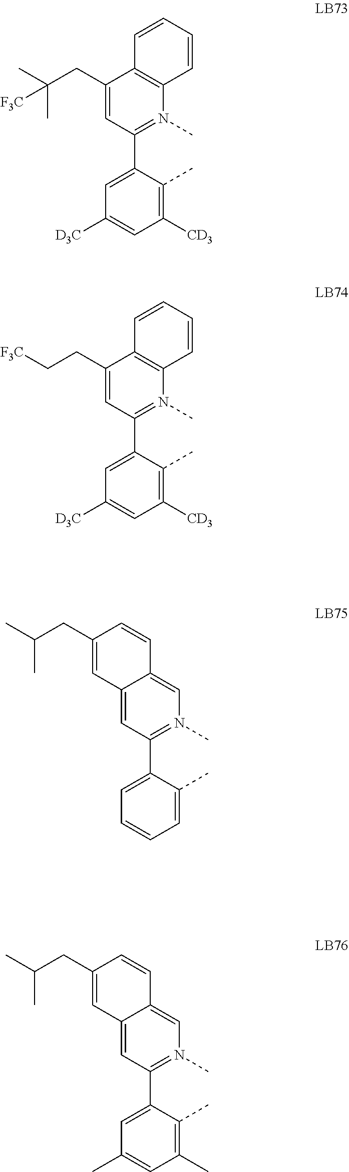

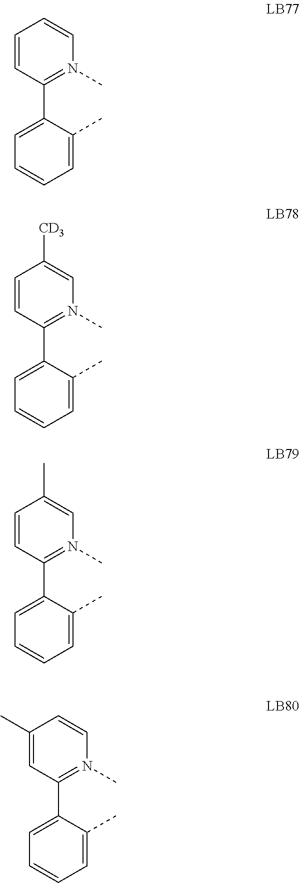

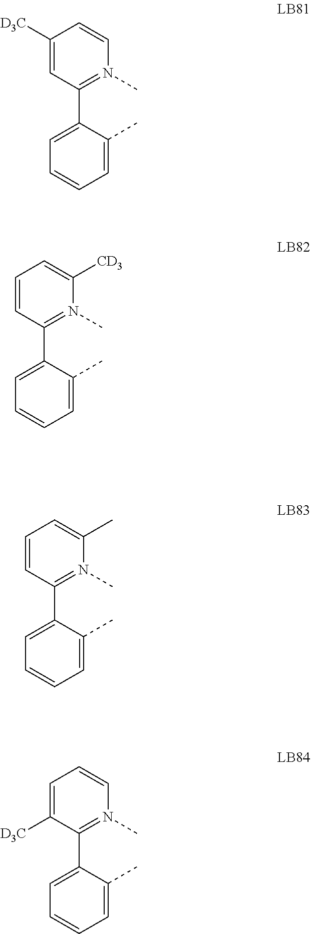

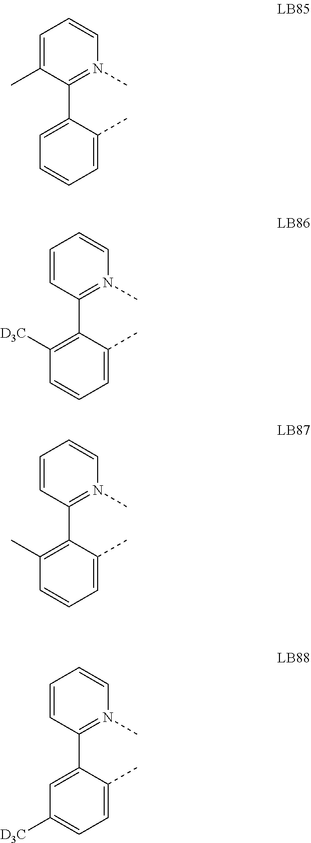

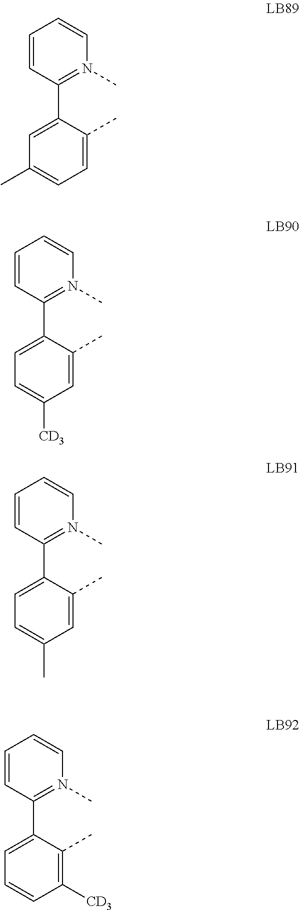

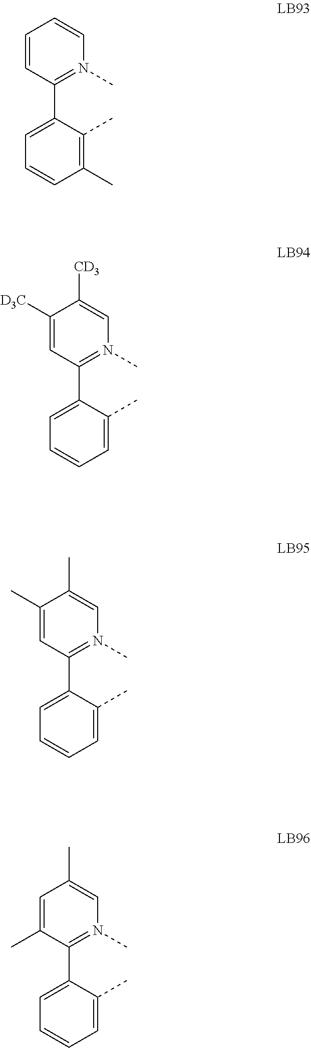

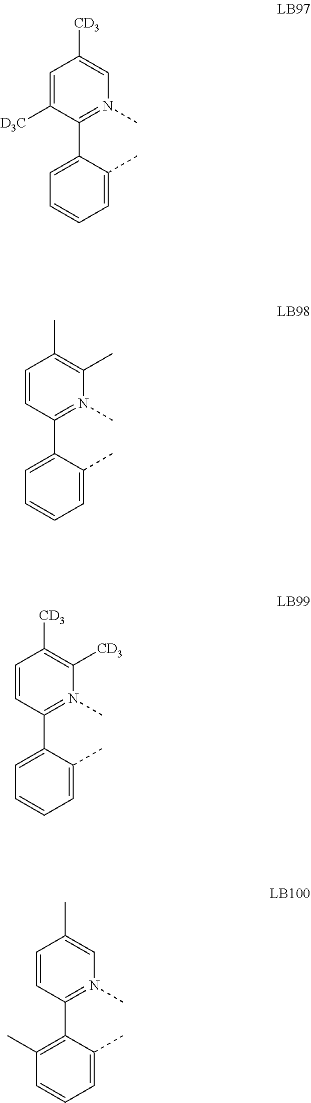

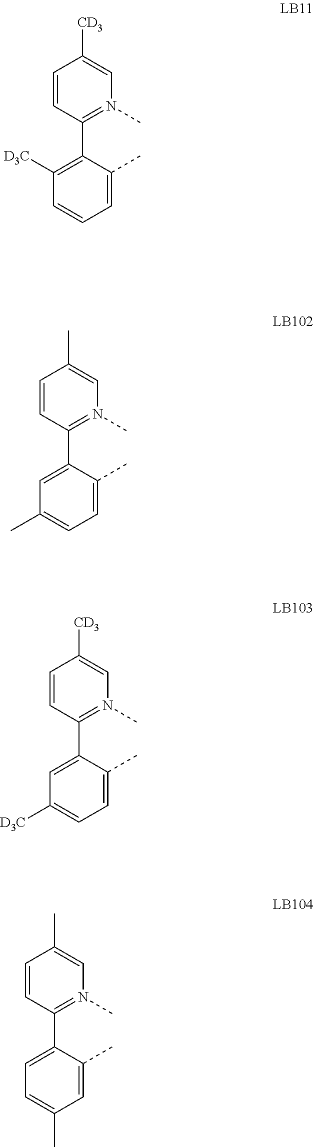

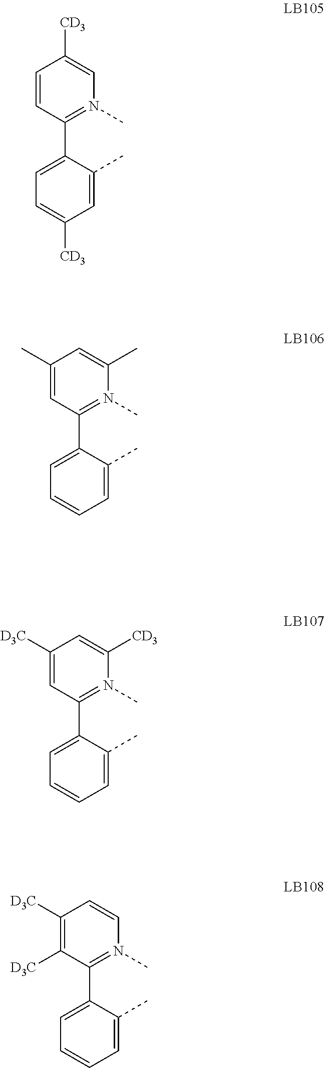

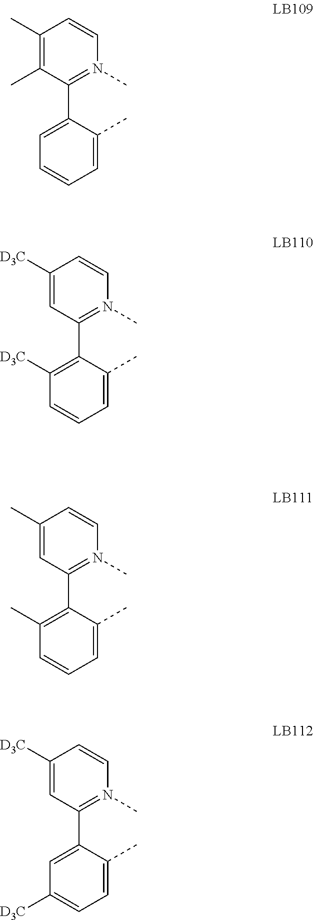

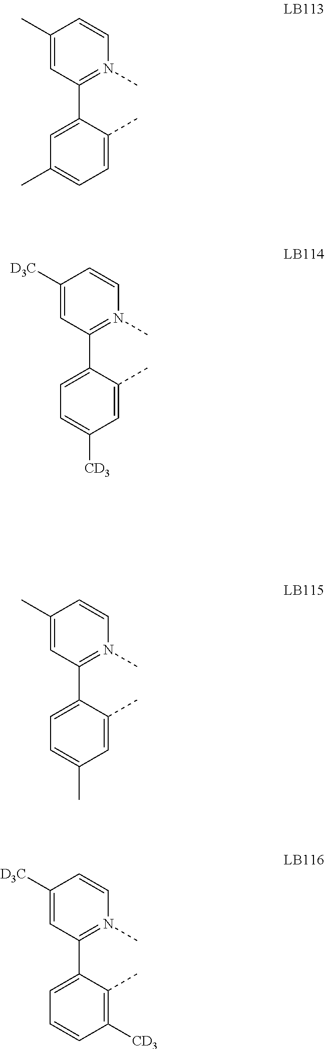

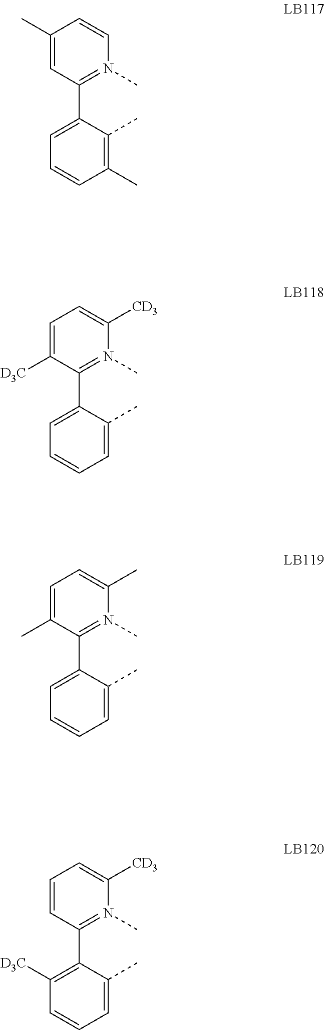

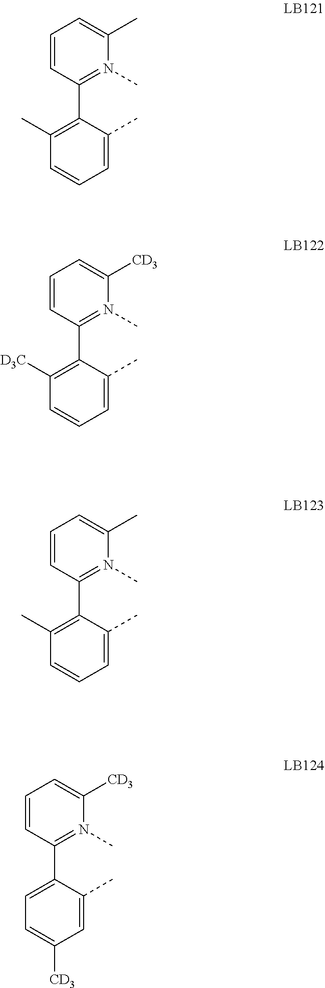

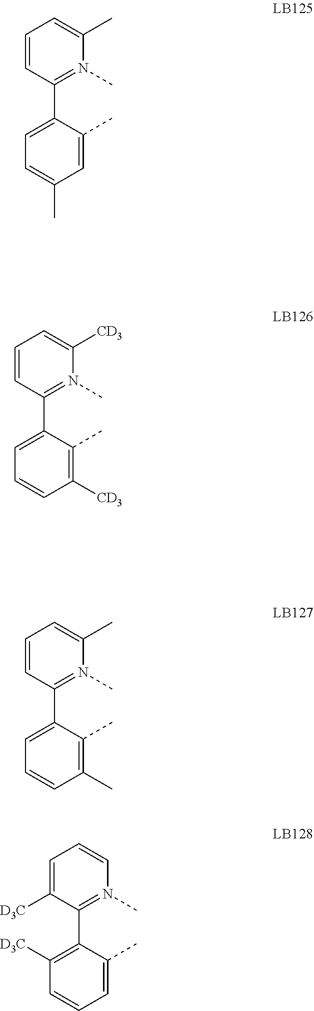

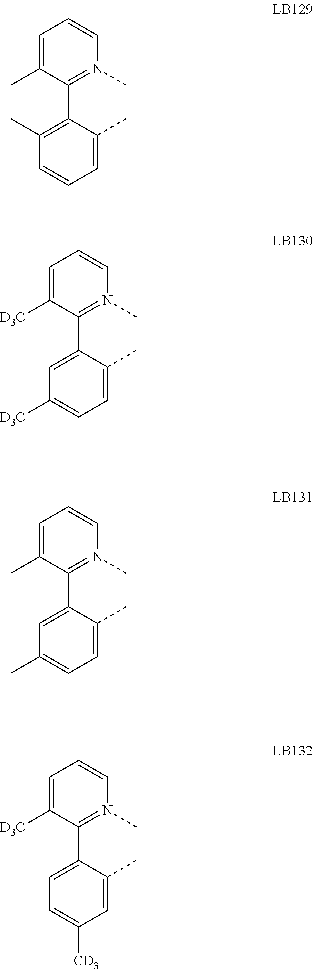

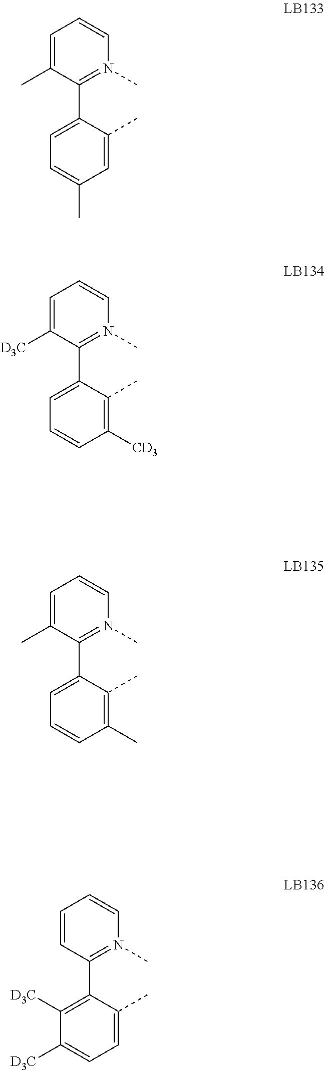

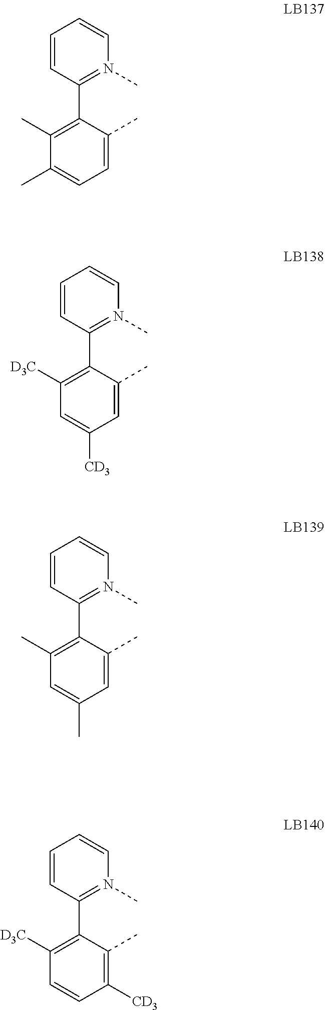

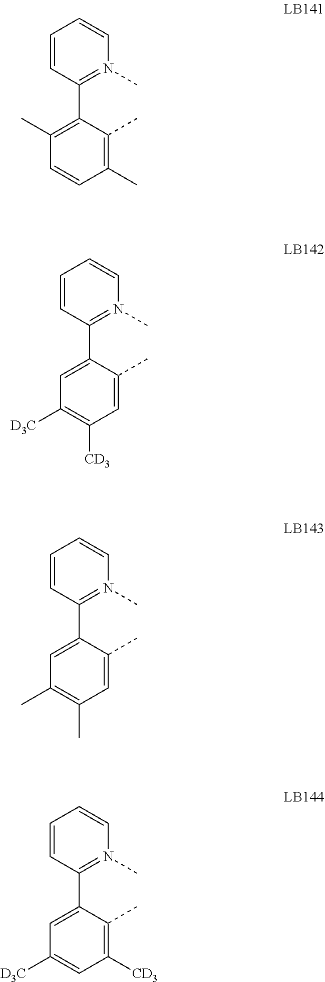

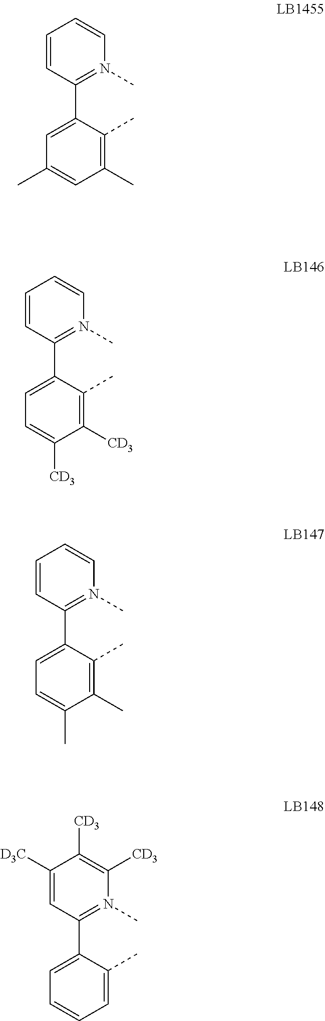

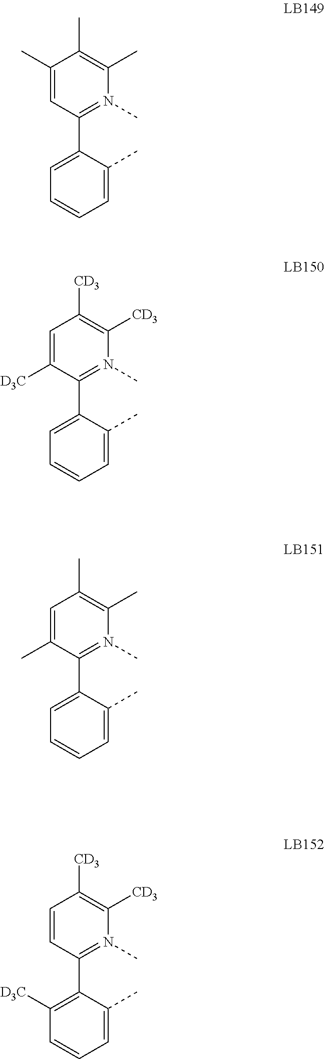

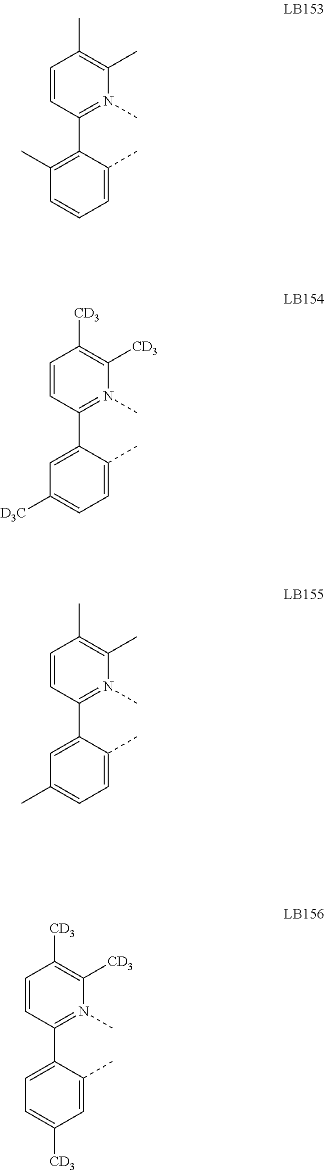

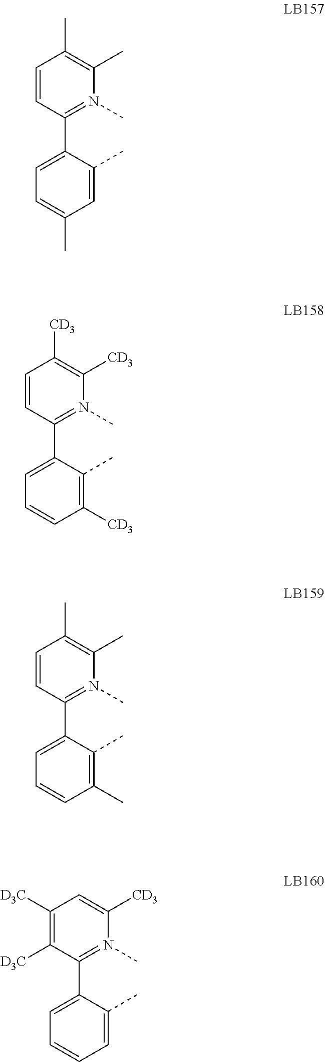

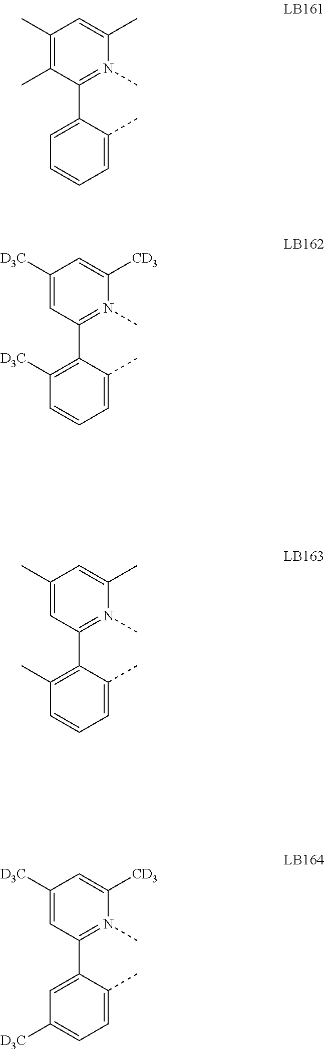

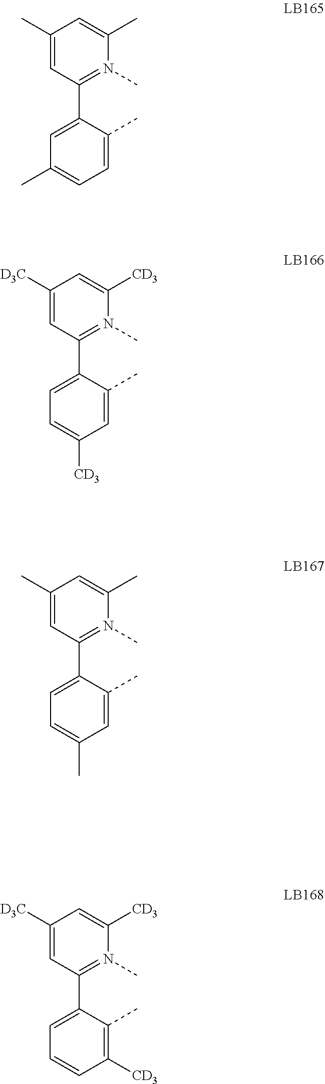

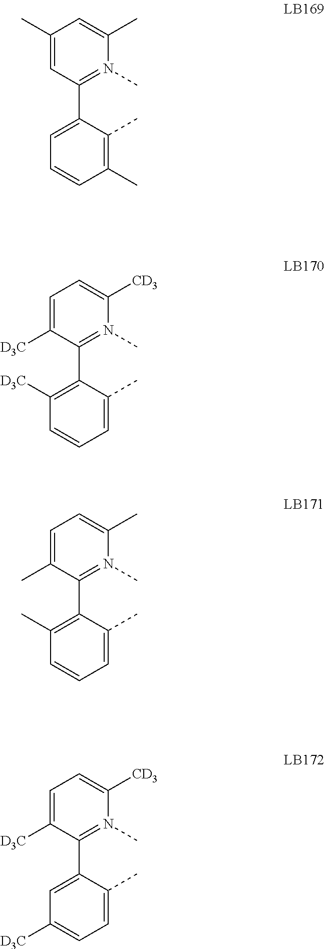

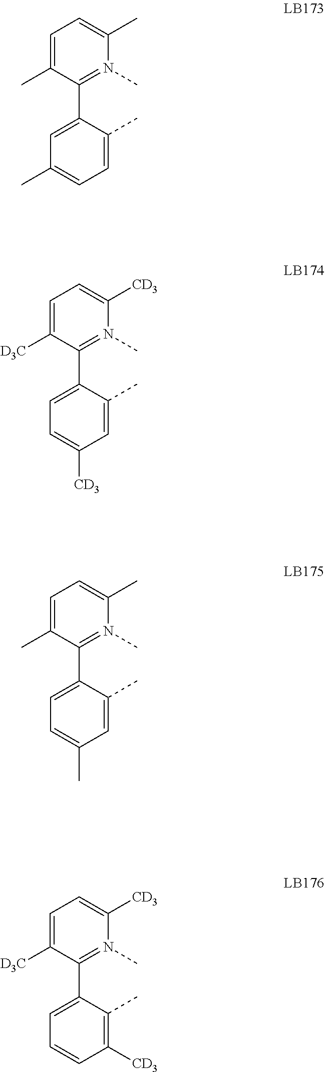

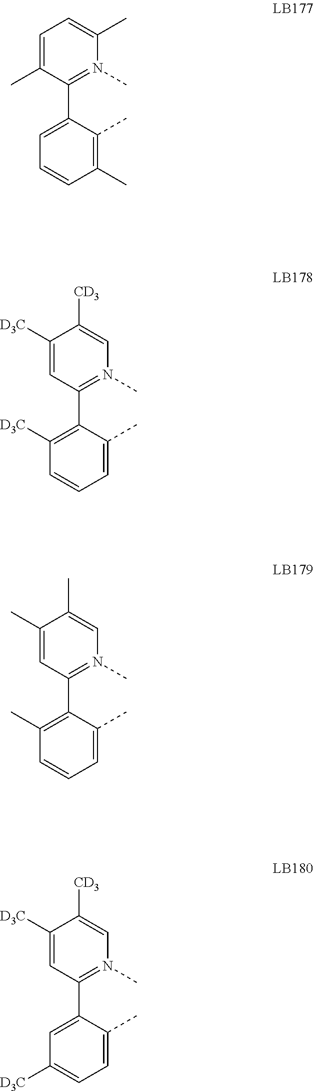

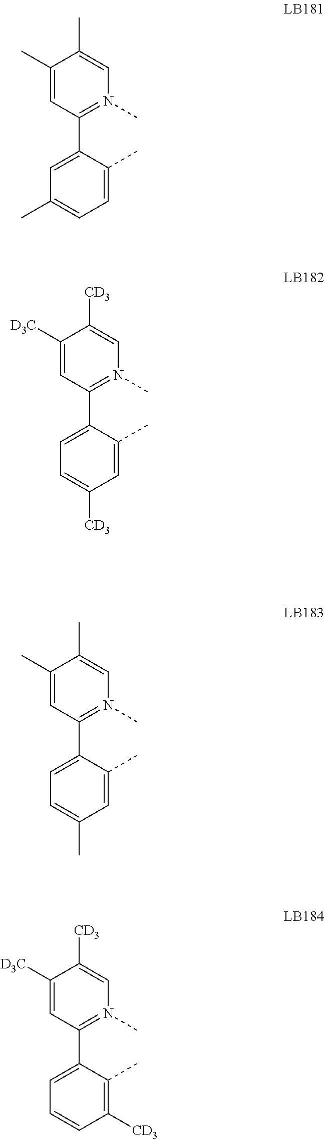

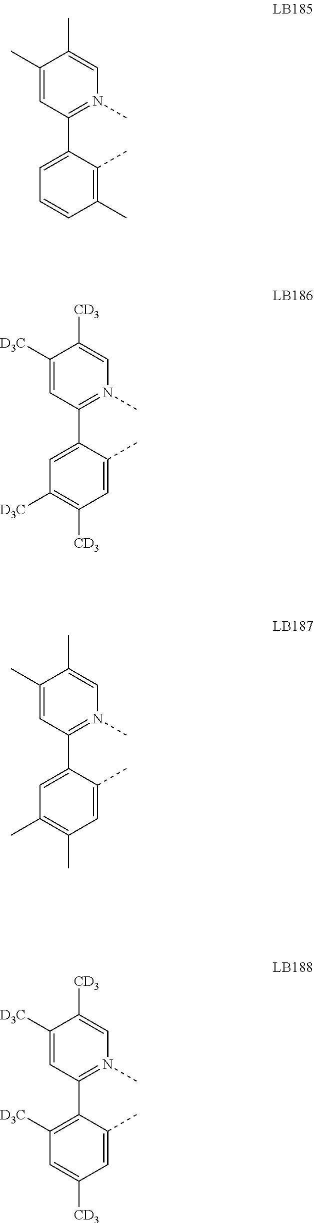

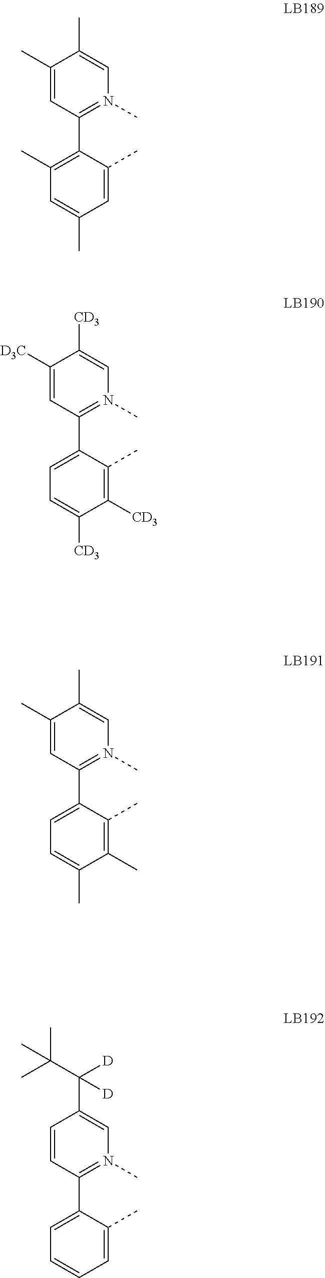

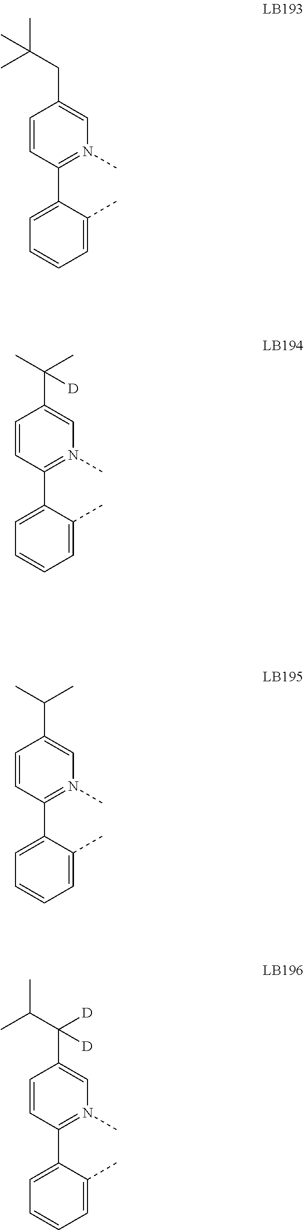

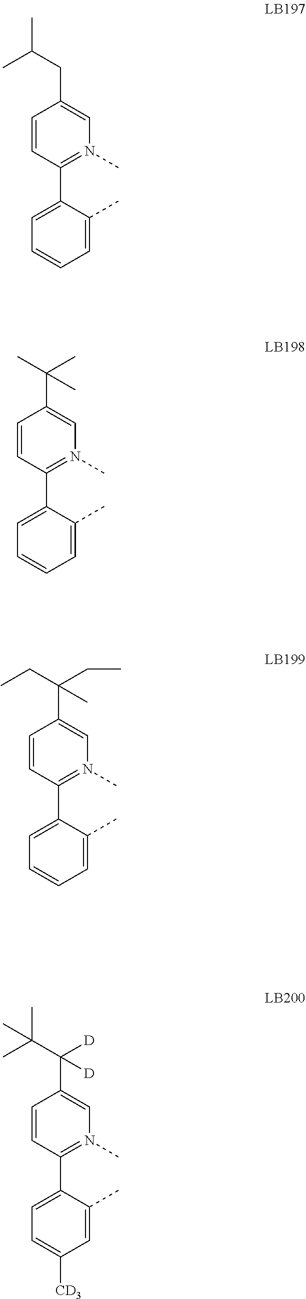

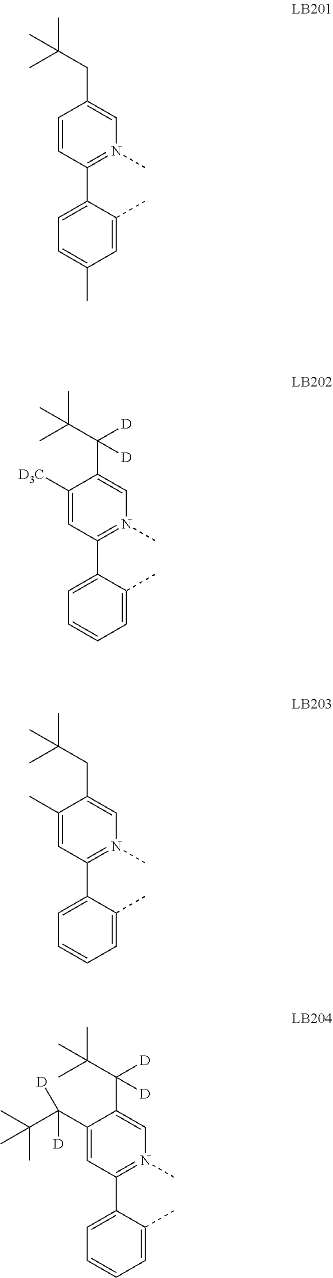

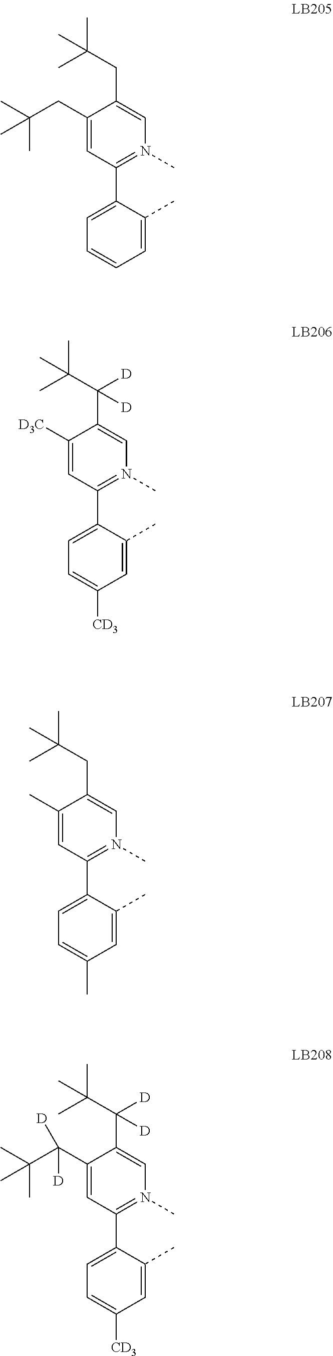

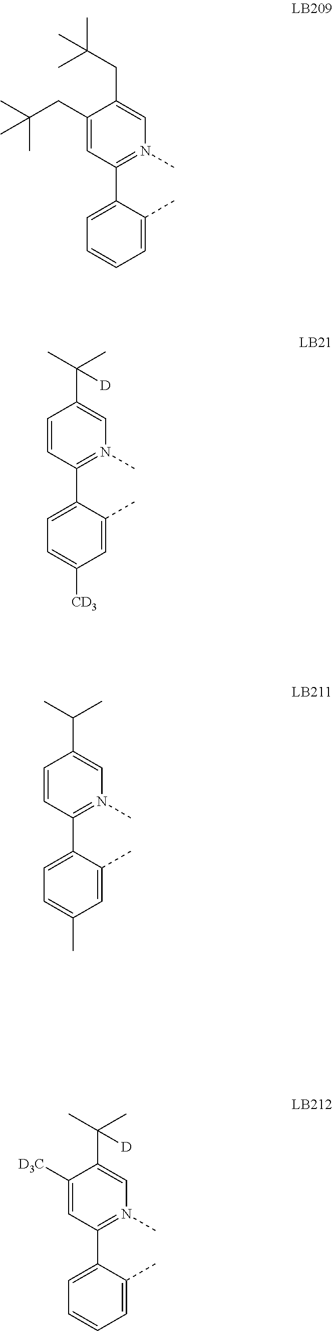

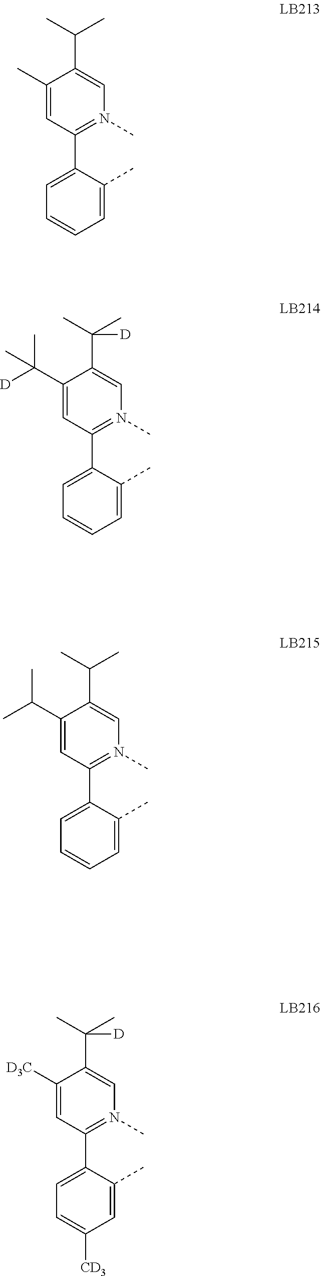

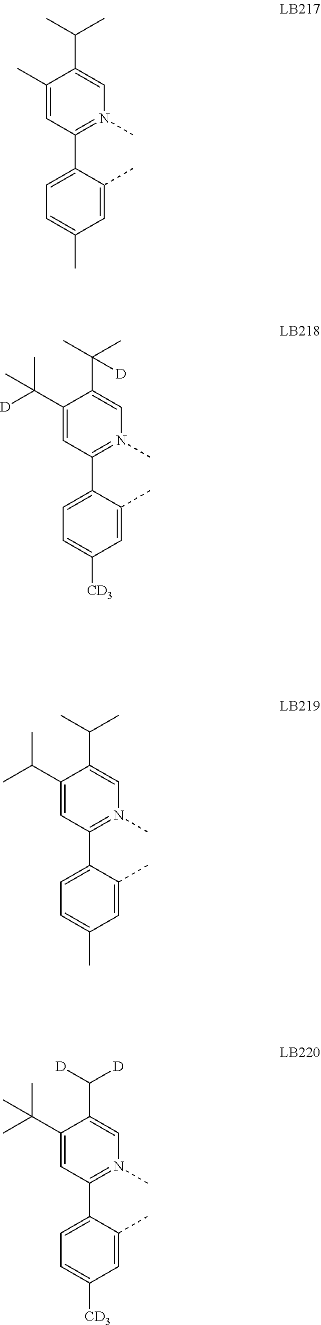

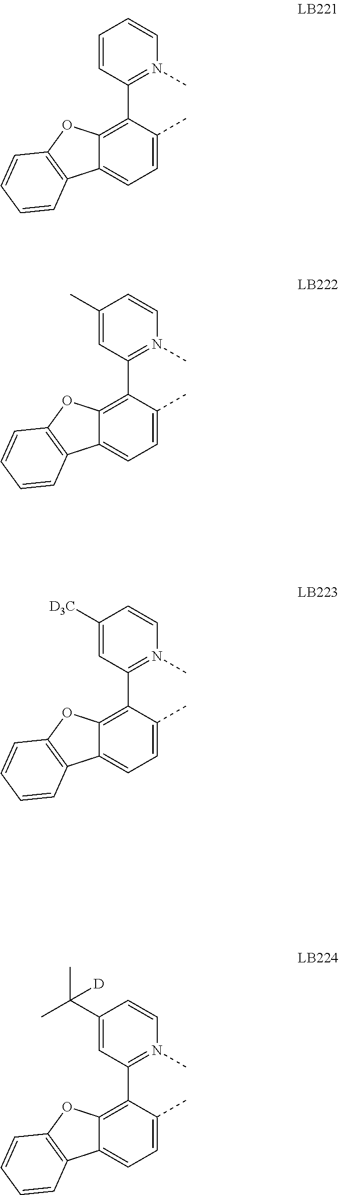

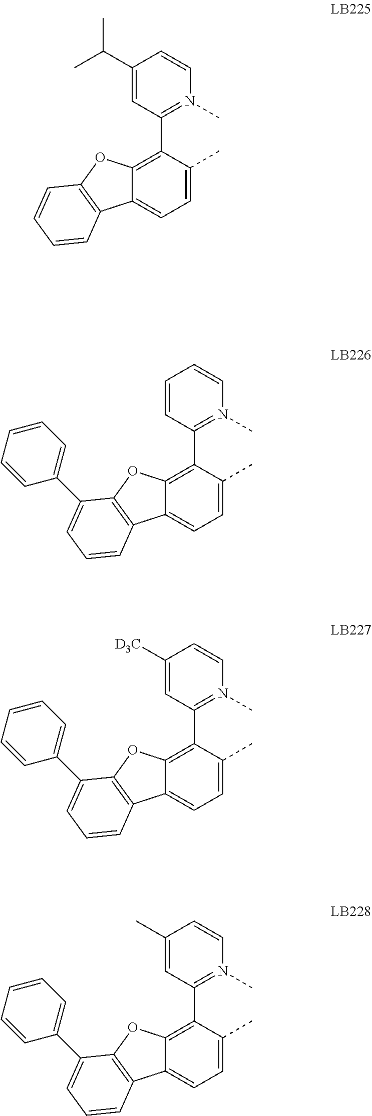

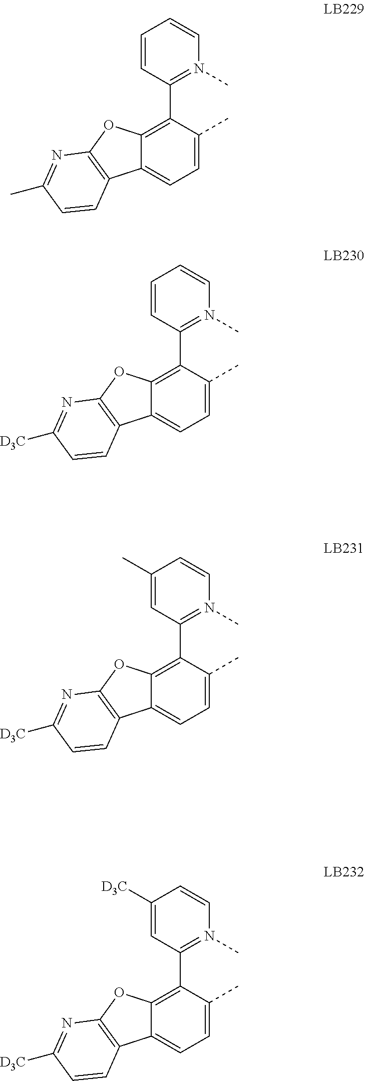

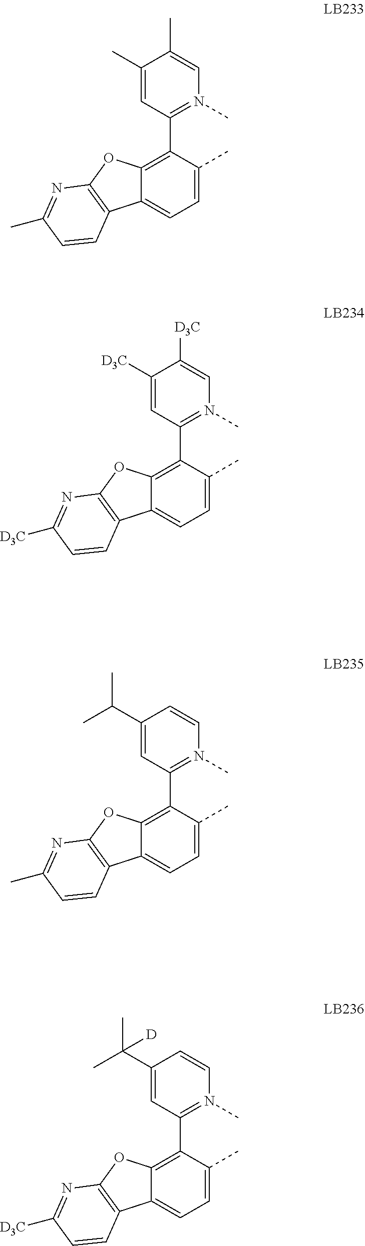

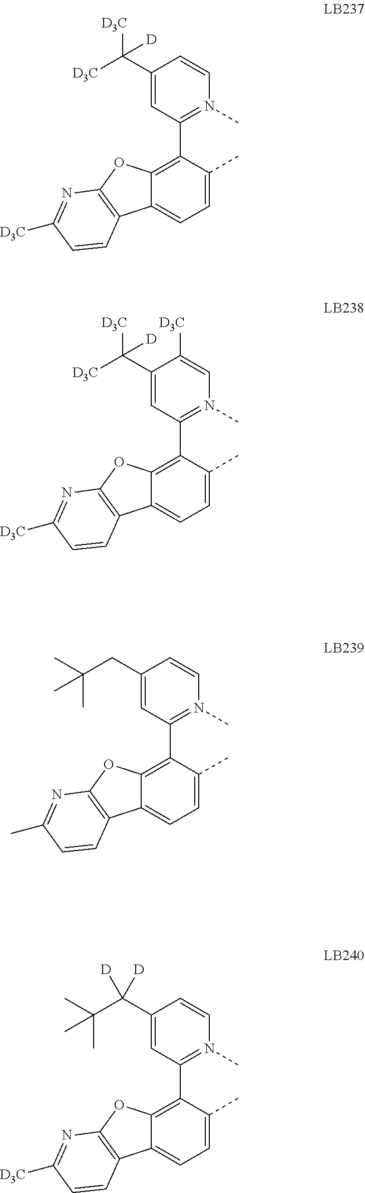

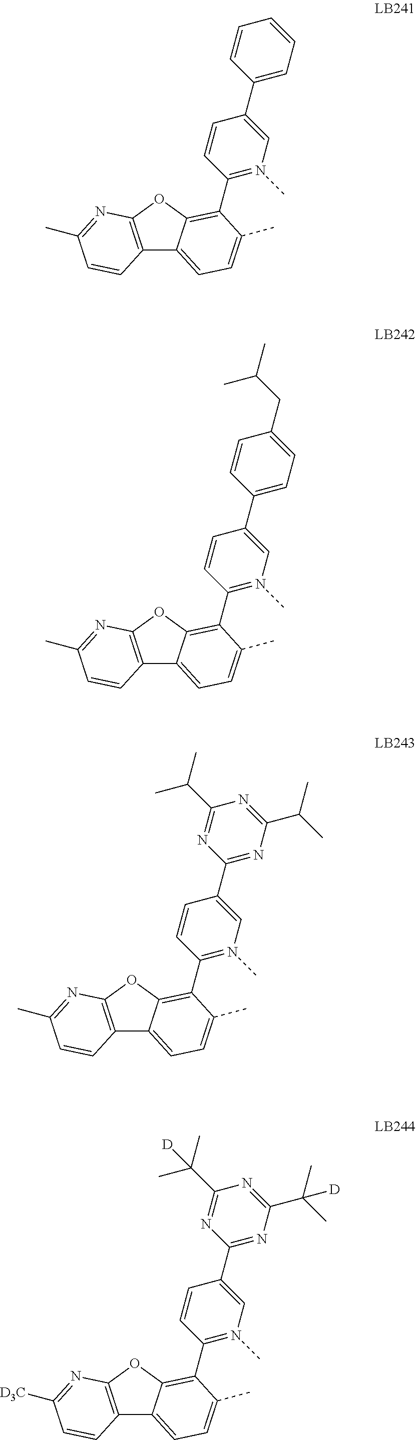

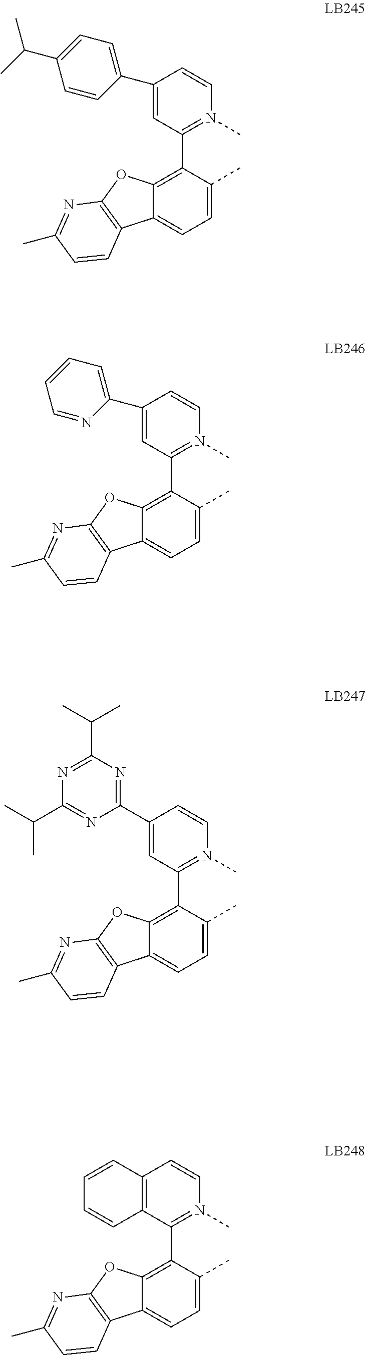

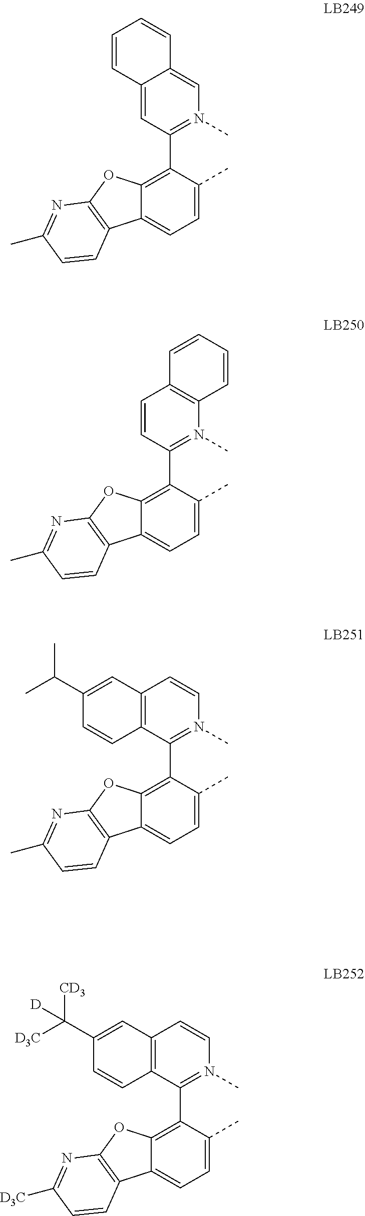

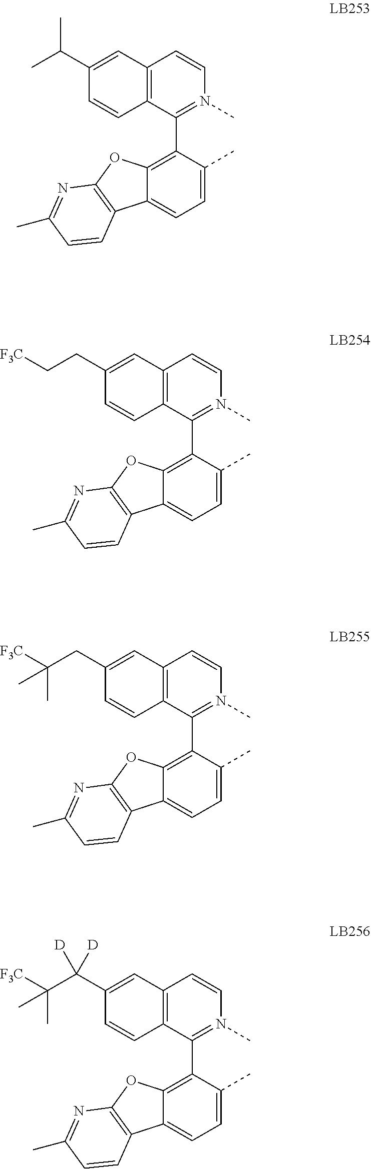

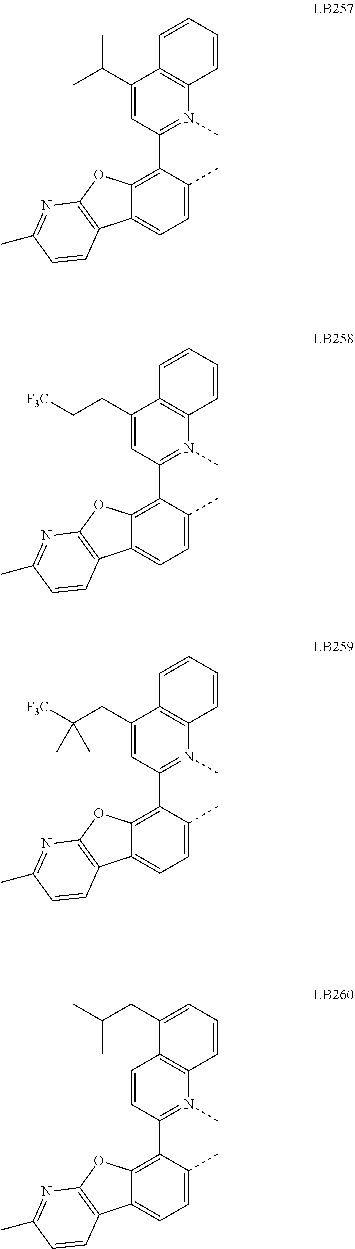

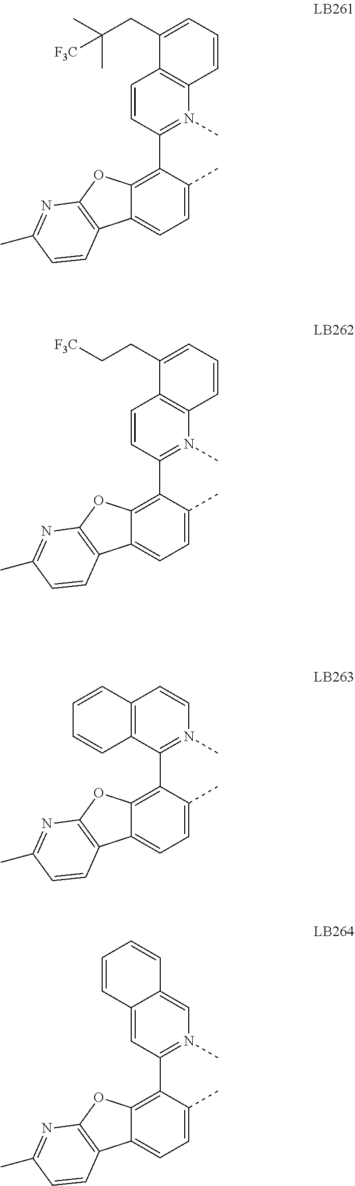

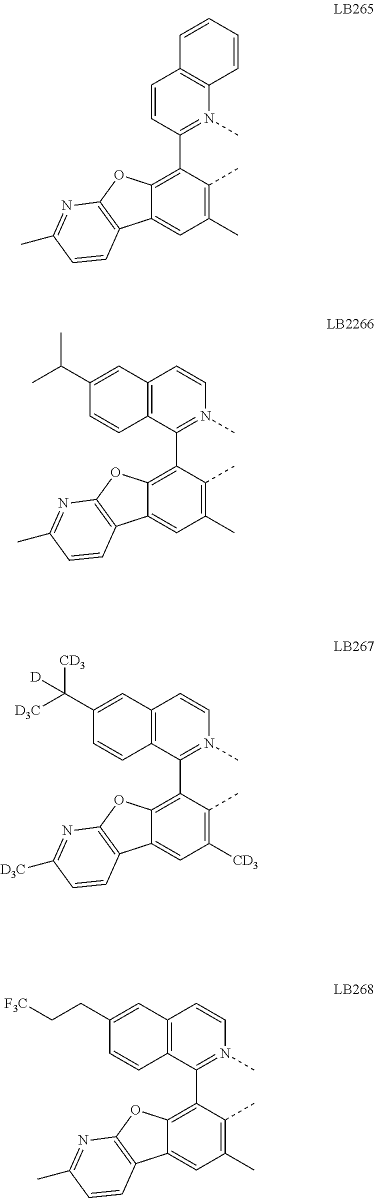

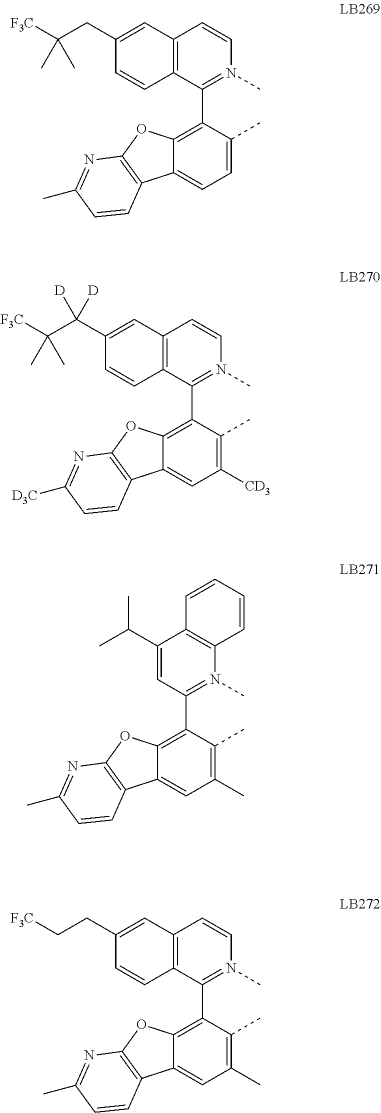

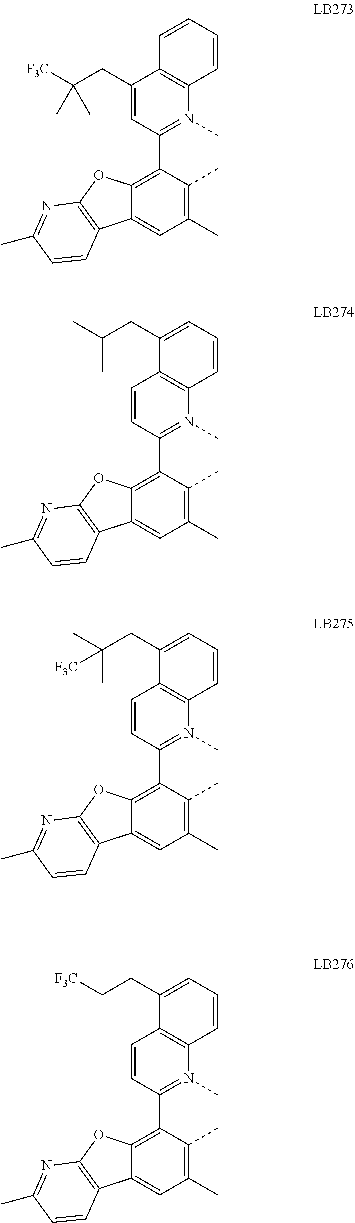

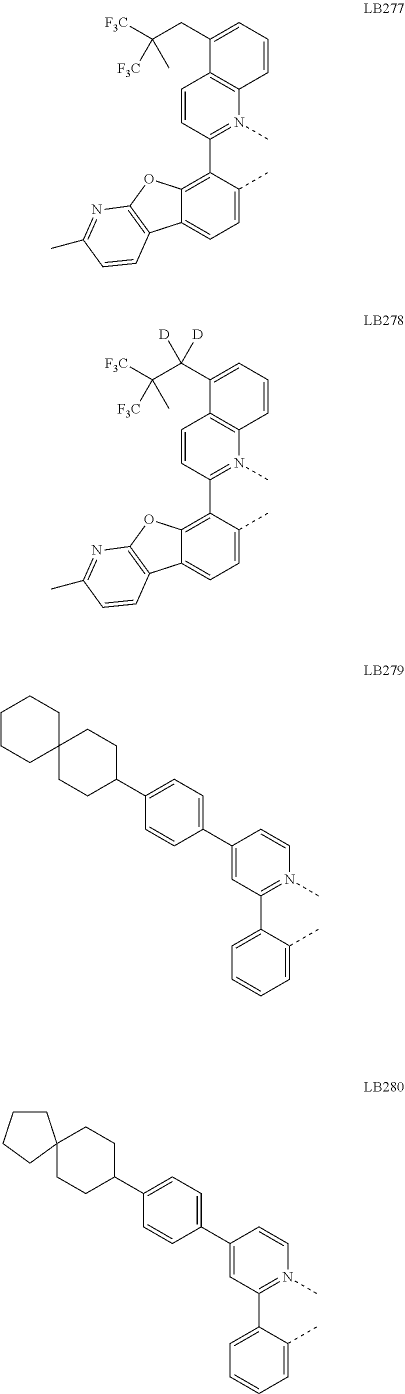

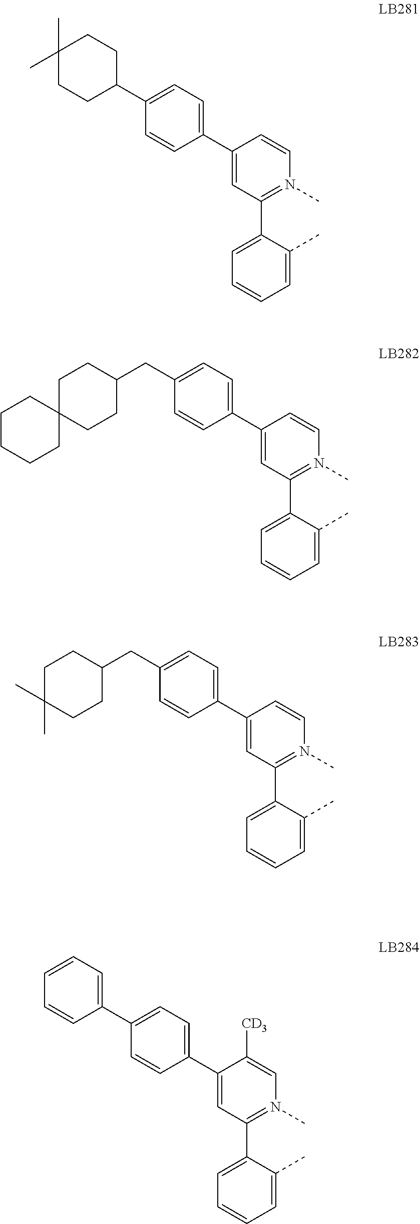

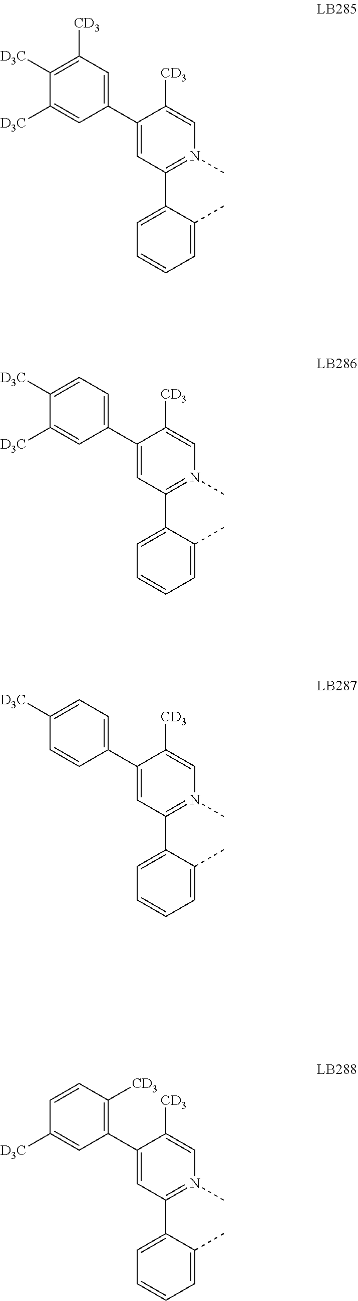

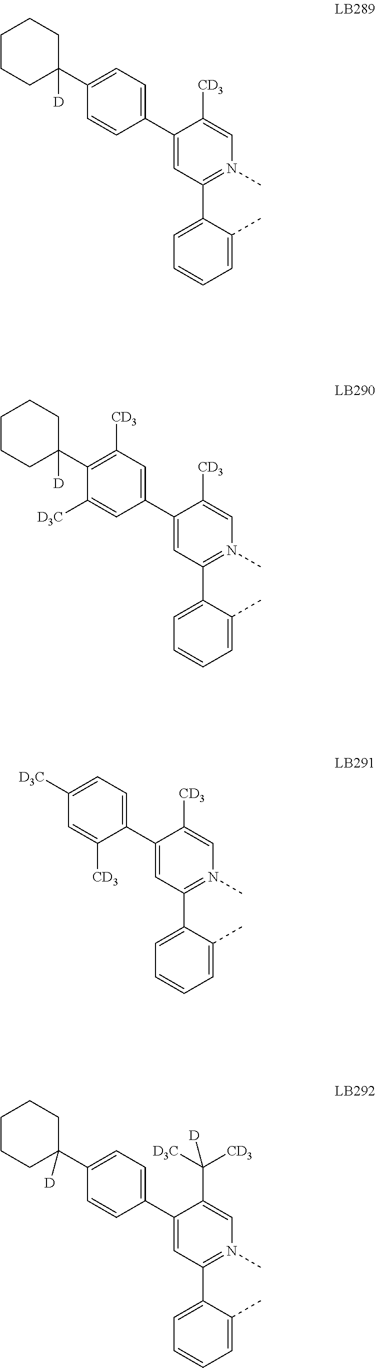

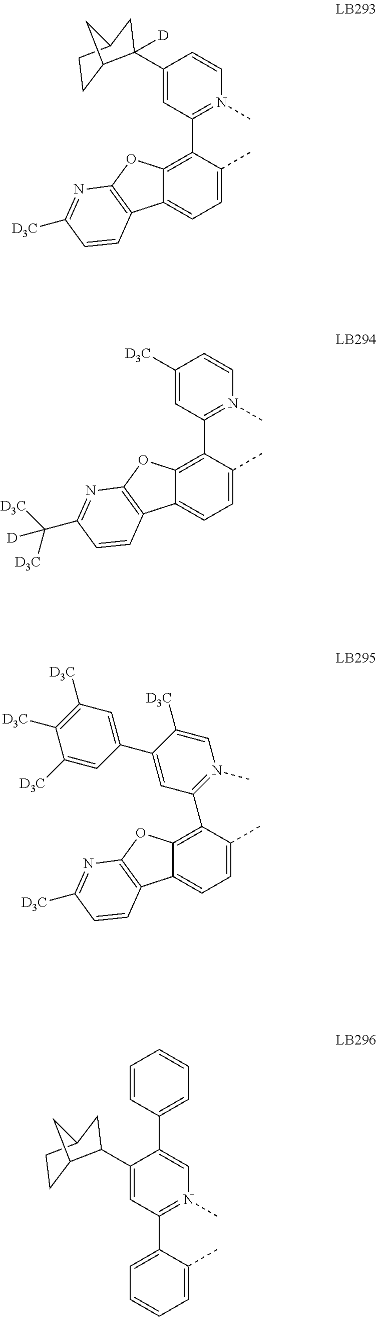

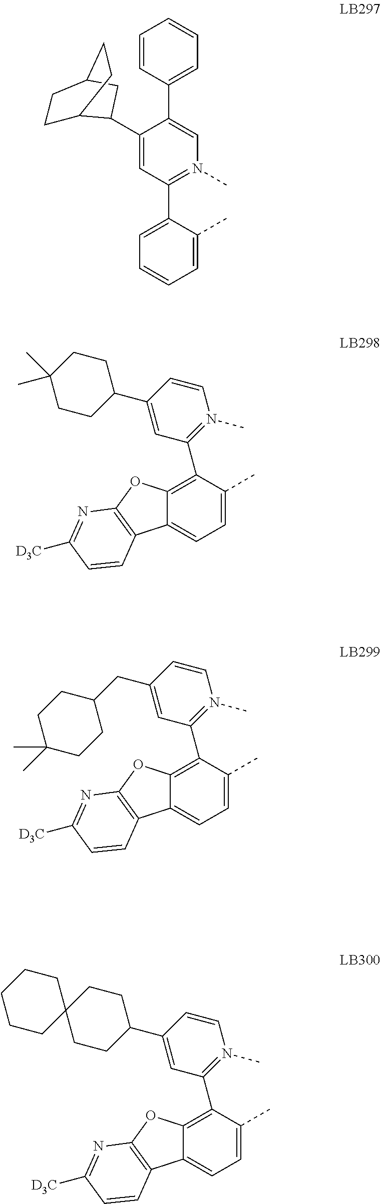

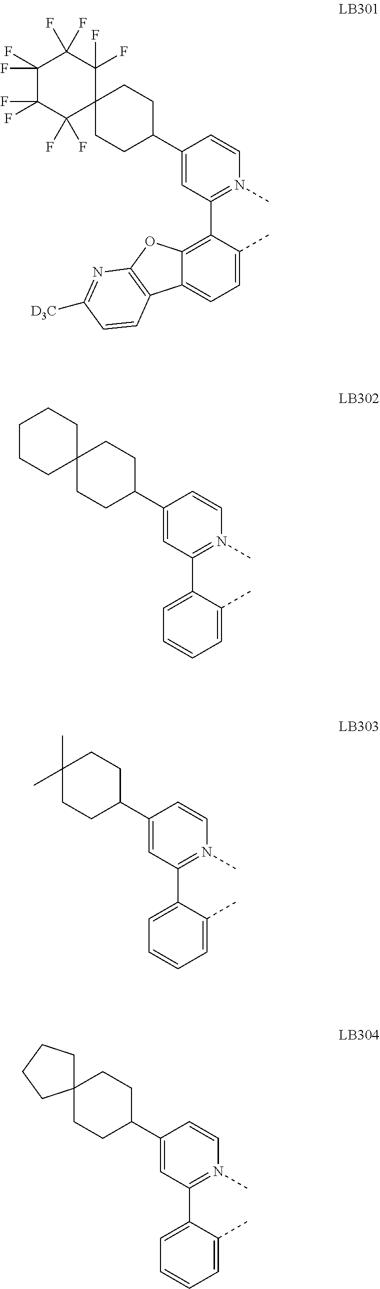

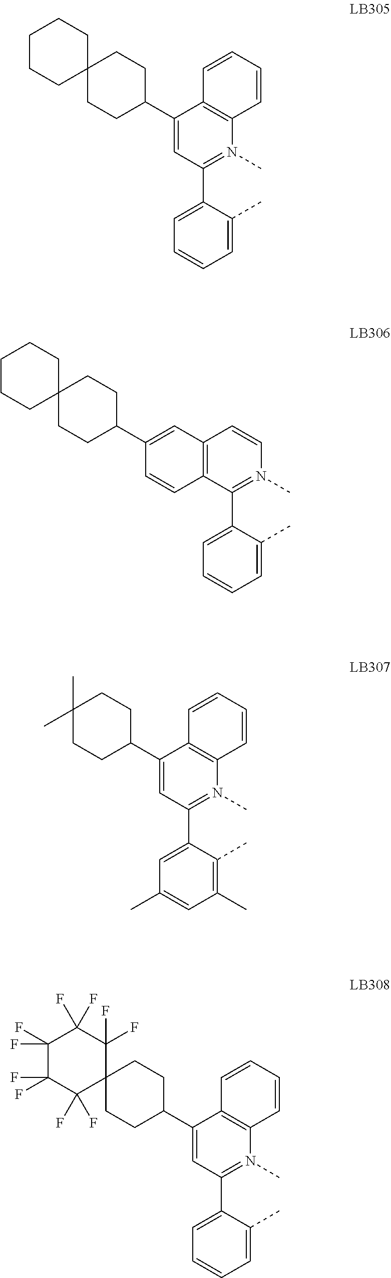

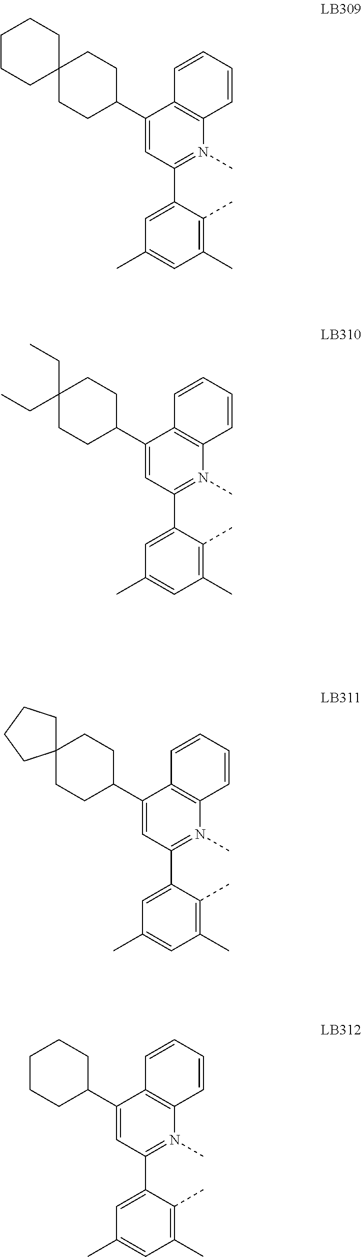

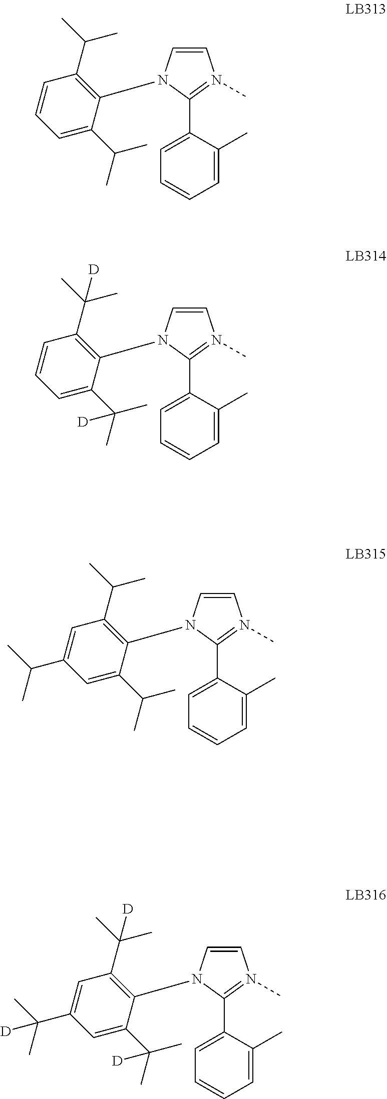

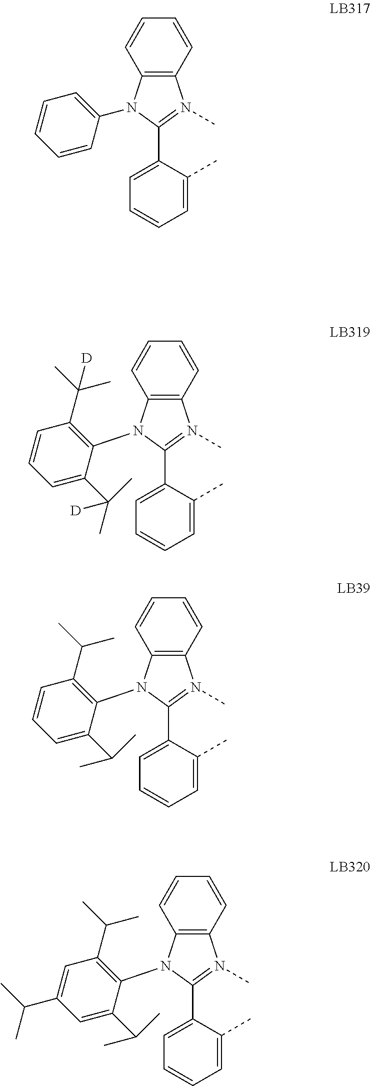

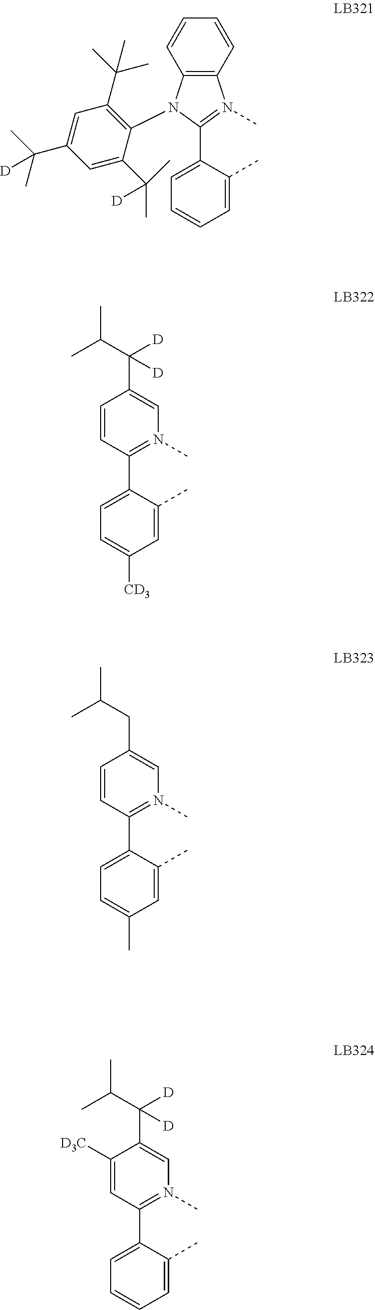

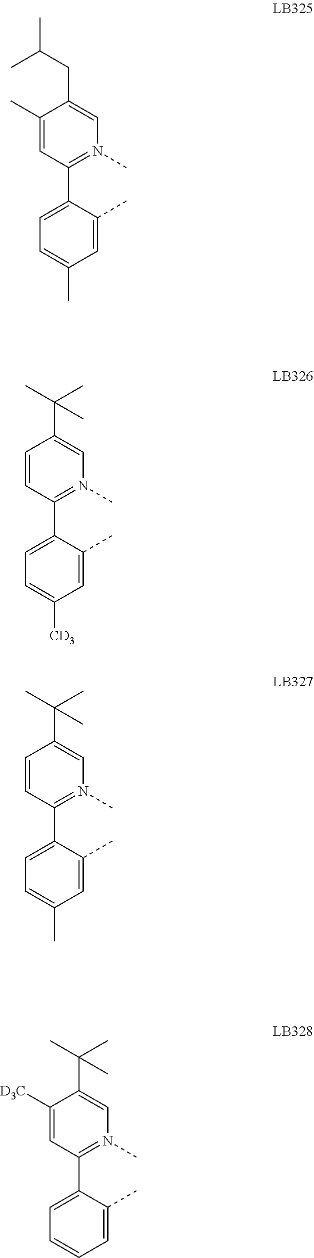

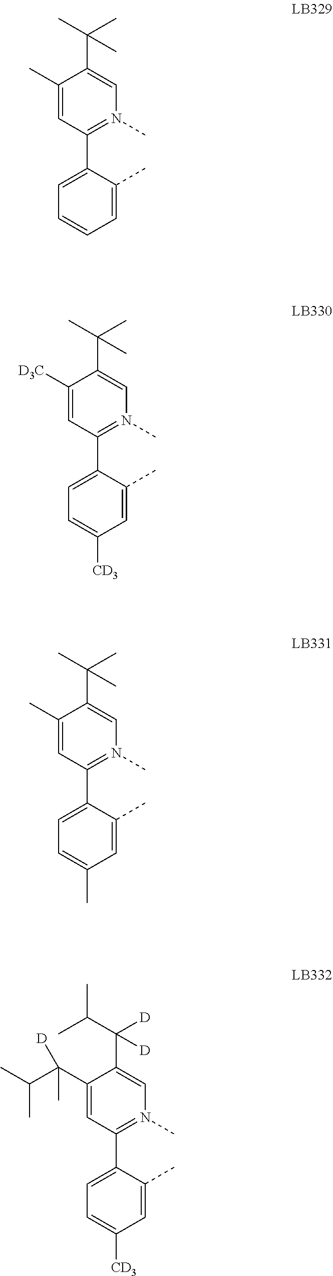

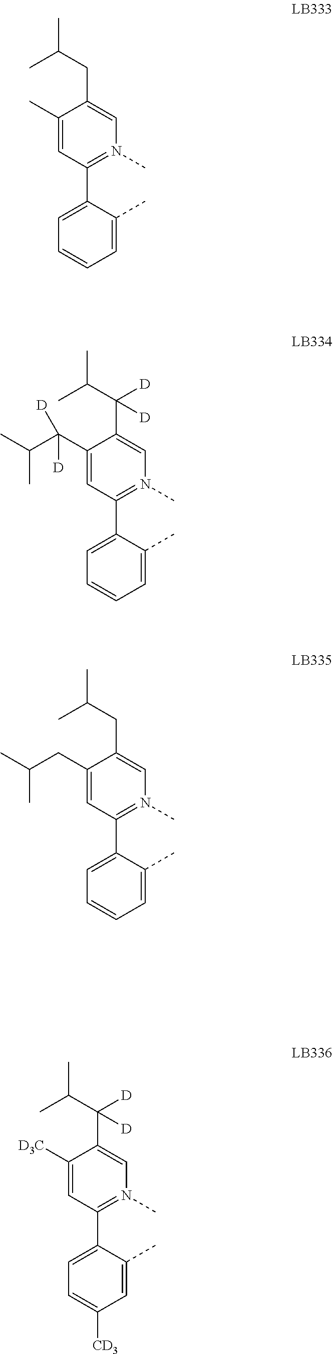

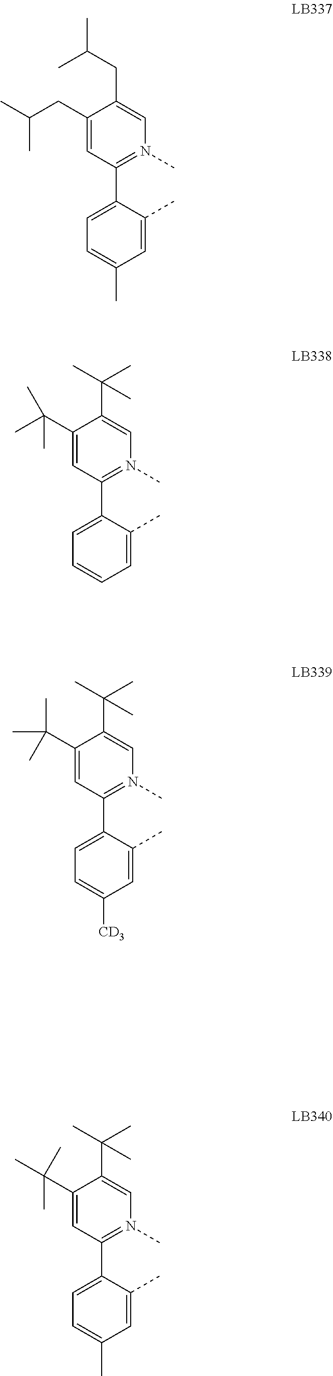

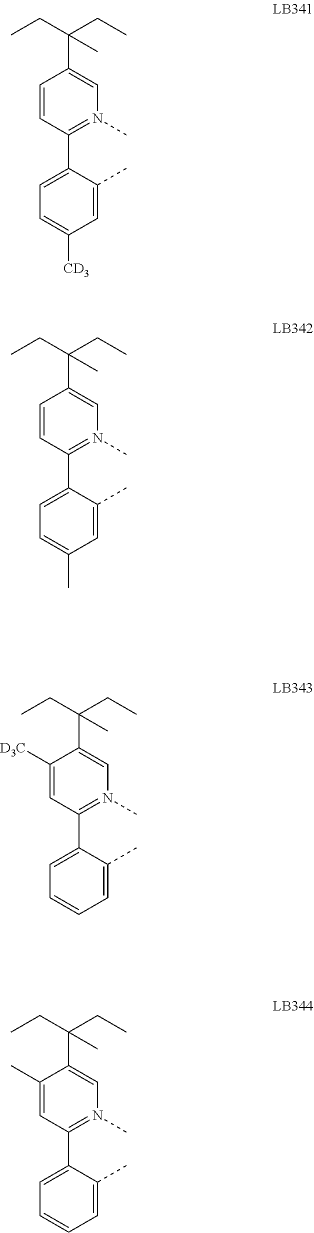

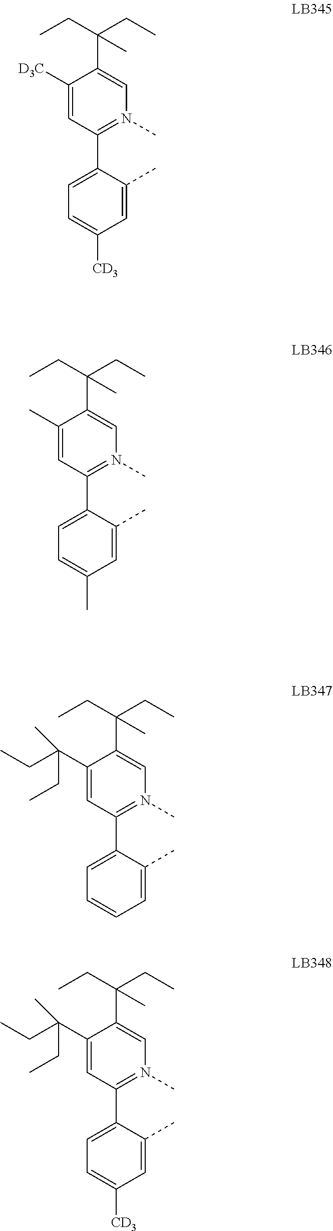

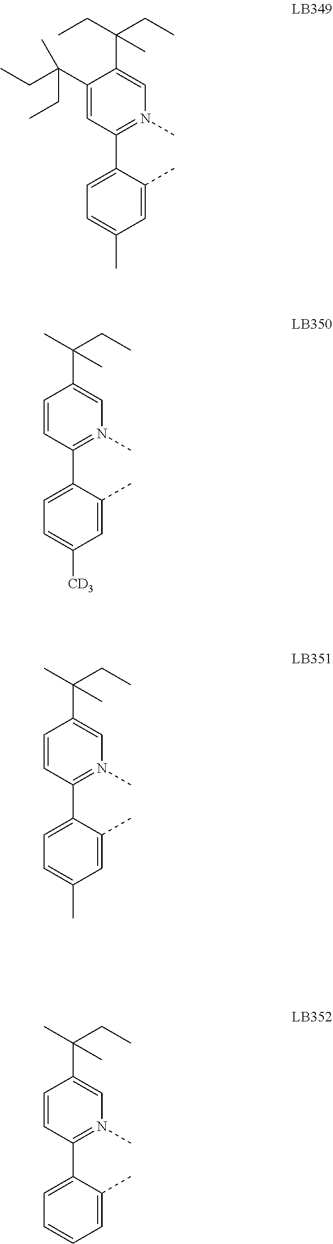

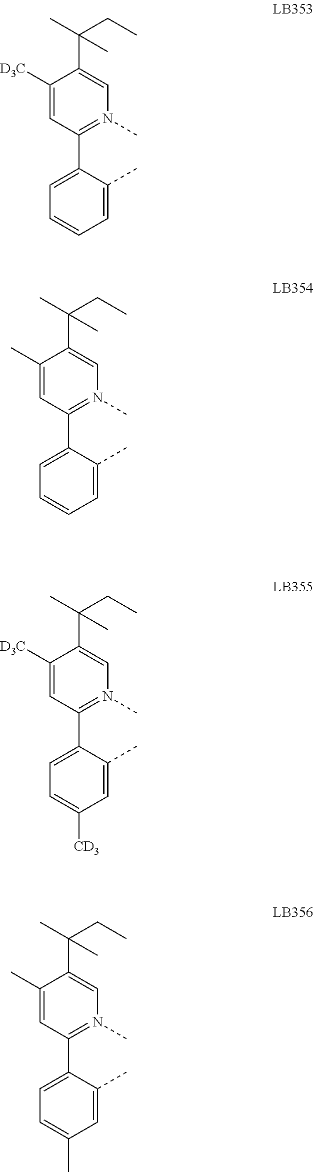

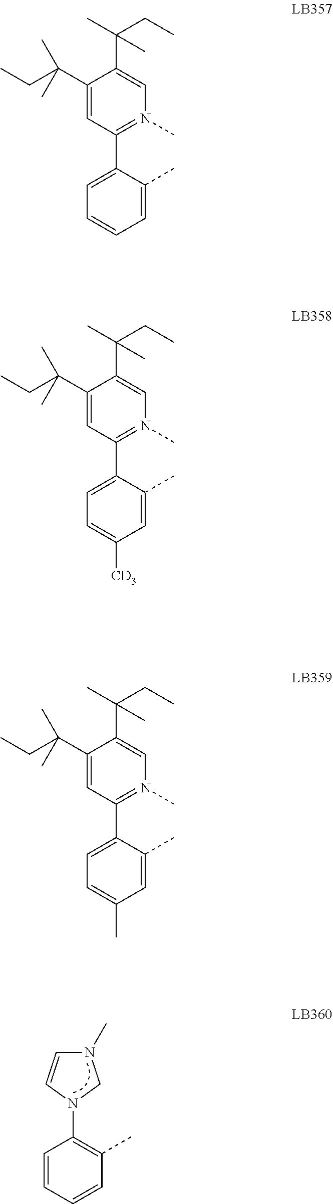

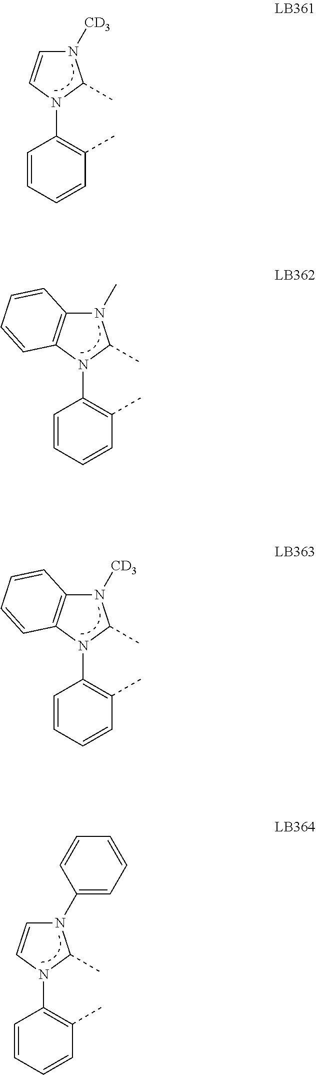

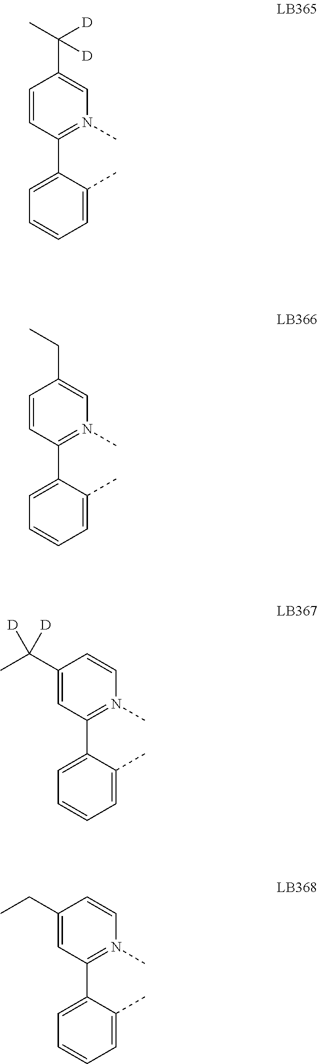

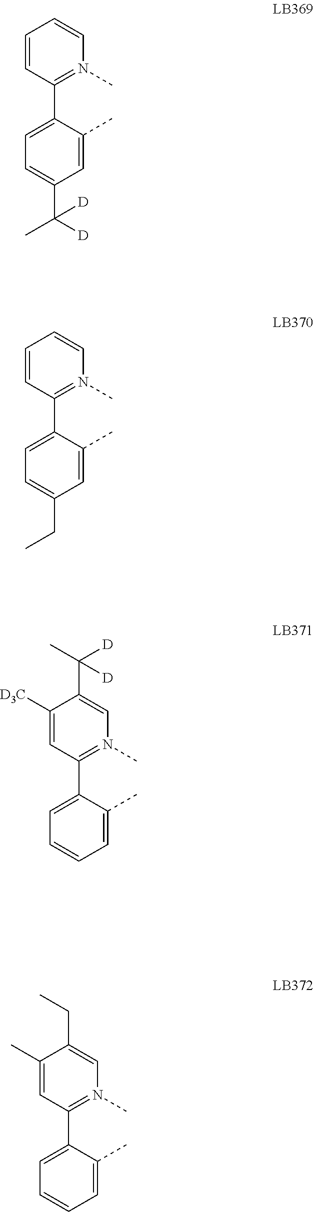

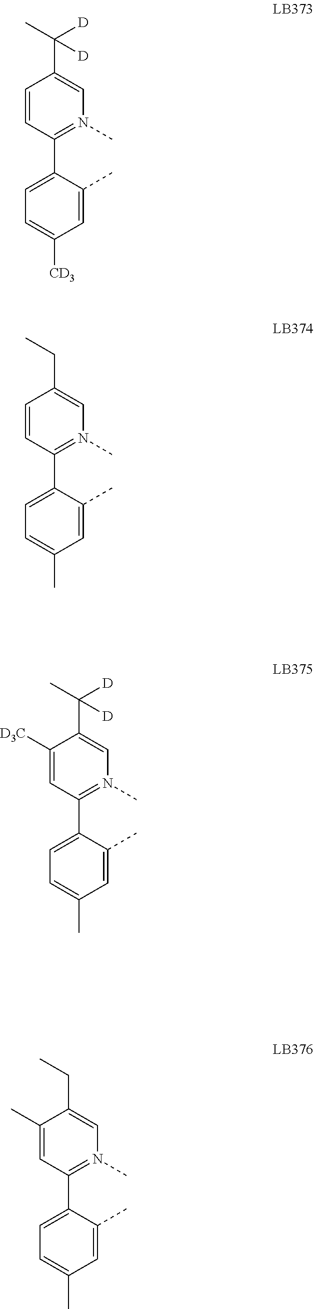

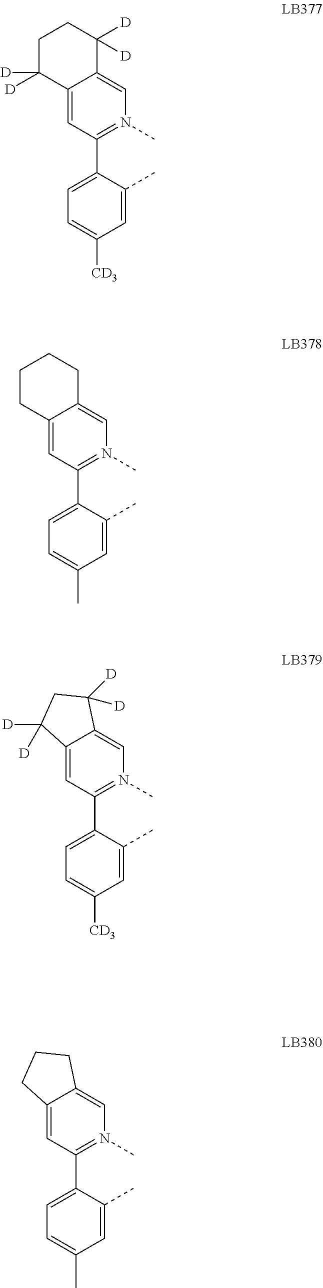

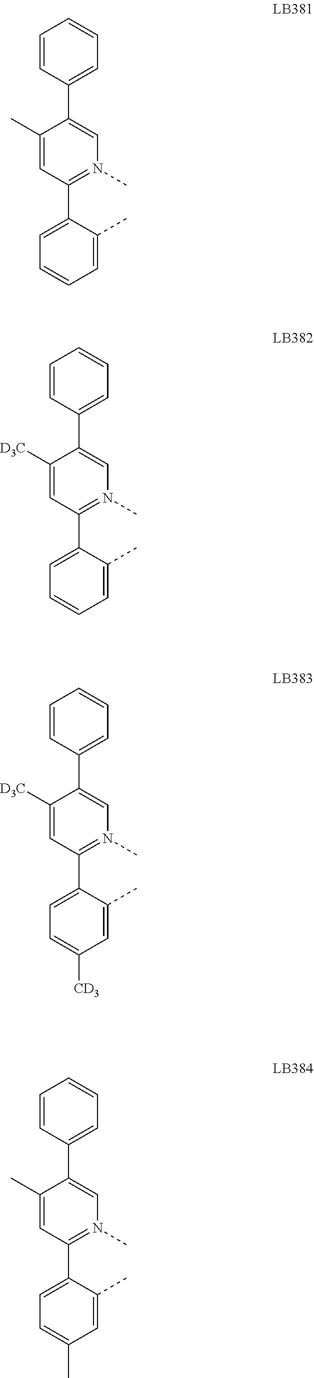

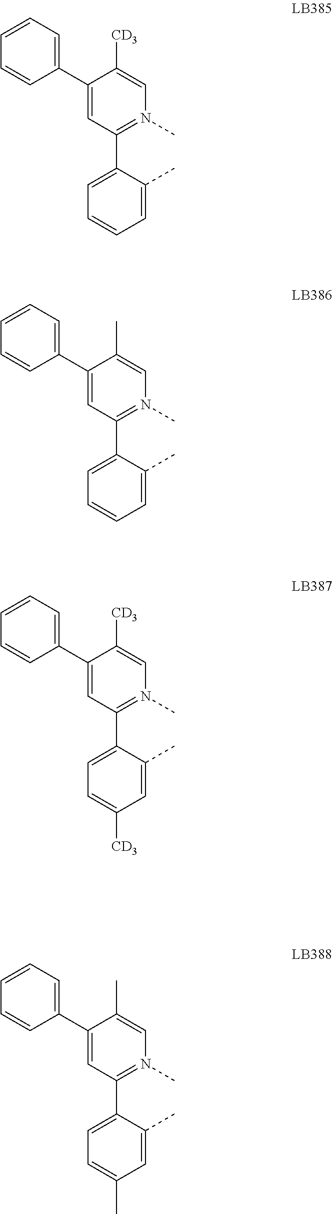

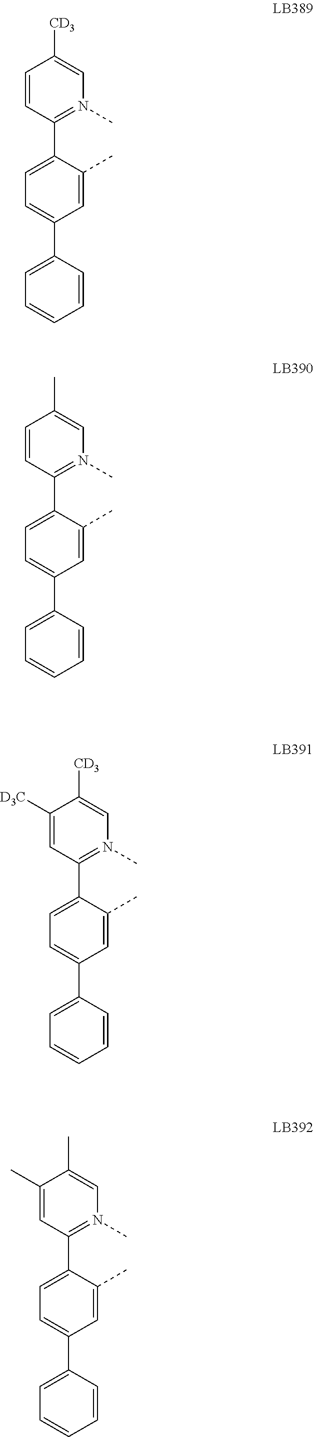

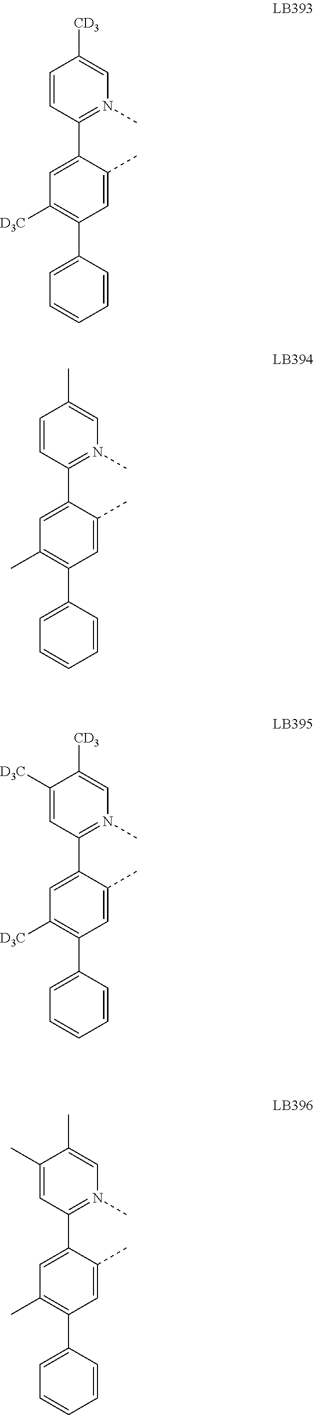

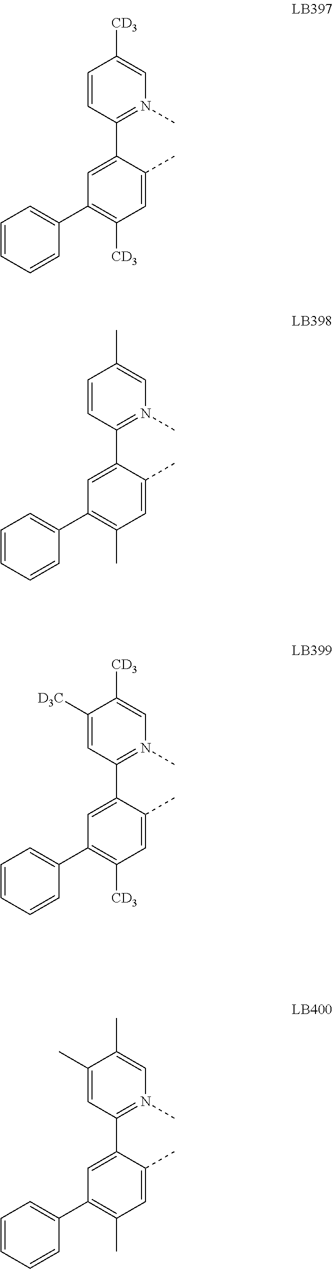

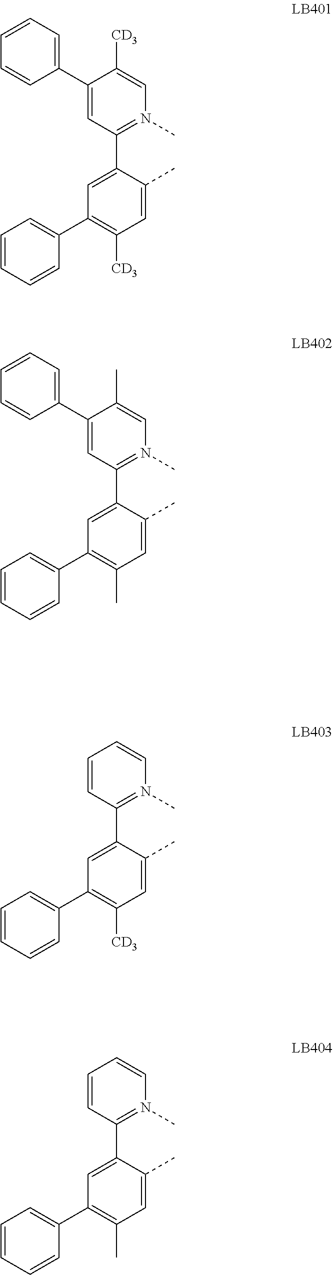

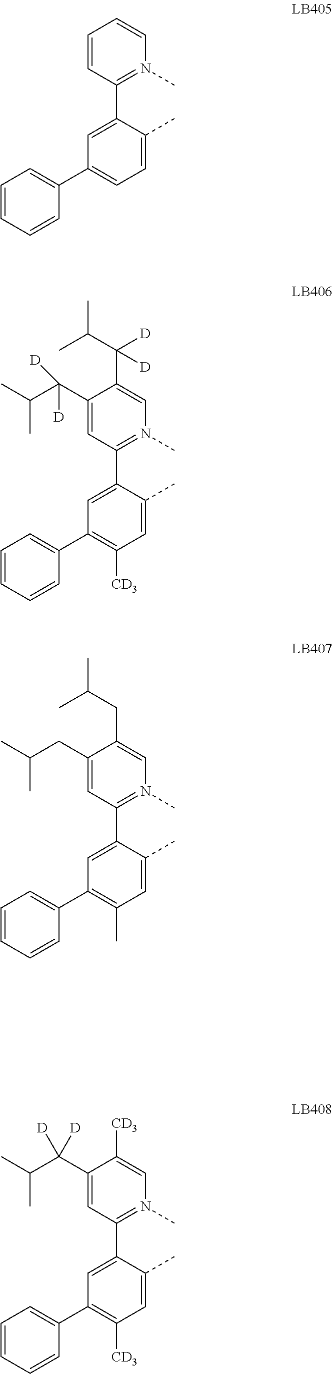

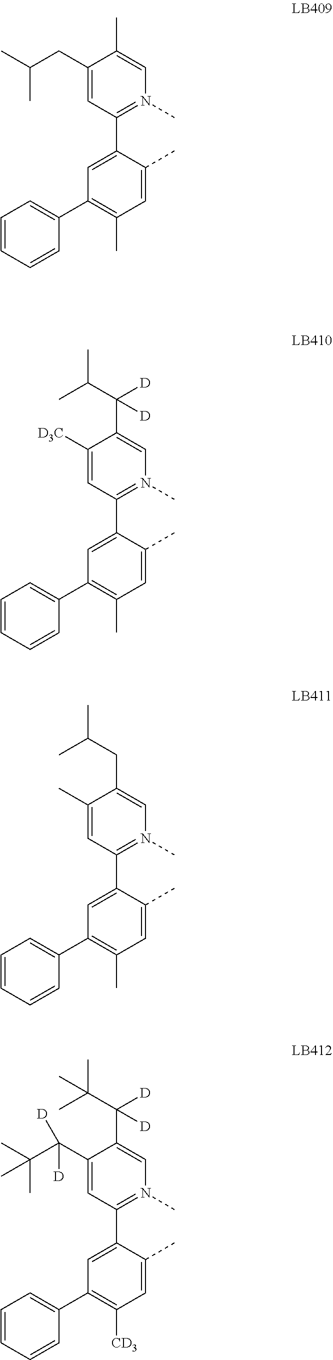

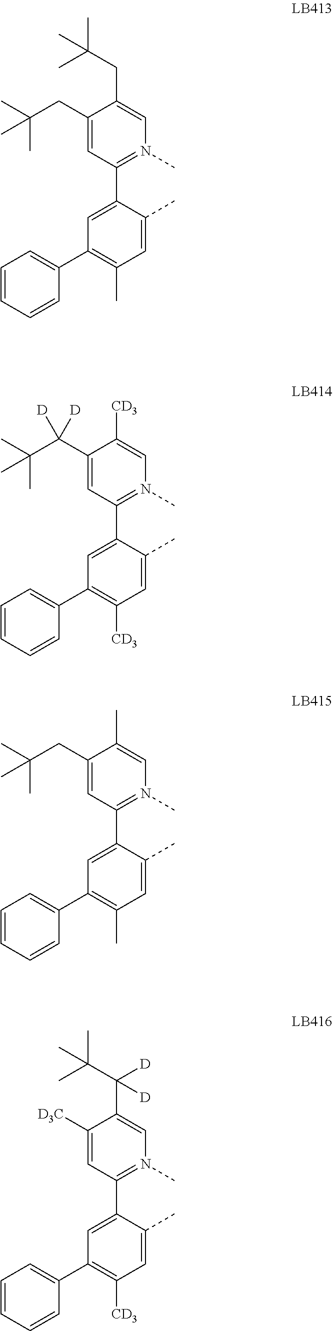

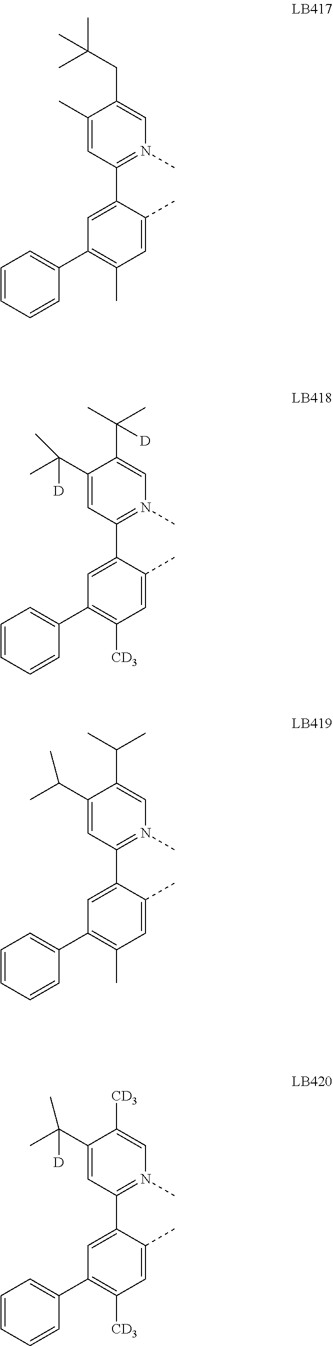

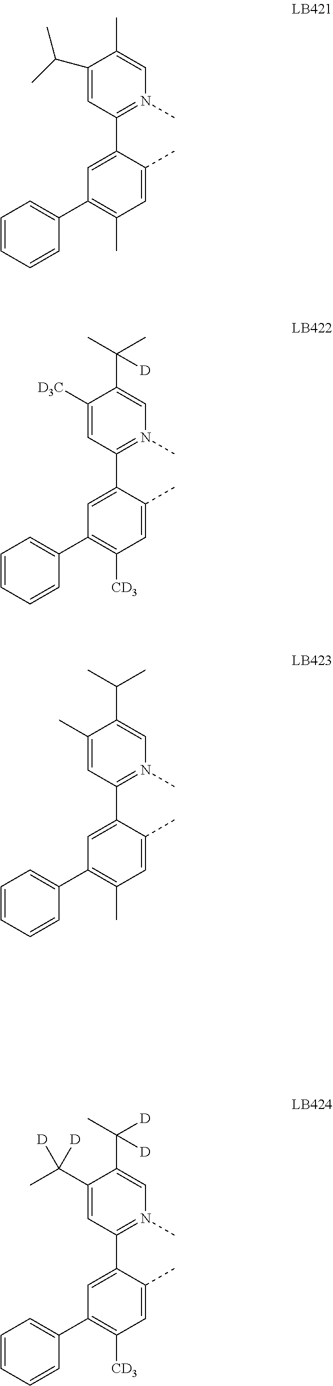

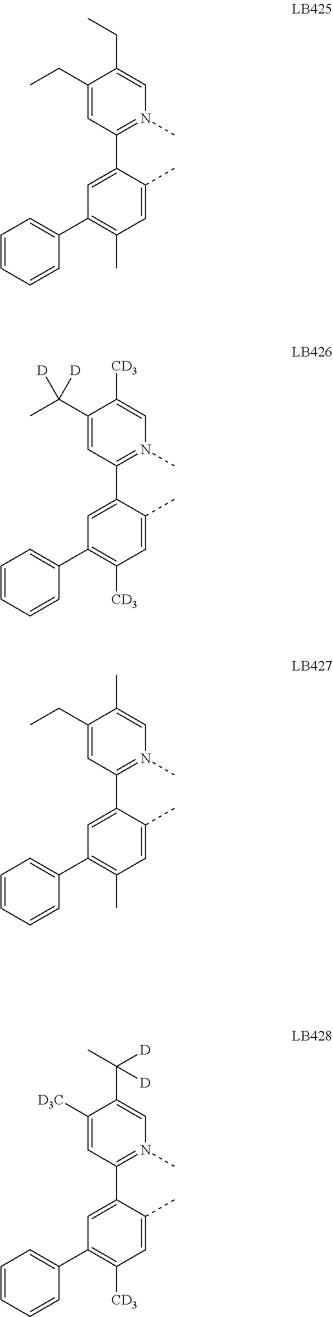

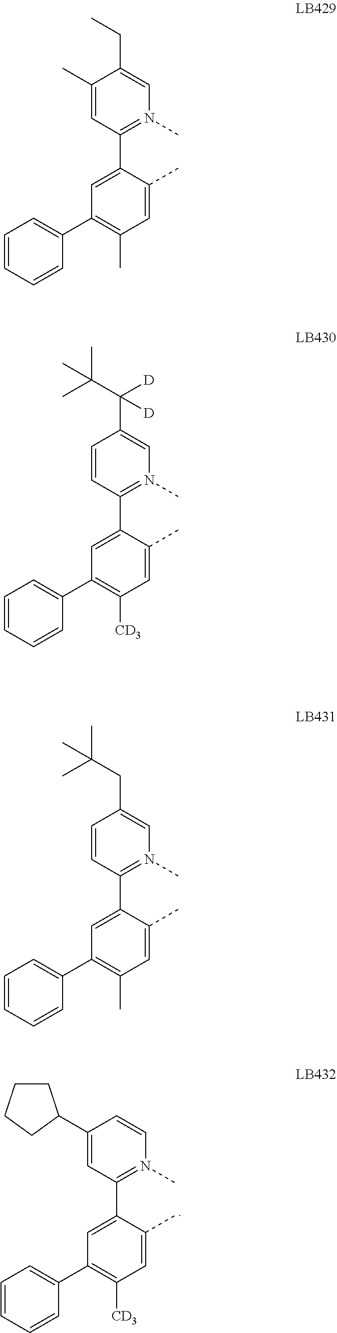

6. The metal complex according to claim 1, wherein the formula (LA) comprises one of LA1-LA208, and the LA1-LA208 have specific structures as follows:

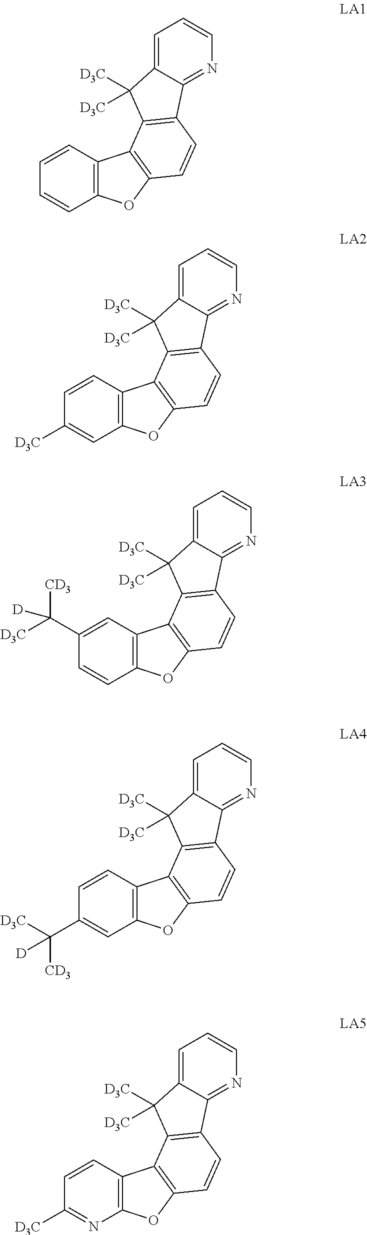 [SMILES: [2H]C([2H])([2H])C1(C([2H])([2H])[2H])c2cccnc2-c2ccc3oc4ccccc4c3c21 ; [2H]C([2H])([2H])c1ccc2c(c1)oc1ccc3c(c12)C(C([2H])([2H])[2H])(C([2H])([2H])[2H])c1cccnc1-3 ; [2H]C([2H])([2H])C([2H])(c1ccc2oc3ccc4c(c3c2c1)C(C([2H])([2H])[2H])(C([2H])([2H])[2H])c1cccnc1-4)C([2H])([2H])[2H] ; [2H]C([2H])([2H])C([2H])(c1ccc2c(c1)oc1ccc3c(c12)C(C([2H])([2H])[2H])(C([2H])([2H])[2H])c1cccnc1-3)C([2H])([2H])[2H] ; [2H]C([2H])([2H])c1ccc2c(n1)oc1ccc3c(c12)C(C([2H])([2H])[2H])(C([2H])([2H])[2H])c1cccnc1-3]

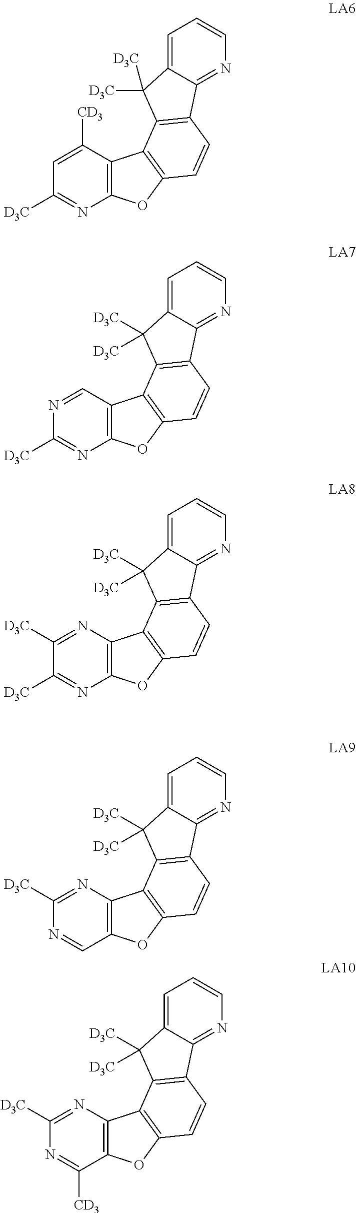

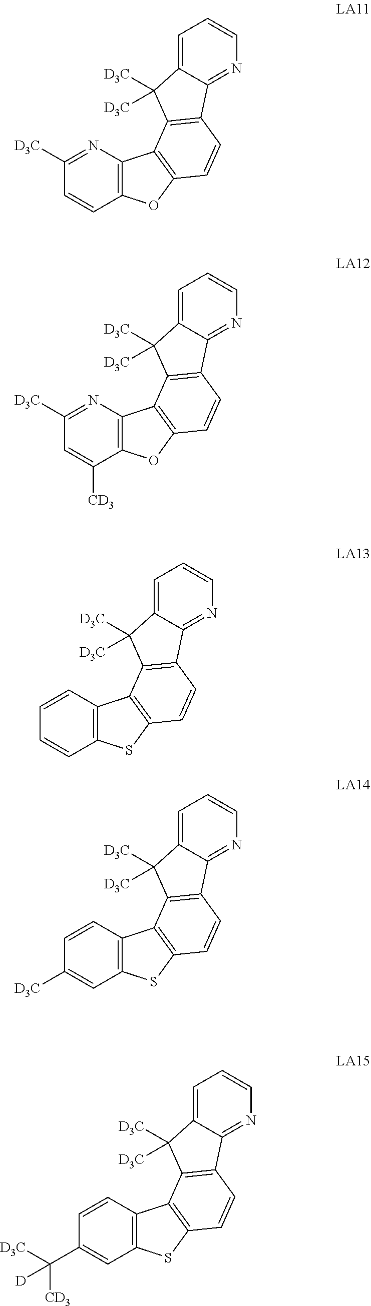 [SMILES: [2H]C([2H])([2H])c1ccc2oc3ccc4c(c3c2n1)C(C([2H])([2H])[2H])(C([2H])([2H])[2H])c1cccnc1-4 ; [2H]C([2H])([2H])c1cc(C([2H])([2H])[2H])c2oc3ccc4c(c3c2n1)C(C([2H])([2H])[2H])(C([2H])([2H])[2H])c1cccnc1-4 ; [2H]C([2H])([2H])C1(C([2H])([2H])[2H])c2cccnc2-c2ccc3sc4ccccc4c3c21 ; [2H]C([2H])([2H])c1ccc2c(c1)sc1ccc3c(c12)C(C([2H])([2H])[2H])(C([2H])([2H])[2H])c1cccnc1-3 ; [2H]C([2H])([2H])C([2H])(c1ccc2c(c1)sc1ccc3c(c12)C(C([2H])([2H])[2H])(C([2H])([2H])[2H])c1cccnc1-3)C([2H])([2H])[2H]]

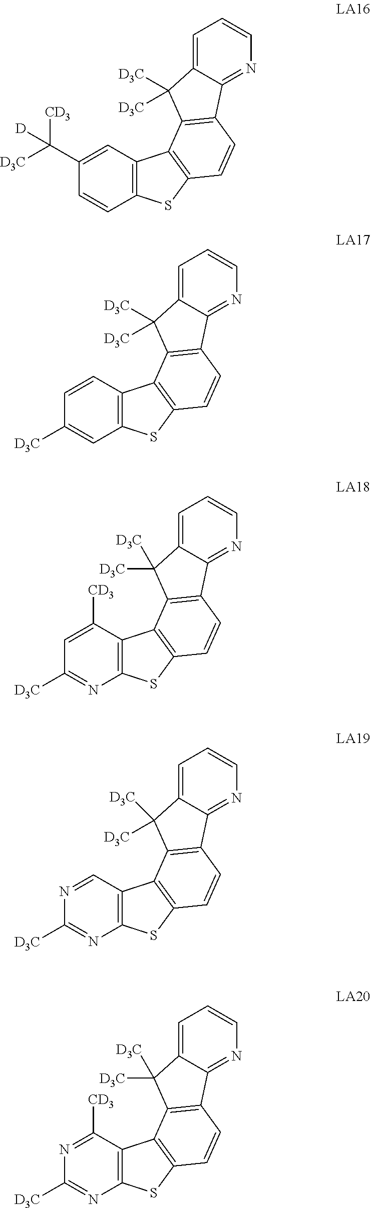

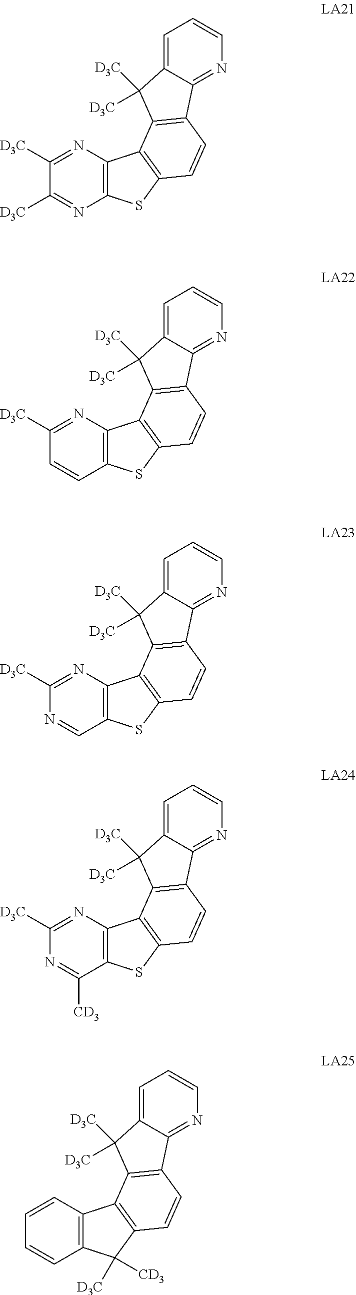

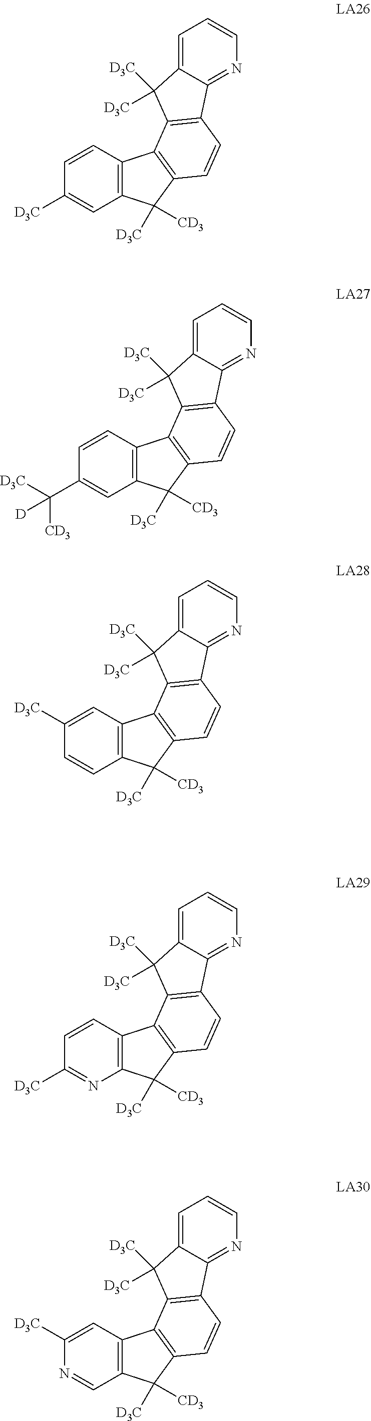

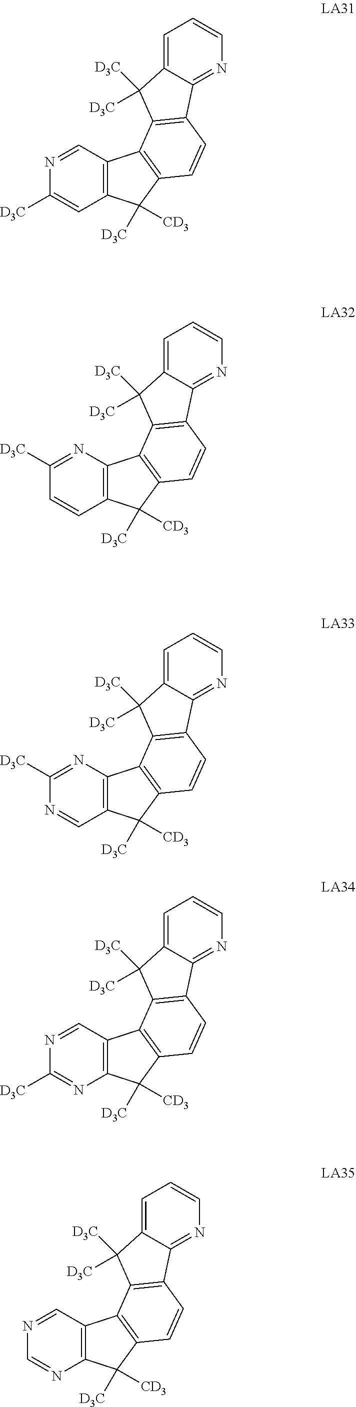

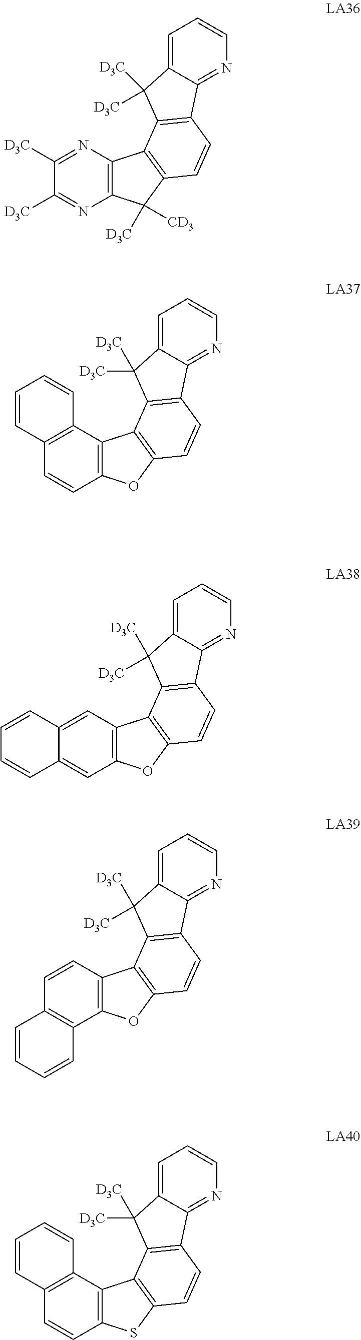 [SMILES: [2H]C([2H])([2H])c1nc2c(nc1C([2H])([2H])[2H])C(C([2H])([2H])[2H])(C([2H])([2H])[2H])c1ccc3c(c1-2)C(C([2H])([2H])[2H])(C([2H])([2H])[2H])c1cccnc1-3 ; [2H]C([2H])([2H])C1(C([2H])([2H])[2H])c2cccnc2-c2ccc3oc4ccc5ccccc5c4c3c21 ; [2H]C([2H])([2H])C1(C([2H])([2H])[2H])c2cccnc2-c2ccc3oc4cc5ccccc5cc4c3c21 ; [2H]C([2H])([2H])C1(C([2H])([2H])[2H])c2cccnc2-c2ccc3oc4c5ccccc5ccc4c3c21 ; [2H]C([2H])([2H])C1(C([2H])([2H])[2H])c2cccnc2-c2ccc3sc4ccc5ccccc5c4c3c21]

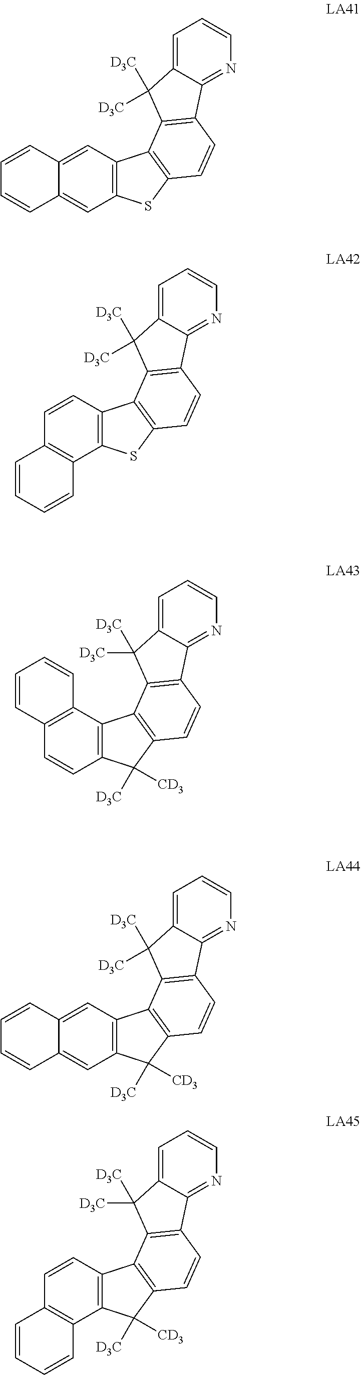 [SMILES: [2H]C([2H])([2H])C1(C([2H])([2H])[2H])c2cccnc2-c2ccc3sc4cc5ccccc5cc4c3c21 ; [2H]C([2H])([2H])C1(C([2H])([2H])[2H])c2cccnc2-c2ccc3sc4c5ccccc5ccc4c3c21 ; [2H]C([2H])([2H])C1(C([2H])([2H])[2H])c2ccc3c(c2-c2c1ccc1ccccc21)C(C([2H])([2H])[2H])(C([2H])([2H])[2H])c1cccnc1-3 ; [2H]C([2H])([2H])C1(C([2H])([2H])[2H])c2cc3ccccc3cc2-c2c1ccc1c2C(C([2H])([2H])[2H])(C([2H])([2H])[2H])c2cccnc2-1 ; [2H]C([2H])([2H])C1(C([2H])([2H])[2H])c2cccnc2-c2ccc3c(c21)-c1ccc2ccccc2c1C3(C([2H])([2H])[2H])C([2H])([2H])[2H]]

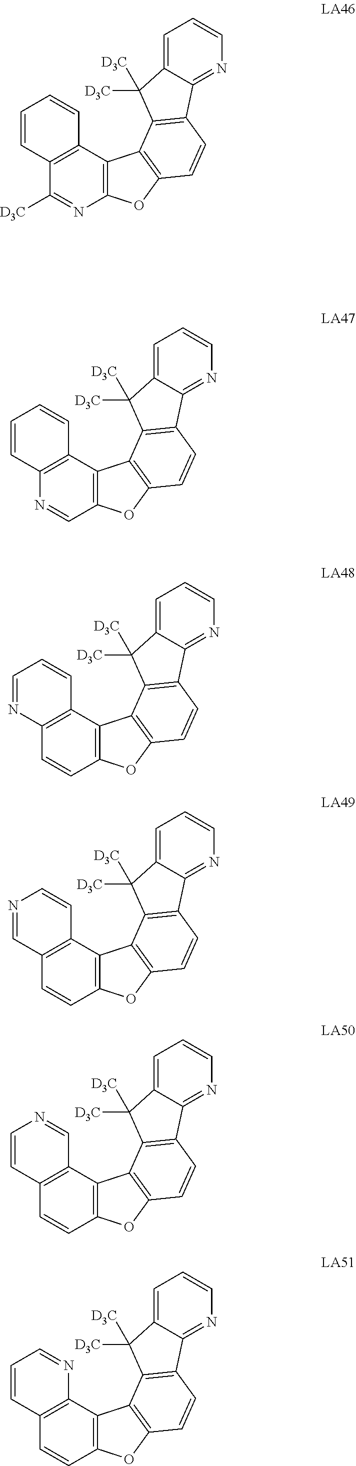 [SMILES: [2H]C([2H])([2H])c1nc2oc3ccc4c(c3c2c2ccccc12)C(C([2H])([2H])[2H])(C([2H])([2H])[2H])c1cccnc1-4 ; [2H]C([2H])([2H])C1(C([2H])([2H])[2H])c2cccnc2-c2ccc3oc4cnc5ccccc5c4c3c21 ; [2H]C([2H])([2H])C1(C([2H])([2H])[2H])c2cccnc2-c2ccc3oc4ccc5ncccc5c4c3c21 ; [2H]C([2H])([2H])C1(C([2H])([2H])[2H])c2cccnc2-c2ccc3oc4ccc5cnccc5c4c3c21 ; [2H]C([2H])([2H])C1(C([2H])([2H])[2H])c2cccnc2-c2ccc3oc4ccc5ccncc5c4c3c21 ; [2H]C([2H])([2H])C1(C([2H])([2H])[2H])c2cccnc2-c2ccc3oc4ccc5cccnc5c4c3c21]

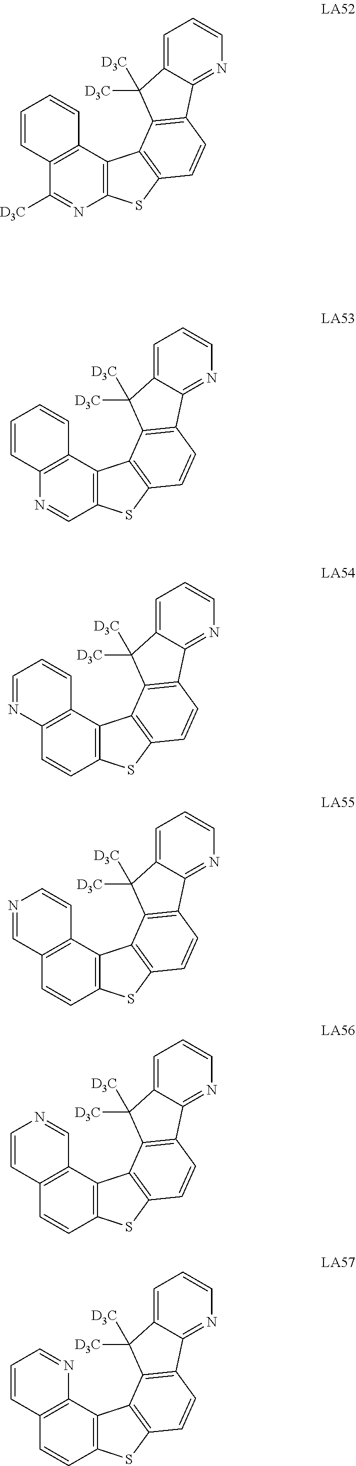 [SMILES: [2H]C([2H])([2H])c1nc2sc3ccc4c(c3c2c2ccccc12)C(C([2H])([2H])[2H])(C([2H])([2H])[2H])c1cccnc1-4 ; [2H]C([2H])([2H])C1(C([2H])([2H])[2H])c2cccnc2-c2ccc3sc4cnc5ccccc5c4c3c21 ; [2H]C([2H])([2H])C1(C([2H])([2H])[2H])c2cccnc2-c2ccc3sc4ccc5ncccc5c4c3c21 ; [2H]C([2H])([2H])C1(C([2H])([2H])[2H])c2cccnc2-c2ccc3sc4ccc5cnccc5c4c3c21 ; [2H]C([2H])([2H])C1(C([2H])([2H])[2H])c2cccnc2-c2ccc3sc4ccc5ccncc5c4c3c21 ; [2H]C([2H])([2H])C1(C([2H])([2H])[2H])c2cccnc2-c2ccc3sc4ccc5cccnc5c4c3c21]

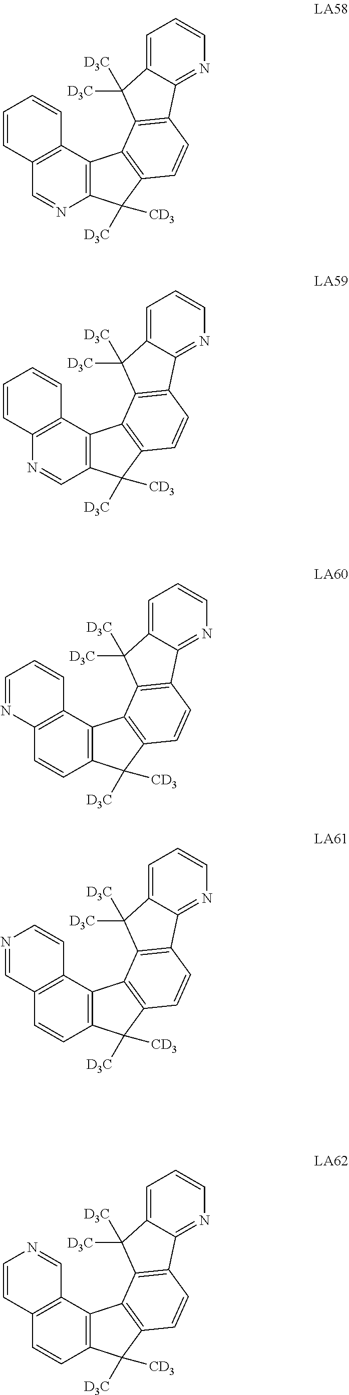

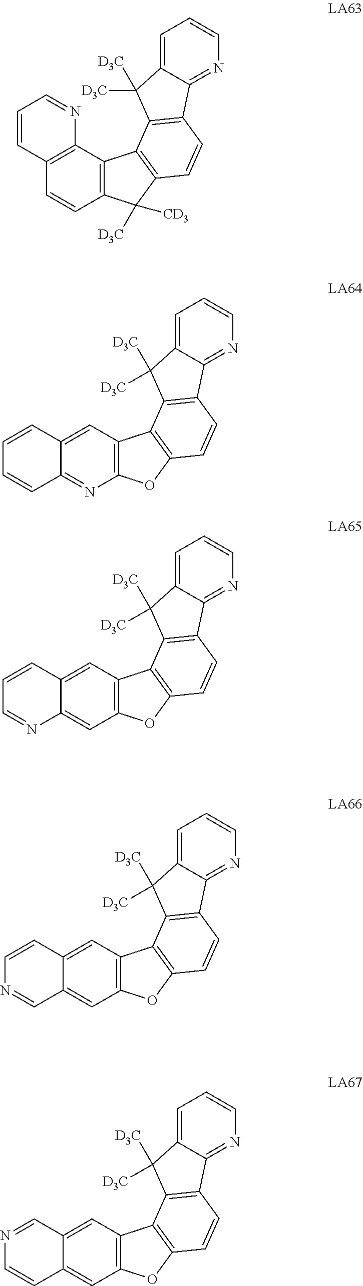 [SMILES: [2H]C([2H])([2H])C1(C([2H])([2H])[2H])c2ccc3c(c2-c2c1ccc1cccnc21)C(C([2H])([2H])[2H])(C([2H])([2H])[2H])c1cccnc1-3 ; [2H]C([2H])([2H])C1(C([2H])([2H])[2H])c2cccnc2-c2ccc3oc4nc5ccccc5cc4c3c21 ; [2H]C([2H])([2H])C1(C([2H])([2H])[2H])c2cccnc2-c2ccc3oc4cc5ncccc5cc4c3c21 ; [2H]C([2H])([2H])C1(C([2H])([2H])[2H])c2cccnc2-c2ccc3oc4cc5cnccc5cc4c3c21 ; [2H]C([2H])([2H])C1(C([2H])([2H])[2H])c2cccnc2-c2ccc3oc4cc5ccncc5cc4c3c21]

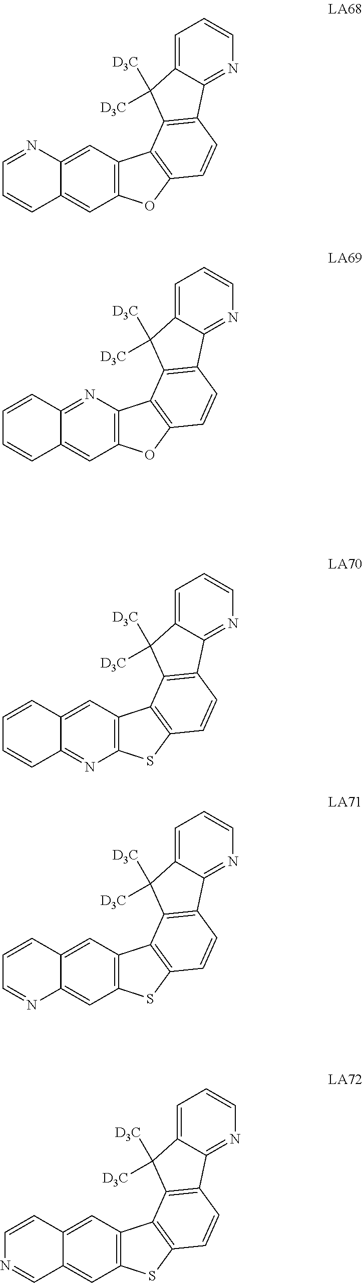 [SMILES: [2H]C([2H])([2H])C1(C([2H])([2H])[2H])c2cccnc2-c2ccc3oc4cc5cccnc5cc4c3c21 ; [2H]C([2H])([2H])C1(C([2H])([2H])[2H])c2cccnc2-c2ccc3oc4cc5ccccc5nc4c3c21 ; [2H]C([2H])([2H])C1(C([2H])([2H])[2H])c2cccnc2-c2ccc3sc4nc5ccccc5cc4c3c21 ; [2H]C([2H])([2H])C1(C([2H])([2H])[2H])c2cccnc2-c2ccc3sc4cc5ncccc5cc4c3c21 ; [2H]C([2H])([2H])C1(C([2H])([2H])[2H])c2cccnc2-c2ccc3sc4cc5cnccc5cc4c3c21]

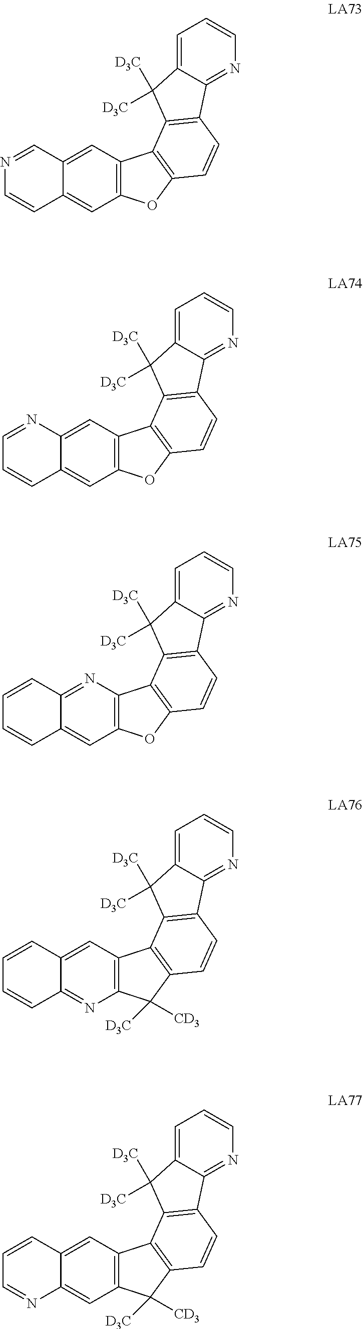 [SMILES: [2H]C([2H])([2H])C1(C([2H])([2H])[2H])c2cccnc2-c2ccc3oc4cc5ccncc5cc4c3c21 ; [2H]C([2H])([2H])C1(C([2H])([2H])[2H])c2cccnc2-c2ccc3oc4cc5cccnc5cc4c3c21 ; [2H]C([2H])([2H])C1(C([2H])([2H])[2H])c2cccnc2-c2ccc3oc4cc5ccccc5nc4c3c21 ; [2H]C([2H])([2H])C1(C([2H])([2H])[2H])c2ccc3c(c2-c2cc4ccccc4nc21)C(C([2H])([2H])[2H])(C([2H])([2H])[2H])c1cccnc1-3 ; [2H]C([2H])([2H])C1(C([2H])([2H])[2H])c2cc3ncccc3cc2-c2c1ccc1c2C(C([2H])([2H])[2H])(C([2H])([2H])[2H])c2cccnc2-1]

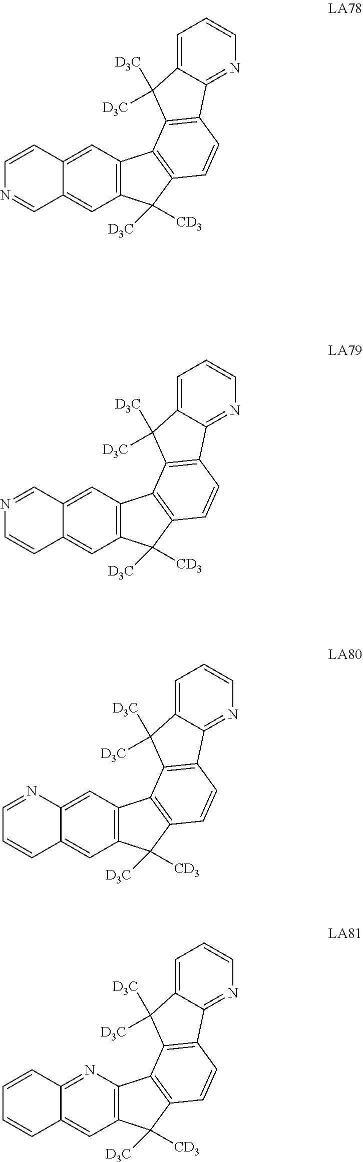 [SMILES: [2H]C([2H])([2H])C1(C([2H])([2H])[2H])c2cc3cnccc3cc2-c2c1ccc1c2C(C([2H])([2H])[2H])(C([2H])([2H])[2H])c2cccnc2-1 ; [2H]C([2H])([2H])C1(C([2H])([2H])[2H])c2cc3ccncc3cc2-c2c1ccc1c2C(C([2H])([2H])[2H])(C([2H])([2H])[2H])c2cccnc2-1 ; [2H]C([2H])([2H])C1(C([2H])([2H])[2H])c2cc3cccnc3cc2-c2c1ccc1c2C(C([2H])([2H])[2H])(C([2H])([2H])[2H])c2cccnc2-1 ; [2H]C([2H])([2H])C1(C([2H])([2H])[2H])c2cc3ccccc3nc2-c2c1ccc1c2C(C([2H])([2H])[2H])(C([2H])([2H])[2H])c2cccnc2-1]

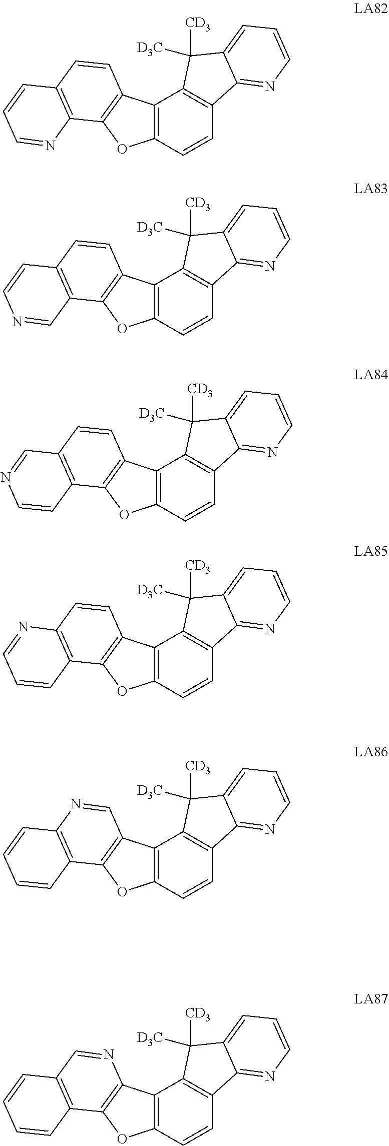

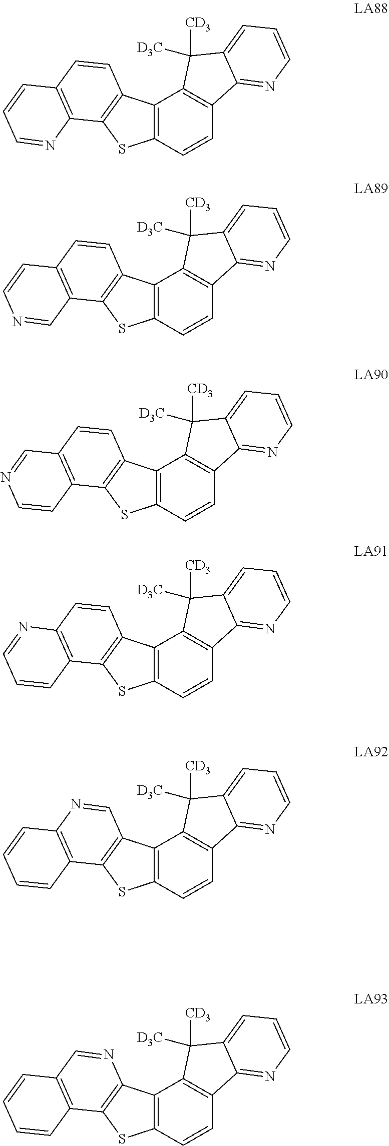

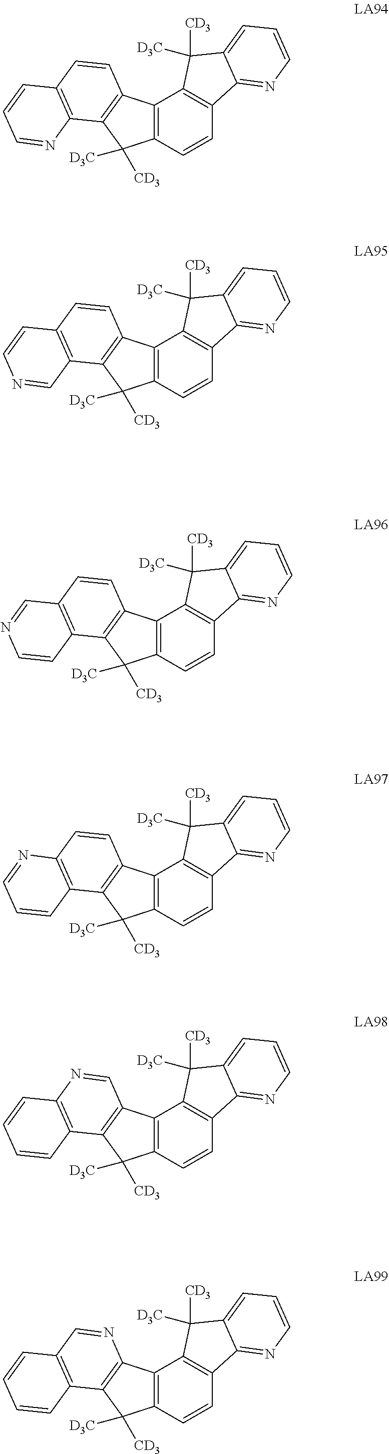

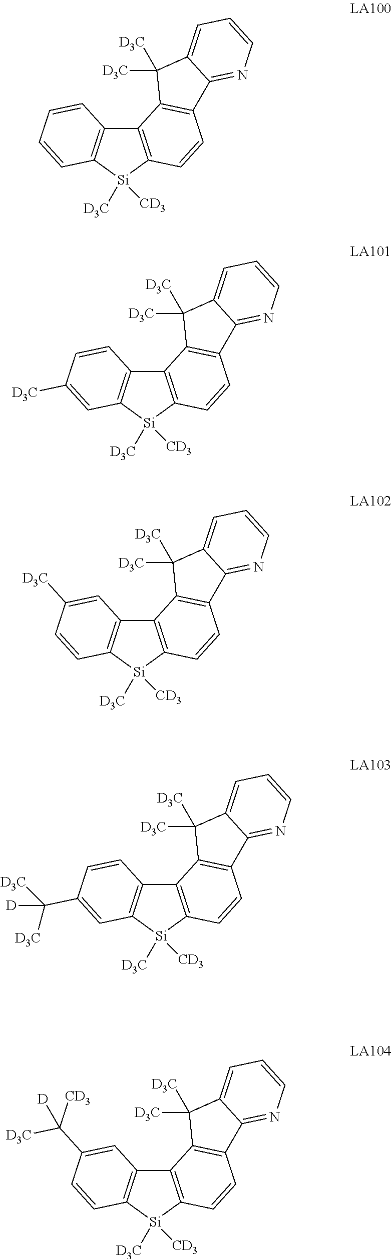

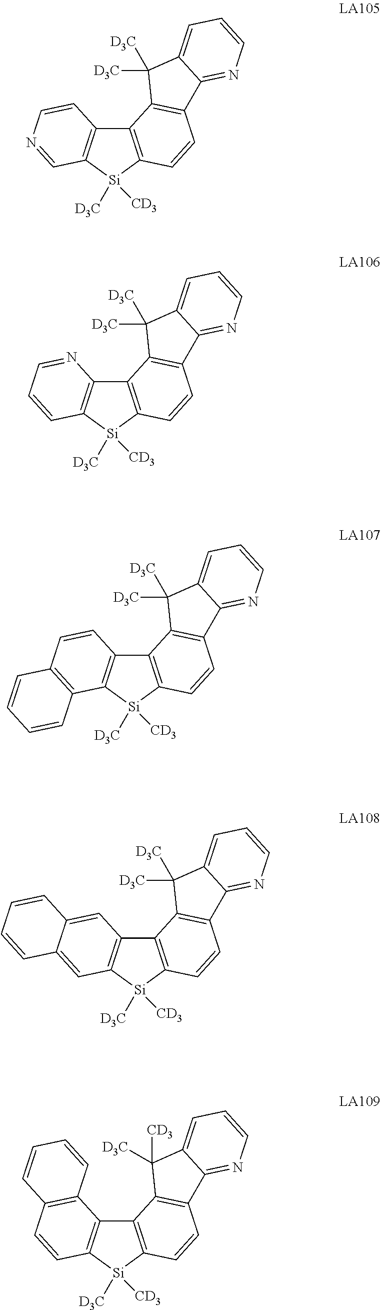

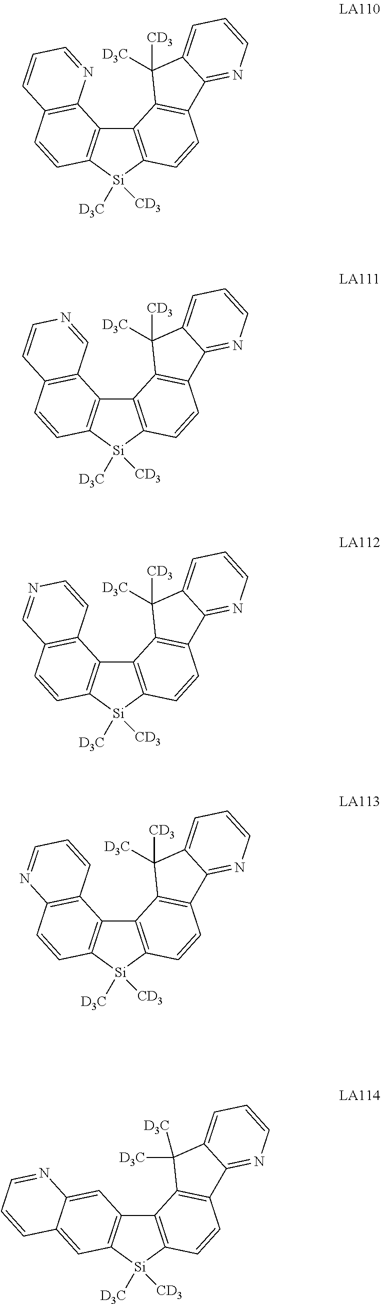

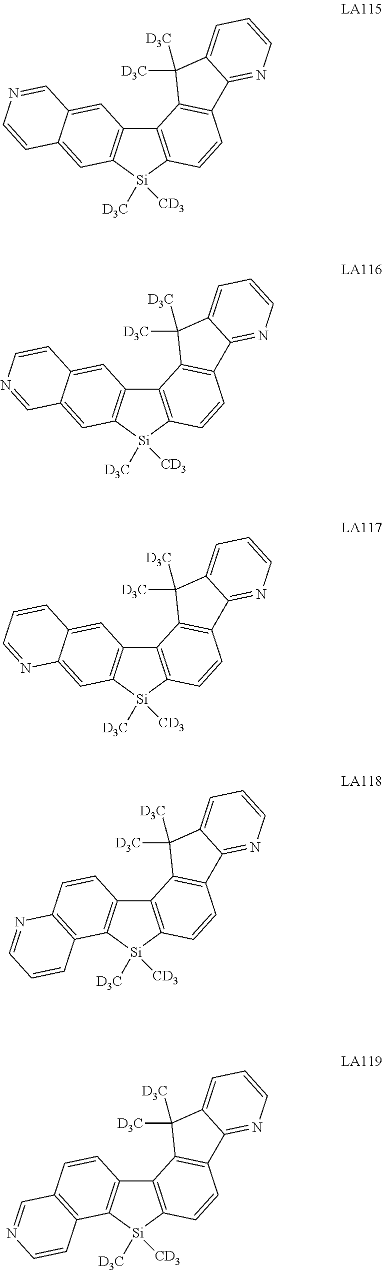

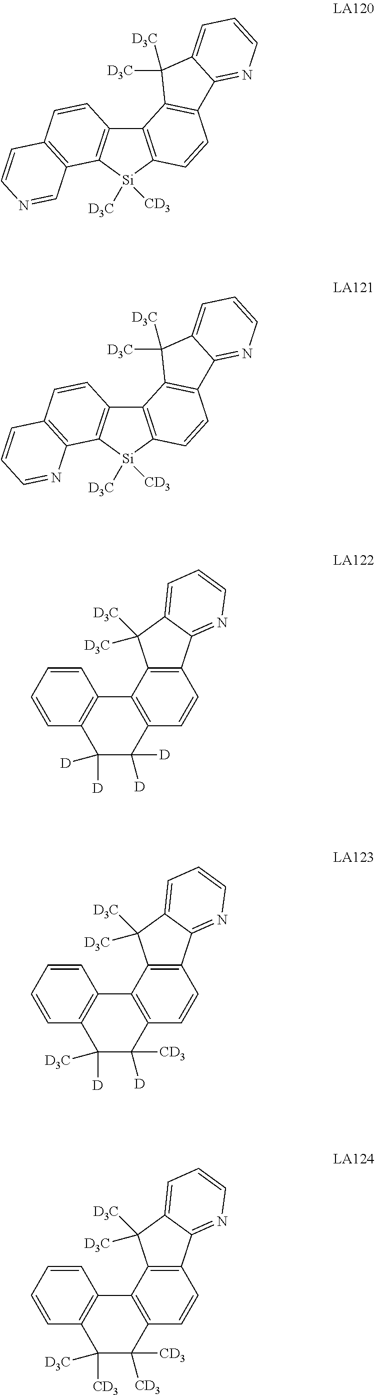

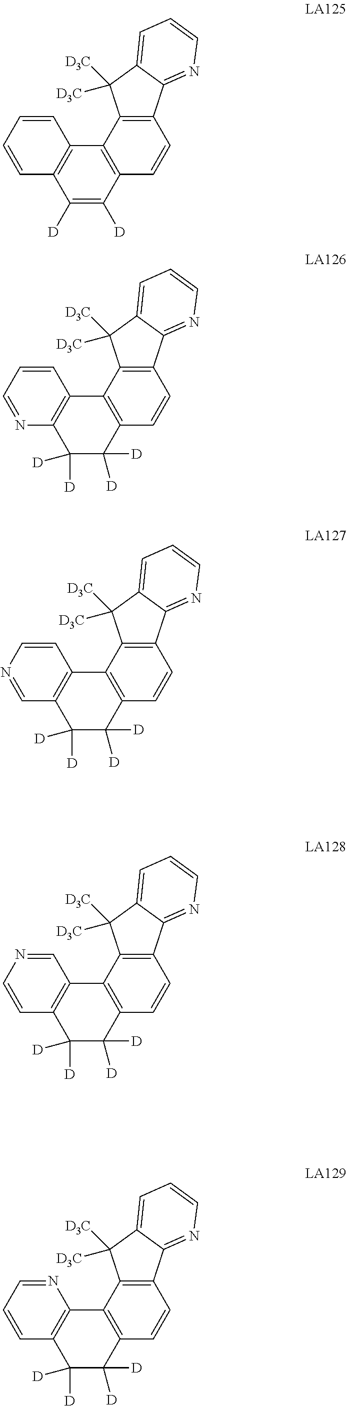 [SMILES: [2H]c1c([2H])c2ccc3c(c2c2ccccc12)C(C([2H])([2H])[2H])(C([2H])([2H])[2H])c1cccnc1-3 ; [2H]C([2H])([2H])C1(C([2H])([2H])[2H])c2cccnc2-c2ccc3c(c21)-c1cccnc1C([2H])([2H])C3([2H])[2H] ; [2H]C([2H])([2H])C1(C([2H])([2H])[2H])c2cccnc2-c2ccc3c(c21)-c1ccncc1C([2H])([2H])C3([2H])[2H] ; [2H]C([2H])([2H])C1(C([2H])([2H])[2H])c2cccnc2-c2ccc3c(c21)-c1cnccc1C([2H])([2H])C3([2H])[2H] ; [2H]C([2H])([2H])C1(C([2H])([2H])[2H])c2cccnc2-c2ccc3c(c21)-c1ncccc1C([2H])([2H])C3([2H])[2H]]

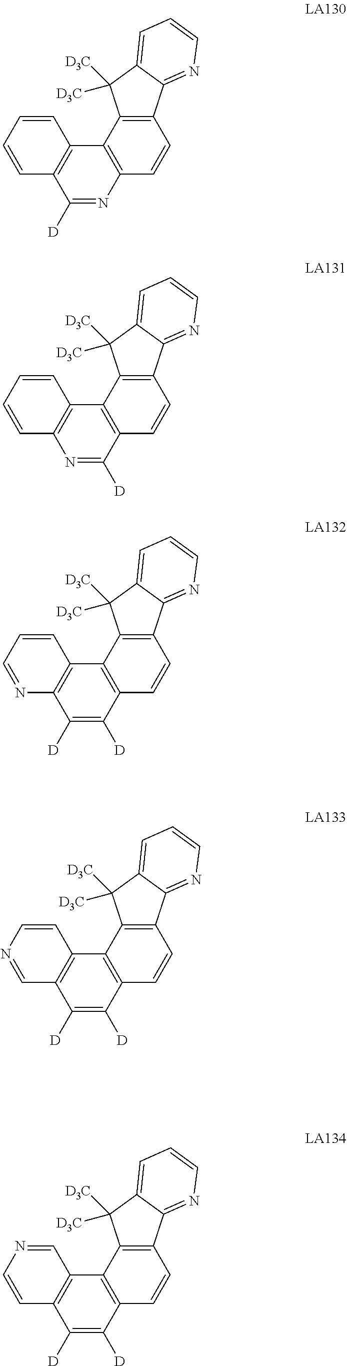 [SMILES: [2H]c1nc2ccc3c(c2c2ccccc12)C(C([2H])([2H])[2H])(C([2H])([2H])[2H])c1cccnc1-3 ; [2H]c1nc2ccccc2c2c3c(ccc12)-c1ncccc1C3(C([2H])([2H])[2H])C([2H])([2H])[2H] ; [2H]c1c([2H])c2ncccc2c2c3c(ccc12)-c1ncccc1C3(C([2H])([2H])[2H])C([2H])([2H])[2H] ; [2H]c1c([2H])c2ccc3c(c2c2ccncc12)C(C([2H])([2H])[2H])(C([2H])([2H])[2H])c1cccnc1-3 ; [2H]c1c([2H])c2ccc3c(c2c2cnccc12)C(C([2H])([2H])[2H])(C([2H])([2H])[2H])c1cccnc1-3]

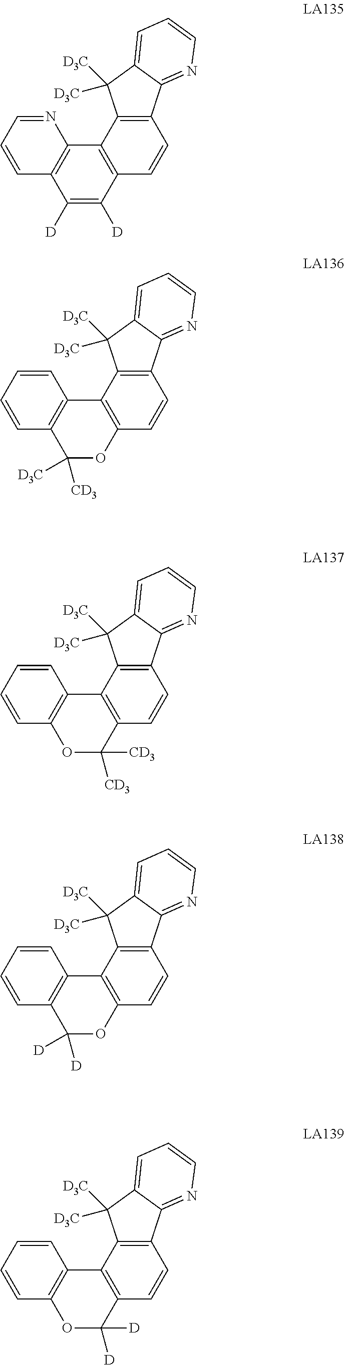 [SMILES: [2H]c1c([2H])c2ccc3c(c2c2ncccc12)C(C([2H])([2H])[2H])(C([2H])([2H])[2H])c1cccnc1-3 ; [2H]C([2H])([2H])C1(C([2H])([2H])[2H])Oc2ccc3c(c2-c2ccccc21)C(C([2H])([2H])[2H])(C([2H])([2H])[2H])c1cccnc1-3 ; [2H]C([2H])([2H])C1(C([2H])([2H])[2H])Oc2ccccc2-c2c1ccc1c2C(C([2H])([2H])[2H])(C([2H])([2H])[2H])c2cccnc2-1 ; [2H]C1([2H])Oc2ccc3c(c2-c2ccccc21)C(C([2H])([2H])[2H])(C([2H])([2H])[2H])c1cccnc1-3 ; [2H]C1([2H])Oc2ccccc2-c2c1ccc1c2C(C([2H])([2H])[2H])(C([2H])([2H])[2H])c2cccnc2-1]

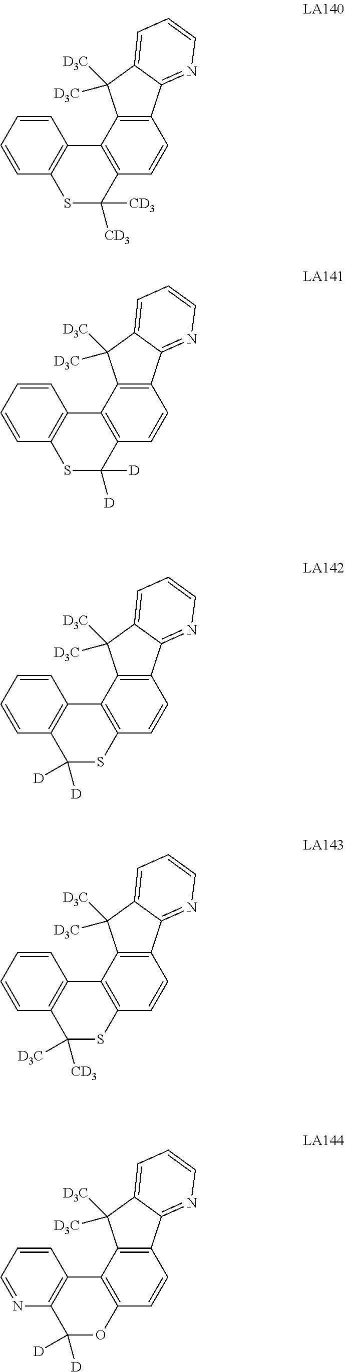 [SMILES: [2H]C([2H])([2H])C1(C([2H])([2H])[2H])Sc2ccccc2-c2c1ccc1c2C(C([2H])([2H])[2H])(C([2H])([2H])[2H])c2cccnc2-1 ; [2H]C1([2H])Sc2ccccc2-c2c1ccc1c2C(C([2H])([2H])[2H])(C([2H])([2H])[2H])c2cccnc2-1 ; [2H]C1([2H])Sc2ccc3c(c2-c2ccccc21)C(C([2H])([2H])[2H])(C([2H])([2H])[2H])c1cccnc1-3 ; [2H]C([2H])([2H])C1(C([2H])([2H])[2H])Sc2ccc3c(c2-c2ccccc21)C(C([2H])([2H])[2H])(C([2H])([2H])[2H])c1cccnc1-3 ; [2H]C1([2H])Oc2ccc3c(c2-c2cccnc21)C(C([2H])([2H])[2H])(C([2H])([2H])[2H])c1cccnc1-3]

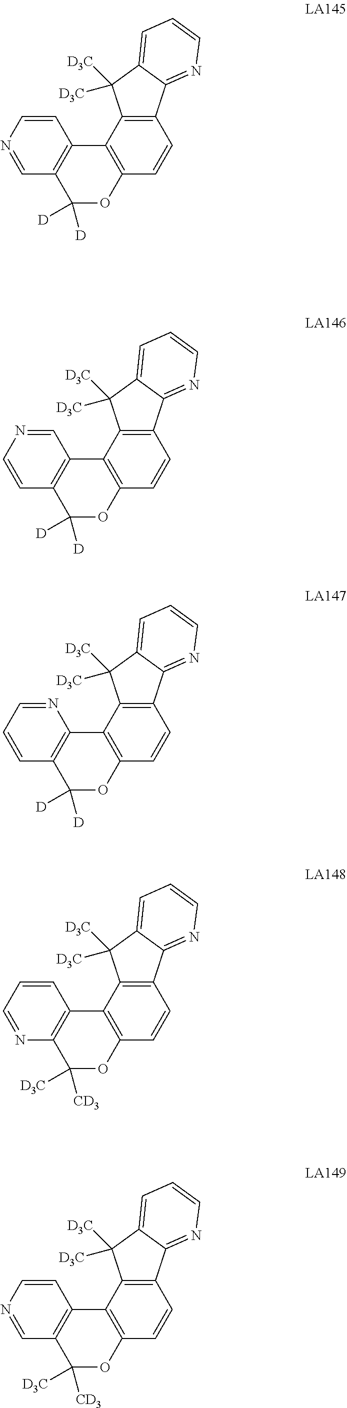 [SMILES: [2H]C1([2H])Oc2ccc3c(c2-c2ccncc21)C(C([2H])([2H])[2H])(C([2H])([2H])[2H])c1cccnc1-3 ; [2H]C1([2H])Oc2ccc3c(c2-c2cnccc21)C(C([2H])([2H])[2H])(C([2H])([2H])[2H])c1cccnc1-3 ; [2H]C1([2H])Oc2ccc3c(c2-c2ncccc21)C(C([2H])([2H])[2H])(C([2H])([2H])[2H])c1cccnc1-3 ; [2H]C([2H])([2H])C1(C([2H])([2H])[2H])Oc2ccc3c(c2-c2cccnc21)C(C([2H])([2H])[2H])(C([2H])([2H])[2H])c1cccnc1-3 ; [2H]C([2H])([2H])C1(C([2H])([2H])[2H])Oc2ccc3c(c2-c2ccncc21)C(C([2H])([2H])[2H])(C([2H])([2H])[2H])c1cccnc1-3]

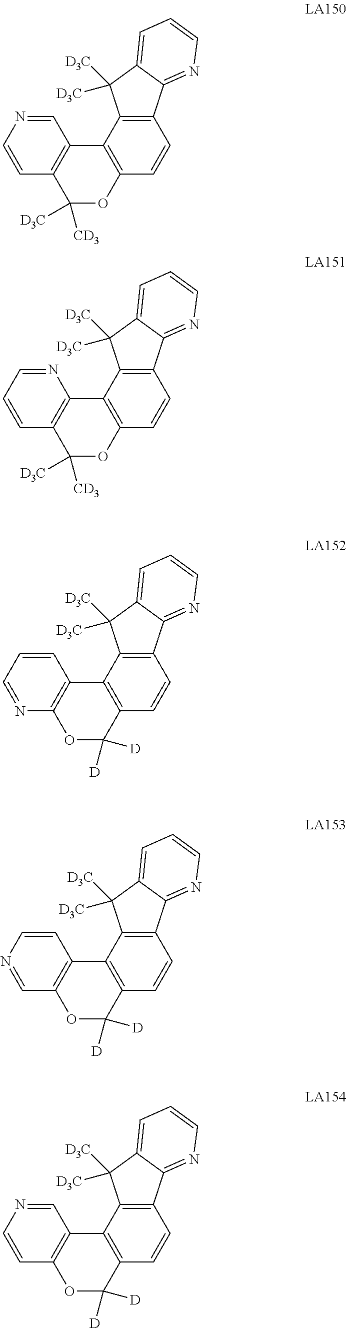 [SMILES: [2H]C([2H])([2H])C1(C([2H])([2H])[2H])Oc2ccc3c(c2-c2cnccc21)C(C([2H])([2H])[2H])(C([2H])([2H])[2H])c1cccnc1-3 ; [2H]C([2H])([2H])C1(C([2H])([2H])[2H])Oc2ccc3c(c2-c2ncccc21)C(C([2H])([2H])[2H])(C([2H])([2H])[2H])c1cccnc1-3 ; [2H]C1([2H])Oc2ncccc2-c2c1ccc1c2C(C([2H])([2H])[2H])(C([2H])([2H])[2H])c2cccnc2-1 ; [2H]C1([2H])Oc2cnccc2-c2c1ccc1c2C(C([2H])([2H])[2H])(C([2H])([2H])[2H])c2cccnc2-1 ; [2H]C1([2H])Oc2ccncc2-c2c1ccc1c2C(C([2H])([2H])[2H])(C([2H])([2H])[2H])c2cccnc2-1]

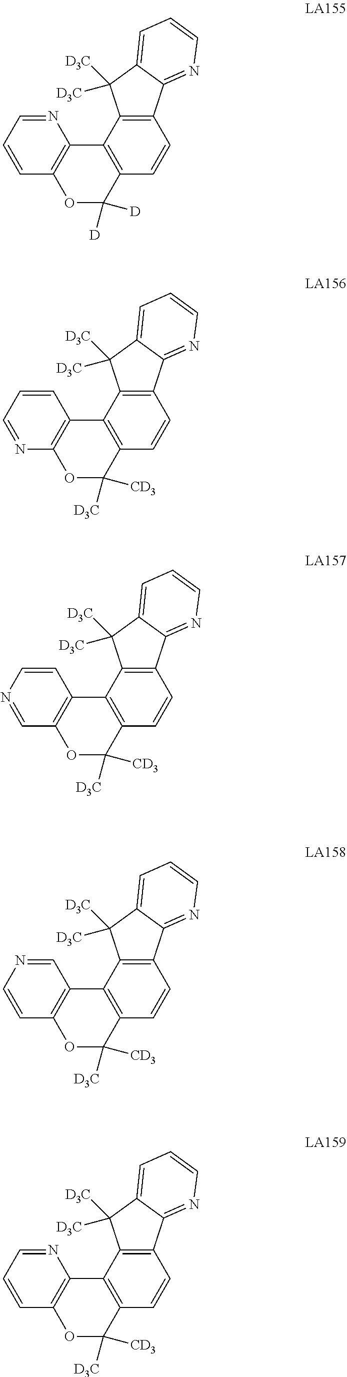

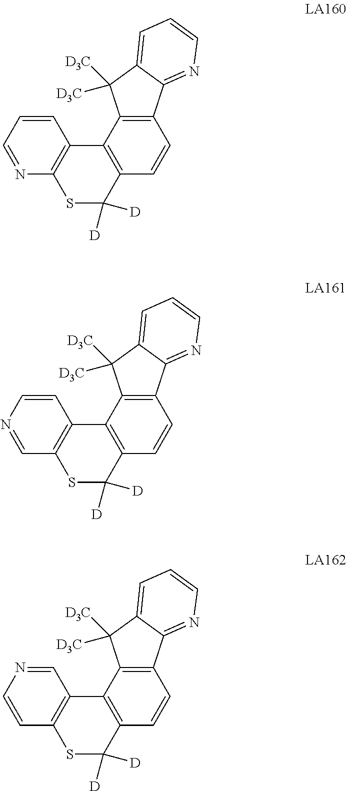 [SMILES: [2H]C1([2H])Sc2ncccc2-c2c1ccc1c2C(C([2H])([2H])[2H])(C([2H])([2H])[2H])c2cccnc2-1 ; [2H]C1([2H])Sc2cnccc2-c2c1ccc1c2C(C([2H])([2H])[2H])(C([2H])([2H])[2H])c2cccnc2-1 ; [2H]C1([2H])Sc2ccncc2-c2c1ccc1c2C(C([2H])([2H])[2H])(C([2H])([2H])[2H])c2cccnc2-1]

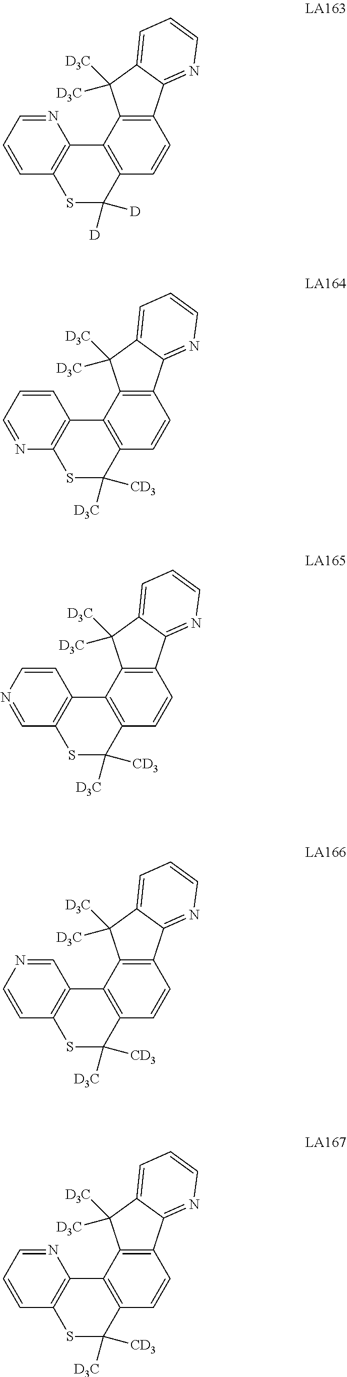

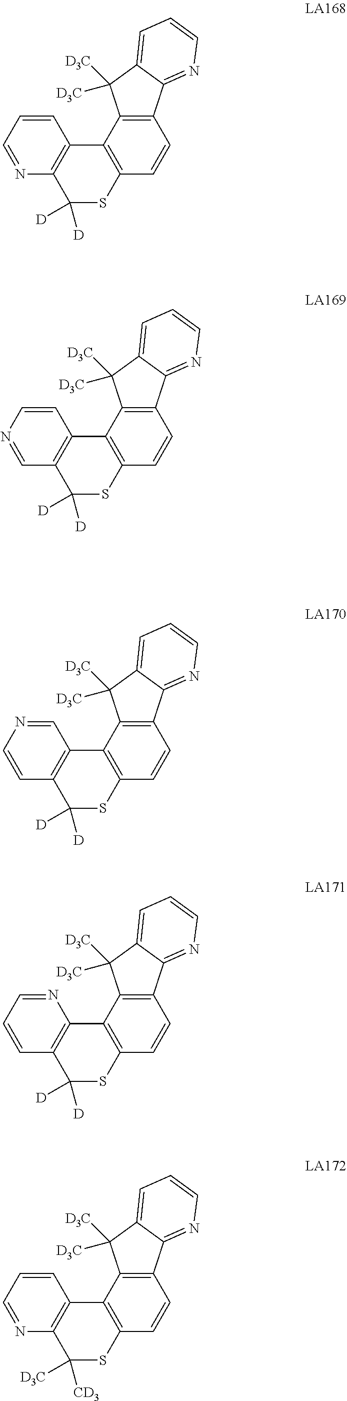 [SMILES: [2H]C1([2H])Sc2ccc3c(c2-c2cccnc21)C(C([2H])([2H])[2H])(C([2H])([2H])[2H])c1cccnc1-3 ; [2H]C1([2H])Sc2ccc3c(c2-c2ccncc21)C(C([2H])([2H])[2H])(C([2H])([2H])[2H])c1cccnc1-3 ; [2H]C1([2H])Sc2ccc3c(c2-c2cnccc21)C(C([2H])([2H])[2H])(C([2H])([2H])[2H])c1cccnc1-3 ; [2H]C1([2H])Sc2ccc3c(c2-c2ncccc21)C(C([2H])([2H])[2H])(C([2H])([2H])[2H])c1cccnc1-3 ; [2H]C([2H])([2H])C1(C([2H])([2H])[2H])Sc2ccc3c(c2-c2cccnc21)C(C([2H])([2H])[2H])(C([2H])([2H])[2H])c1cccnc1-3]

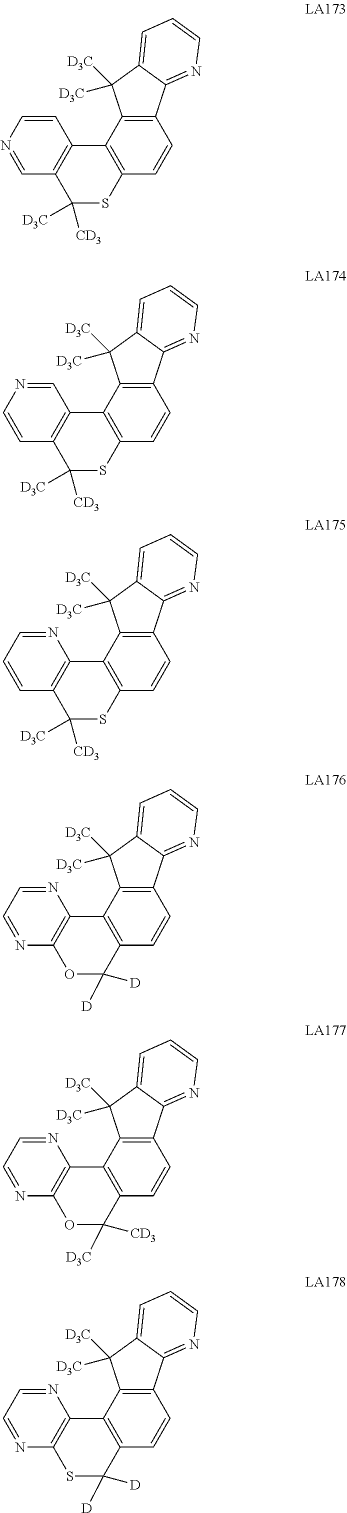

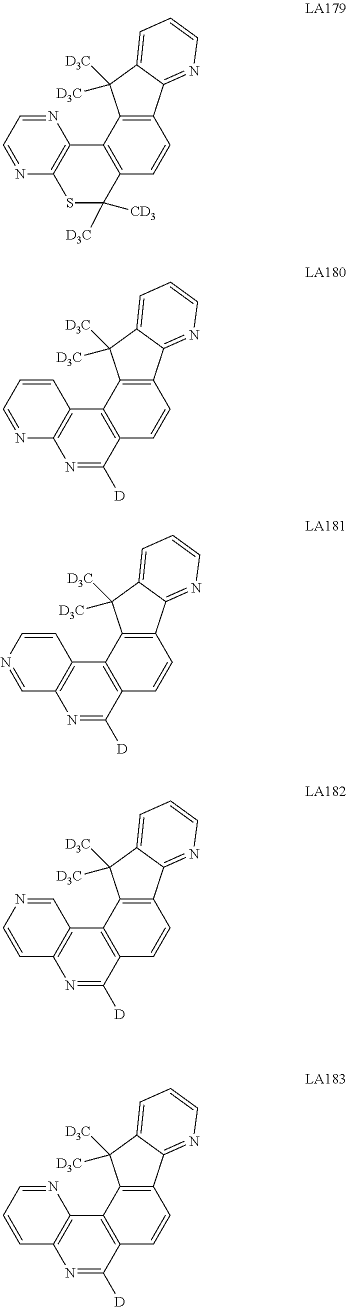 [SMILES: [2H]C([2H])([2H])C1(C([2H])([2H])[2H])Sc2nccnc2-c2c1ccc1c2C(C([2H])([2H])[2H])(C([2H])([2H])[2H])c2cccnc2-1 ; [2H]c1nc2ncccc2c2c3c(ccc12)-c1ncccc1C3(C([2H])([2H])[2H])C([2H])([2H])[2H] ; [2H]c1nc2cnccc2c2c3c(ccc12)-c1ncccc1C3(C([2H])([2H])[2H])C([2H])([2H])[2H] ; [2H]c1nc2ccncc2c2c3c(ccc12)-c1ncccc1C3(C([2H])([2H])[2H])C([2H])([2H])[2H] ; [2H]c1nc2cccnc2c2c3c(ccc12)-c1ncccc1C3(C([2H])([2H])[2H])C([2H])([2H])[2H]]

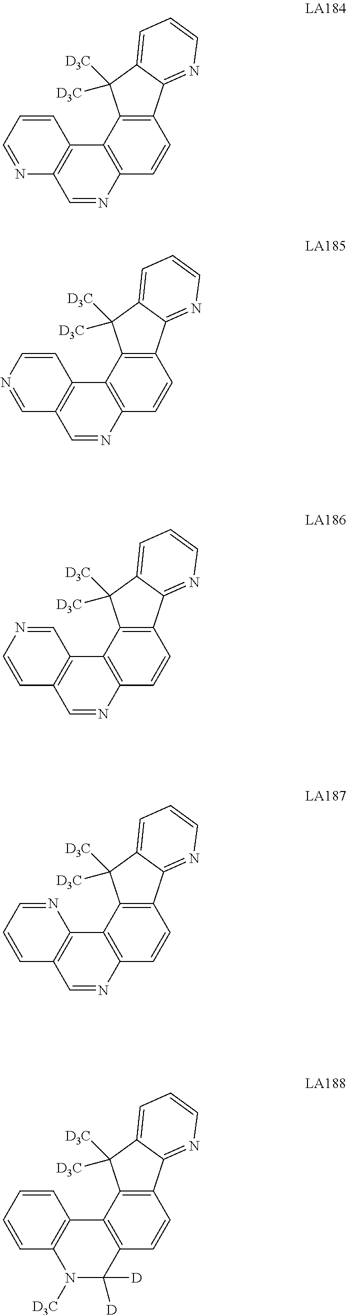 [SMILES: [2H]C([2H])([2H])C1(C([2H])([2H])[2H])c2cccnc2-c2ccc3ncc4ncccc4c3c21 ; [2H]C([2H])([2H])C1(C([2H])([2H])[2H])c2cccnc2-c2ccc3ncc4cnccc4c3c21 ; [2H]C([2H])([2H])C1(C([2H])([2H])[2H])c2cccnc2-c2ccc3ncc4ccncc4c3c21 ; [2H]C([2H])([2H])C1(C([2H])([2H])[2H])c2cccnc2-c2ccc3ncc4cccnc4c3c21 ; [2H]C([2H])([2H])N1c2ccccc2-c2c(ccc3c2C(C([2H])([2H])[2H])(C([2H])([2H])[2H])c2cccnc2-3)C1([2H])[2H]]

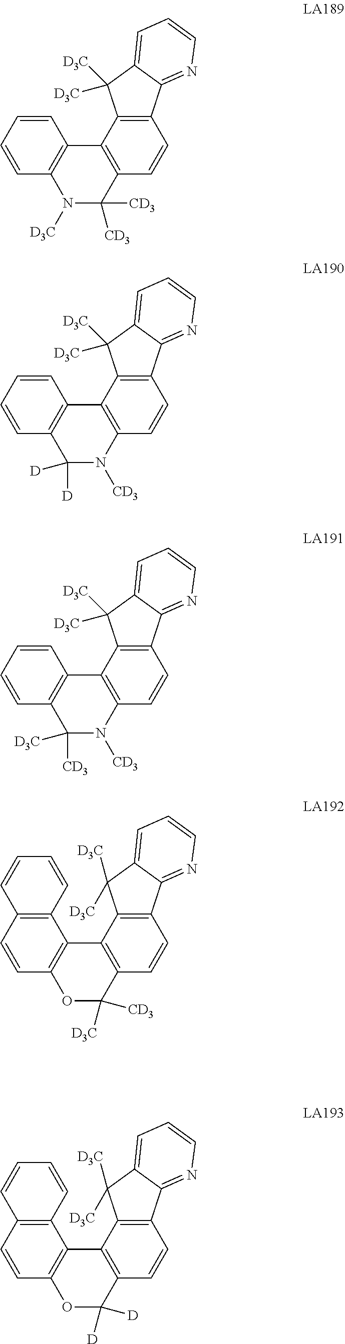

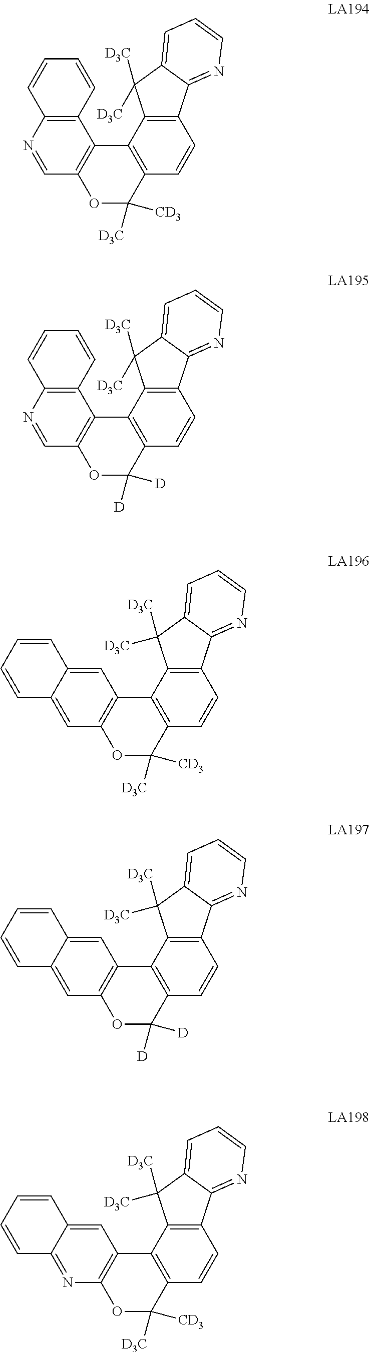

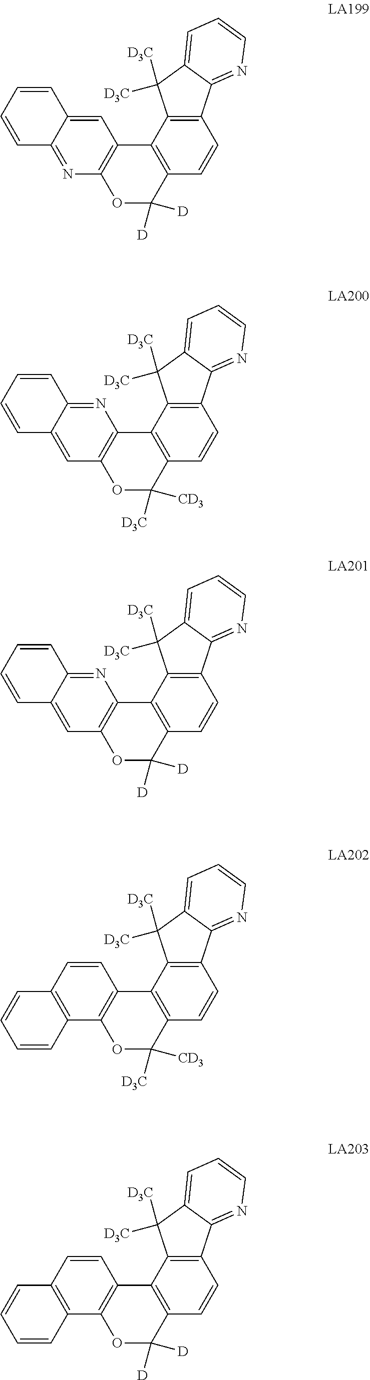

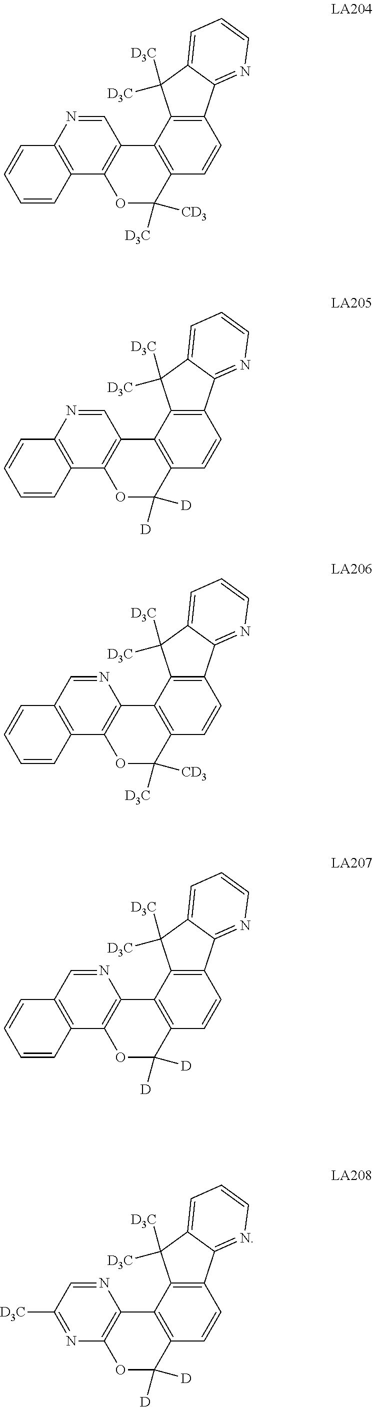

7. The metal complex according to claim 5, wherein the metal complex has a chemical formula of Ir(LAi)(LBj)₂, Ir(LAi)₂(LBj) or Ir(LAi)₃, wherein the i is an integer of 1-208 and the j is an integer of 1-432.

8. An organic electroluminescent element, comprising a first electrode, a second electrode, and an organic layer arranged between the first electrode and the second electrode, wherein the organic layer comprises the metal complex according to claim 1.

9. The organic electroluminescent element according to claim 8, wherein the organic layer further comprises a host material comprising the following chemical groups: the group consisting of triphenylene, carbazole, dibenzothiophene, dibenzofuran, dibenzoselenophene, azatriphenylene, azacarbazole, azadibenzothiophene, azadibenzofuran, and azadibenzoselenophene.

10. A consumer product made from the organic electroluminescent element according to claim 8.
